(19) United States
(12) Patent Application Publication
(10) Pub. No.: US 2026/0123282 A1
(43) Pub. Date: Apr. 30, 2026

(54) POLYCYCLIC COMPOUND, LIGHT-EMITTING DEVICE AND ELECTRONIC DEVICE

(71) Applicant: Samsung Display Co., Ltd., Yongin-si (KR)

(72) Inventors: Hirokazu MIYASHITA, Yongin-si (KR); Hyung Jong KIM, Yongin-si (KR); Jun Ha PARK, Yongin-si (KR); Han Kyu PAK, Yongin-si (KR); Min Jae SUNG, Yongin-si (KR); Mun Ki SIM, Yongin-si (KR); Min Jung JUNG, Yongin-si (KR)

(21) Appl. No.: 19/278,121

(22) Filed: Jul. 23, 2025

(30) Foreign Application Priority Data
Oct. 31, 2024 (KR) 10-2024-0151691

(51) Int. Cl. H10K 85/60; C07B 59/00; C07F 5/02; C09K 11/06; H10K 50/115; H10K 101/00; H10K 101/20

(52) U.S. Cl. CPC H10K 85/658; C07B 59/004; C07F 5/027; C09K 11/06; H10K 85/654; H10K 85/6572; H10K 85/6576; C07B 2200/05; C09K 2211/1007; C09K 2211/1018; H10K 50/115; H10K 2101/20; H10K 2101/27

(57) ABSTRACT

A light-emitting device includes a first electrode, a second electrode, and an emission layer between the first electrode and the second electrode, where the emission layer includes a polycyclic compound represented by Chemical Formula 1. In addition, an electronic device that includes the light-emitting device, an electronic apparatus that includes the light-emitting device, and the polycyclic compound are also provided.

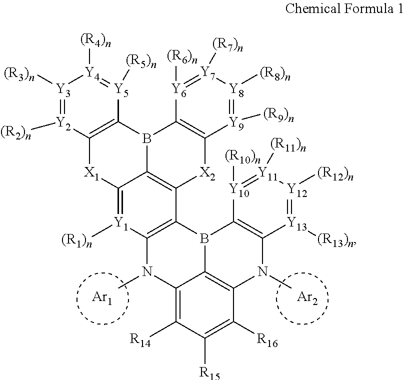

### CROSS-REFERENCE TO RELATED APPLICATION

The present application claims priority to and the benefit of Korean Patent Application No. 10-2024-0151691, filed on Oct. 31, 2024, in the Korean Intellectual Property Office, the entire disclosure of which is incorporated herein by reference.

### BACKGROUND

### 1. Field

One or more embodiments of the present disclosure relate to a polycyclic compound, a light-emitting device, and an electronic device.

### 2. Description of the Related Art

An organic light-emitting device has a self-luminous property under a driving voltage and may provide improved viewing angle and contrast properties. Additionally, the organic light-emitting device has characteristics of high response speed and high luminance compared to other light-emitting devices of the comparable art.

The organic light-emitting device may include an emission layer arranged between a first electrode and a second electrode. Holes provided from the first electrode and electrons provided from the second electrode may be recombined in the emission layer to generate excitons. As the excitons transition and decay from an excited state to a ground state, light is emitted from the emission layer.

The emission layer may include a host material and a dopant material to implement the above-described light emitting mechanism.

### SUMMARY

One or more aspects of embodiments of the present disclosure are directed toward a polycyclic compound having improved oxidation stability and intramolecular charge transfer (CT) properties.

One or more aspects of embodiments of the present disclosure are directed toward a light-emitting device having improved light-emitting and life-span properties.

One or more aspects of embodiments of the present disclosure are directed toward an electronic device including the light-emitting device.

Additional aspects will be set forth in part in the description which follows and, in part, will be apparent from the description, or may be learned by practice of the presented embodiments of the disclosure.

According to one or more embodiments of the present disclosure, a polycyclic compound represented by Chemical Formula 1 is provided.

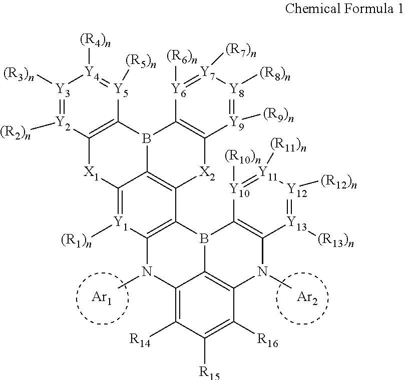

In Chemical Formula 1, X₁ and X₂ may each independently be N(R₁₇), S, O, or Se. Y₁ to Y₁₃ may each independently be C or N. R₁ to R₁₃ and R₁₇ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, or an electron withdrawing group. Two adjacent groups selected from among R₂ to R₁₃ may be optionally bonded to each other to form a saturated ring. The electron withdrawing group is a group having a para Hammett substituent constant (σp) according to Hammett's rule of greater than 0. n at each occurrence may independently be 0 or 1. R₁₄ to R₁₆ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Ar₁ and Ar₂ may each independently be a substituted or unsubstituted C₆-C₆₀ aryl group or a substituted or unsubstituted C₂-C₆₀ heteroaryl group. At least one selected from among Y₁ to Y₁₃ is N; at least one selected from among R₁ to R₁₃ and R₁₇ is an electron withdrawing group; at least one selected from among R₁ to R₁₃ and R₁₇ is a group substituted with an electron withdrawing group; at least one selected from among Y₁ to Y₁₃ is N, and at least one selected from among R₁ to R₁₃ and R₁₇ is an electron withdrawing group; at least one selected from among Y₁ to Y₁₃ is N, and at least one selected from among R₁ to R₁₃ and R₁₇ is a group substituted with an electron withdrawing group; at least one selected from among R₁ to R₁₃ and R₁₇ is an electron withdrawing group, and at least one selected from among the remainder of R₁ to R₁₃ and R₁₇ is a group substituted with an electron withdrawing group; or at least one selected from among Y₁ to Y₁₃ is N, at least one selected from among R₁ to R₁₃ and R₁₇ is an electron withdrawing group, and at least one selected from among the remainder of R₁ to R₁₃ and R₁₇ is a group substituted with an electron withdrawing group. When the number of the electron withdrawing group and/or the number of the group substituted with the electron withdrawing group are each two or more, the electron withdrawing groups may each independently be the same as or different from each other, and/or the groups substituted with the electron withdrawing group may each independently be the same as or different from each other.

In one or more embodiments, the electron withdrawing group may be selected from among —F, —Cl, —Br, —I, —CF₃, —COR₁₈, —CO₂R₁₉, —SOR₂₀, —SO₂R₂₁, —CN, —SCN, —NO₂, and a π electron-depleted nitrogen-containing C₂-C₃₀ cyclic group. R₁₈ to R₂₁ may each independently be a substituted or unsubstituted C₁-C₃₀ alkyl group, a substituted or unsubstituted C₃-C₃₀ cycloalkyl group, or a substituted or unsubstituted C₆-C₆₀ aryl group.

In one or more embodiments, R₁₄ to R₁₆ may not be an electron withdrawing group, and may not be a group substituted with an electron withdrawing group.

In one or more embodiments, R₁₄ to R₁₆ may not be an electron donating group, and may not be a group substituted with electron donating group. The electron donating group is a group having a substituent constant (σp) of Hammett's rule of less than −0.23.

In one or more embodiments, the electron donating group may be —NH₂, —NH(R₂₂), —N(R₂₃)(R₂₄), —OR₂₅, or a π electron-rich C₃-C₃₀ cyclic group. R₂₂ to R₂₅ may each independently be a substituted or unsubstituted C₁-C₃₀ alkyl group, a substituted or unsubstituted C₃-C₃₀ cycloalkyl group, or a substituted or unsubstituted C₆-C₆₀ aryl group.

In one or more embodiments, at least one selected from among Y₂ to Y₉ may be N; at least one selected from among R₂ to R₉ may be an electron withdrawing group; at least one selected from among R₂ to R₉ may be a group substituted with an electron withdrawing group; at least one selected from among Y₂ to Y₉ may be N, and at least one selected from among R₂ to R₉ may be an electron withdrawing group; at least one selected from among Y₂ to Y₉ may be N, and at least one selected from among R₂ to R₉ may be a group substituted with an electron withdrawing group; at least one selected from among R₂ to R₉ may be an electron withdrawing group, and at least one selected from among the remainder of R₂ to R₉ may be a group substituted with an electron withdrawing group; or at least one selected from among Y₂ to Y₉ may be N, and at least one selected from among R₂ to R₉ may be an electron withdrawing group, and at least one selected from among the remainder of R₂ to R₉ may be a group substituted with an electron withdrawing group.

In one or more embodiments, the polycyclic compound may be represented by any one selected from among Chemical Formulae 1-1 to 1-4.

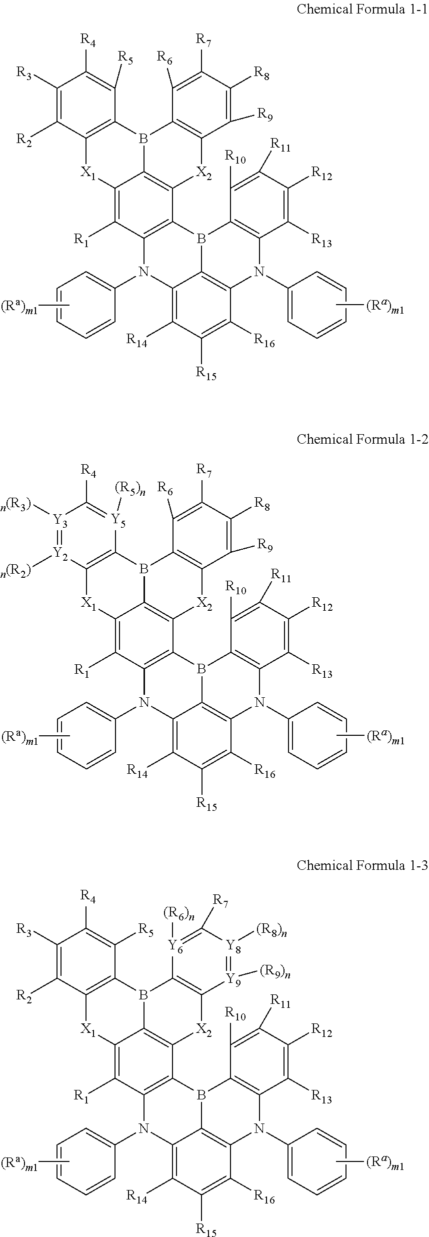

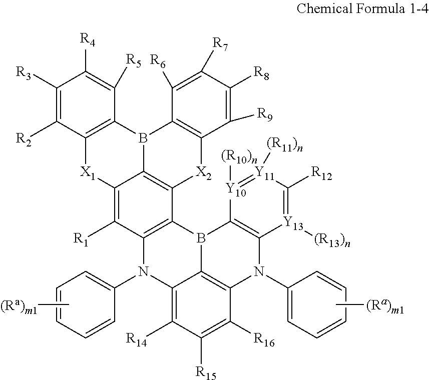

In Chemical Formulae 1-1 to 1-4, X₁ and X₂ may each independently be N(R₁₇) or O. Y₂, Y₃, Y₅, Y₆, Y₈, Y₉, Y₁₀, Y₁₁, and Y₁₃ may each independently be C or N. R₁ to R₁₃ and R₁₇ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted condensed polycyclic group of C₈-C₆₀, a substituted or unsubstituted silyl group, or an electron withdrawing group. Two adjacent groups selected from among R₂ to R₁₃ are not bonded to each other. n at each occurrence may independently be 0 or 1. R₁₄ to R₁₆ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. m1 at each occurrence may independently be an integer from 0 to 5. A single or multiple R^{a}(s) may each independently be hydrogen, deuterium, a substituted or unsubstituted C₁-C₂₀ alkyl group, a substituted or unsubstituted C₂-C₂₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₆₀ aryl group, a substituted or unsubstituted C₂-C₃₀ heteroaryl group, or a substituted or unsubstituted C₈-C₃₀ condensed polycyclic group. When the number of R^{a}(s) is 2 or more, two adjacent groups selected from among multiple R^{a}(s) may be optionally combined with each other to form a saturated ring or an unsaturated ring.

In one or more embodiments, at least one selected from among R₁ to R₁₃ and R₁₇ may be selected from among groups represented by any one selected from among Chemical Formulae 2-1 to 2-25.

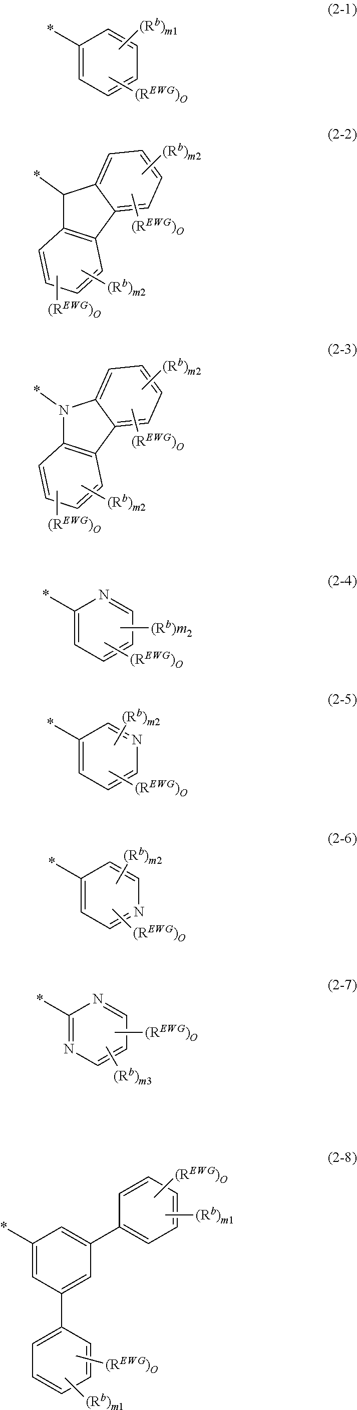

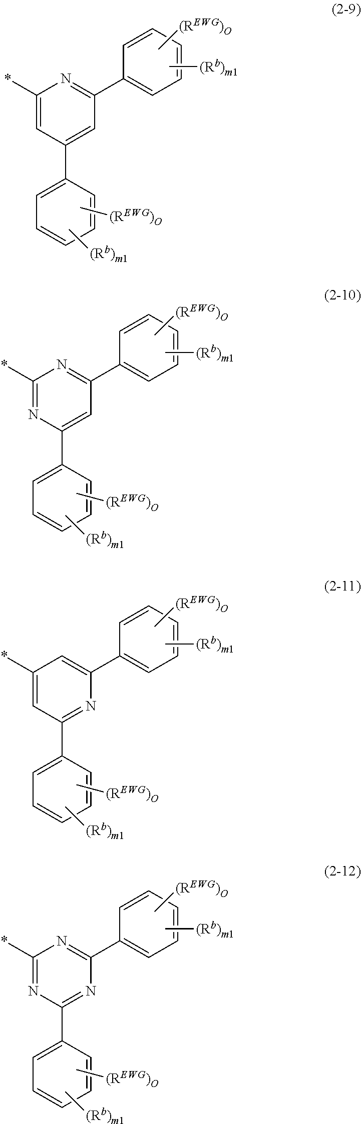

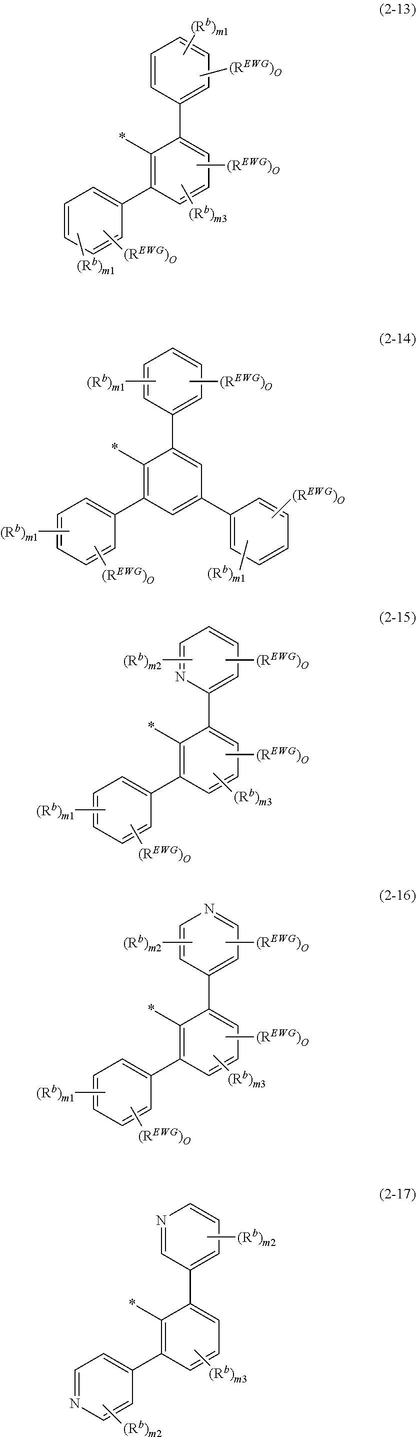

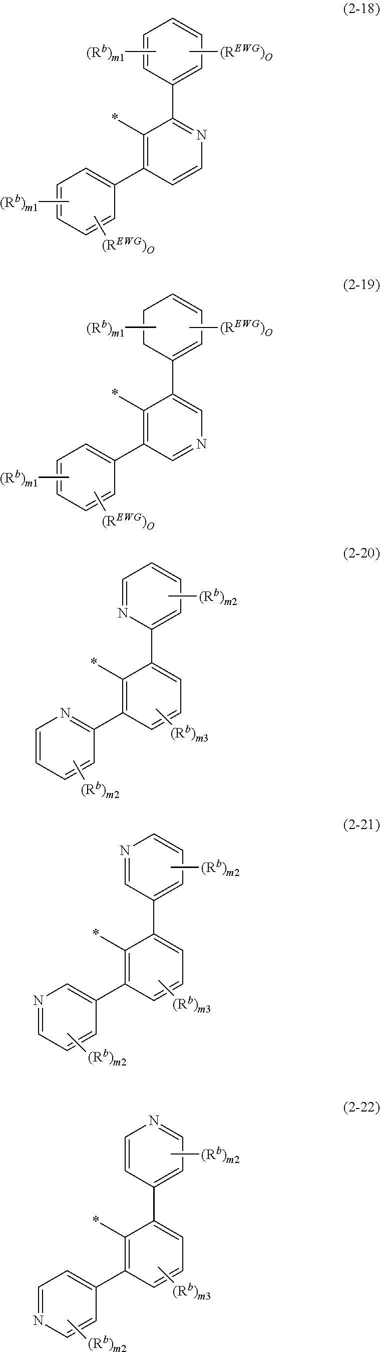

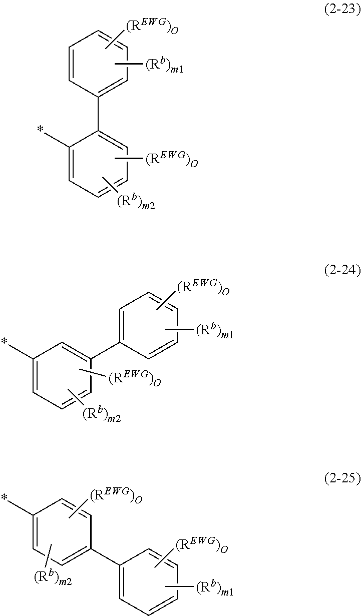

In Chemical Formulae 2-1 to 2-25, o at each occurrence may independently be an integer from 0 to 2. A single or plural R^{EWG}(s) may each independently be selected from among —F, —Cl, —Br, —I, —CF₃, —COR₁₈, —CO₂R₁₉, —SOR₂₀, —SO₂R₂₁, —CN, —SCN, —NO₂, and a π electron-depleted nitrogen-containing C₃-C₃₀ cyclic group. R₁₈ to R₂₁ may each independently be a substituted or unsubstituted C₁-C₃₀ alkyl group, a substituted or unsubstituted C₃-C₃₀ cycloalkyl group, or a substituted or unsubstituted C₆-C₆₀ aryl group. m1 at each occurrence may independently be an integer from 0 to 5, m2 at each occurrence may independently be an integer from 0 to 4, and m3 at each occurrence may independently be an integer from 0 to 3. A single or multiple R^{b}(s) may each independently be hydrogen, deuterium, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group. When the number of R^{b}(s) is 2 or more, multiple R^{b}(s) may each independently be the same as or different from each other, and two adjacent groups selected from among the multiple R^{b}(s) may be optionally combined with each other to form a saturated ring or an unsaturated ring.

In one or more embodiments, Ar₁ and Ar₂ may each independently be a group represented by any one selected from among Chemical Formulae 3-1 to 3-12.

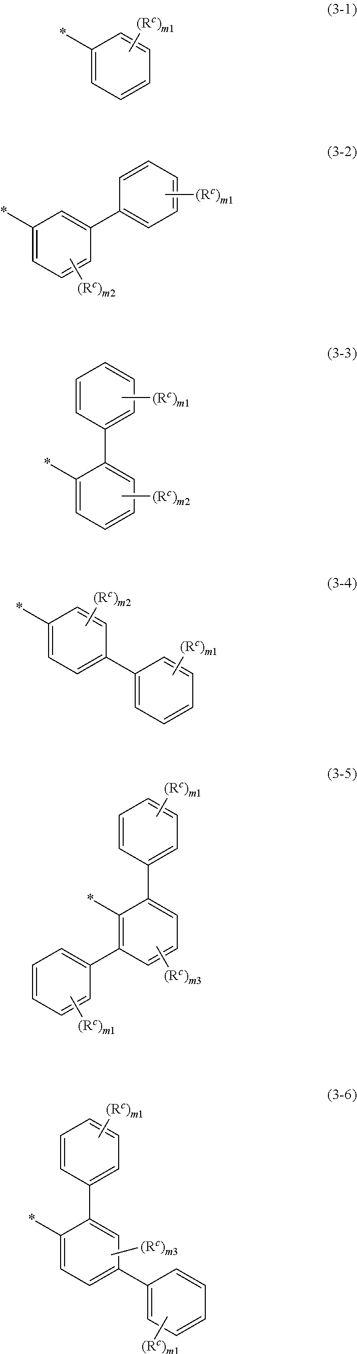

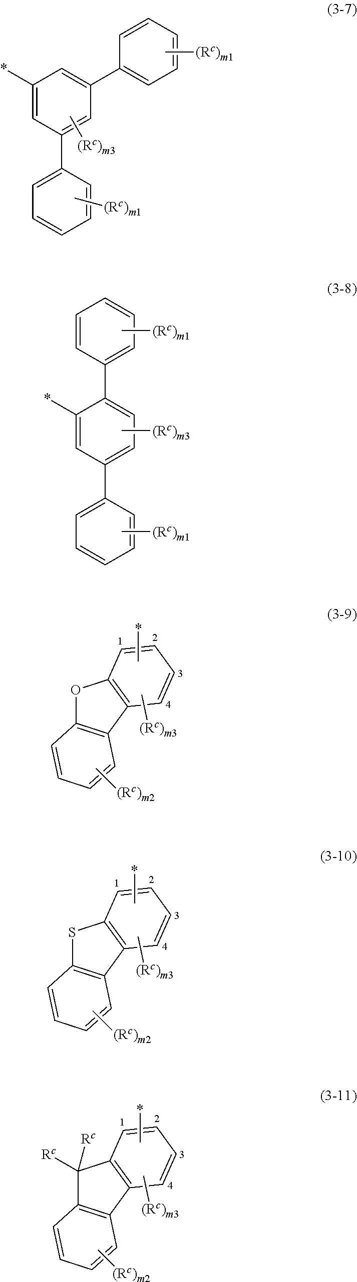

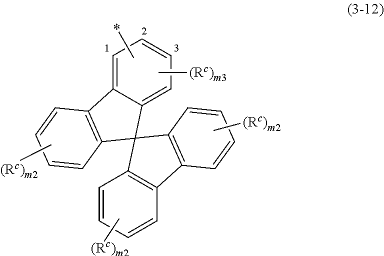

In Chemical Formulae 3-1 to 3-12, m1 at each occurrence may independently be an integer from 0 to 5, m2 at each occurrence may independently be an integer from 0 to 4, and m3 at each occurrence may independently be an integer from 0 to 3. A single or multiple R^{c}(s) may each independently be hydrogen, deuterium, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group. When multiple R^{c}(s) are included, the multiple R^{c}(s) may each independently be the same as or different from each other, and two adjacent groups selected from among the multiple R^{c}(s) may be optionally combined with each other to form a saturated ring or an unsaturated ring. In Chemical Formulae 3-9 to 3-11, *- binding site is one of carbons designated as the numbers of 1 to 4, and *- binding site in Chemical Formula 3-12 is one of carbons designated as the numbers of 1 to 3.

In one or more embodiments, R₁₇ may be a group represented by any one selected from among Chemical Formulae 2-14 to 2-25; R₁₂ may be a group represented by any one selected from among Chemical Formulae 2-2, 2-3, and 2-8 to 2-12; or R₁₇ may be a group represented by any one selected from among Chemical Formulae 2-14 to 2-25, and R₁₂ may be a group represented by any one of Chemical Formulae 2-2, 2-3, and 2-8 to 2-12.

In one or more embodiments, Ar₁ and Ar₂ may each independently be a group represented by any one selected from among Chemical Formulae 3-5 to 3-12.

In one or more embodiments, Ar₁ and Ar₂ may each independently be a group represented by Chemical Formula 3-5.

In one or more embodiments, the electron withdrawing group may be selected from among —F, —Cl, —Br, —I, —CF₃, —COR₁₈, —CO₂R₁₉, —SOR₂₀, —SO₂R₂₁, —CN, —SCN, a substituted or unsubstituted triazine group, a substituted or unsubstituted thiazole group, a substituted or unsubstituted benzothiazole group, a substituted or unsubstituted pyrazine group, a substituted or unsubstituted pyridine group, a substituted or unsubstituted pyridazine group, a substituted or unsubstituted pyrimidine group, a substituted or unsubstituted naphthyridine group, a substituted or unsubstituted phthalazine group, a substituted or unsubstituted quinoline group, a substituted or unsubstituted quinazoline group, a substituted or unsubstituted benzocinnoline group, a substituted or unsubstituted phenanthroline group, and a substituted or unsubstituted acridine group. R₁₈ to R₂₁ may each independently be a substituted or unsubstituted C₁-C₁₀ alkyl group, a substituted or unsubstituted C₃-C₁₀ cycloalkyl group, or a substituted or unsubstituted C₆-C₁₀ aryl group.

According to one or more embodiments, a light-emitting device may include a first electrode, a second electrode, and an emission layer between (e.g., arranged between) the first electrode and the second electrode. The emission layer may include a polycyclic compound represented by Chemical Formula 1.

In one or more embodiments, the light-emitting device may further include a charge generation layer between the first electrode and the second electrode. The emission layer may include a plurality of emission layers, and the charge generation layer may be arranged between adjacent emission layers. At least one selected from among the plurality of emission layers may include the polycyclic compound of Chemical Formula 1.

In one or more embodiments, the polycyclic compound may be included as a thermally activated delayed fluorescence (TADF) dopant, or as a host for a phosphorescent device (e.g., for a phosphorescent dopant).

In one or more embodiments, the emission layer may be to emit a blue light having a maximum emission wavelength (e.g., wavelength at the maximum emission intensity or peak emission wavelength) from about 440 nm to about 480 nm.

In one or more embodiments, the polycyclic compound may be represented by any one selected from among Chemical Formulae 1-1 to 1-4.

According to one or more embodiments of the present disclosure, an electronic device including the light-emitting device is provided.

The electronic apparatus may be at least one of a flat panel display, a curved display, a computer monitor, a medical monitor, a television, a billboard, an indoor light, an outdoor light, a light for signaling, a head-up display, a fully transparent display, a partially transparent display, a flexible display, a rollable display, a foldable display, a stretchable display, a laser printer, a phone, a mobile phone, a tablet, a phablet, a personal information terminal (PDA), a wearable device, a laptop computer, a digital camera, a camcorder, a viewfinder, a micro display, a 3D display, a virtual reality display, an augmented reality display, a vehicle, a video wall with multiple displays tiled together, a theater screen, a stadium screen, a phototherapy device, or a signage.

The polycyclic compound according to one or more embodiments of the present disclosure may include at least one of an electron withdrawing group or an electron-deficient nitrogen atom at a lowest unoccupied molecular orbital (LUMO) site.

Accordingly, oxidation stability and intramolecular charge transfer (CT) properties of the polycyclic compound may both (e.g., simultaneously) be improved.

For example, the polycyclic compound may be applied as a thermally activated delayed fluorescence (TADF) dopant to an emission layer to enhance light-emitting and life-span properties of the light-emitting device.

The light-emitting device, and an electronic device and an electronic apparatus each including the light-emitting device according to one or more embodiments of the present disclosure may have improved light-emitting and life-span properties.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings.

FIGS. 1-6 are each a schematic cross-sectional view illustrating a light-emitting device in accordance with one or more embodiments of the present disclosure.

FIG. 7 is a schematic cross-sectional view illustrating a display device in accordance with one or more embodiments of the present disclosure.

FIG. 8 is a schematic cross-sectional view illustrating a display device in accordance with one or more embodiments of the present disclosure.

FIG. 9 is a schematic cross-sectional view illustrating a stack construction of light-emitting structure in a display device in accordance with one or more embodiments of the present disclosure.

FIG. 10 is a schematic cross-sectional view illustrating a display device in accordance with one or more embodiments of the present disclosure.

FIG. 11 is a schematic cross-sectional view illustrating a display device in accordance with one or more embodiments of the present disclosure.

FIG. 12 is a block diagram of an electronic device in accordance with one or more embodiments of the present disclosure.

FIG. 13 is a schematic diagram illustrating electronic devices in accordance with one or more embodiments of the present disclosure.

FIG. 14 is a schematic exploded perspective view illustrating an electronic device in accordance with one or more embodiments of the present disclosure.

FIG. 15 is a schematic cross-sectional view illustrating an electronic device in accordance with one or more embodiments of the present disclosure.

### DETAILED DESCRIPTION

According to one or more embodiments of the present disclosure, a polycyclic compound including at least one of an electron withdrawing group or an electron-deficient nitrogen atom at a lowest unoccupied molecular orbital (LUMO) site.

According to one or more embodiments of the present disclosure, a light-emitting device, a display device, an electronic device, and an electronic apparatus each including the polycyclic compound are provided.

### Definition of Terminology

In the present disclosure, the term “substituted or unsubstituted” may refer to being substituted or unsubstituted by one or more substituent selected from among the group consisting of deuterium, a halogen, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group (e.g., a C₁-C₆₀ alkyl group, a C₁-C₁₀ alkyl group), an alkenyl group (e.g., a C₂-C₆₀ alkenyl, a C₂-C₁₀ alkenyl group), an alkynyl group (e.g., a C₂-C₆₀ alkynyl group, a C₂-C₁₀ alkynyl group), an alkoxy group (e.g., a C₁-C₆₀ alkoxy group, a C₁-C₁₀ alkoxy group), a hydrocarbon ring group, an aryl group (e.g., a C₆-C₆₀ aryl group), and a heterocyclic group (e.g., a C₁-C₆₀ heterocyclic group). For example, the term “substituted alkyl group” may refer to a group in which at least one of hydrogen atoms of the alkyl group is substituted with the above-described substituent, and thus the substituent is bonded to a carbon atom of the alkyl group.

The substituent may include a combination of substituents selected from among the groups described above. For example, at least one hydrogen atom in the alkyl group, the aryl group, and/or the like, included as a substituent may be substituted with deuterium, a halogen, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group, an alkenyl group, an alkynyl group, a hydrocarbon ring group, an aryl group, a heterocyclic group, or a (e.g., any suitable) combination thereof.

In the substituents described above, a multivalent substituent such as an amino group, a phosphine sulfide group, a phosphine oxide group, a sulfinyl group, a sulfonyl group, an oxy group, a carbonyl group, an ester group, and/or the like, may each independently be substituted with a C₁-C₁₀ alkyl group, a C₁-C₁₀ alkenyl group, a C₁-C₁₀ alkynyl group, and/or a C₆-C₁₀ aryl group.

In the disclosure, regarding the term “substituted or unsubstituted Cₐ-C_{b} Y group,” the range of a to b refers to the number of carbon atoms in an unsubstituted Y group, and may not include (e.g., may exclude) the number of carbon atoms of its substituent.

In the disclosure, an alkyl group may be a monovalent hydrocarbon group in which one hydrogen atom is removed from a linear or branched hydrocarbon group. Non-limiting examples of an alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, and/or the like.

In the disclosure, an alkylene group may be a divalent hydrocarbon group in which two hydrogen atoms are removed from a linear or branched hydrocarbon group.

In the disclosure, an alkenyl group may have substantially the same skeleton as that of an alkyl group, and may be a monovalent hydrocarbon group that includes at least one carbon-carbon double bond. In the disclosure, an alkenylene group may be a divalent hydrocarbon group in which one hydrogen atom is further removed from an alkenyl group.

In the disclosure, an alkynyl group may have substantially the same skeleton as that of an alkyl group, and may be a monovalent hydrocarbon group that includes at least one carbon-carbon triple bond. In the disclosure, an alkynylene group may be a divalent hydrocarbon group in which one hydrogen atom is further removed from an alkynyl group.

In the disclosure, an aryl group may be a monovalent hydrocarbon group in which one hydrogen atom is removed from a hydrocarbon group having an aromatic structure. The definition of an aryl group may also encompass a group in which multiple aromatic rings are directly connected, such as a biphenyl group. Non-limiting examples of an aryl group may include, e.g., a phenyl group, a naphthyl group, an anthracenyl group, a phenanthrenyl group, a pyrenyl group, a fluorenyl group, a tetracenyl group, a biphenyl group, a terphenyl group, a quaterphenyl group, a chrysenyl group, and/or the like.

In the disclosure, a group in which two or more aryl rings are condensed to each other or linked to each other by an alicyclic hydrocarbon ring, such as a fluorenyl group, may be encompassed in the definition of an aryl group.

For example, a biphenyl group may be interpreted as an aryl group, or may be interpreted as a phenyl group that is substituted with a phenyl group.

In the disclosure, an arylene group may be a divalent hydrocarbon group in which one hydrogen atom is further removed from an aryl group.

In the disclosure, a heteroaryl group may be a monovalent group having an aromatic structure that includes at least one heteroatom such as B, O, P, S, and/or Si as a ring-forming atom. In the disclosure, a heteroarylene group may be a divalent group having an aromatic structure that includes at least one heteroatom such as B, O, P, S, and/or Si as a ring-forming atom. When a heteroaryl group or a heteroarylene group includes two or more heteroatoms, the two or more heteroatoms may be the same as or different from each other.

In the disclosure, a group in which two or more aryl rings are condensed or linked to a non-aromatic heterocyclic ring, such as a carbazole group, may also be encompassed in the definition of a heteroaryl group.

In the disclosure, the term “cyclic group” may encompass a monocyclic group or a polycyclic group, and may also encompass an alicyclic ring or an aromatic ring.

In the disclosure, the term “polycyclic group” may be a group in which two or more rings are connected to each other or condensed with each other through one or more atoms. For example, a polycyclic structure may include a bicyclic structure through a bridge carbon, a spiro structure, a fused structure, and/or the like.

In the disclosure, the term “condensed group” or “condensed ring structure” may each be a group in which two or more adjacent rings share two or more atoms among the above-described polycyclic structures. Non-limiting examples of a condensed ring structure may include naphthalene, anthracene, phenanthrene, fluorene, pyrene, benzopyrene, pentacene, polyacene, helicene, and/or the like.

In the disclosure, the term “carbocyclic group (e.g., C₃-C₆₀ carbocyclic group)” may be a cyclic group in which only carbon atoms are ring-forming atoms. In the disclosure, a heterocyclic group (e.g., a C₁-C₆₀ heterocyclic group) may be a cyclic group that includes at least one heteroatom as a ring-forming atom, in addition to carbon atoms.

In the disclosure, a carbocyclic group and a heterocyclic group may each independently be a monocyclic group that includes (e.g., consists of) one (e.g., exactly one) ring or a polycyclic group in which two or more rings are condensed with each other.

### Polycyclic Compound

A polycyclic compound according to one or more embodiments includes at least one of an electron withdrawing group or an electron deficient N at an LUMO site.

The polycyclic compound according to one or more embodiments may be represented by Chemical Formula 1:

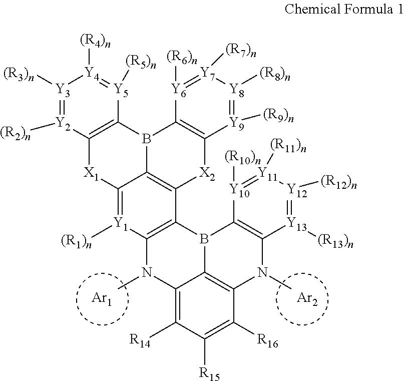

In Chemical Formula 1, X₁ and X₂ may each independently be N(R₁₇), S, O, or Se. Y₁ to Y₁₃ may each independently be C or N.

R₁ to R₁₃, and R₁₇ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, or an electron withdrawing group, and two adjacent groups selected from among R₂ to R₁₃ may be optionally bonded to each other to form a saturated ring.

The saturated ring may be, e.g., a substituted or unsubstituted C₄-C₆ cycloalkane ring, or a substituted or unsubstituted 5-membered or 6-membered ring.

If (e.g., when) two adjacent groups selected from among R₂ to R₁₃ are bonded to each other to form an unsaturated ring, a triplet energy level of the polycyclic compound may be lowered, and a triplet exciton generated in an emission layer may not be easily converted into a singlet exciton.

In one or more embodiments, X₂ and Rio may not be bonded to each other. When X₂ is N(R₁₇), R₁₇ and Rio may not be bonded to each other.

In one or more embodiments, the substituted or unsubstituted C₈-C₆₀ condensed polycyclic group may be a condensed polycyclic group in which a C₄-C₁₀ aliphatic hydrocarbon ring and a C₆-C₆₀ aromatic hydrocarbon ring are condensed. In one or more embodiments, the condensed polycyclic group may have a structure in which, e.g., one C₄-C₆ aliphatic hydrocarbon ring is condensed between two C₆-C₁₅ aromatic hydrocarbon rings. In one or more embodiments, the condensed polycyclic group may be, e.g., a substituted or unsubstituted carbazole group, a substituted or unsubstituted fluorene group, or a spiro-bifluorene group.

In one or more embodiments, the silyl group may be —Si(R₂₆)(R₂₇)(R₂₈), and R₂₆ to R₂₈ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or an unsubstituted C₆-C₆₀ arylthio group, or a substituted or unsubstituted C₈-C₆₀ condensed polycyclic group. The descriptions of the condensed polycyclic group may be also applied herein.

The electron withdrawing group may be a group having a para Hammett substituent constant (σp) according to Hammett's rule of greater than 0.

In one or more embodiments, the electron withdrawing group may have a para Hammett substituent constant (σp) according to Hammett's rule of greater than 0.05.

In one or more embodiments, the electron withdrawing group may be a group having a para Hammett substituent constant (σp) according to Hammett's rule of greater than 0.10, greater than 0.20, greater than 0.30, greater than 0.40, or greater than 0.42.

Hammett's rule can be used as a criterion expressing a degree of electron-withdrawing or electron-donating of a functional group. The para Hammett substituent constant (σp) determined by Hammett's rule can be found in the literature, such as “A survey of Hammett substituent constants and resonance and field parameters,” Chem. Rev. 1991, 91(2), p 165-195, the entire content of which is incorporated herein by reference, but the para Hammett substituent constant (σp) can be measured based on Hammett's rule even without a reference to the literature,
n at each occurrence may independently be 0 or 1.

R₁₄ to R₁₆ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. The above descriptions of —Si(R₂₆)(R₂₇)(R₂₈) may also be applied to the silyl group.

Ar₁ and Ar₂ may each independently be a substituted or unsubstituted C₆-C₆₀ aryl group or a substituted or unsubstituted C₂-C₆₀ heteroaryl group.

At least one selected from among Y₁ to Y₁₃ is N; at least one selected from among R₁ to R₁₃ and R₁₇ is an electron withdrawing group; at least one selected from among R₁ to R₁₃ and R₁₇ is a group substituted with an electron withdrawing group; at least one selected from among Y₁ to Y₁₃ is N, and at least one selected from among R₁ to R₁₃ and R₁₇ is an electron withdrawing group; at least one selected from among Y₁ to Y₁₃ is N, and at least one selected from among R₁ to R₁₃ and R₁₇ is a group substituted with an electron withdrawing group; at least one selected from among R₁ to R₁₃ and R₁₇ is an electron withdrawing group, and at least one selected from among the remainder of R₁ to R₁₃ and R₁₇ is a group substituted with an electron withdrawing group; or at least one selected from among Y₁ to Y₁₃ is N, at least one selected from among R₁ to R₁₃ and R₁₇ is an electron withdrawing group, and at least one selected from among the remainder of R₁ to R₁₃ and R₁₇ is a group substituted with an electron withdrawing group.

Based on the definitions of R₁ to R₁₃ and R₁₇ in Chemical Formula 1, the group substituted with an electron withdrawing group may each independently be a C₁-C₆₀ alkyl group substituted with an electron withdrawing group, a C₂-C₆₀ alkenyl group substituted with an electron withdrawing group, a C₂-C₆₀ alkynyl group substituted with an electron withdrawing group, a C₁-C₆₀ alkoxy group substituted with an electron withdrawing group, a C₃-C₆₀ cycloalkyl group substituted with an electron withdrawing group, a C₅-C₆₀ cycloalkenyl group substituted with an electron withdrawing group, a C₃-C₆₀ heterocycloalkyl group substituted with an electron withdrawing group, a C₃-C₆₀ heterocycloalkenyl group substituted with an electron withdrawing group, a C₆-C₆₀ aryl group substituted with an electron withdrawing group, a C₂-C₆₀ heteroaryl group substituted with an electron withdrawing group, a C₆-C₆₀ aryloxy group substituted with an electron withdrawing group, a C₆-C₆₀ arylthio group substituted with an electron withdrawing group, a C₈-C₆₀ condensed polycyclic group substituted with an electron withdrawing group, or a silyl group substituted with an electron withdrawing group.

When the number of the electron withdrawing group and/or the number of the group substituted with the electron withdrawing groups are each two or more, the electron withdrawing groups may be the same as or different from each other, and/or the groups substituted with the electron withdrawing group may be the same as or different from each other.

The polycyclic compound may have a structure in which boron and nitrogen are alternately arranged, so that a multiple resonance effect may occur within the polycyclic compound, and thus a half-width of its emission spectrum may become narrower.

The polycyclic compound has at least one of the electron withdrawing group or an electron-deficient N introduced to an LUMO site, and thus the depth of a highest occupied molecular orbital (HOMO) level may increase, and an absolute value (ΔEₛₜ) of a difference between an energy level of the lowest singlet excited state (S1 level) of the polycyclic compound and an energy level of the lowest triplet excited state (T1 level) of the polycyclic compound may become smaller.

Thus, the polycyclic compound may have improved oxidation stability and may convert a triplet exciton to a singlet exciton more quickly in a reverse intersystem crossing (RISC) mechanism.

In one or more embodiments, the electron withdrawing group may be selected from among —F, —Cl, —Br, —I, —CF₃, —COR₁₈, —CO₂R₁₉, —SOR₂₀, —SO₂R₂₁, —CN, —SCN, —NO₂, and a π electron-depleted nitrogen-containing C₂-C₃₀ cyclic group. R₁₈ to R₂₁ may each independently be a substituted or unsubstituted C₁-C₃₀ alkyl group, a substituted or unsubstituted C₃-C₃₀ cycloalkyl group, or a substituted or unsubstituted C₆-C₆₀ aryl group.

In one or more embodiments, the electron withdrawing group may be selected from among —F, —Cl, —Br, —I, —CF₃, —COR₁₈, —CO₂R₁₉, —SOR₂₀, —SO₂R₂₁, —CN, —SCN, a substituted or unsubstituted triazine group, a substituted or unsubstituted thiazole group, a substituted or unsubstituted benzothiazole group, a substituted or unsubstituted pyrazine group, a substituted or unsubstituted pyridine group, a substituted or unsubstituted pyridazine group, a substituted or unsubstituted pyrimidine group, a substituted or unsubstituted naphthyridine group, a substituted or unsubstituted phthalazine group, a substituted or unsubstituted quinoline group, a substituted or unsubstituted quinazoline group, a substituted or unsubstituted benzocinnoline group, a substituted or unsubstituted phenanthroline group, and a substituted or unsubstituted acridine group. R₁₈ to R₂₁ may each independently be a substituted or unsubstituted C₁-C₁ alkyl group, a substituted or unsubstituted C₃-C₁₀ cycloalkyl group, or a substituted or unsubstituted C₆-C₁ aryl group.

In one or more embodiments, the electron withdrawing groups may each independently be selected from among —CF₃, —COR_{18′}, —CO₂R_{19′}, —SOR_{20′}, —SO₂R_{21′}, —CN, —SCN, a substituted or unsubstituted triazine group, a substituted or unsubstituted thiazole group, a substituted or unsubstituted pyrazine group, a substituted or unsubstituted pyridine group, a substituted or unsubstituted pyridazine group, a substituted or unsubstituted pyrimidine group, a substituted or unsubstituted naphthyridine group, a substituted or unsubstituted quinazoline group, and a substituted or unsubstituted phenanthroline group. R_{18′} to R_{21′} may each independently be a C₁-C₁ alkyl group or a C₃-C₆ cycloalkyl group.

In one or more embodiments, R₁₄ to R₁₆ may not be an electron withdrawing group and may not be a group substituted with an electron withdrawing group. Accordingly, a depth of an HOMO level of the polycyclic compound may increase to improve charge transfer (CT) properties within a molecule. If the HOMO energy level of a dopant is shallow, a hole trap phenomenon may be induced in the emission layer to reduce an efficiency of the light-emitting device.

In one or more embodiments, R₁₄ to R₁₆ may not be an electron donating group, and may not be a group substituted with an electron donating group. The electron donating group may be a group having a substituent constant (σp) of the Hammett rule of less than −0.23.

The electron donating group may have a substituent constant (σp) of the Hammett rule of, e.g., less than −0.25, less than −0.30, or less than −0.40.

In one or more embodiments, the electron donating group may be —NH₂, —NH(R₂₂), —N(R₂₃)(R₂₄), —OR₂₅, or a π electron-rich C₃-C₃₀ cyclic group.

R₂₂ to R₂₅ may each independently be a substituted or unsubstituted C₁-C₃₀ alkyl group, a substituted or unsubstituted C₃-C₃₀ cycloalkyl group, or a substituted or unsubstituted C₆-C₆₀ aryl group.

In one or more embodiments, the electron donating group may be —NH₂, —NH(R₂₂), —N(R₂₃)(R₂₄), —OR₂₅, a substituted or unsubstituted thiophene group, a substituted or unsubstituted benzothiophene group, a substituted or unsubstituted benzonaphthothiophene group, a substituted or unsubstituted pyrrole group, a substituted or unsubstituted furan group, or a substituted or unsubstituted benzofuran group. R₂₂ to R₂₅ may each independently be a substituted or unsubstituted C₁-C₃₀ alkyl group, a substituted or unsubstituted C₃-C₃₀ cycloalkyl group, or a substituted or unsubstituted C₆-C₆₀ aryl group.

In one or more embodiments, at least one selected from among Y₂ to Y₉ may be N; at least one selected from among R₂ to R₉ may be an electron withdrawing group; at least one selected from among R₂ to R₉ may be a group substituted with an electron withdrawing group; at least one selected from among Y₂ to Y₉ may be N, and at least one selected from among R₂ to R₉ may be an electron withdrawing group; at least one selected from among Y₂ to Y₉ may be N, and at least one selected from among R₂ to R₉ may be a group substituted with an electron withdrawing group; at least one selected from among R₂ to R₉ may be an electron withdrawing group, and at least one selected from among the remainder of R₂ to R₉ may be a group substituted with an electron withdrawing group; or at least one selected from among Y₂ to Y₉ may be N, and at least one selected from among R₂ to R₉ may be an electron withdrawing group, and at least one selected from among the remainder of R₂ to R₉ may be a group substituted with an electron withdrawing group.

In one or more embodiments, the polycyclic compound may be represented by any one selected from among Chemical Formulae 1-1 to 1-4.

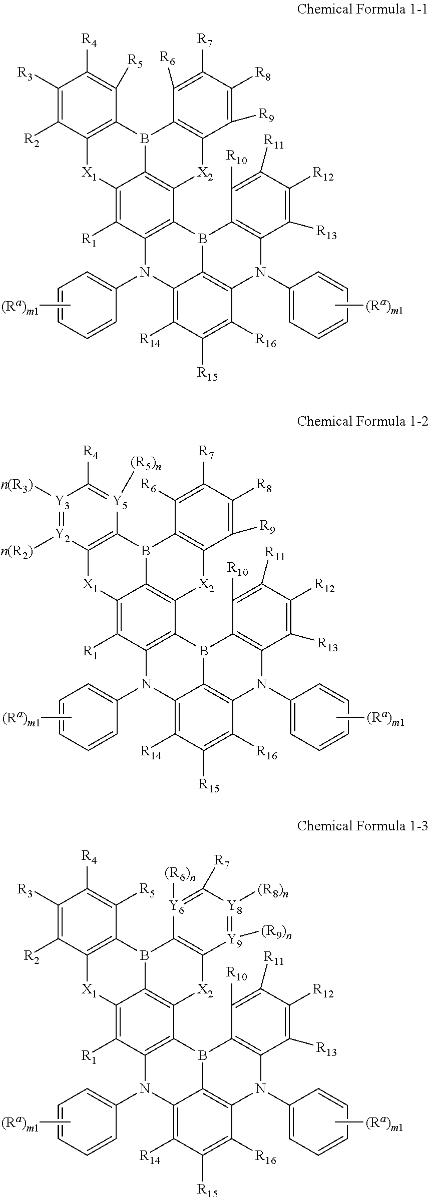

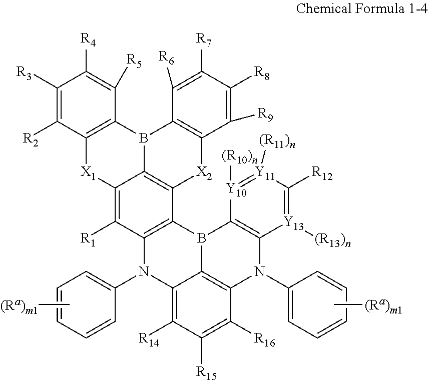

In Chemical Formulae 1-1 to 1-4, X₁ and X₂ may each independently be N(R₁₇) or O. Y₂, Y₃, Y₅, Y₆, Y₈, Y₉, Y₁o, Y₁₁, and Y₁₃ may each independently be C or N.

R₁ to R₁₃ and R₁₇ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted condensed polycyclic group of C₈-C₆₀, a substituted or unsubstituted silyl group, or an electron withdrawing group.

Two adjacent groups selected from among R₂ to R₁₃ may not be bonded to each other.

n at each occurrence may independently be 0 or 1.

R₁₄ to R₁₆ may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. In Chemical Formulae 1-to 1-4, the silyl group described with reference to Chemical Formula 1 may also be applied.

m1 at each occurrence may independently be an integer from 0 to 5.

A single or multiple R^{a}(s) may each independently be hydrogen, deuterium, a substituted or unsubstituted C₁-C₂₀ alkyl group, a substituted or unsubstituted C₂-C₂₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₆₀ aryl group, a substituted or unsubstituted C₂-C₃₀ heteroaryl group, or a substituted or unsubstituted C₈-C₃₀ condensed polycyclic group. When the number of R^{a}(s) is 2 or more, multiple R^{a}(s) may be the same as or different from each other, and two adjacent ones therefrom may be optionally combined with each other to form a saturated ring or an unsaturated ring.

In one or more embodiments, at least one selected from among R₁ to R₁₃ and R₁₇ may be selected from among groups represented by any one selected from among Chemical Formulae 2-1 to 2-25.

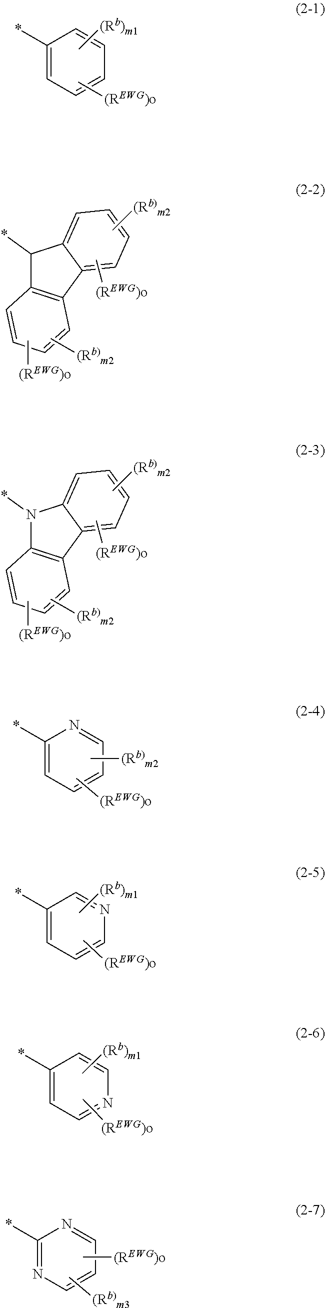

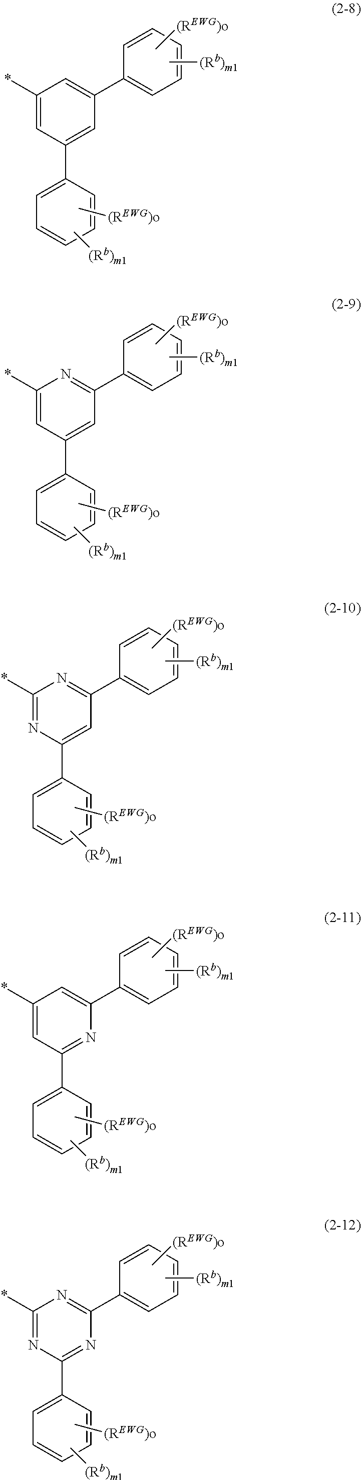

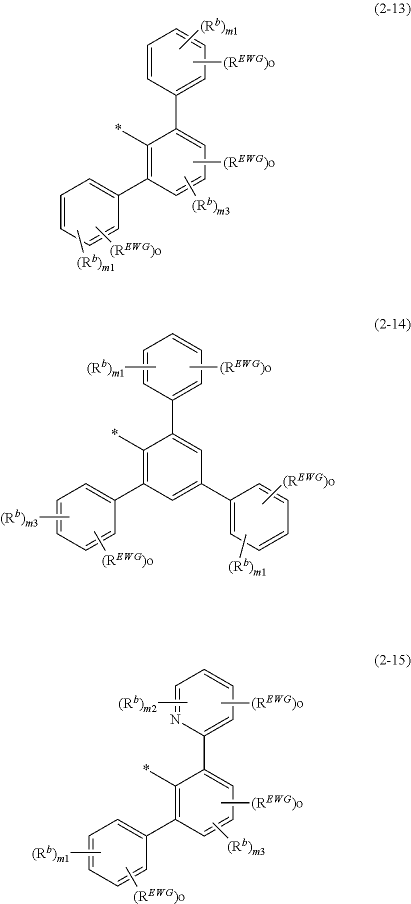

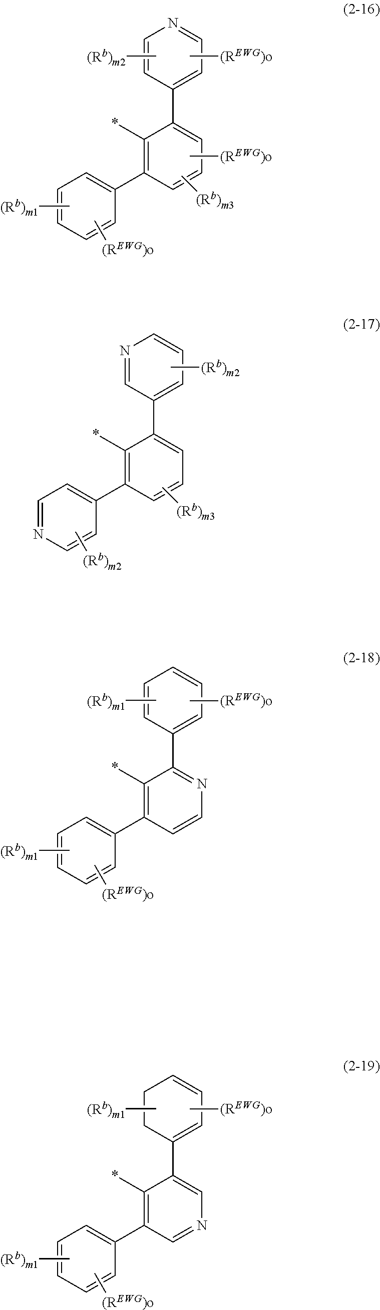

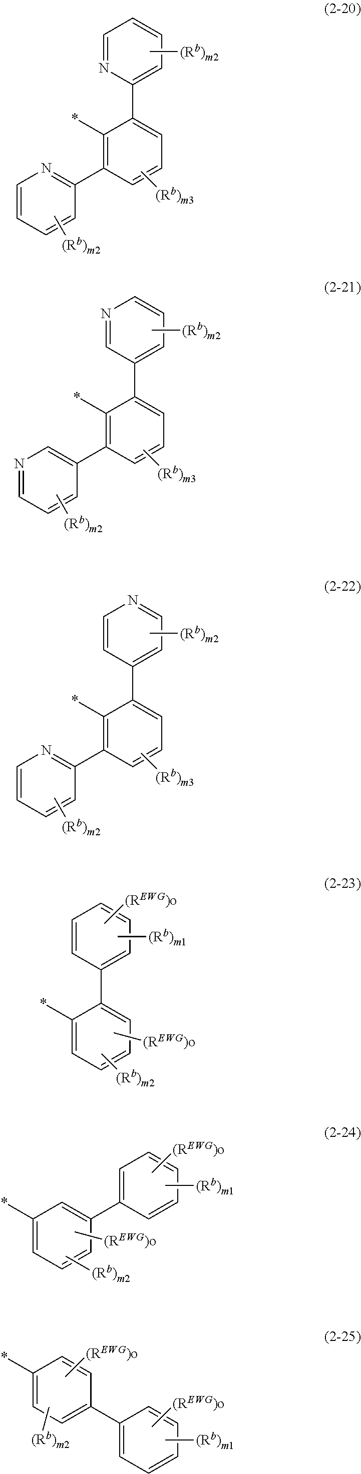

In Chemical Formulae 2-1 to 2-25, o at each occurrence may independently be an integer from 0 to 2.

A single or plural R^{EWG}(s) may each independently be selected from among —F, —Cl, —Br, —I, —CF₃, —COR₁₈, —CO₂R₁₉, —SOR₂₀, —SO₂R₂₁, —CN, —SCN, —NO₂, and a π electron-depleted nitrogen-containing C₃-C₃₀ cyclic group. R₁₈ to R₂₁ may each independently be a substituted or unsubstituted C₁-C₃₀ alkyl group, a substituted or unsubstituted C₃-C₃₀ cycloalkyl group, or a substituted or unsubstituted C₆-C₃₀ aryl group.

When the number of R^{EWG}(s) is 2 or more, multiple R^{EWG}(s) may be the same as or different from each other.

m1 at each occurrence may independently be an integer from 0 to 5, m2 at each occurrence may independently be an integer from 0 to 4, and m3 at each occurrence may each independently be an integer from 0 to 3.

o+m1, o+m2, and o+m3 may each independently be an integer from 0 to 5. For example, o, m1, m2, and m3 may satisfy 0≤o+m155, 0≤o+m2≤5, and 0≤o+m3≤5, and o+m1, o+m2, and o+m3 may be integers that may be the same as or different from each other.

A single or multiple R^{b}(s) may each independently be hydrogen, deuterium, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group.

When the number of R^{b}(s) is 2 or more, multiple R^{b}(s) may be the same as or different from each other, and two adjacent ones therefrom may be optionally combined with each other to form a saturated ring or an unsaturated ring.

In one or more embodiments, Ar₁ and Ar₂ may each independently be a group represented by any one selected from among Chemical Formulae 3-1 to 3-12.

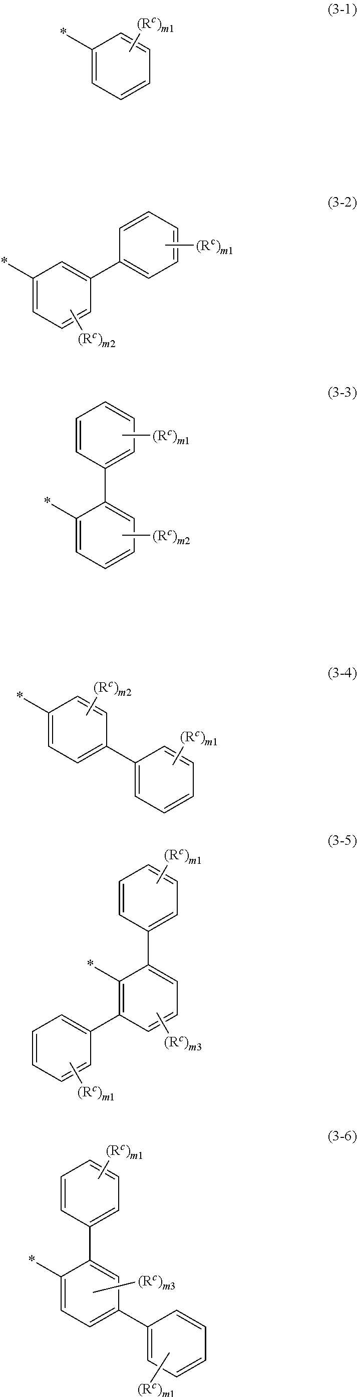

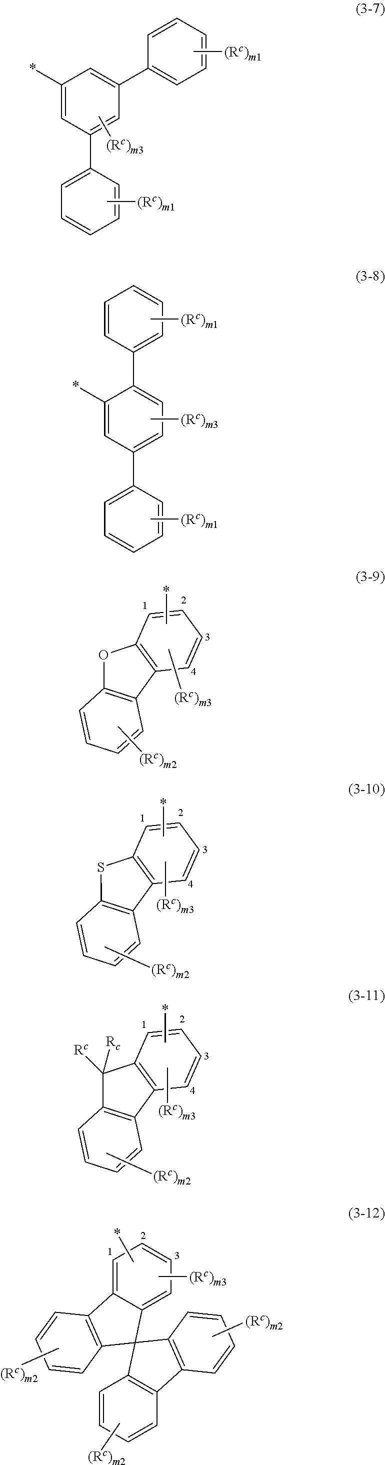

In Chemical Formulae 3-1 to 3-12, m1 at each occurrence may independently be an integer from 0 to 5, m2 at each occurrence may each independently be an integer from 0 to 4, and m3 at each occurrence may independently be an integer from 0 to 3.

A single or multiple R^{c}(s) may each independently be hydrogen, deuterium, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group.

When multiple R^{c}(s) are included, the multiple R^{c}(s) may be the same as or different from each other, and two adjacent ones therefrom may be optionally combined with each other to form a saturated ring or an unsaturated ring.

In Chemical Formulae 3-9 to 3-11, *- binding site may be one of carbons designated as the numbers of 1 to 4. In one or more embodiments, in Chemical Formulae 3-9 to 3-10, *- binding site may be one of carbons designated as the numbers of 1, 2, and 4.

In Chemical Formula 3-12, *- binding site may be one of carbons designated as the numbers of 1 to 3.

In one or more embodiments, R₁₇ may be a group represented by any one selected from among Chemical Formulae 2-14 to 2-25.

In one or more embodiments, R₁₂ may be a group represented by any one selected from among Chemical Formulae 2-2, 2-3, and 2-8 to 2-12.

In one or more embodiments, R₁₇ may be a group represented by any one selected from among Chemical Formulae 2-14 to 2-25; R₁₂ may be a group represented by any one selected from among Chemical Formulae 2-2, 2-3, and 2-8 to 2-12. Accordingly, oxidation stability of the polycyclic compound may be further improved.

In one or more embodiments, Ar₁ and Ar₂ may each independently be a group represented by any one selected from among Chemical Formulae 3-5 to 3-12.

In one or more embodiments, Ar₁ and Ar₂ may each independently be a group represented by Chemical Formula 3-5. Accordingly, aggregation between molecules of the polycyclic compound may be further prevented or reduced.

In one or more embodiments, the electron withdrawing group may be selected from among —F, —Cl, —Br, —I, —CF₃, —COR₁₈, —CO₂R₁₉, —SOR₂₀, —SO₂R₂₁, —CN, —SCN, a substituted or unsubstituted triazine group, a substituted or unsubstituted thiazole group, a substituted or unsubstituted benzothiazole group, a substituted or unsubstituted pyrazine group, a substituted or unsubstituted pyridine group, a substituted or unsubstituted pyridazine group, a substituted or unsubstituted pyrimidine group, a substituted or unsubstituted naphthyridine group, a substituted or unsubstituted phthalazine group, a substituted or unsubstituted quinoline group, a substituted or unsubstituted quinazoline group, a substituted or unsubstituted benzocinnoline group, a substituted or unsubstituted phenanthroline group, and a substituted or unsubstituted acridine group.

R₁₈ to R₂₁ may each independently be a substituted or unsubstituted C₁-C₁₀ alkyl group, a substituted or unsubstituted C₃-C₁₀ cycloalkyl group, or a substituted or unsubstituted C₆-C₁₀ aryl group.

R₁₄ and R₁₆ may each independently be, e.g., hydrogen, deuterium, a linear C₁-C₁₀ alkyl group, a branched C₃-C₁₀ alkyl group, a linear C₂-C₁₀ alkenyl group, or a branched C₃-C₁₀ alkenyl group.

R₁₅ may be, e.g., hydrogen, deuterium, a linear C₁-C₁₀ alkyl group, or a branched C₃-C₁₀ alkyl group.

In one or more embodiments, R₁₅ may be a branched C₃-C₁₀ alkyl group. For example, in one or more embodiments, R₁₅ may be a tert-butyl group.

According to one or more embodiments, the polycyclic compound may be any one selected from among compounds represented by chemical formulae 1-100.

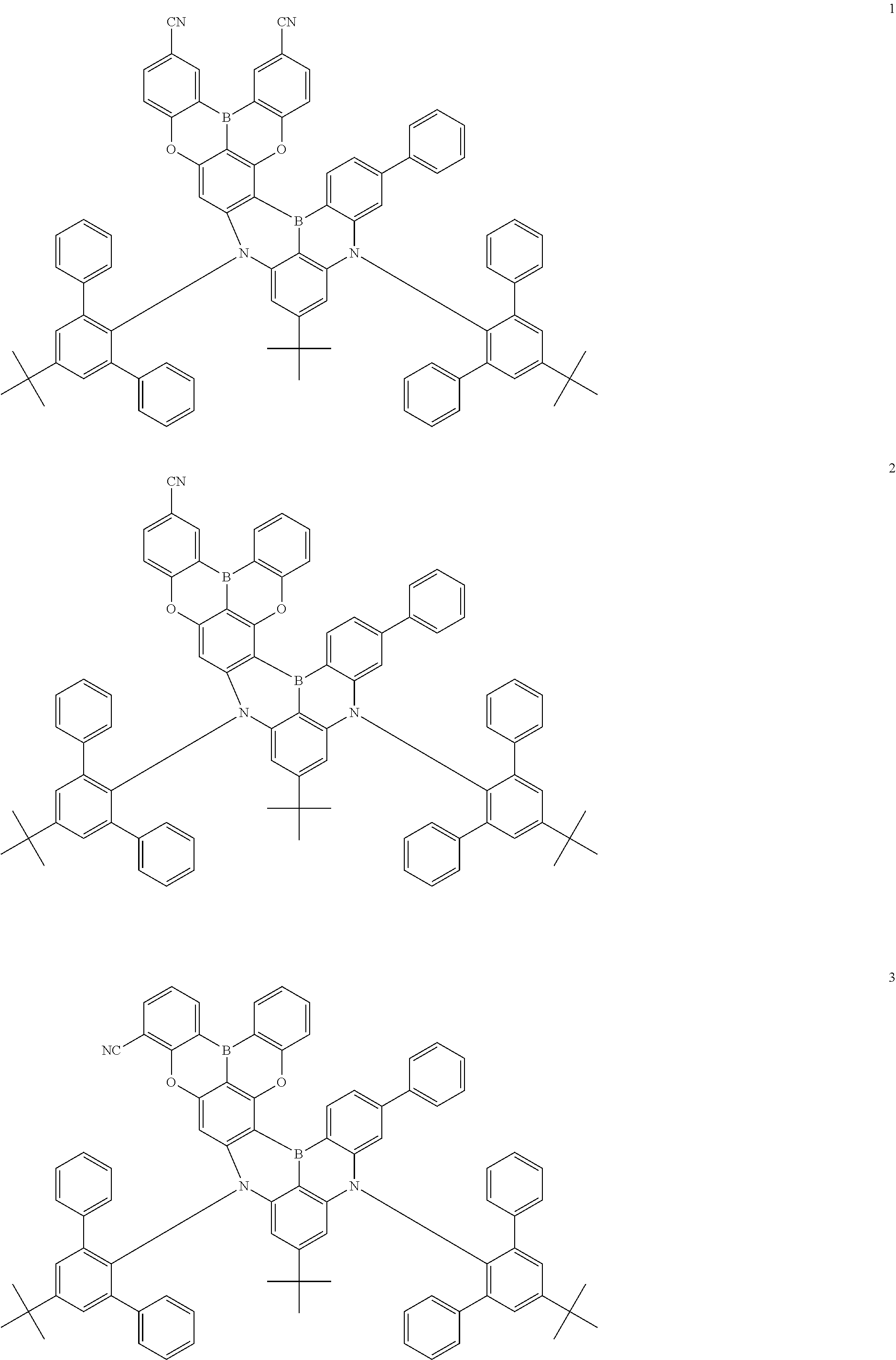

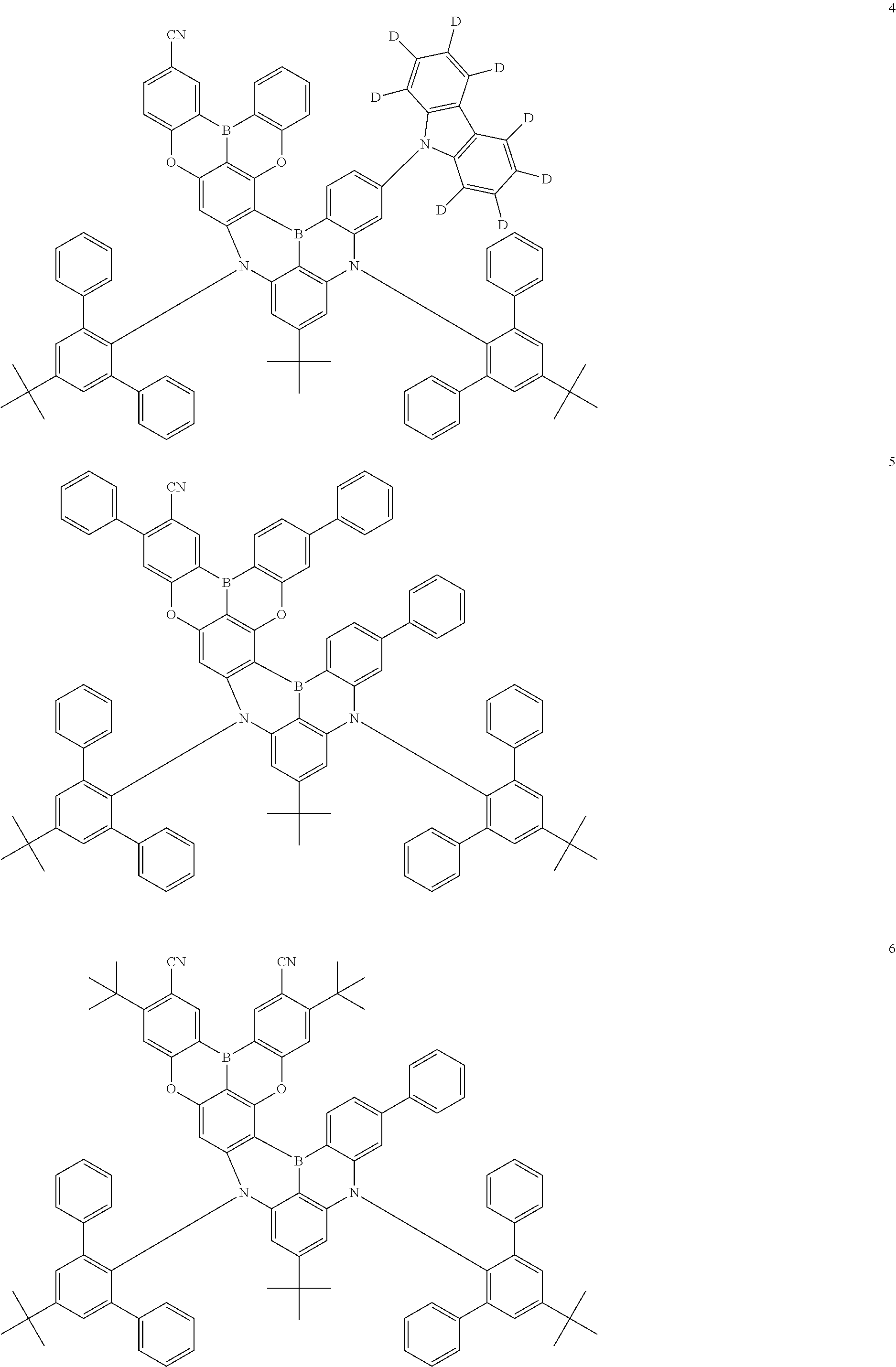

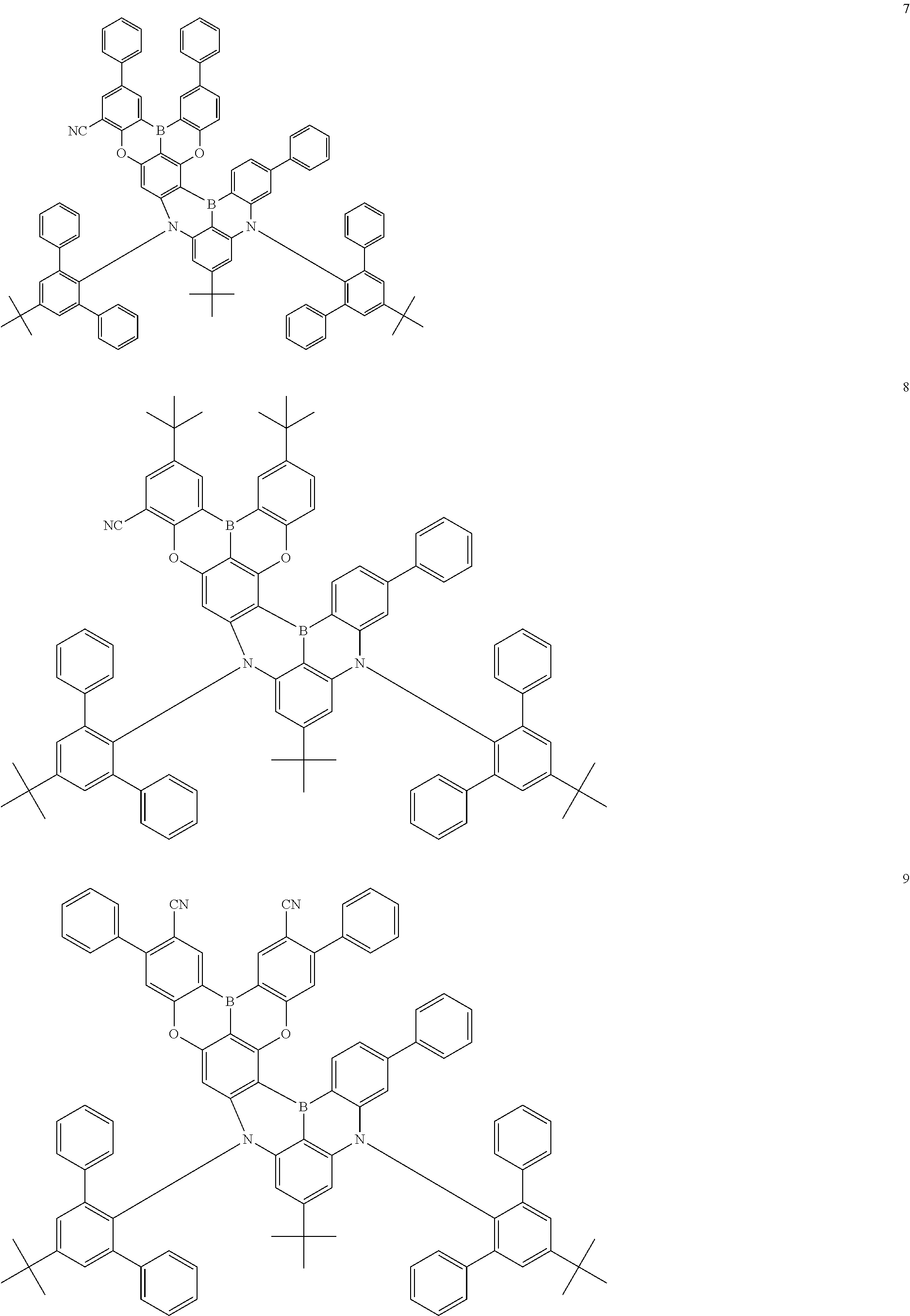

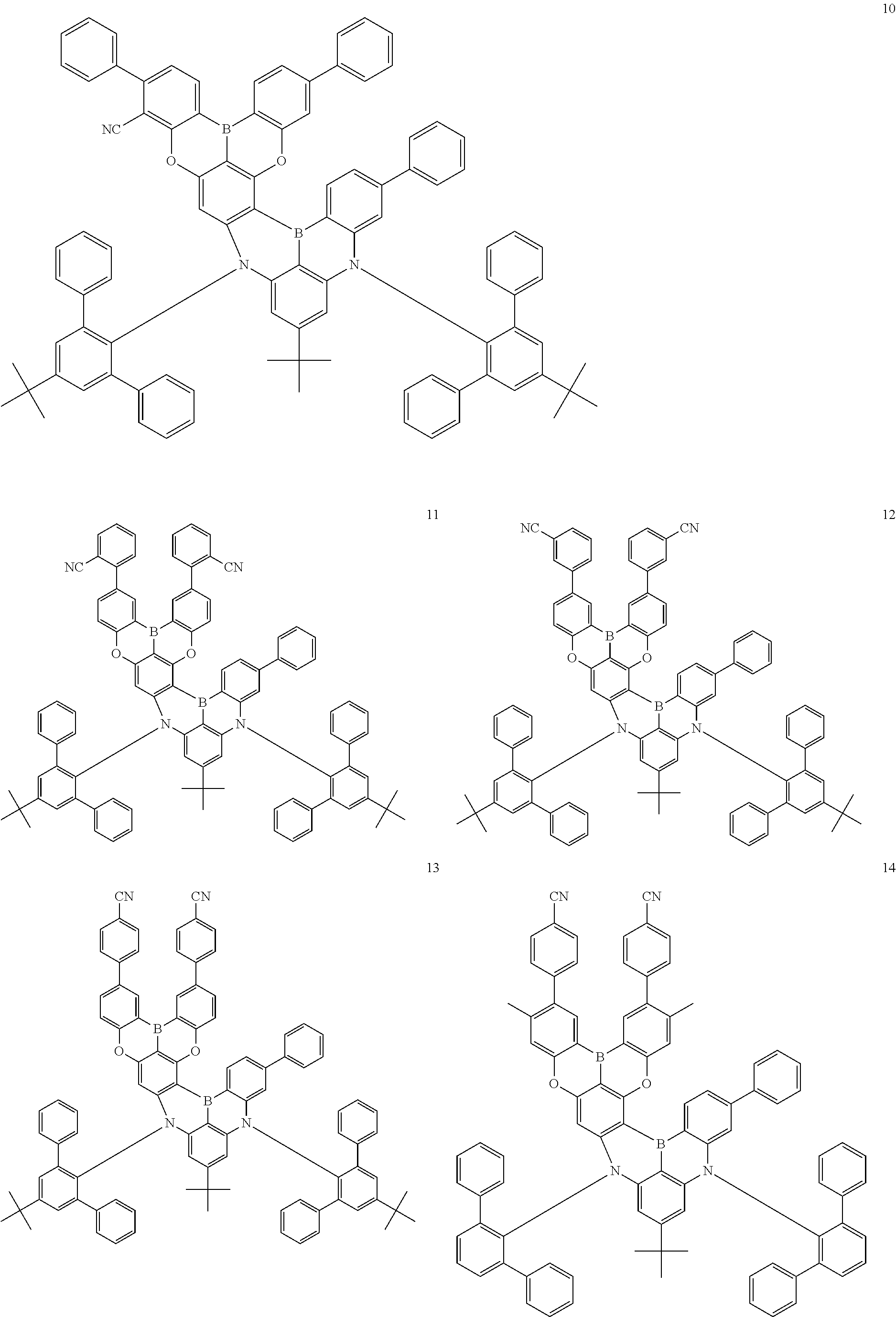

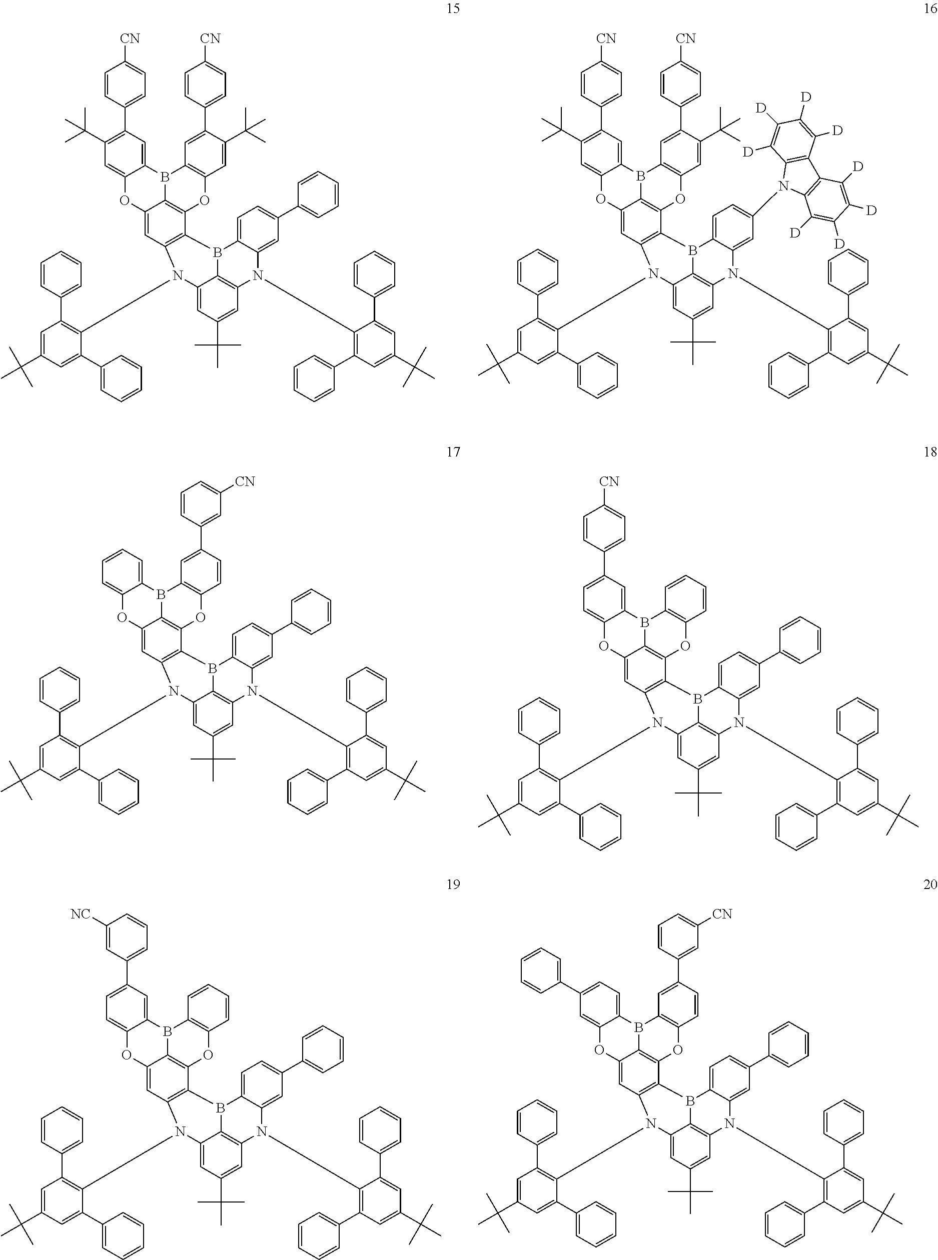

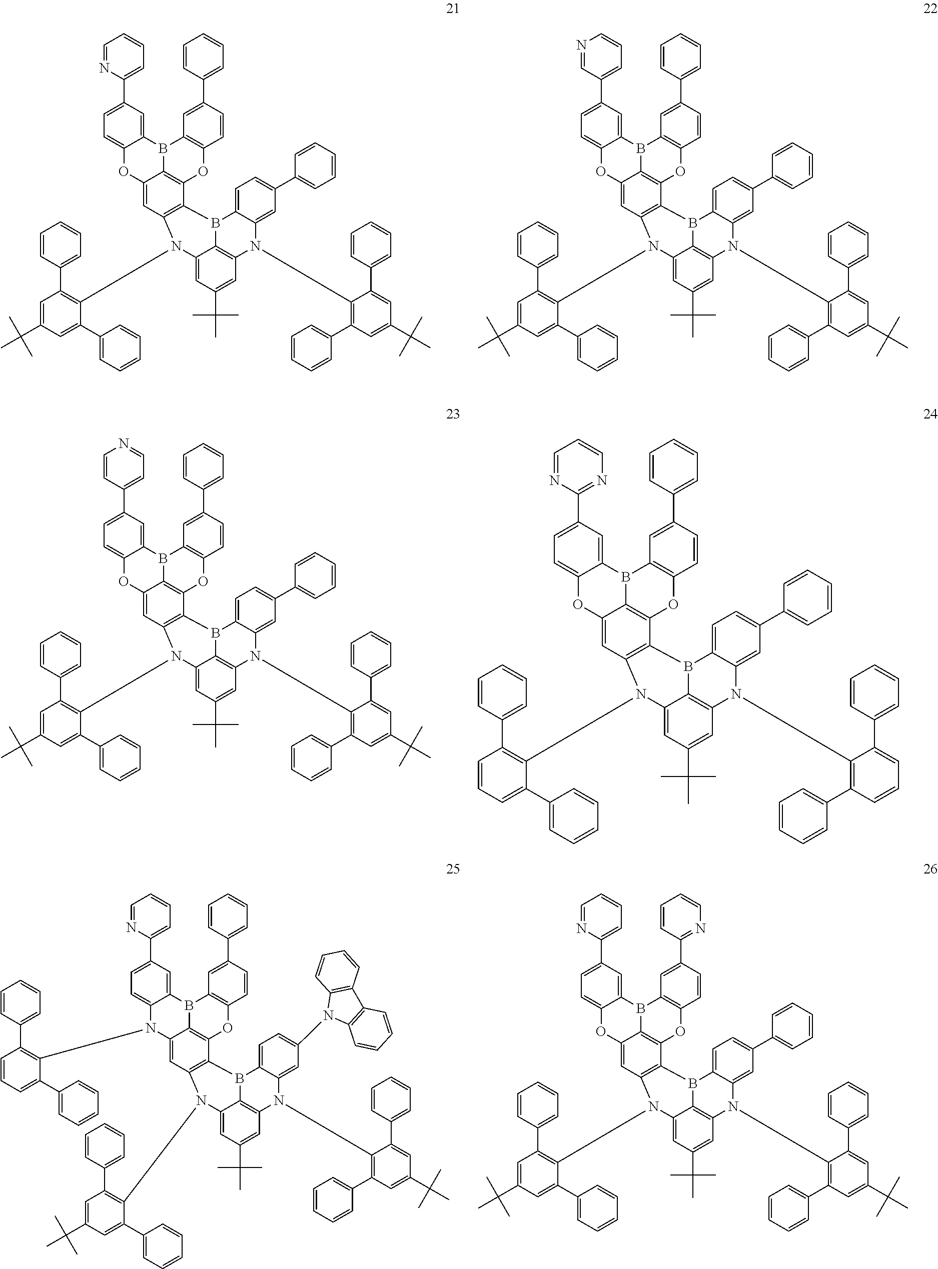

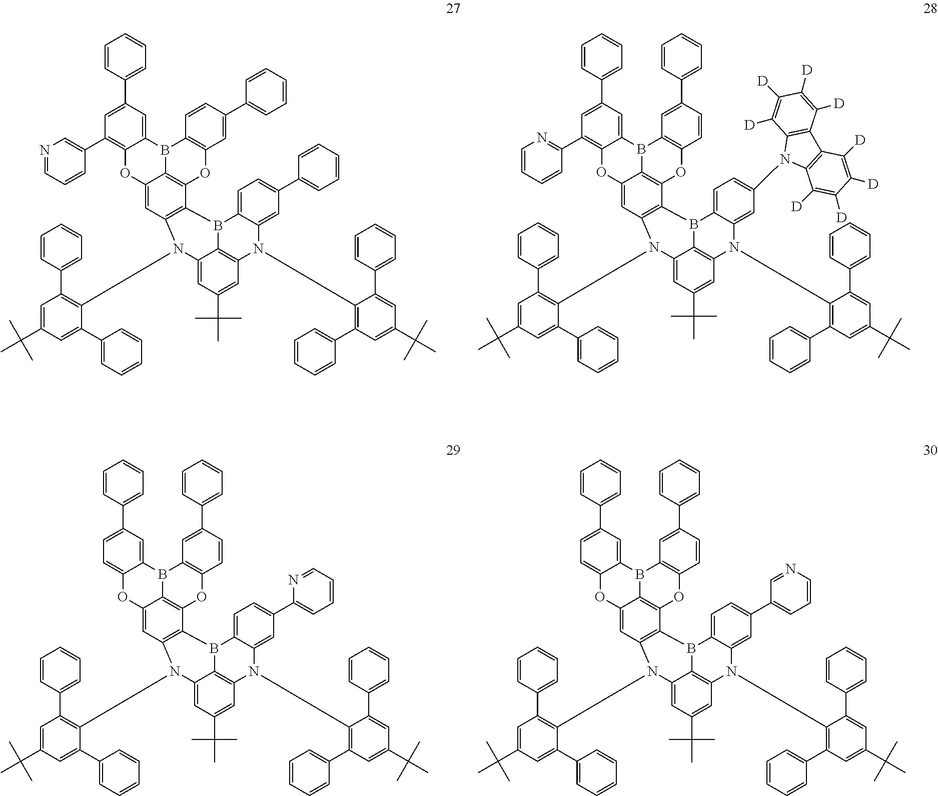

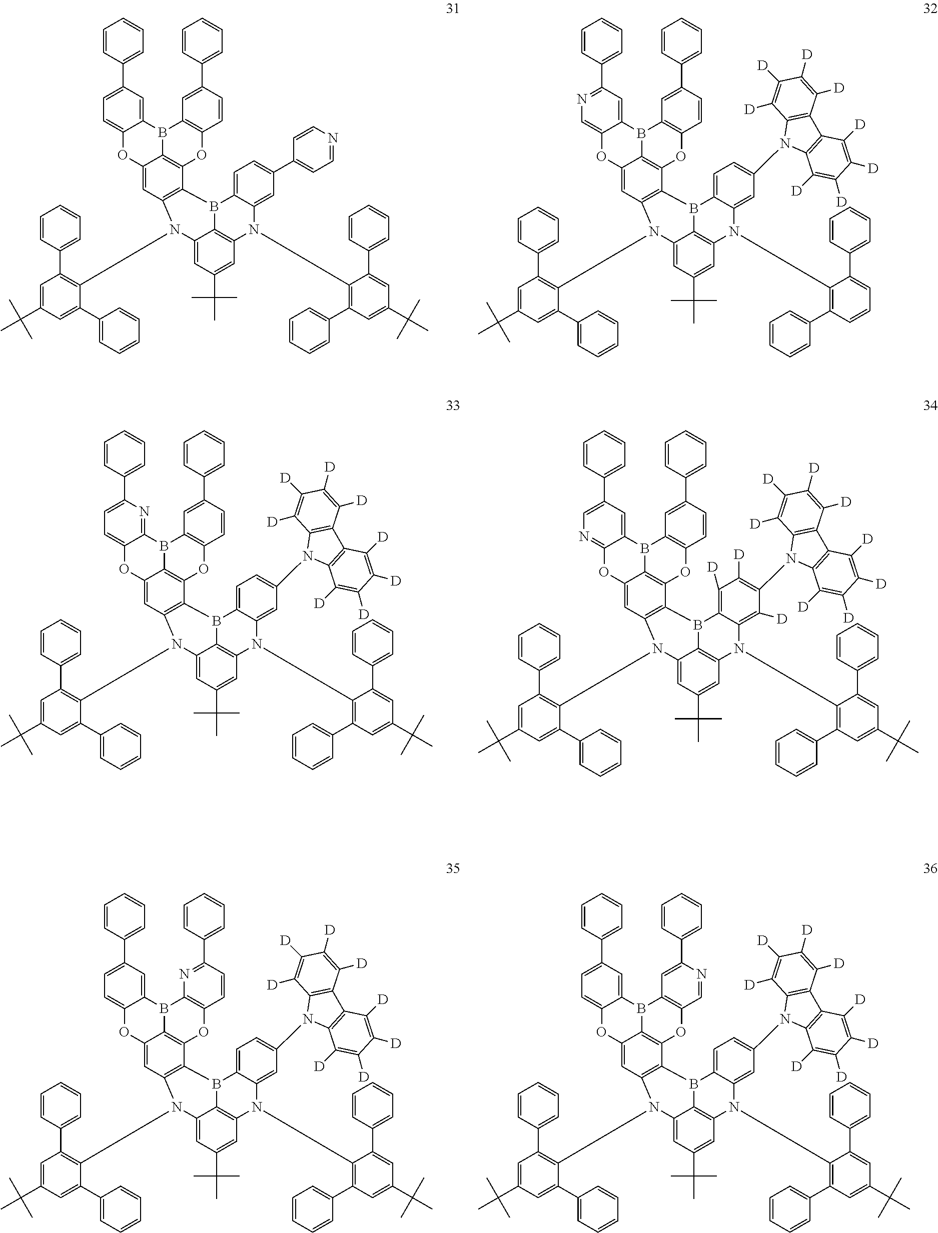

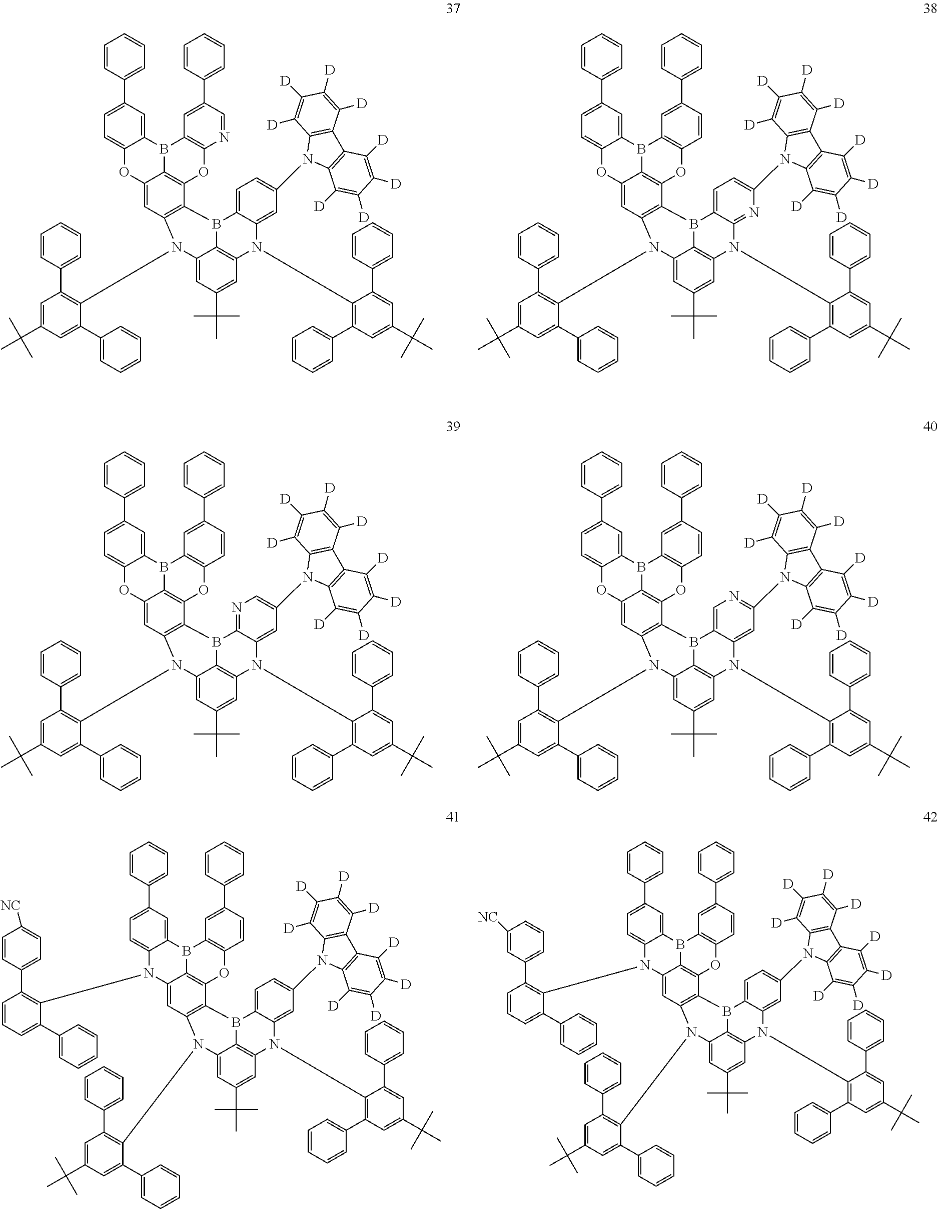

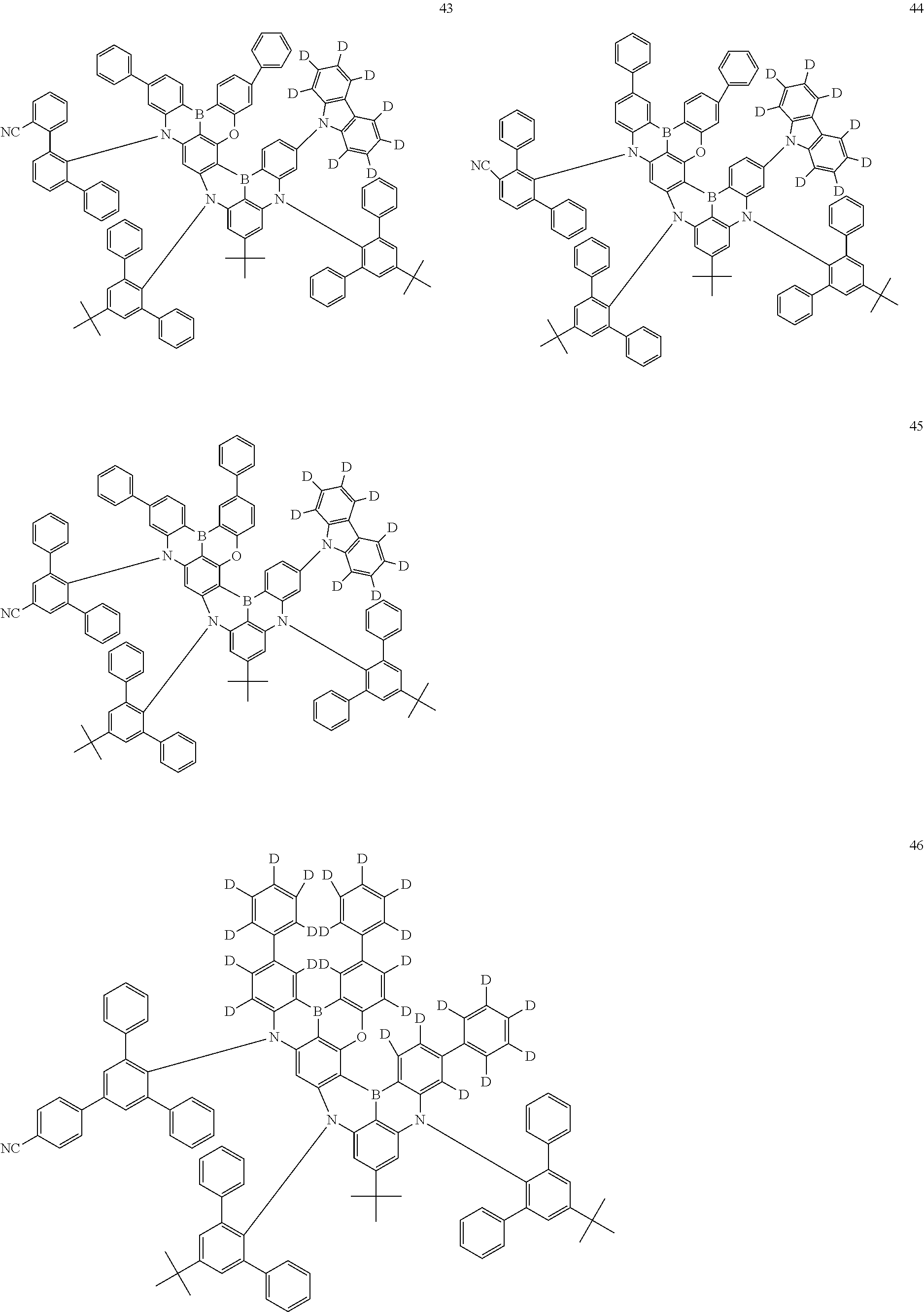

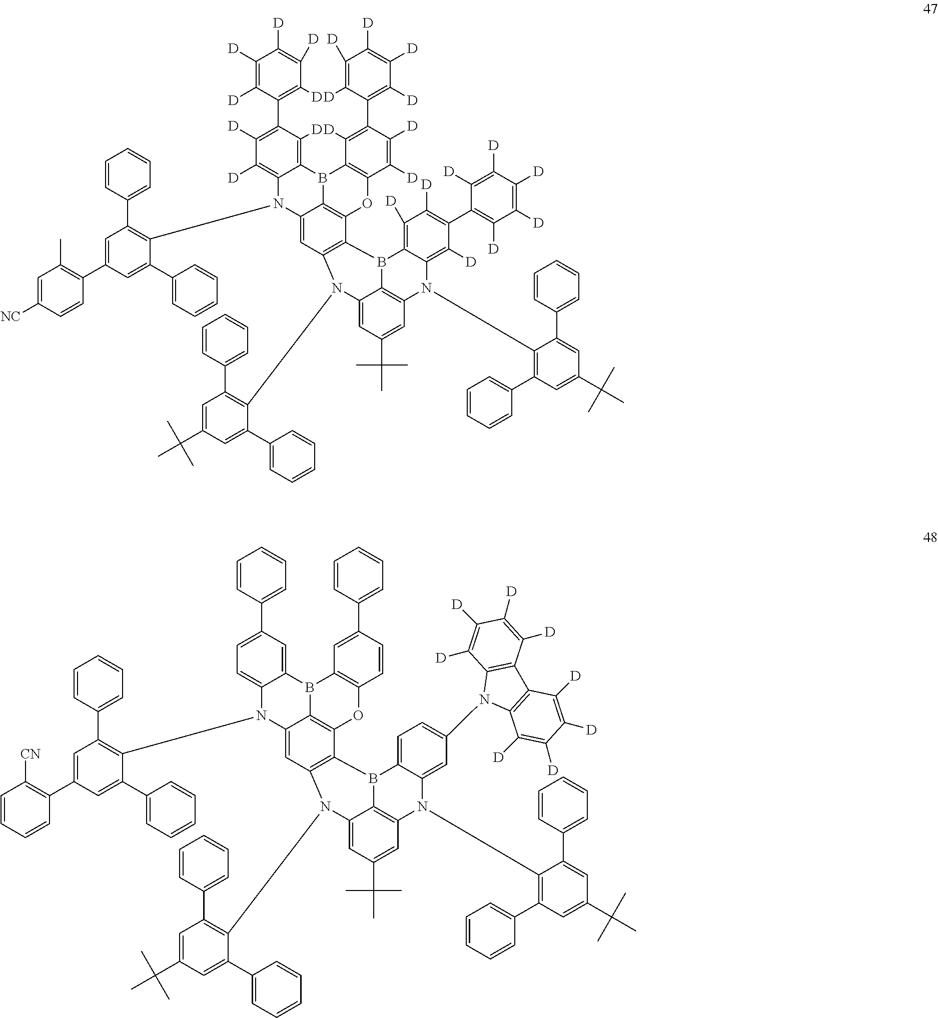

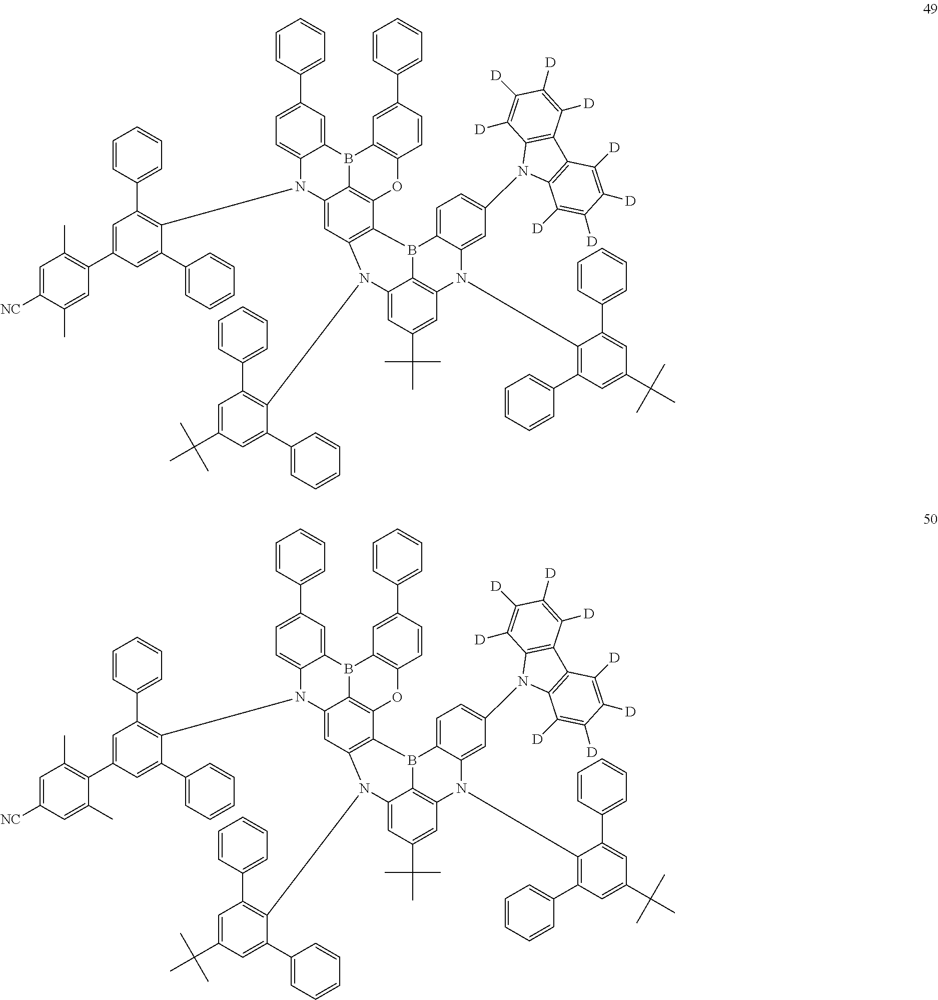

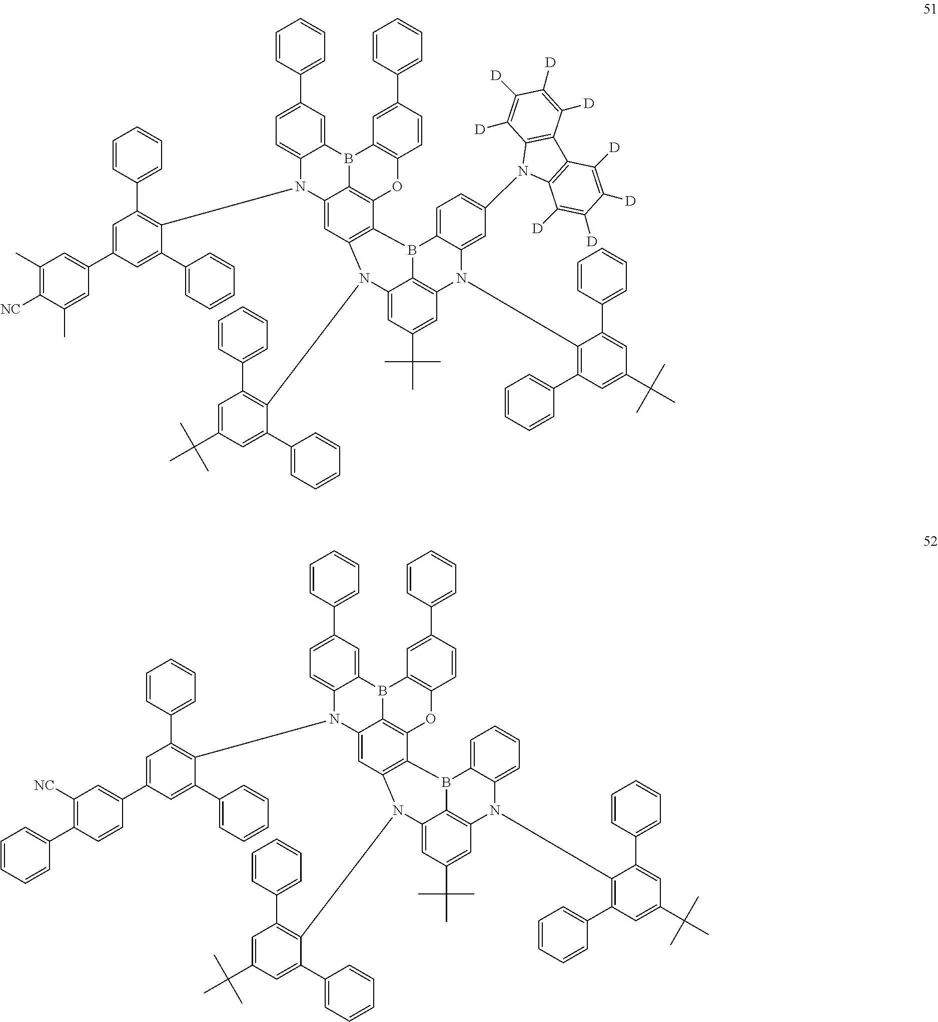

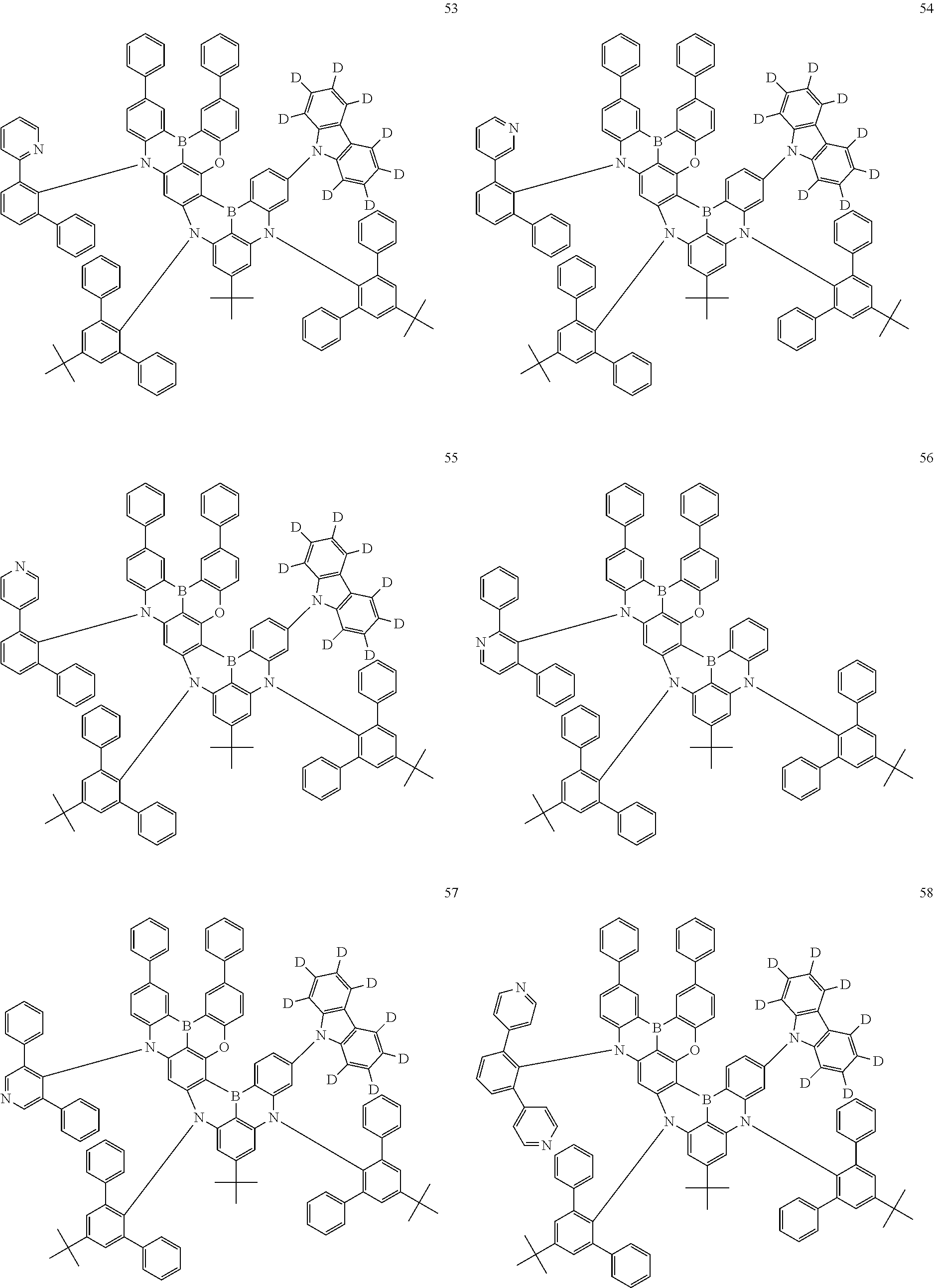

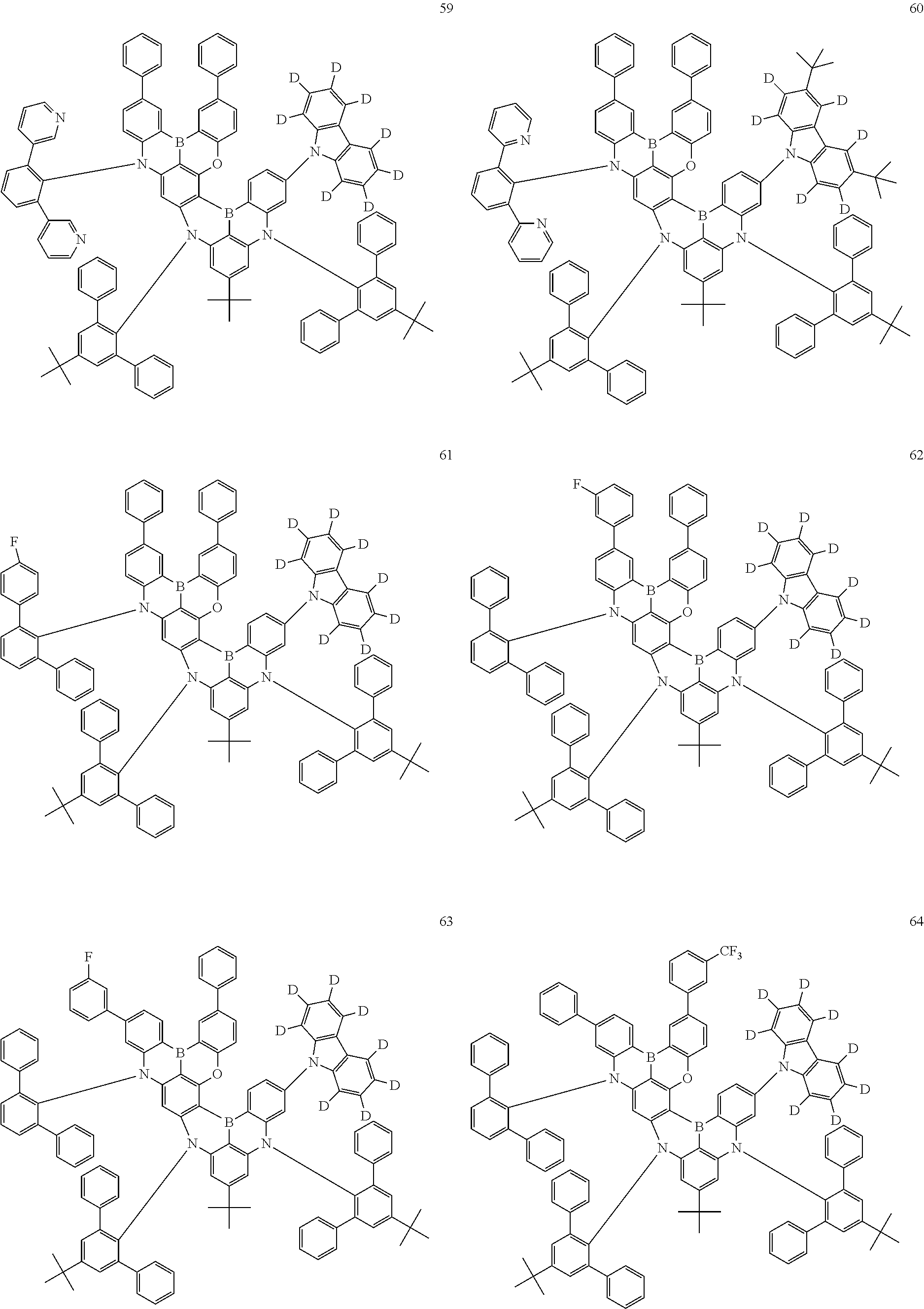

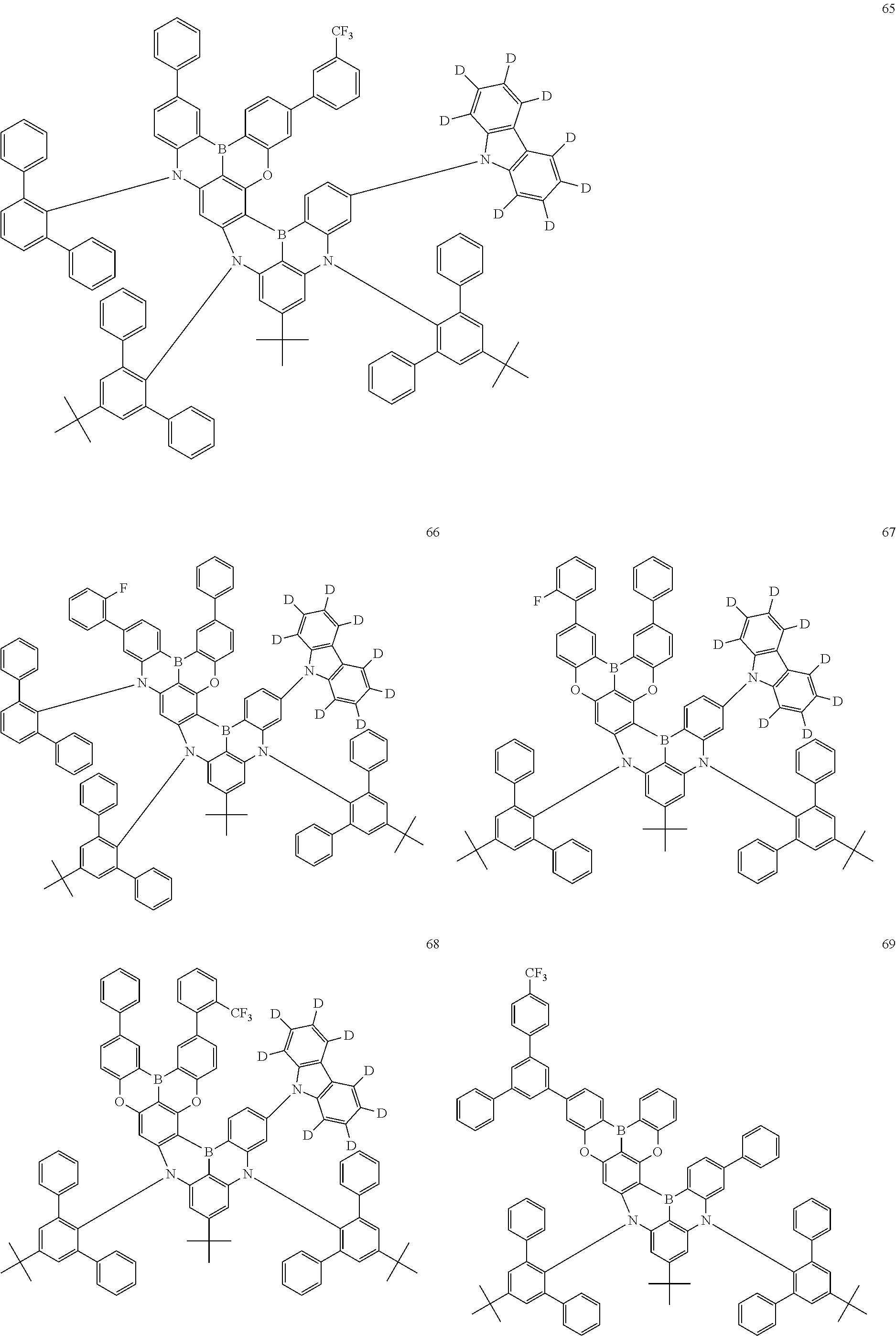

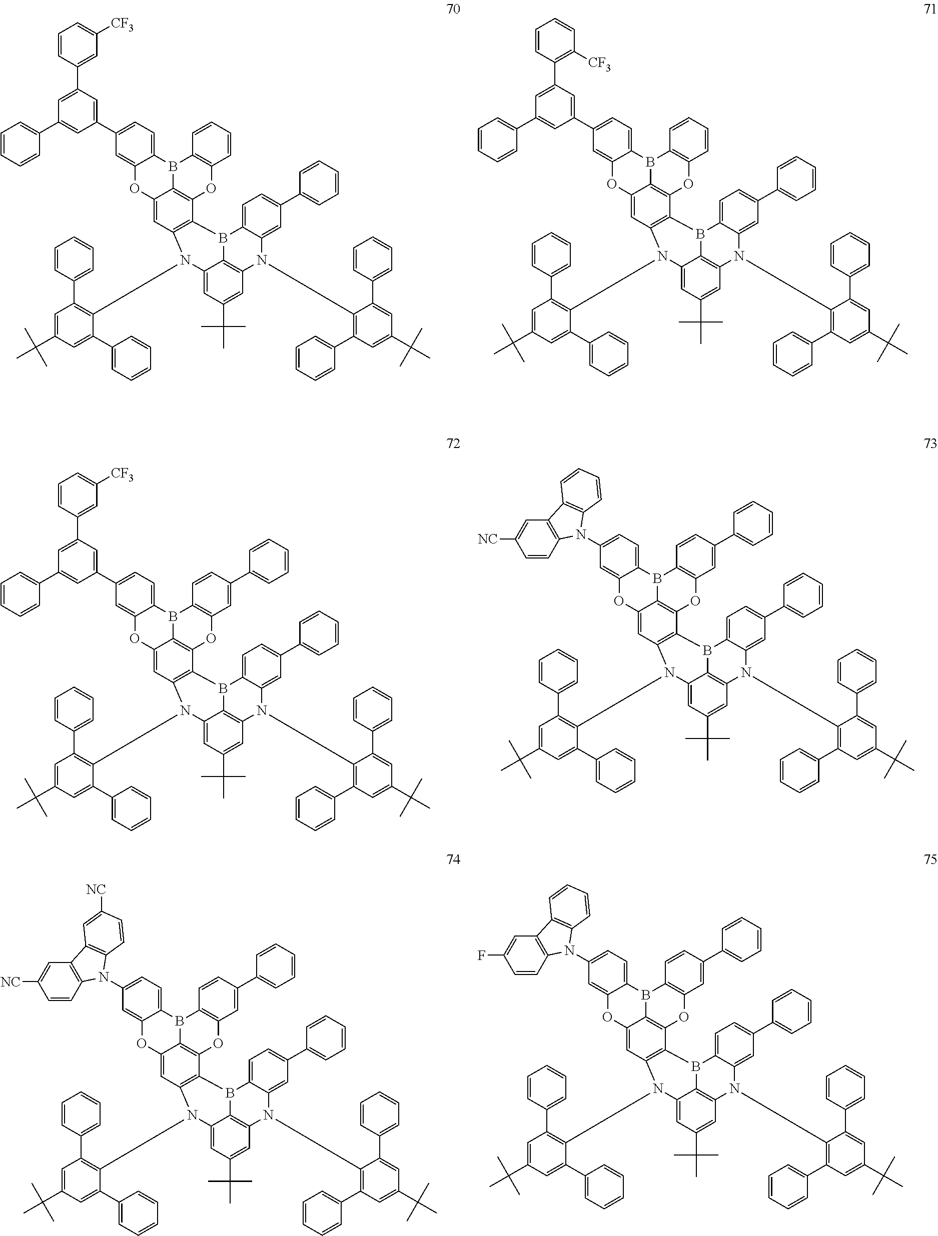

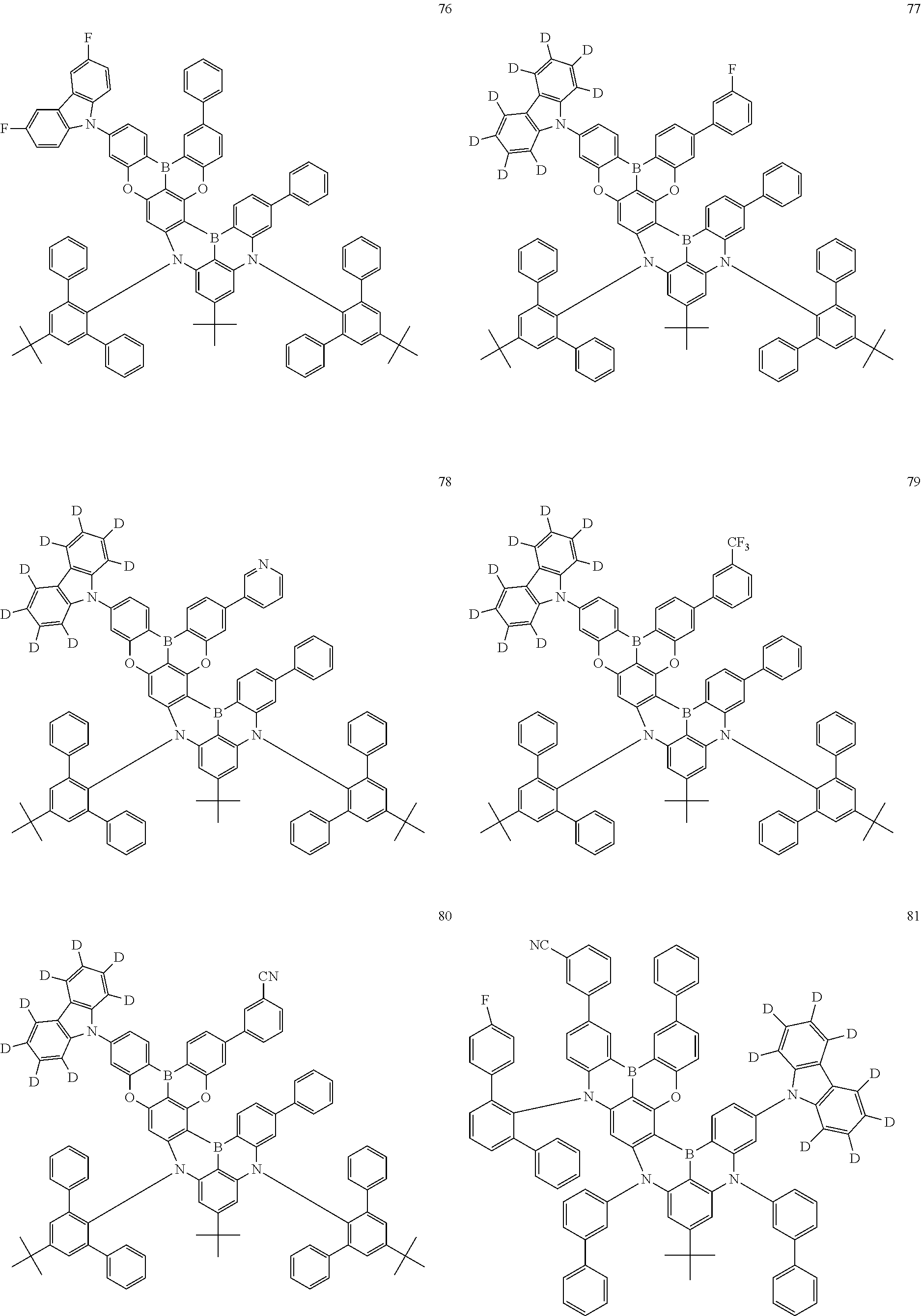

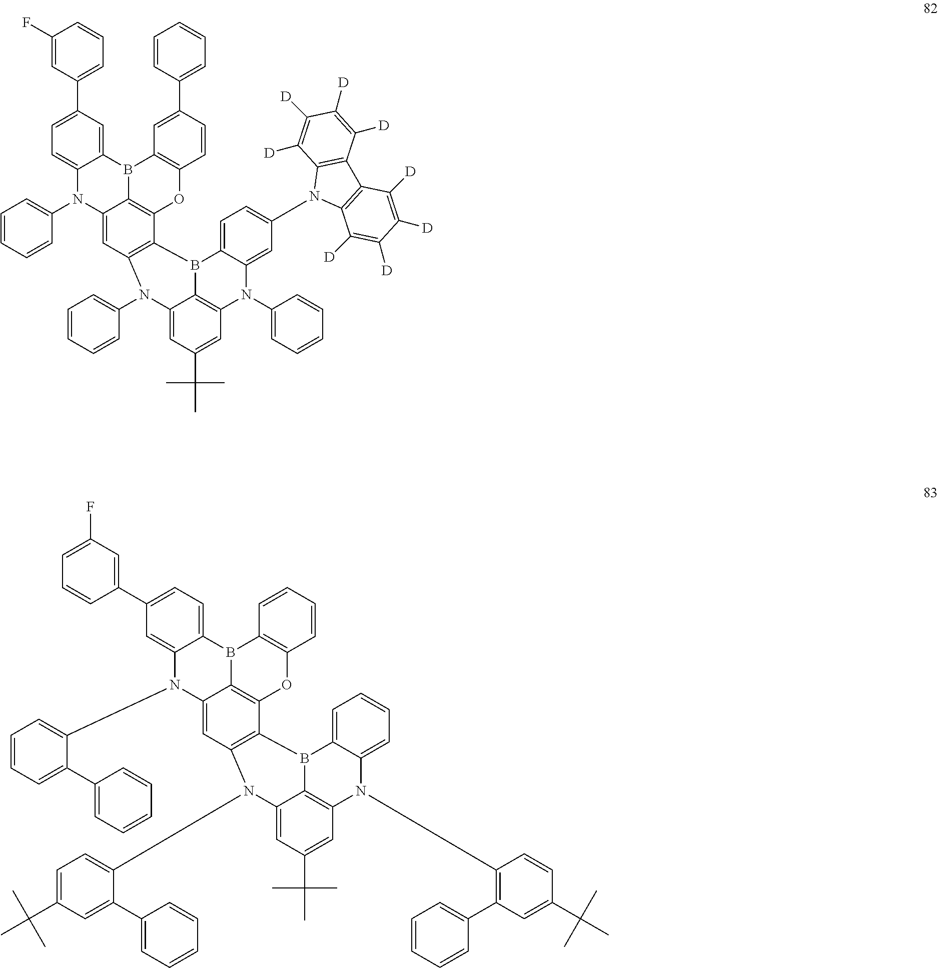 [SMILES: [2H]c1c([2H])c([2H])c2c(c1[2H])c1c([2H])c([2H])c([2H])c([2H])c1n2-c1ccc2c(c1)N(c1ccccc1)c1cc(C(C)(C)C)cc3c1B2c1c(cc2c4c1Oc1ccc(-c5ccccc5)cc1B4c1cc(-c4cccc(F)c4)ccc1N2c1ccccc1)N3c1ccccc1 ; CC(C)(C)c1ccc(N2c3ccccc3B3c4c2cc(C(C)(C)C)cc4N(c2ccc(C(C)(C)C)cc2-c2ccccc2)c2cc4c5c(c23)Oc2ccccc2B5c2ccc(-c3cccc(F)c3)cc2N4c2ccccc2-c2ccccc2)c(-c2ccccc2)c1]

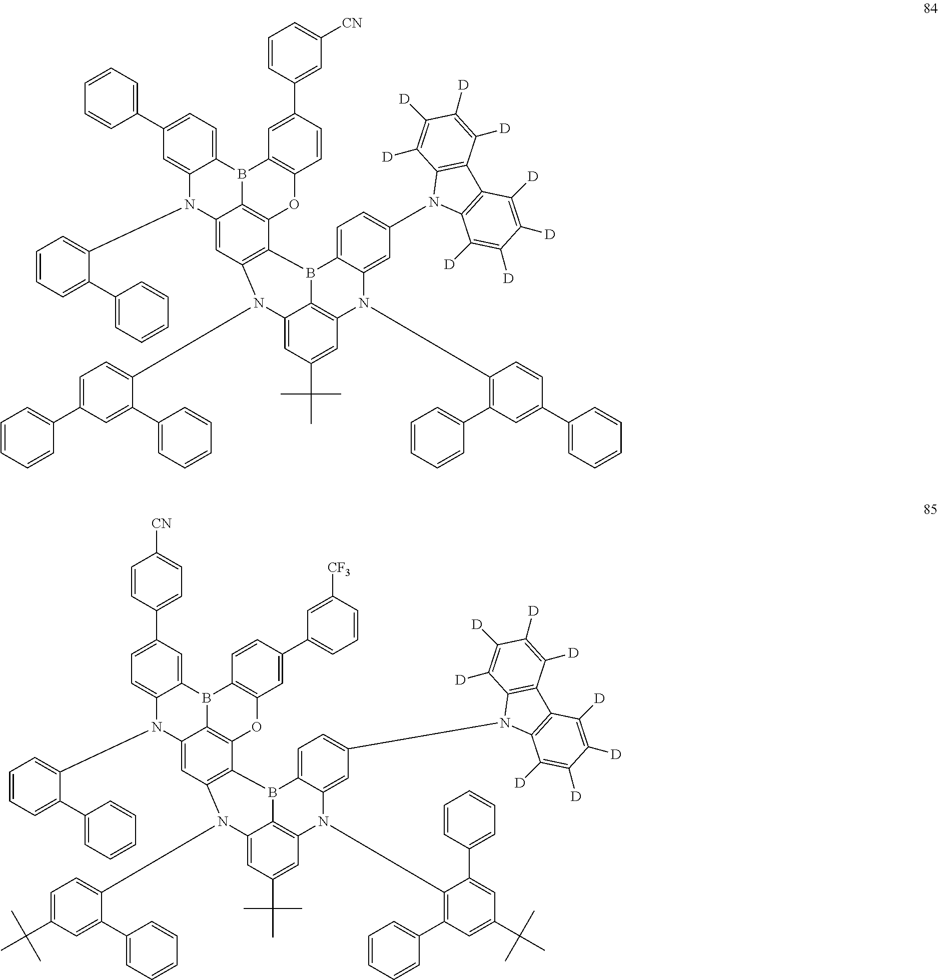 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(C(C)(C)C)cc3c1B2c1c(cc2c4c1Oc1ccc(-c5cccc(C#N)c5)cc1B4c1ccc(-c4ccccc4)cc1N2c1ccccc1-c1ccccc1)N3c1ccc(-c2ccccc2)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1c(cc2c4c1Oc1cc(-c5cccc(C(F)(F)F)c5)ccc1B4c1cc(-c4ccc(C#N)cc4)ccc1N2c1ccccc1-c1ccccc1)N3c1ccc(C(C)(C)C)cc1-c1ccccc1]

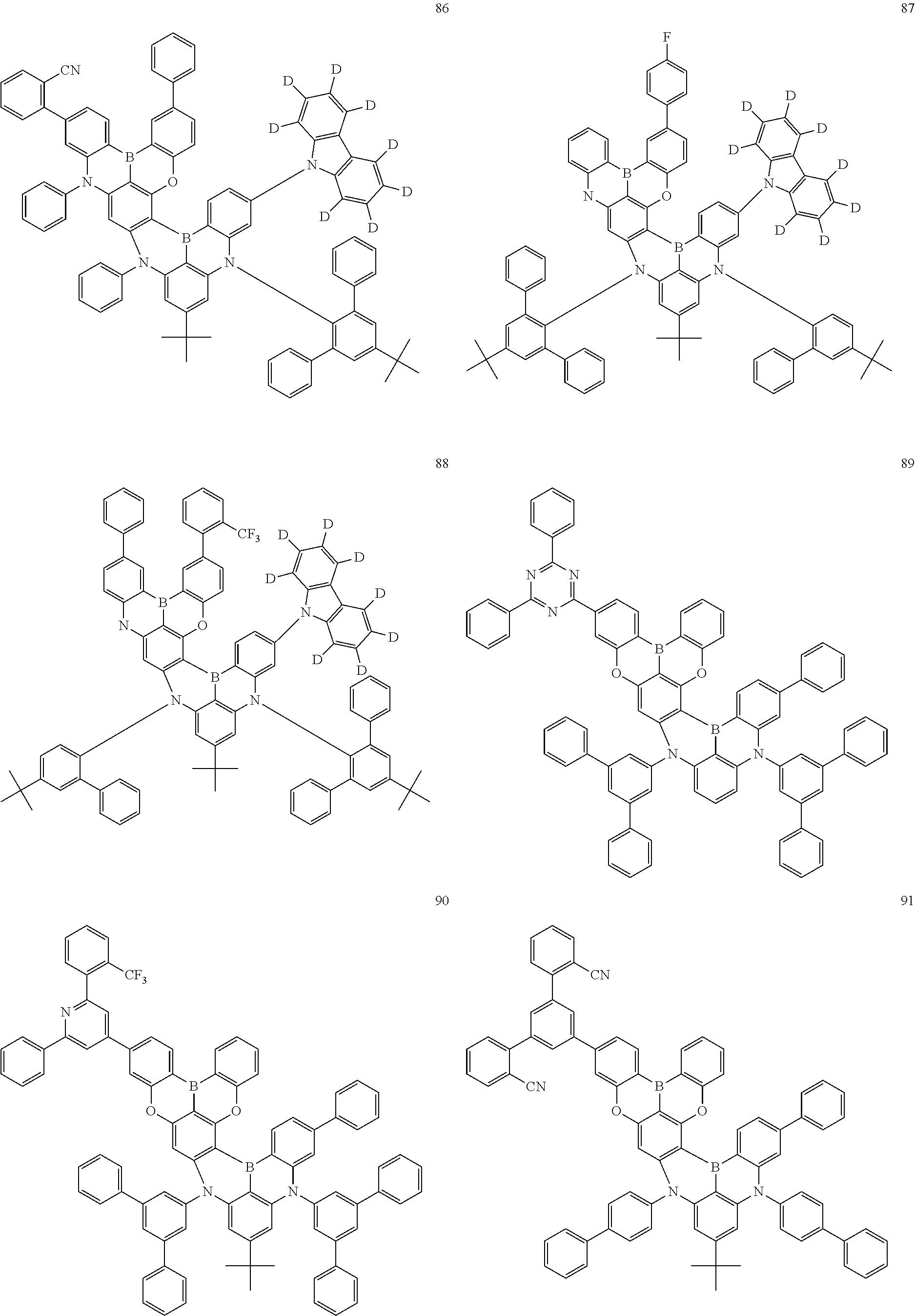

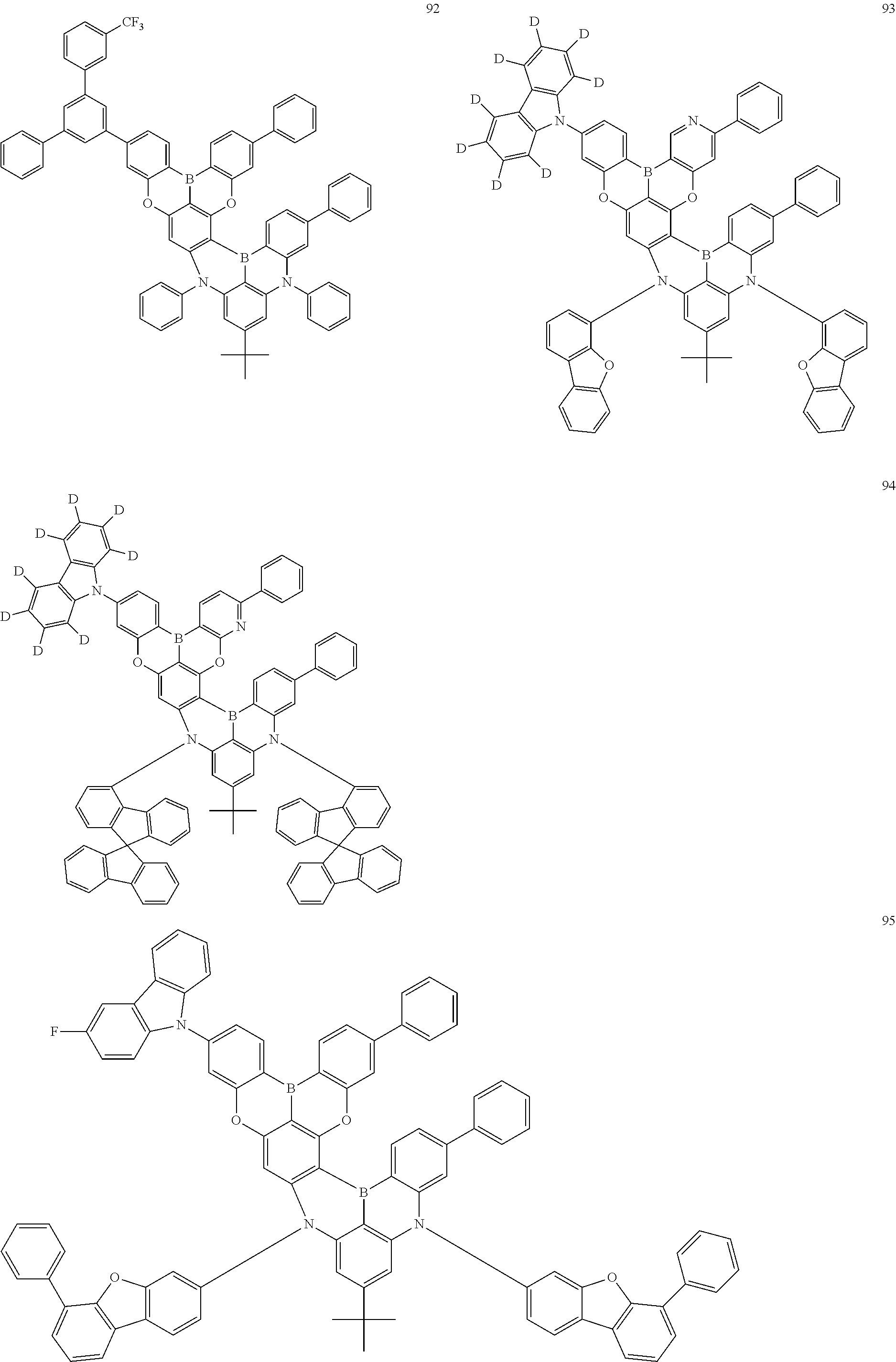

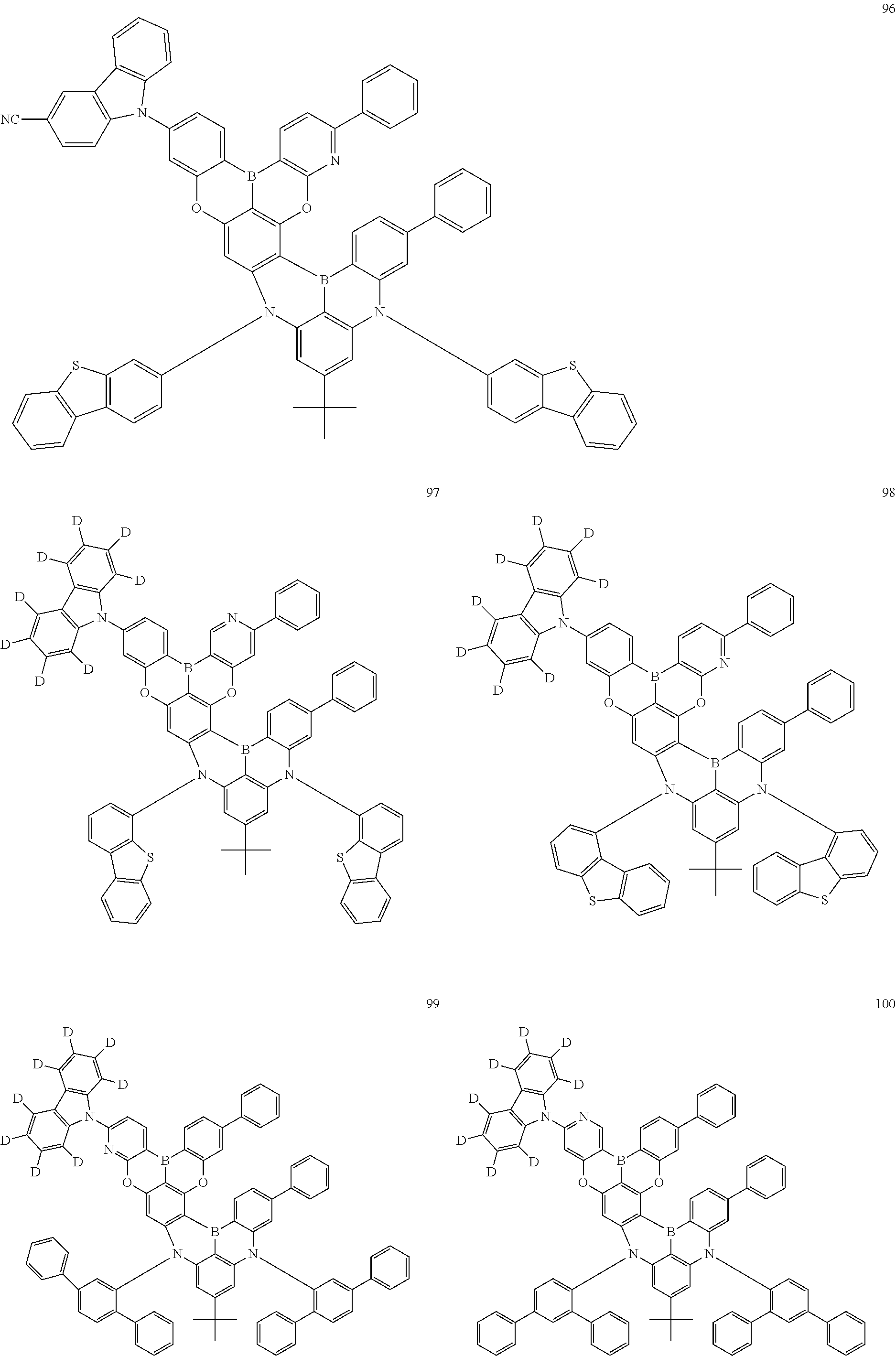

As described above, the polycyclic compound may include at least one of the electron withdrawing group or the electron-deficient N in the LUMO site. The polycyclic compound may have a multiple resonance effect enhanced by appropriately or suitably arranged boron and nitrogen.

The polycyclic compound may have a deep HOMO energy level to suppress or reduce a trap-assisted recombination phenomenon in which holes and electrons recombine in the emission layer. Accordingly, life-span of the light-emitting device may be improved.

In one or more embodiments, the HOMO energy level of the polycyclic compound may be about −5.30 eV or less, about −5.50 eV or less, or about −5.60 eV or less.

The polycyclic compound may have a more reduced absolute value (ΔEst) of a difference between an energy level of the lowest singlet excited state (S1 level) and an energy level of the lowest triplet excited state (T1 level), so that RISC and CT properties in the molecule may be improved.

In one or more embodiments, the absolute value (ΔEst) of the difference between the energy level of the lowest singlet excited state (S1 level) and the energy level of the lowest triplet excited state (T1 level) in the polycyclic compound may be about 0.14 eV or less, about 0.12 eV or less, or about 0.11 eV or less.

In one or more embodiments, the polycyclic compound may be used as a thermally activated delayed fluorescence (TADF) dopant or a host for a phosphorescent light-emitting device.

The polycyclic compound may improve light-emitting and life-span properties of the light-emitting device by enhancing both (e.g., simultaneously) exciton generation efficiency and oxidation stability in the emission layer.

The polycyclic compound may have a narrow half-width of emission spectrum to provide improved color purity.

In one or more embodiments, the polycyclic compound may be used as a blue light-emitting dopant.

In one or more embodiments, a maximum emission wavelength (e.g., peak emission wavelength) of the blue light may be, e.g., in a range from about 430 nm to about 480 nm, from about 440 nm to about 475 nm, from about 440 nm to about 465 nm, or from about 445 nm to about 465 nm.

In one or more embodiments, an emission half-width of the blue light may be about 28 nm or less, about 25 nm or less, about 20 nm or less, about 18 nm or less, from about 10 nm to about 20 nm, or from about 10 nm to about 18 nm, or from about 10 nm to about 15 nm Light-Emitting Device

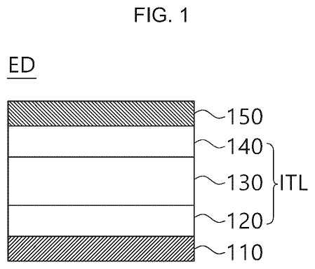

FIGS. 1 to 6 are each a schematic cross-sectional view illustrating a light-emitting device in accordance with one or more embodiments of the present disclosure.

Referring to FIG. 1, a light-emitting device ED may include a first electrode 110, a second electrode 150, and an emission layer 130 interposed between the first electrode 110 and the second electrode 150. The emission layer 130 may include the polycyclic compound of Chemical Formula 1 described above, and may have improved color properties, luminous efficiency, and life-span properties.

The light-emitting device ED may include an intermediate layer ITL including the emission layer 130 arranged between the first electrode 110 and the second electrode 150. The intermediate layer ITL may further include a hole transfer region 120 and an electron transfer region 140.

In one or more embodiments, a plurality of the emission layers may be arranged between the first electrode 110 and the second electrode 150, and a charge generation layer may be arranged between adjacent emission layers. At least one of the emission layers may include the polycyclic compound of Chemical Formula 1 described above.

Accordingly, the light-emitting device ED may have improved color properties, luminous efficiency, and life-span properties.

In one or more embodiments, the light-emitting device ED may include two or more light-emitting structures, each of which may include the emission layer, between the first electrode 110 and the second electrode 150. The light-emitting structure may include, e.g., a stacked structure of the hole transfer region 120, the emission layer 130, and the electron transfer region 140. The charge generation layer may include, e.g., a p-type (kind) charge generation layer and/or an n-type (kind) charge generation layer.

In one or more embodiments, the light-emitting device ED may be a light-emitting device of a tandem structure which may include m light-emitting structures (m is an integer of 2 or more) between the first electrode 110 and the second electrode 150, and (m−1) charge generation layers respectively arranged between adjacent light-emitting structures.

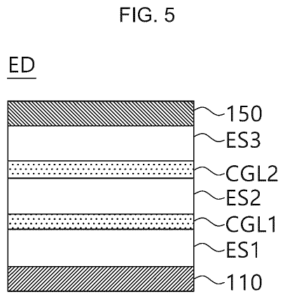

In FIG. 5, a 3-stack tandem structure including three light-emitting structures is provided, but the light-emitting device ED may have a tandem structure of a 2-stack, 4-stack, 5-stack, or more.

The first electrode 110 may be an anode or a cathode. In one or more embodiments, the first electrode 110 may be an anode, and may serve as a pixel electrode. In these embodiments, the first electrode 110 may include a conductive material with a high work function that promotes hole injection.

In one or more embodiments, the first electrode 110 may be a transmissive electrode. The first electrode 110 may include a transparent conductive oxide such as indium tin oxide (ITO), indium zinc oxide (IZO), zinc oxide (ZnO), indium tin oxide (ITZO), and/or the like.

In one or more embodiments, the first electrode 110 may be a translucent electrode or a reflective electrode. The first electrode 110 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), zinc (Zn), and an alloy containing at least two therefrom. For example, in one or more embodiments, the first electrode 110 may include Li, Ca, LiF/Ca (a stacked structure of LiF and Ca), LiF/Al (a stacked structure of LiF and Al), a mixture of Ag and Mg, and/or the like.

The first electrode 110 may have a single-layered structure or a multi-layered structure. For example, in one or more embodiments, the first electrode 110 may have a triple-layered structure of ITO/Ag/ITO.

A thickness of the first electrode 110 may be in a range of about 700 Å to about 10,000 Å. For example, in one or more embodiments, the thickness of the first electrode 110 may be in a range of about 1,000 Å to about 3,000 Å.

The second electrode 150 may be a cathode or an anode. In one or more embodiments, the second electrode 150 may serve as an electron injection electrode or as a cathode. The second electrode 150 may include a metal, an alloy, an electrically conductive compound, and/or the like, having a low work function.

For example, in one or more embodiments, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, and/or the like. The second electrode 150 may include one of the aforementioned materials, or a (e.g., any suitable) combination thereof.

The second electrode 150 may be a transmissive electrode, a translucent electrode, or a reflective electrode. The second electrode 150 may have a single-layered structure or a multi-layered structure.

The emission layer 130 may include the polycyclic compound of Chemical Formula 1 as described above.

The polycyclic compound may be included as a host or a dopant in the emission layer 130. The polycyclic compound may serve as, e.g., a thermally activated delayed fluorescence (TADF) dopant, or a host for a phosphorescent light-emitting device.

In one or more embodiments, the polycyclic compound may serve as the TADF dopant.

Accordingly, the emission layer 130 may have improved color purity and oxidation stability.

In one or more embodiments, the polycyclic compound may include at least one selected from among the compounds represented by Chemical Formulae 1-1 to 1-4 as described above.

In a non-limiting example, the emission layer 130 may include a dopant in an amount of about 0.01 parts by weight to about 15.00 parts by weight, or about 0.01 parts by weight to about 12.00 parts by weight, based on 100 parts by weight of the host.

The emission layer 130 may be to emit a blue light. For example, a maximum emission central wavelength of the blue light may be in a range from about 430 nm to about 480 nm, from about 440 nm to about 475 nm, or from about 440 nm to about 465 nm, or from about 445 nm to about 465 nm.

In one or more embodiments, the emission layer 130 may further include a host material and/or a dopant which will be described in more detail herein.

For example, in one or more embodiments, the emission layer 130 may include a host material widely suitable in the related art, such as an anthracene derivative, a pyrene derivative, a fluoranthene derivative, a chrysene derivative, a dihydrobenzanthracene derivative, a triphenylene derivative, and/or the like.

In one or more embodiments, the emission layer 130 may include, e.g., a host material represented by Chemical Formula FH. For example, the compound represented by Chemical Formula FH may be used as a fluorescent host material.

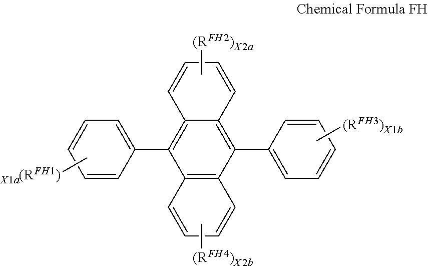

In Chemical Formula FH, R^{FH1} to R^{FH4} may each independently be hydrogen, deuterium, a halogen, a substituted or unsubstituted silyl group, a substituted or unsubstituted thio group, a substituted or unsubstituted oxy group, a substituted or unsubstituted C₁-C₁₀ alkyl group, a substituted or unsubstituted C₂-C₁₀ alkenyl group, a substituted or unsubstituted C₆-C₃₀ aryl group, a substituted or unsubstituted C₆-C₃₀ heteroaryl group, or a cyclic group formed through a combination thereof. In one or more embodiments, in Chemical Formula FH, at least one selected from among R^{FH1} to R^{FH4} may form a condensed ring with a bonded benzene ring.

In Chemical Formula FH, x1a and x1b may each independently be an integer from 0 to 5; and x2a and x2b may each independently be an integer from 0 to 4. When x1 a, x1 b, x2a, and x2b are each 2 or more, two or more of respective R^{FH1}(s) to R^{FH4}(s) may be the same as or different from each other.

In one or more embodiments, the emission layer 130 may include, e.g., a host material represented by Chemical Formula PH. For example, the compound represented by Chemical Formula PH may be used as a host material for a phosphorescent device (e.g., for a phosphorescent dopant).

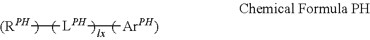

In Chemical Formula PH, R^{PH} may be a substituted or unsubstituted carbazole group. L^{PH} may be a direct linkage, a substituted or unsubstituted C₆-C₃₀ arylene group, or a substituted or unsubstituted C₂-C₃₀ heteroarylene group. Ar^{PH} may be a substituted or unsubstituted C₆-C₆₀ aryl group or a substituted or unsubstituted C₂-C₆₀ heteroaryl group.

As described above in the definition of terminology, the term “C₆-C₆₀ aryl group” may encompass a group in which multiple aryl rings are condensed or bonded through a cyclic group (e.g., an alicyclic hydrocarbon ring). For example, a C₆-C₆₀ aryl group may be a fluorenyl group.

As described above in the definition of terminology, the term “C₂-C₃₀ heteroaryl group” may encompass a group in which multiple aryl rings are condensed or bonded through a heterocyclic ring. For example, a C₂-C₃₀ heteroaryl group may be a carbazole group, a dibenzofuran group, a dibenzothiophene group, and/or the like.

In one or more embodiments, a C₂-C₃₀ heteroaryl group may be a group in which multiple aryl rings are condensed or bonded to each other through same or different heterocyclic rings.

In one or more embodiments, a substituent included in Ar^{PH} may be a silyl group represented by —Si(R^{sa})(R^{sb})(R^{sc}); and R^{sa}, R^{sb}, and R^{sc} may each independently be hydrogen, a halogen, a hydroxyl group, a C₁-C₆₀ alkyl group, a C₁-C₆₀ alkoxy group, a C₆-C₆₀ aryl group, or a C₂-C₃₀ heteroaryl group. At least one selected from among R^{sa}, R^{sb}, and R^{sc} may be a C₆-C₆₀ aryl group or a C₂-C₃₀ heteroaryl group. For example, in one or more embodiments, R^{sa}, R^{sb} and R^{sc} may each independently be a C₆-C₆₀ aryl group or a C₂-C₃₀ heteroaryl group.

In Chemical Formula PH, Ix may be an integer from 0 to 10. When Ix is 2 or more, two or more of L^{PH}(s) may be the same as or different from each other.

In one or more embodiments, the emission layer 130 may include, e.g., BCPDS (bis(4-(9H-carbazol-9-yl) phenyl) diphenylsilane), POPCPA ((4-(1-(4-(diphenylamino) phenyl) cyclohexyl) phenyl) diphenyl-phosphine oxide), DPEPO (bis[2-(diphenylphosphino)phenyl]ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl) dibenzo[b,d]furan), TCTA (4,4′,4″-tris(carbazol-9-yl)-triphenylamine), TPBi (1,3,5-tris(1-phenyl-1H-benzo[d]imidazol-2-yl)benzene), Alq3 (tris(8-hydroxyquinolinato) aluminum), ADN (9,10-di(naphthalen-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (hexaphenyl cyclotriphosphazene), UGH2 (1,4-bis(triphenylsilyl)benzene), DPSiO3 (hexaphenylcyclotrisiloxane), DPSiO4 (octaphenylcyclotetrasiloxane), and/or the like, as a host material.

In one or more embodiments, in the emission layer 130, the host may include one of the materials described above, or any combination thereof.

Non-limiting examples of compounds represented by Chemical Formula PH are as follows.

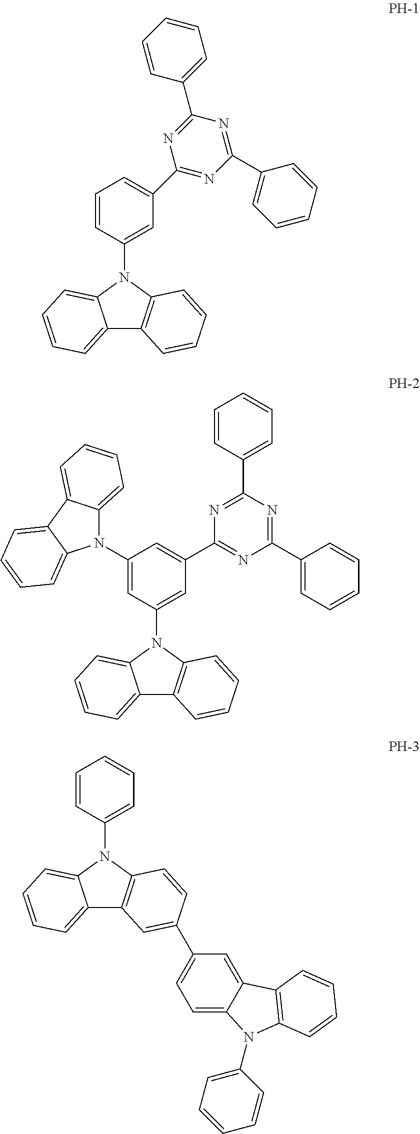

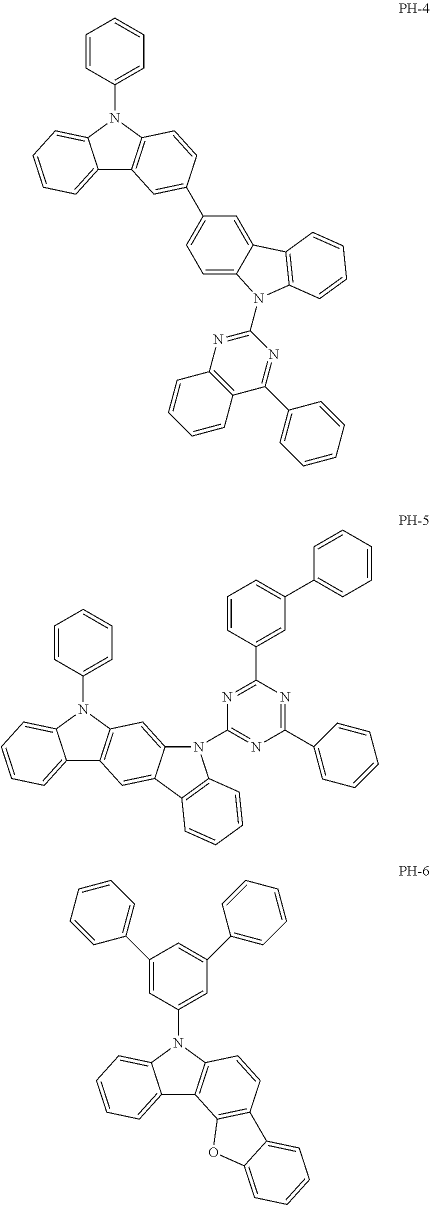

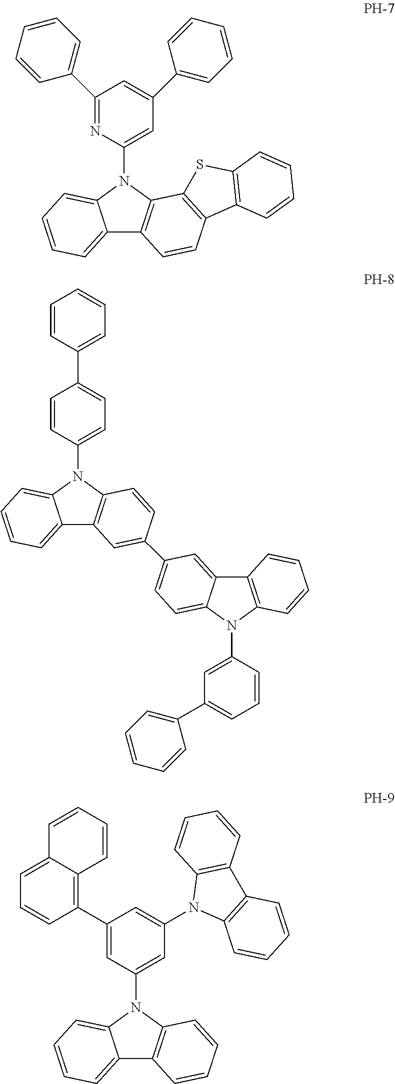

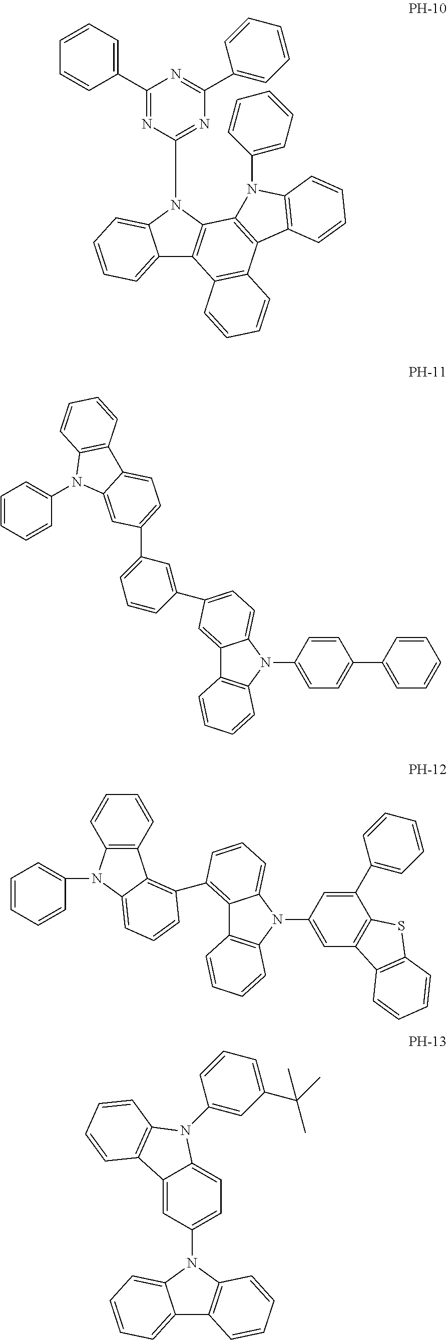 [SMILES: c1ccc(-c2nc(-c3ccccc3)nc(-n3c4ccccc4c4c5ccccc5c5c6ccccc6n(-c6ccccc6)c5c43)n2)cc1 ; c1ccc(-c2ccc(-n3c4ccccc4c4cc(-c5cccc(-c6ccc7c8ccccc8n(-c8ccccc8)c7c6)c5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; CC(C)(C)c1cccc(-n2c3ccccc3c3cc(-n4c5ccccc5c5ccccc54)ccc32)c1]

In one or more embodiments, the emission layer 130 may further include a dopant interacting with the host.

In one or more embodiments, the emission layer 130 may include a dopant represented by Chemical Formula FD. For example, the compound represented by Chemical Formula FD may be used as a fluorescent dopant.

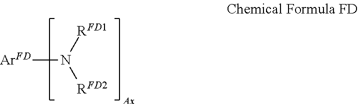

In Chemical Formula FD, Ar^{FD}, R^{FD1}, and R^{FD2} may each independently be a substituted or unsubstituted C₃-C₆₀ carbocyclic group or a substituted or unsubstituted C₁-C₆₀ heterocyclic group. Ax may be an integer from 1 to 6.

In one or more embodiments, Ar^{FD} may include a condensed ring structure in which three or more aryl rings or benzene rings are condensed together (e.g., an anthracene group, a chrysene group, a pyrene group, and/or the like).

In one or more embodiments, the emission layer 130 may include a dopant for a phosphorescent device (e.g., a phosphorescent dopant). The dopant for the phosphorescent device may include an organometallic compound that includes a central metal and at least one ligand bonded to the central metal via a coordinate bond. The central metal may include, e.g., a transition metal, and the ligand may include, e.g., a monodentate ligand, a bidentate ligand, a tridentate ligand, a tetradentate ligand, a pentadentate ligand, a hexadentate ligand, and/or a (e.g., any suitable) combination thereof.

In one or more embodiments, the dopant for the phosphorescent device (e.g., phosphorescent dopant) may include, e.g., a compound represented by Chemical Formula PD.

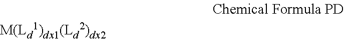

In Chemical Formula PD, M may be a transition metal, e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), ruthenium (Ru), copper (Cu), or thulium (Tm).

In Chemical Formula PD, L_{d}¹ may be a ligand represented by Chemical Formula LD1.

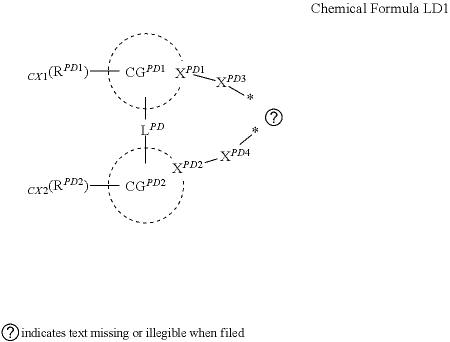

In Chemical Formula LD1, X^{PD1} and X^{PD2} may each independently be C or N.

In one or more embodiments, one of X^{PD1} and X^{PD2} may be C and the other may be N. In one or more embodiments, X^{PD1} and X^{PD2} may each be N.

In Chemical Formula LD1, CG^{PD1} and CG^{PD2} may each independently be a substituted or unsubstituted C₃-C₆₀ carbocyclic group or a substituted or unsubstituted C₁-C⁶⁰ heterocyclic group.

For example, CG^{PD1} and CG^{PD2} may each independently be a pyrrole group, a pyrazole group, an imidazole group, a triazole group, an oxazole group, an isoxazole group, a thiazole group, an isothiazole group, an oxadiazole group, a thiadiazole group, a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In Chemical Formula LD1, L^{PD} may be a single bond, a substituted or unsubstituted methylene group, a substituted or unsubstituted ethylene group, *—O—*′, *—S—*′, *—C(═O)—*′, *—N(R^{PD3})—*′, *—C(R^{PD4})═*′, or *=C(R^{PD5})—*′.

In Chemical Formula LD1, X^{PD3} and X^{PD4} may each independently be a chemical bond, O, S, N(R^{PD6}), B(R^{PD7}), P(R^{PD8}), C(R^{PD8})(R^{PD9}), or Si(R^{PD10})(R^{PD11}).

The chemical bond may be, e.g., a covalent bond or a coordinate bond.

In Chemical Formula LD1, R^{PD1} and R^{PD2} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, a substituted or unsubstituted amine group, a substituted or unsubstituted aniline group, —B(R^{PD12})(R^{PD13}), —C(═O)(R^{PD14}), —S(═O)₂(R^{PD15}), or —P(═O)(R^{PD16})(R^{PD17}). The silyl group may be represented by -Si(R^{sa})(R^{sb})(R^{sc}), as explained above.

R^{PD3} to R^{PD17} may each independently be hydrogen, deuterium, —F, —Cl, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group.

In Chemical Formula LD1, cx1 and cx2 may each independently be an integer from 0 to 10. When at least one of cx1 or cx2 is 2 or more, two or more of R^{PD1}(s) and/or two or more of R^{PD2}(s) may be the same as or different from each other.

The symbols —* and —*′ each represent a binding site where the ligand represented by Chemical Formula LD1 bonds to M.

In Chemical Formula PD, dx1 may be an integer from 1 to 3. When dx1 is 2 or 3, two or three of L_{d}¹(s) may be the same as or different from each other. Among two or three of L_{d}¹(s), CG^{PD1} and/or CG^{PD2} adjacent to each other may be connected to each other through a connecting group such as L^{PD1}, L^{PD2}, and/or the like. The connecting group such as L^{PD1}, L^{PD2}, and/or the like, may each independently be the same as defined with respect to L^{PD}.

In Chemical Formula PD, L_{d}² may be an organic ligand. L_{d}² may include, e.g., a halogen, CO, NO, CS, picolinate, acetate, oxalate, a diketone group, an isonitrile group, isothiocyanato-N, thiosulphato-S, an alkyl phosphine, phenylphosphine, an aryl phosphine, phosphine oxide, phosphite, or a (e.g., any suitable) combination thereof.

In Chemical Formula PD, dx2 is an integer of 1 to 4. When dx2 is 2 or more, two or more of L_{d}²(s) may be the same as or different from each other.

Non-limiting examples of the compound represented by Chemical Formula PD are as follows.

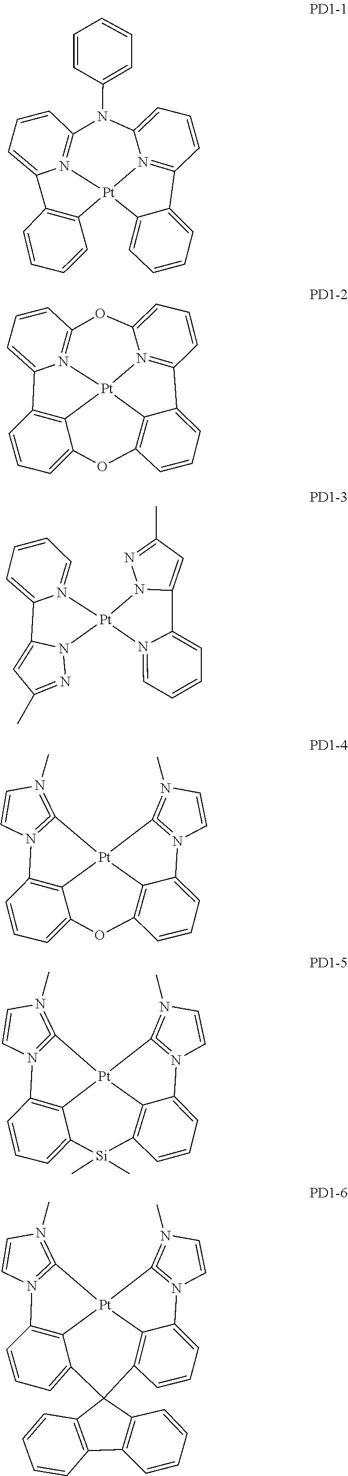

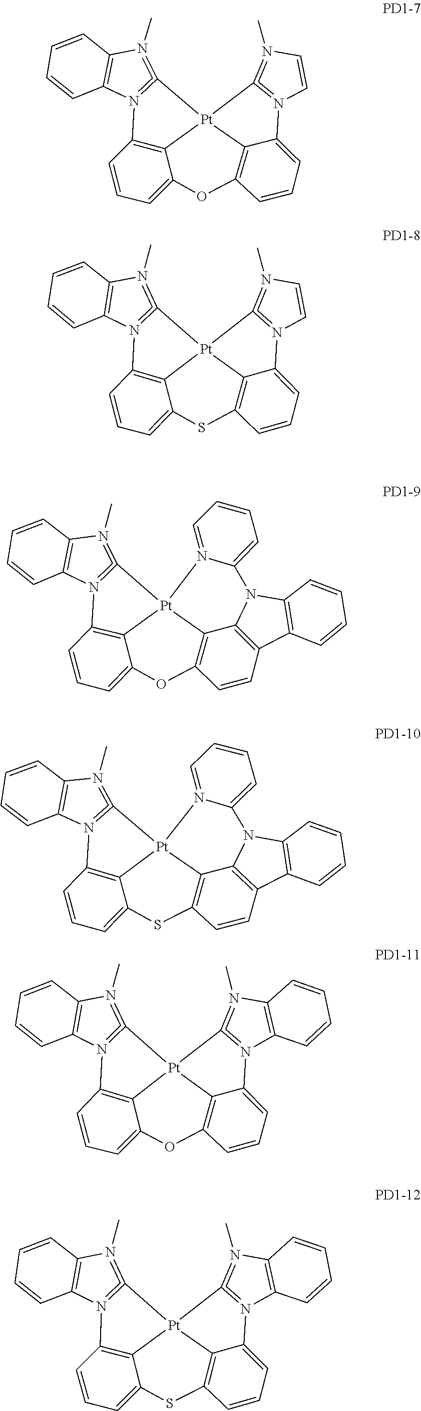

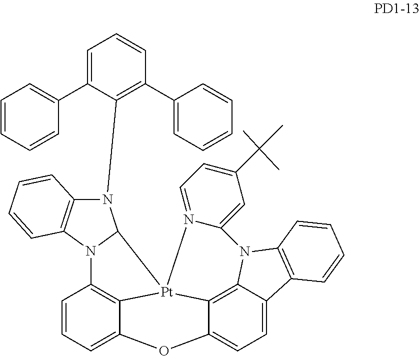

In one or more embodiments, the emission layer 130 may include one or more selected from among a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi), and/or the like), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), and/or the like), and/or the like, as a fluorescent dopant material.

In one or more embodiments, the emission layer 130 may include a metal complex that includes iridium (Ir), platinum (Pt), osmium (Os), gold (Au), titanium (Ti), zirconium (Zr), hafnium (Hf), europium (Eu), terbium (Tb), or thulium (Tm) as a phosphorescent dopant, in addition to one or more of the materials described above. For example, Flrpic (iridium(III) bis(4,6-difluorophenylpyridinato-N,C2′)picolinate), FIr6 (bis(2,4-difluorophenylpyridinato)-tetrakis(1-pyrazolyl)borate iridium(Ill)), PtOEP (platinum octaethyl porphyrin), and/or the like, may be used as a phosphorescent dopant.

In one or more embodiments, the emission layer 130 may include a boron-containing dopant represented by Chemical Formula BD.

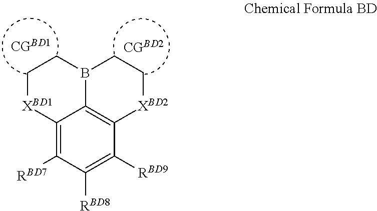

In Chemical Formula BD, X^{BD1} and X^{BD2} may each independently be N(R^{BD1}), P(R^{BD2}), C(R^{BD3})(R^{BD4}), Si(R^{BD5})(R^{BD6}), S, or O. In one or more embodiments, X^{BD1} and X^{BD2} may each be N. R^{BD1} to R^{BD6} may each independently be hydrogen, deuterium, a substituted or unsubstituted C₁-C₂₀ alkyl group, a substituted or unsubstituted C₆-C₆₀ aryl group, or a substituted or unsubstituted C₂-C₃₀ heteroaryl group. R^{BD7}, R^{BD8}, and R^{BD9} may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted C₁-C₂₀ alkyl group, a substituted or unsubstituted C₆-C₆₀ aryl group, or a substituted or unsubstituted C₂-C₃₀ heteroaryl group. R^{BD7}, R^{BD8}, and/or R^{BD9} may be optionally bonded to an adjacent group to form a ring.

In Chemical Formula BD, CG^{BD1} and CG^{BD2} each represent a cyclic group, and CG^{BD1} and CG^{BD2} may each independently be a substituted or unsubstituted C₃-C₆₀ carbocyclic group or a substituted or unsubstituted C₁-C₆₀ heterocyclic group. In one or more embodiments, CG^{BD1} and CG^{BD2} may each independently be a substituted or unsubstituted C₆-C₆₀ aryl group or a substituted or unsubstituted C₂-C₃₀ heteroaryl group.

In one or more embodiments, CG^{BD1} and CG^{BD2} may each independently be a substituted or unsubstituted benzene ring. In these embodiments, the boron-containing dopant may serve as a thermally activated delayed fluorescence (TADF) dopant.

In one or more embodiments, one of CG^{BD1} and CG^{BD2} may be a non-condensed aryl group or a non-condensed heteroaryl group, and the other one thereof may be a condensed polycyclic aryl group or a condensed polycyclic heteroaryl group. In these embodiments, the boron-containing dopant may serve as a fluorescent dopant.

In one or more embodiments, the emission layer 130 may include one of the dopant materials described above, or any combination thereof.

In one or more embodiments, the emission layer 130 may include two or more host materials. For example, in one or more embodiments, the emission layer 130 may include a hole transporting host and an electron transporting host. In these embodiments, the emission layer 130 may include a hole transporting host, an electron transporting host, a photosensitive agent, and a dopant. In one or more embodiments, the hole transporting host and the electron transporting host may form an exciplex, and energy may be transferred from the exciplex to the photosensitive agent and from the photosensitive agent to the dopant, thereby inducing a light emission.

Non-limiting examples of the hole transporting host may include a compound represented by Chemical Formula HT which will be described in more detail later.

Non-limiting examples of the electron transporting host may include a compound represented by Chemical Formula ET which will be described in more detail later.

In one or more embodiments, the emission layer 130 may include quantum dots. A quantum dot may include a Group II-VI compound, a Group III-VI compound, a Group I-III-VI compound, a Group III-V group compound, a Group III-II-V group compound, a Group IV-VI compound, a Group IV element, a Group IV compound, and/or a (e.g., any suitable) combination thereof.

The quantum dot may include a core that includes the compound as described above, and a shell around (e.g., surrounding) the core. The shell may include an inorganic oxide or a semiconductor compound. Examples of the semiconductor compound as a shell may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AIP, AlSb, and/or the like.

In one or more embodiments, a color of light from a quantum dot may be adjusted according to a particle size of the quantum dot. The quantum dot may be a blue quantum dot that is to emit blue light, a red quantum dot that is to emit red light, or a green quantum dot that is to emit green light.

The hole transfer region 120 may be formed between the first electrode 110 and the emission layer 130. The hole transfer region 120 may have a single-layered structure or a multi-layered structure including different materials.

The hole transfer region 120 may include a hole injection layer, a hole transport layer, and/or an electron blocking layer, and may further include an auxiliary emission layer.

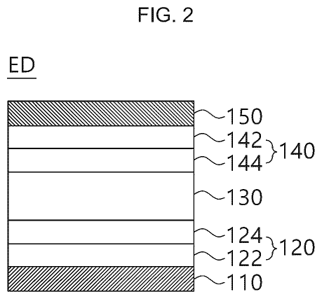

In one or more embodiments, as illustrated in FIG. 2, the hole transfer region 120 may include a hole injection layer 122 and a hole transport layer 124, sequentially stacked from the first electrode 110.

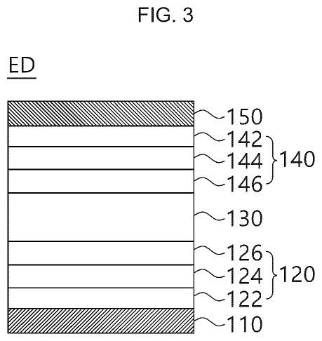

In one or more embodiments, as illustrated in FIG. 3, the hole transfer region 120 may include a hole injection layer 122, a hole transport layer 124, and an electron blocking layer 126, sequentially stacked from the first electrode 110. The electron blocking layer 126 may block electrons from the electron transfer region 140 to the hole transfer region 120. Accordingly, the generation of excitons in the emission layer 130 may be increased, and light-emission efficiency may be further increased.

For example, in one or more embodiments, the hole transfer region 120 may include a compound represented by Chemical Formula HT.

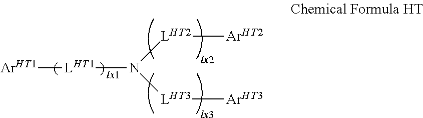

In Chemical Formula HT, L^{HT1}, L^{HT2}, and L^{HT3} may each independently be a direct linkage, a substituted or unsubstituted C₆-C₆₀ arylene group, or a substituted or unsubstituted C₂-C₃₀ heteroarylene group.

In Chemical Formula HT, Ix1 to Ix3 may each independently be an integer from 0 to 10. When Ix1, Ix2, or Ix3 is 2 or more, two or more of respective L^{HT3}(s), L^{HT1}(s), or L^{HT2}(s), may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group. For example, when Ix3 is 2 or more, two or more of L^{HT3}(s) may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group. When Ix1 is 2 or more, two or more of L^{HT1}(s) may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group. When Ix2 is 2 or more, two or more of L^{HT2}(s) may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group.

In Chemical Formula HT, Ar^{HT1} and Ar^{HT2} may each independently be a substituted or unsubstituted C₆-C₆₀ aryl group or a substituted or unsubstituted C₂-C₃₀ heteroaryl group. Ar^{HT3} may be a substituted or unsubstituted C₆-C₃₀ aryl group.

In one or more embodiments, the compound represented by Chemical Formula HT may be a monoamine compound. In one or more embodiments, the compound represented by Chemical Formula HT may be a diamine compound in which at least one selected from among Ar^{HT1} to Ar^{HT3} includes an amine group as a substituent.

In one or more embodiments, the compound represented by Chemical Formula HT may be a carbazole-based compound in which at least one of Ar^{HT1} or Ar^{HT2} includes a substituted or unsubstituted carbazole group, or a fluorene-based compound in which at least one of Ar^{HT1} or Ar^{HT2} includes a substituted or unsubstituted fluorene group.

In one or more embodiments, two adjacent groups among Ar^{HT1} to Ar^{HT3} may be condensed together to form a ring.

Non-limiting examples of the compound represented by the formula HT are as follows.

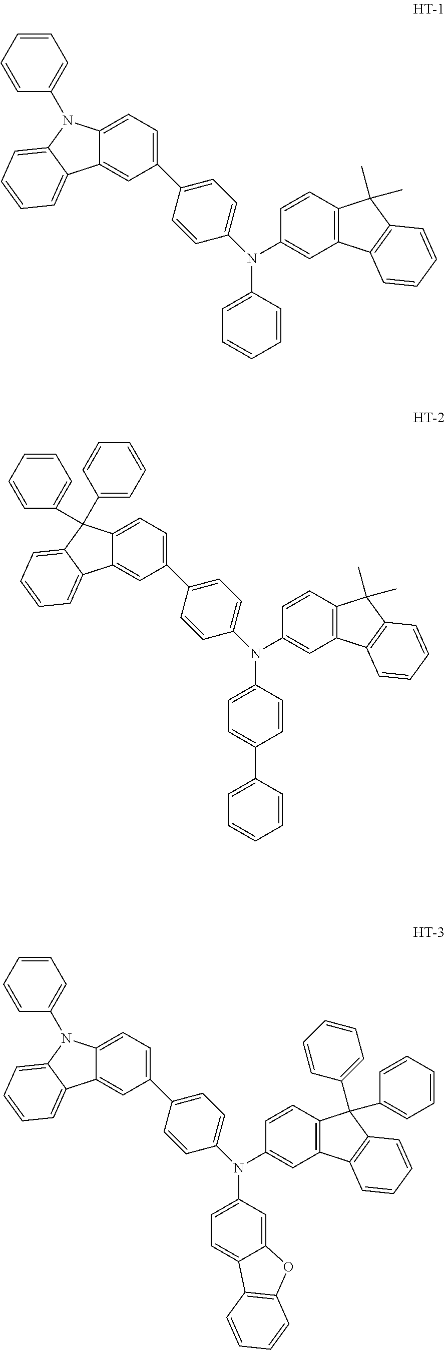 [SMILES: CC1(C)c2ccccc2-c2cc(N(c3ccccc3)c3ccc(-c4ccc5c(c4)c4ccccc4n5-c4ccccc4)cc3)ccc21 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21 ; c1ccc(-n2c3ccccc3c3cc(-c4ccc(N(c5ccc6c(c5)-c5ccccc5C6(c5ccccc5)c5ccccc5)c5ccc6c(c5)oc5ccccc56)cc4)ccc32)cc1]

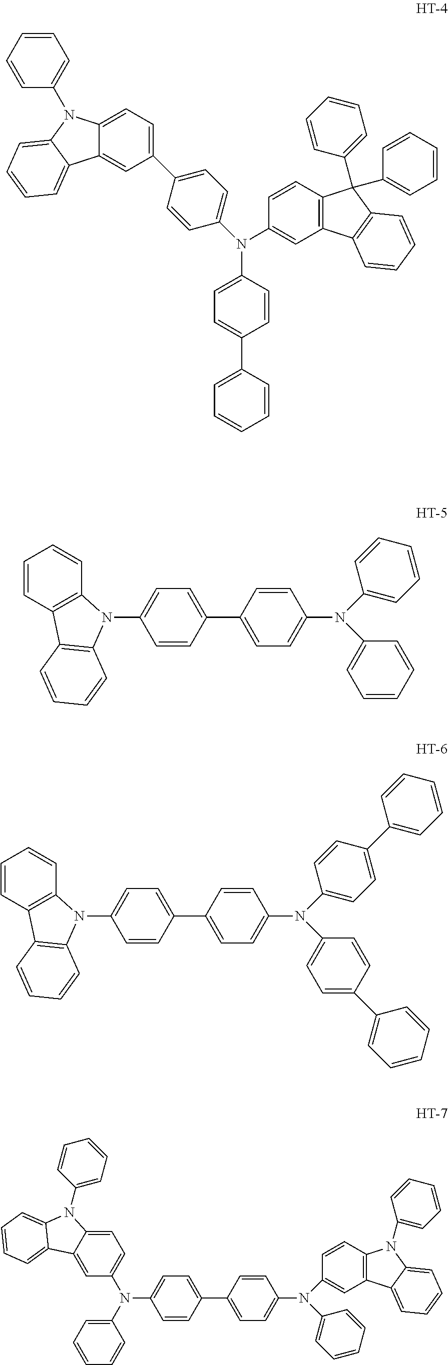 [SMILES: c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(N(c2ccccc2)c2ccc(-c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

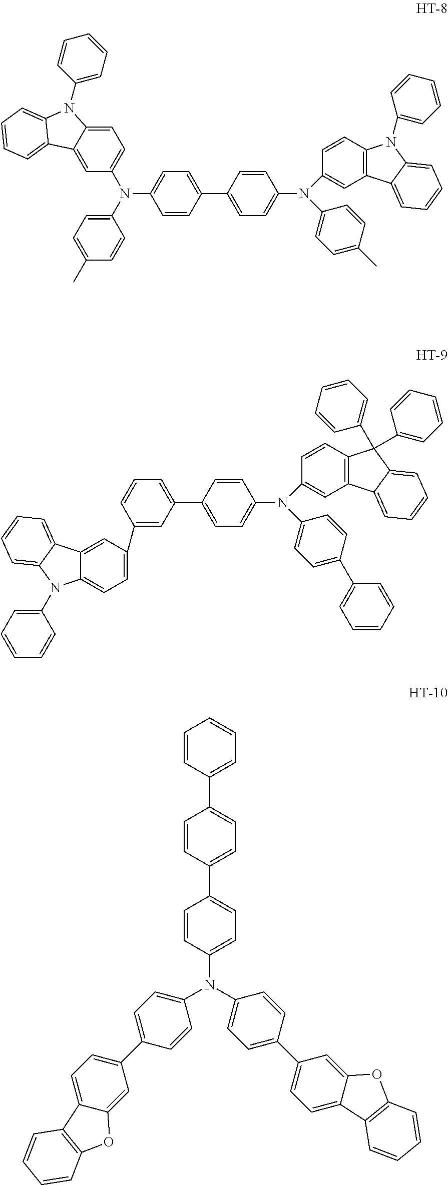 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; c1ccc(-c2ccc(N(c3ccc(-c4cccc(-c5ccc6c(c5)c5ccccc5n6-c5ccccc5)c4)cc3)c3ccc4c(c3)-c3ccccc3C4(c3ccccc3)c3ccccc3)cc2)cc1 ; c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1]

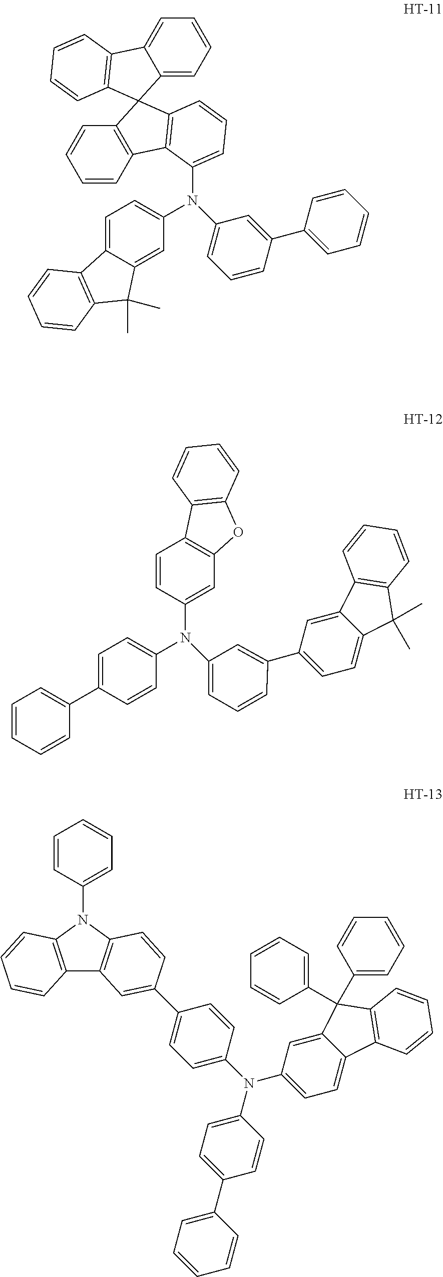 [SMILES: CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

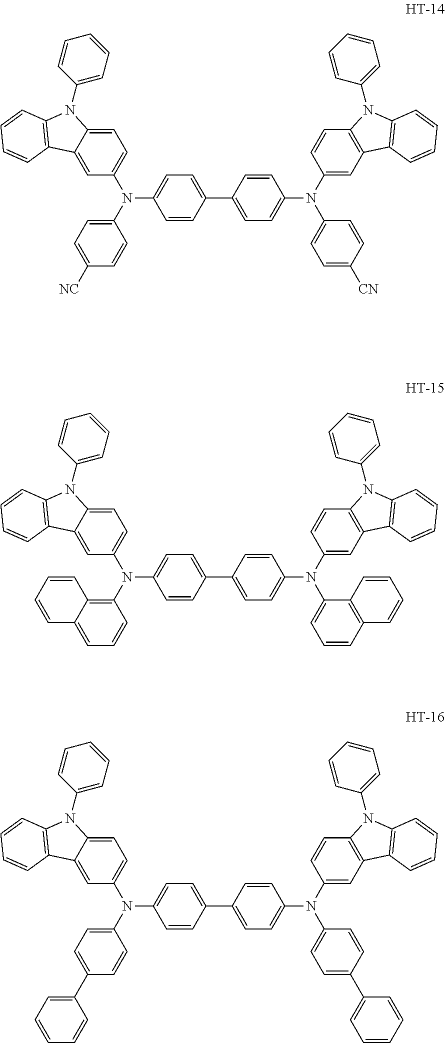 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

For example, in one or more embodiments, the hole transfer region 120 may include one or more selected from among m-MTDATA (4,4′, 4″-[tris(3-methylphenyl)phenylamino]triphenylamine), TDATA (4,4′4″-tris(N,N-diphenylamino)triphenylamine), 2-TNATA (4,4′, 4″-tris[N(2-naphthyl)-N-phenylamino]-triphenylamine), NPB (N,N′-di(naphthalen-1-yl)-N,N′-diphenyl-benzidine), TPD (N,N′-bis(3-methylphenyl)-N,N′-diphenyl-[1,1′-biphenyl]-4,4′-diamine), Spiro-TPD, Spiro-NPB, DNTPD (N¹,N^{1′}-([1,1′-biphenyl]-4,4′-diyl)bis(N¹-phenyl-N⁴,N⁴-di-m-tolylbenzene-1,4-diamine), TAPC (4,4′-cyclohexylidene bis[N,N-bis(4-methylphenyl)benzenamine]), HMTPD (4,4′-bis[N,N′-(3-tolyl)amino]-3,3′-dimethyl biphenyl), TCTA (4,4′, 4″-tris(N-carbazolyl)triphenylamine), PANI/DBSA (polyaniline/dodecylbenzenesulfonic acid), PEDOT/PSS (poly(3,4-ethylenedioxythiophene)/poly(4-styrenesulfonate)), PANI/CSA(Polyaniline/Camphor sulfonic acid), PANI/PSS (polyaniline/poly(4-styrenesulfonate)), a phthalocyanine compound, a carbazole compound (N-phenylcarbazole, polyvinylcarbazole, and/or the like), a fluorene compound, and/or the like. The hole transfer region 120 may include one of the hole transfer materials described above, or a (e.g., any suitable) combination thereof.

The hole transfer materials described above may be included in at least one of the hole injection layer 122, the hole transport layer 124, or the electron blocking layer 126.

In one or more embodiments, the hole transfer region 120 may further include a charge generating material. The charge generating material may be a dopant material such as a p-dopant, so that conductivity of the hole transfer region 120 may be improved.

Non-limiting examples of dopant materials may include a halogenated metal compound (e.g., a metal halide) such as LiF, NaCl, CsF, RbCl, RbI, CuI, and/or KI; a quinone derivative such as TCNQ (tetracyanoquinodimethane), F4-TCNQ (2,3,5,6-tetrafluoro-7,7,8,8-tetracyanoquinodimethane), and/or the like; a cyano-containing compound such as HATCN (dipyrazino[2,3-f:2′,3′-h]quinoxaline-2,3,6,7,10,11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), and/or the like; a tungsten (W) oxide; a molybdenum (Mo) oxide; and/or the like. The hole transfer region 120 may include one of the dopant materials described above, or a (e.g., any suitable) combination thereof.

A thickness of the hole transfer region 120 may be in a range of about 100 Å to about 10,000 Å. For example, the thickness of the hole transfer region 120 may be in a range of about 100 Å to about 1,500 Å.

When the hole transfer region 120 includes the hole injection layer 122 and/or the hole transport layer 124, a thickness of the hole injection layer 122 may be in a range from about 100 Å to about 9,000 Å, from about 100 Å to about 3,000 Å, or from about 100 Å to about 1,000 Å. A thickness of the hole transport layer 124 may be in a range from about 50 Å to about 2,000 Å, from about 100 Å to about 1,500 Å, from about 100 Å to about 1,000 Å, or from about 100 Å to about 600 Å.

Within the thickness ranges described above, hole transfer properties may be enhanced even at a low voltage operation, and a life-span of the device may be further improved.

Each constituent layer of the hole transfer region 120 may be formed by a process such as a vacuum deposition, a spin coating, an inkjet printing, a laser printing, a casting, a laser thermal transfer, and/or the like.

The electron transfer region 140 may be formed between the second electrode 150 and the emission layer 130. The electron transfer region 140 may have a single-layered structure, or a multi-layered structure including different materials.

The electron transfer region 140 may include an electron injection layer, an electron transport layer, and/or a hole blocking layer, and may further include an auxiliary emission layer.

In one or more embodiments, as illustrated in FIG. 2, the electron transfer region 140 may include an electron injection layer 142 and an electron transport layer 144, stacked from the second electrode 150 to the emission layer 130.

In one or more embodiments, as illustrated in FIG. 3, the electron transfer region 140 may include an electron injection layer 142, an electron transport layer 144, and a hole blocking layer 146, stacked from the second electrode 150 to the emission layer 130. The hole blocking layer 146 may block or suppress or reduce holes from the hole transfer region 120 to the electron transfer region 140. Accordingly, emission energy and luminescence efficiency in the emission layer 130 may be further improved.

For example, in one or more embodiments, the electron transfer region 140 may include a compound represented by Chemical Formula ET.

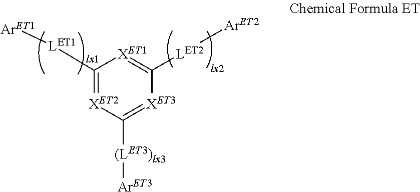

In Chemical Formula ET, at least one selected from among X^{ET1} to X^{ET3} may be N, and the remainder of X^{ET1} to X^{ET3} may each independently be C(R^{ET}). R^{ET} may be hydrogen, deuterium, a substituted or unsubstituted C₁-C₂₀ alkyl group, a substituted or unsubstituted C₆-C₆₀ aryl group, or a substituted or unsubstituted C₂-C₆₀ heteroaryl group.

When one of X^{ET1} to X^{ET3} is N, the compound represented by Chemical Formula ET may include a pyridine group. When two of X^{ET1} to X^{ET3} are N, the compound represented by Chemical Formula ET may include a pyrimidine group. When X^{ET1} to X^{ET3} are each N, the compound represented by Chemical Formula ET may include a triazine group.

In Chemical Formula ET, Ix1 to Ix3 may each independently be an integer from 0 to 10. L^{ET1} to L^{ET3} may each independently be a direct linkage, a substituted or unsubstituted C₆-C₆₀ arylene group, or a substituted or unsubstituted C₂-C₃₀ heteroarylene group.

When Ix1, Ix2, or Ix3 is 2 or more, two or more of respective L^{ET1}(s), L^{ET2}(s), or L^{ET3}(s), may be directly linked together, e.g., by carbon atoms of each aryl ring (e.g., sp² carbons), to form a substituted or unsubstituted C₆-C₆₀ arylene group or a substituted or unsubstituted C₂-C₃₀ heteroarylene group. For example, when Ix1 is 2 or more, two or more of L^{ET1}(s) may be directly linked together, e.g., by carbon atoms of each aryl ring (e.g., sp₂ carbons), to form a substituted or unsubstituted C₆-C₆₀ arylene group or a substituted or unsubstituted C₂-C₃₀ heteroarylene group. When Ix2 is 2 or more, two or more of L^{ET2}(s) may be directly linked together, e.g., by carbon atoms of each aryl ring (e.g., sp₂ carbons), to form a substituted or unsubstituted C₆-C₆₀ arylene group or a substituted or unsubstituted C₂-C₃₀ heteroarylene group. When Ix3 is 2 or more, two or more of L^{ET3}(s) may be directly linked together, e.g., by carbon atoms of each aryl ring (e.g., sp₂ carbons), to form a substituted or unsubstituted C₆-C₆₀ arylene group or a substituted or unsubstituted C₂-C₃₀ heteroarylene group.

In Chemical Formula ET, Ar^{ET1} to Ar^{ET3} may each independently be hydrogen, deuterium, a substituted or unsubstituted C₁-C₂₀ alkyl group, a substituted or unsubstituted C₆-C₆₀ aryl group, or a substituted or unsubstituted C₂-C₃₀ heteroaryl group. For example, in one or more embodiments, Ar^{ET1} to Ar^{ET3} may each independently be a substituted or unsubstituted phenyl group, a substituted or unsubstituted carbazole group, a substituted or unsubstituted fluorene group, or a substituted or unsubstituted silyl group. The silyl group may be represented by -Si(R^{sa})(R^{sb})(R^{sc}), as explained above.

Non-limiting examples of compounds represented by the formula ET are as follows.

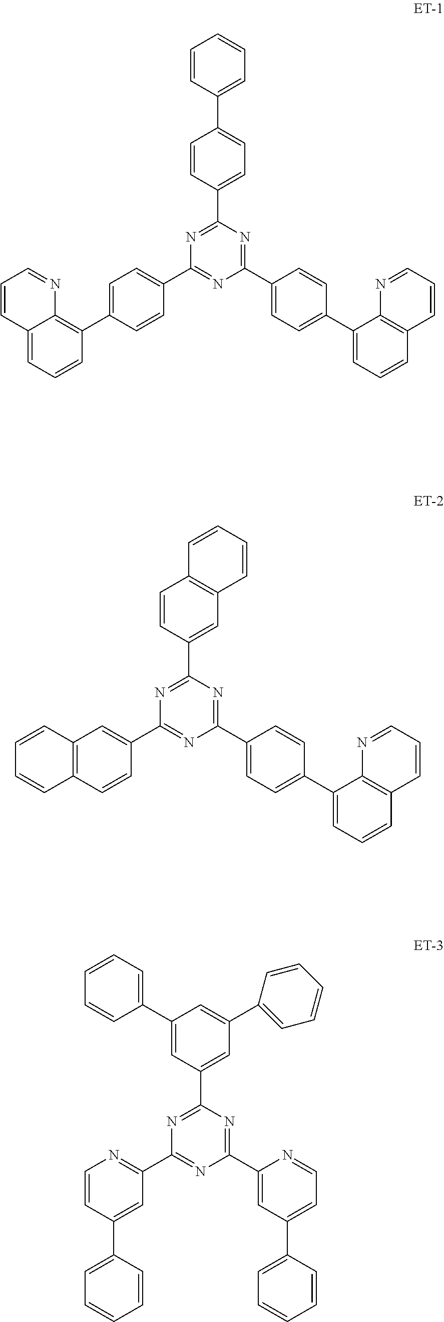 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; c1ccc(-c2cc(-c3ccccc3)cc(-c3nc(-c4cc(-c5ccccc5)ccn4)nc(-c4cc(-c5ccccc5)ccn4)n3)c2)cc1]

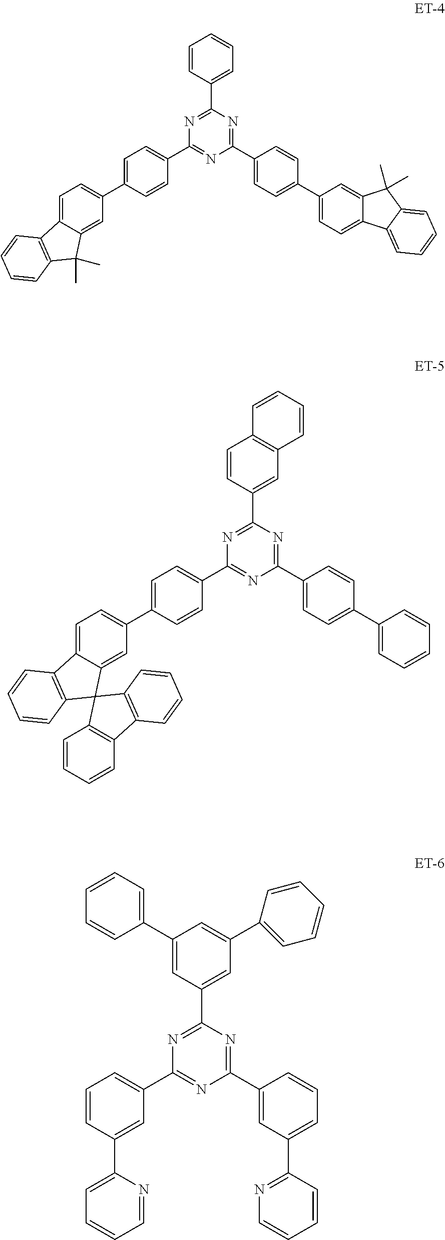 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc(-c5ccc6c(c5)C5(c7ccccc7-c7ccccc75)c5ccccc5-6)cc4)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

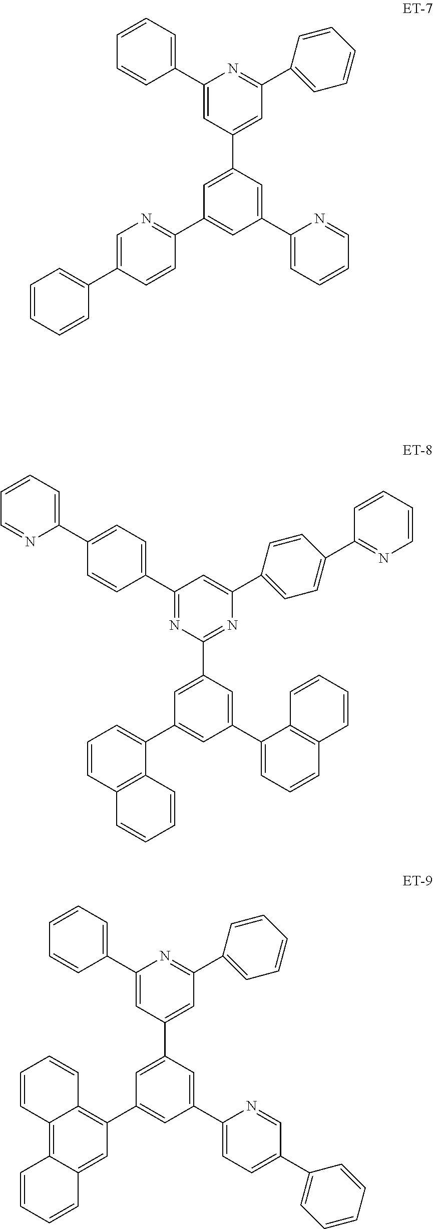 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

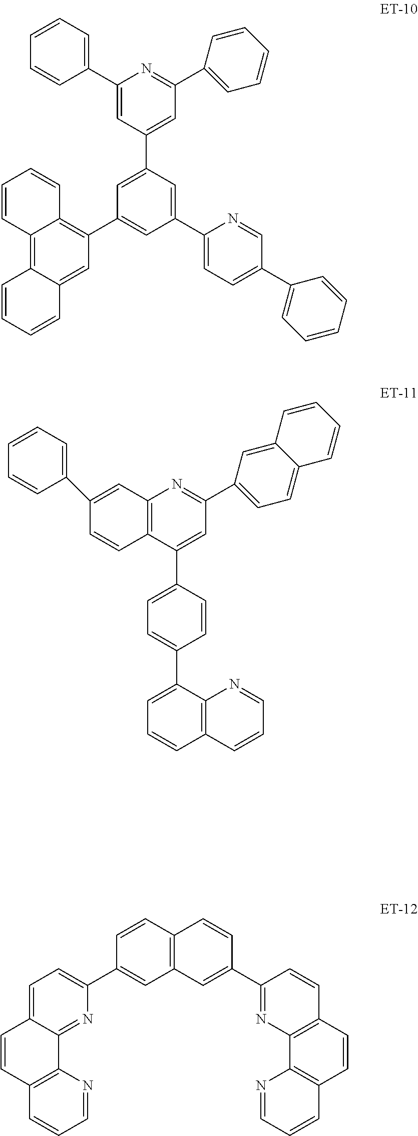 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

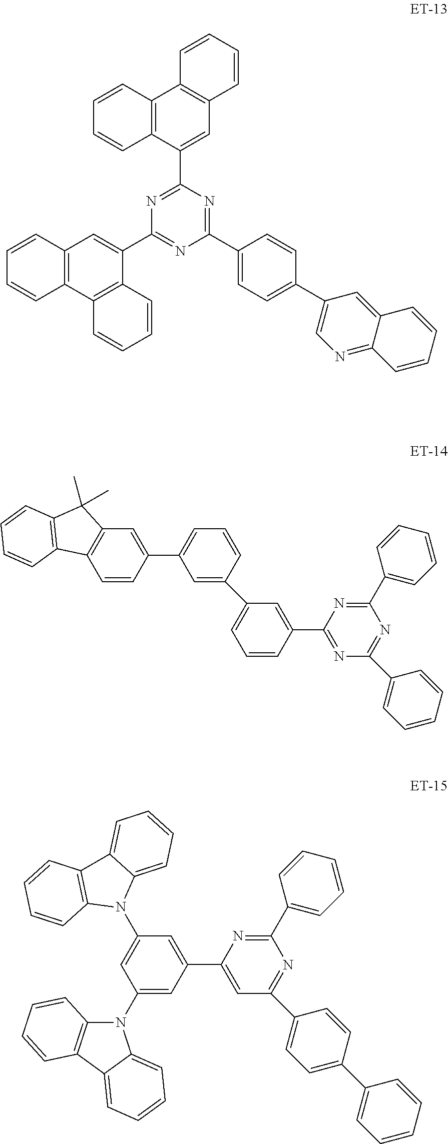 [SMILES: c1ccc2ncc(-c3ccc(-c4nc(-c5cc6ccccc6c6ccccc56)nc(-c5cc6ccccc6c6ccccc56)n4)cc3)cc2c1 ; CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

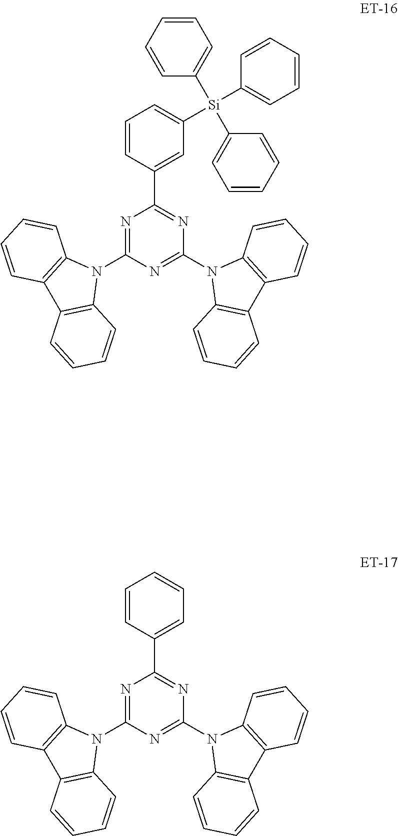 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-n3c4ccccc4c4ccccc43)nc(-n3c4ccccc4c4ccccc43)n2)cc1]

In one or more embodiments, the electron transfer region 140 may include an anthracene compound, Alq3 (tris(8-hydroxyquinolinato) aluminum), 1,3,5-tri[(3-pyridyl)-phen-3-yl]benzene, 2,4,6-tris (3′-(pyridin-3-yl)biphenyl-3-yl)-1,3,5-triazine, 2-(4-(N-phenylbenzimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(biphenyl-4-yl)-4-phenyl-5-tert-butylphenyl-1,2,4-triazole), NTAZ (4-(naphthalen-1-yl)-3,5-diphenyl-4H-1,2,4-triazole), tBu-PBD (2-(biphenyl-4-yl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (beryllium bis(benzoquinolin-10-olate)), ADN (9,10-di(naphthalen-2-yl)anthracene), BmPyPhB (1,3-bis[3,5-di(pyridin-3-yl)phenyl]benzene), and/or the like. The electron transfer region 140 may include one of the electron transfer materials described above, or a (e.g., any suitable) combination thereof.

The above-mentioned material may be included in at least one of the electron injection layer 142, the electron transport layer 144, or the hole blocking layer 146.

In one or more embodiments, the electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a (e.g., any suitable) combination thereof. In one or more embodiments, one or more of the above-mentioned materials may be included electron injection layer 142.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include an oxide, a halide (e.g., a fluoride, a chloride, a bromide, an iodide, and/or the like), a telluride of the alkali metal, the alkaline earth metal, and the rare earth metal, respectively, and/or a (e.g., any suitable) combination thereof.

The alkali metal complex, the alkaline earth metal complex, and the rare earth metal complex may include a respective metal ion such as an alkali metal ion, an alkaline earth metal ion, or a rare earth metal ion, and a ligand bonded to the respective metal ion. The ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, and/or a (e.g., any suitable) combination thereof.

A thickness of the electron transfer region 140 may be in a range from about 100 Å to about 1,000 Å, e.g., from about 150 Å to about 500 Å.

When the electron transfer region 140 includes an electron injection layer 142 or an electron transport layer 144, a thickness of the electron injection layer 142 may be in a range from about 1 Å to about 100 Å, from about 1 Å to about 90 Å, or from about 5 Å to about 50 Å, and a thickness of the electron transport layer 144 may be in a range from about 10 Å to about 900 Å, from about 10 Å to about 500 Å, or from about 100 Å to about 400 Å.

Within any of the thickness ranges described above, electron injection and electron transport properties may be further improved without an excessive increase in driving voltage, and stability of the electron transfer region 140 may be improved.

Each constituent layer of the electron transfer region 140 may be formed by a process such as a vacuum deposition, a spin coating, an inkjet printing, a laser printing, a casting, a laser thermal transfer, and/or the like.

In one or more embodiments, the light-emitting device ED may further include a capping layer. Light emission efficiency to an outside of the light-emitting device ED may be improved through the capping layer.

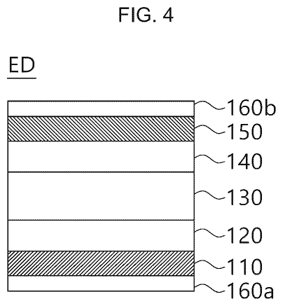

As illustrated in FIG. 4, in one or more embodiments, a second capping layer 160b may be formed on an outer surface of the second electrode 150. In one or more embodiments, a first capping layer 160a may be formed on an outer surface of the first electrode 110.

A refractive index of the first capping layer 160a and/or the second capping layer 160b may be 1.6 or more. For example, in one or more embodiments, the refractive index of the first capping layer 160a and/or the second capping layer 160b may be 1.6 or more, 1.8 or more, or 2.0 or more for light in a wavelength range of 550 nm to 660 nm.

The first capping layer 160a and the second capping layer 160b may each be formed as an organic capping layer including an organic material, an inorganic capping layer including an inorganic material, or an organic-inorganic hybrid capping layer including both (e.g., simultaneously) the organic material and the inorganic material.

The first capping layer 160a and/or the second capping layer 160b may each have a single-layered structure or a multi-layered structure including different materials.

In one or more embodiments, the first capping layer 160a and the second capping layer 160b may each independently include a carbocyclic compound, a heterocyclic compound, an amine group-containing compound, a porphine derivative, a phthalocyanine derivative, a naphthalocyanine derivative, an alkali metal complex, an alkaline earth metal complex, and/or the like. The first capping layer 160a and the second capping layer 160b may each independently include one of the aforementioned materials, or a (e.g., any suitable) combination thereof.

In one or more embodiments, the first capping layer 160a and/or the second capping layer 160b may each independently include an amine group-containing compound.

In a non-limiting example, the first capping layer 160a and/or the second capping layer 160b may include at least one selected from among the compounds represented by Chemical Formulae P1 to P4 and/or at least one selected from among the compounds HT-7, HT-8, HT-14, HT-15 and HT-16.

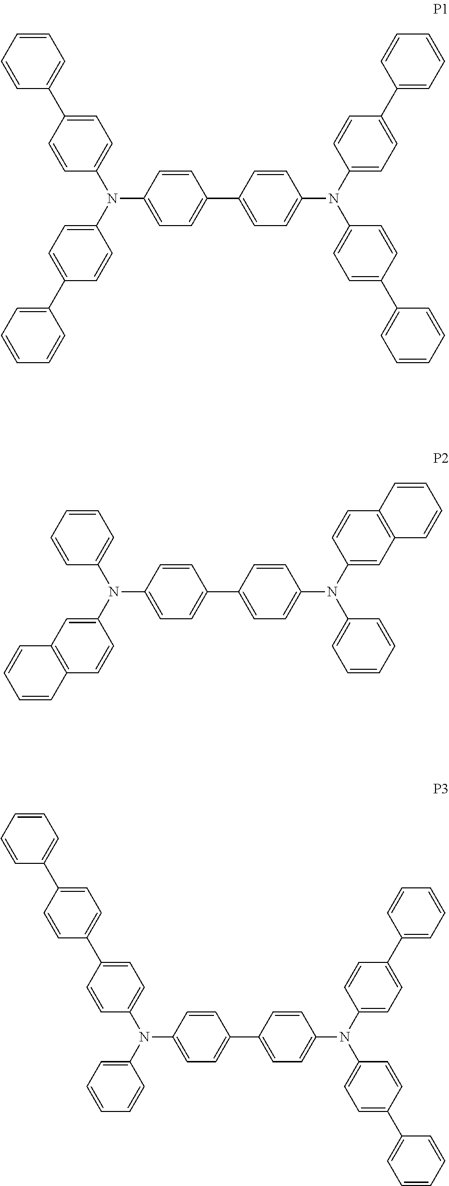 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

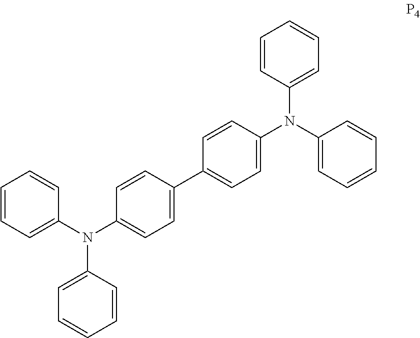 [SMILES: c1ccc(N(c2ccccc2)c2ccc(-c3ccc(N(c4ccccc4)c4ccccc4)cc3)cc2)cc1]

Referring to FIG. 5, in one or more embodiments, the light-emitting device ED may include a plurality of light-emitting structures (e.g., the light-emitting structures ES1, ES2, and ES3). The light-emitting structures ES1, ES2, and ES3 may each include a stacked structure of the hole transfer region 120, the emission layer 130, and the electron transfer region 140, as described with reference to FIGS. 1 to 3. In one or more embodiments, the light-emitting device ED of FIG. 5 may be a light-emitting device having a tandem structure.

Charge generation layers CGL1 and CGL2 may each be respectively arranged between adjacent structures among the light-emitting structures ES1, ES2, and ES3. Charge generation layers CGL1 and CGL2 may each independently include a p-type (kind) charge (e.g., P-charge) generation layer and/or an n-type (kind) charge (e.g., N-charge) generation layer.

The p-type (kind) charge generation layer may include a hole transport host compound, such as NPB. For example, in one or more embodiments, the p-type (kind) charge generation layer may include a compound represented by Chemical Formula HT described above. In one or more embodiments, the p-type (kind) charge generation layer may further include a p-dopant, such as TCNQ.

The n-type (kind) charge generation layer may include an electron transport host compound. For example, in one or more embodiments, the n-type (kind) charge generation layer may include a compound represented by Chemical Formula ET described above. In one or more embodiments, the n-type (kind) charge generation layer may include a phenanthroline-based compound.

The charge generation layers CGL1 and CGL2 may include a first charge generation layer CGL1 arranged between the first light-emitting structure ES1 and the second light-emitting structure ES2, and a second charge generation layer CGL2 arranged between the second light-emitting structure ES2 and the third-light emitting structure ES3.

In one or more embodiments, the first light-emitting structure ES1, the first charge generation layer CGL1, the second light-emitting structure ES2, the second charge generation layer CGL2, the third light-emitting structure ES3, and the second electrode 150 may be sequentially stacked on a top surface of the first electrode 110.

Colors emitted from the first light-emitting structure ES1, the second light-emitting structure ES2, and the third light-emitting structure ES3 may be the same as or different from each other. In one or more embodiments, the first light-emitting structure ES1, the second light-emitting structure ES2, and the third light-emitting structure ES3 may include a red light-emitting layer, a green light-emitting layer, and a blue light-emitting layer, respectively, and a white light-emitting structure may be implemented through the tandem structure, but embodiments of the present disclosure are not limited thereto.

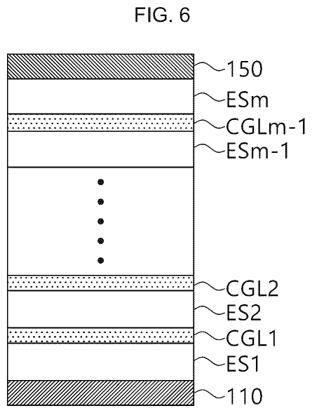

In FIG. 5, a 3-stack tandem structure in which three light-emitting structures are stacked is illustrated as an example, but the tandem structure of the light-emitting device of the present disclosure is not limited to the structure illustrated in FIG. 5. For example, a 2-stack structure, a 4-stack structure, a 5-stack structure, or a 6 or more stacked structure which will be described with reference FIG. 6 may also be implemented.

Referring to FIG. 6, as described with reference to FIG. 5, a tandem structure in which a light-emitting structure and a charge generation layer are alternately and repeatedly stacked may be arranged between the first electrode 110 and the second electrode 150.

In one or more embodiments, first to mth light-emitting structures ES1 to ESm may be sequentially stacked from a top surface of the first electrode 110 with a charge generation layer interposed therebetween. The charge generation layer may include a first charge generation layer CGL1 to an (m−1)th charge generation layer CGLm−1 sequentially stacked from the top surface of the first electrode 110.

As illustrated in FIG. 6, the first light-emitting structure ES1, the first charge generation layer CGL1, the second light-emitting structure ES2, the second charge generation layer CGL2, . . . , an (m−1)th light-emitting structure ESm−1, an (m−1)th charge generation layer CGLm−1, an mth light-emitting structure ESm, and the second electrode 150 may be sequentially stacked from the top surface of the first electrode 110.

In one or more embodiments, m is 4, and an intermediate layer of the light-emitting device may have a 4-stack tandem structure, and may include first to fourth light-emitting structures ES1, ES2, ES3, and ES4, and first to third charge generation layers CGL1, CGL2, and CGL3. Colors of light generated from the first to fourth light-emitting structures ES1, ES2, ES3, and ES4 may be the same as or different from each other.

In one or more embodiments, the first to fourth light emitting structures ES1, ES2, ES3, and ES4 may include at least one blue light-emitting structure and at least one green-light emitting structure. In a non-limiting example, the first to third light emitting structures ES1, ES2, and ES3 may correspond to the blue light-emitting structure, and the fourth light emitting structure ES4 may correspond to the green-light emitting structure.

In one or more embodiments, m is 5, and an intermediate layer of the light-emitting device may have a 5-stack tandem structure, and may include first to fifth light-emitting structures ES1, ES2, ES3, ES4, and ES5, and first to fourth charge generation layers CGL1, CGL2, CGL3, and CGL4. Colors of light generated from the first to fifth light-emitting structures ES1, ES2, ES3, ES4, and ES5 may be the same as or different from each other.

In one or more embodiments, the first to fifth light-emitting structures ES1, ES2, ES3, ES4, and ES5 may include at least one blue light emitting structure and at least one green light emitting structure. In a non-limiting example, the first to fifth light-emitting structures ES1, ES2, ES3, ES4, and ES5 may include three blue light-emitting structures and two green light-emitting structures. For example, in one or more embodiments, the first, third, and fifth light-emitting structures ES1, ES3, and ES5 may correspond to the blue light-emitting structures, and the second and fourth light-emitting structures ES2 and ES4 may correspond to the green light-emitting structures.

### Electronic Device

The above-described light-emitting device ED may be applied to an electronic device and may be provided as a light-emitting portion or a light-emitting unit of the electronic device.

The electronic device may include a light-emitting device (ED) including the polycyclic compound of Chemical Formula 1 described above, thereby achieving improved color properties, luminous efficiency, and life-span properties.

In one or more embodiments, the electronic device may further include, e.g., a functional layer arranged on the light-emitting device, and may include a sensor layer, a polarizing layer, a color conversion layer, a color filter layer, or a (e.g., any suitable) combination of at least two thereof.

Non-limiting examples of the electronic device may include a display device, a billboard, a signboard, a light source, a lighting device, a personal computer such as a laptop computer or a desktop computer, a mobile phone, an electronic book, an electronic dictionary, an electronic notebook, a health-care device including a diagnostic device and one or more suitable sensors, one or more suitable display parts for transportation apparatuses (automobile, aircraft, ship, train, and/or the like).

In one or more embodiments, the light-emitting device ED may be applied to an organic light emitting diode (OLED) display device or a quantum dot (QD)-OLED display device.

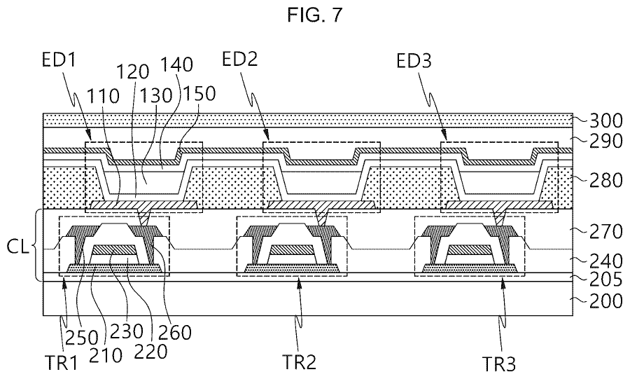

FIG. 7 is a schematic cross-sectional view illustrating a display device in accordance with one or more embodiments of the present disclosure.

Referring to FIG. 7, the display device may include a circuit layer CL arranged on a base substrate 200, and light-emitting devices ED1, ED2, and ED3 each arranged on the circuit layer CL.

The base substrate 200 may serve as a supporting substrate or as a back-plane substrate of the display device. The base substrate 200 may be a glass substrate or a plastic substrate.

In one or more embodiments, the base substrate 200 may include a polymer material having transparent and flexible properties. If (e.g., when) the base substrate 200 includes a polymer material, the base substrate 200 may be used in a transparent flexible display device. For example, in one or more embodiments, the base substrate 200 may include a polymer material such as polyimide, polysiloxane, an epoxy resin, an acrylic resin, polyester, and/or the like. In one or more embodiments, the base substrate 200 may include polyimide.

The circuit layer CL may include transistors TR1, TR2, and TR3. The circuit layer CL may include wiring layers and insulating layers that form a thin film transistor array (TFT-Array).

In one or more embodiments, the circuit layer CL may include a buffer layer 205 on a top surface of the base substrate 200. The buffer layer 205 may block the penetration of moisture through the base substrate 200, and may also block the diffusion of impurities between the base substrate 200 and the structures formed thereon.

The buffer layer 205 may include, e.g., silicon oxide, silicon nitride, and/or silicon oxynitride. The buffer layer 205 may include one of the aforementioned materials, or a (e.g., any suitable) combination thereof. In one or more embodiments, the buffer layer 205 may have a stacked structure that includes a silicon oxide layer and a silicon nitride layer.

The transistors TR1, TR2, and TR3 may be arranged on the buffer layer 205. A first transistor TR1, a second transistor TR2, and a third transistor TR3 may be electrically connected to a first light-emitting device ED1, a second light-emitting device ED2, and a third light-emitting device ED3, respectively.

The transistors TR1, TR2, and TR3 may each include an active layer 210, a gate insulation layer 220, and a gate electrode 230.

The active layer 210 may be arranged on the buffer layer 205, and may be patterned for each pixel. In one or more embodiments, the active layer 210 may include a silicon compound such as amorphous silicon or polysilicon. A p-type (kind) dopant or an n-type (kind) dopant may be doped in a region of the active layer 210, and the active layer 210 may include a source region, a drain region, and a channel region.

In one or more embodiments, the active layer 210 may include an oxide semiconductor, such as indium gallium zinc oxide (IGZO), zinc tin oxide (ZTO), or ITZO.

The gate insulation layer 220 may be formed on the active layer 210, and the gate electrode 230 may be stacked on the gate insulation layer 220. As illustrated in FIG. 7, the gate insulation layer 220 may be patterned to partially cover each active layer 210. In one or more embodiments, the gate insulation layer 220 may extend continuously over multiple pixels or light-emitting regions, and may be provided as a common layer for the first, second, and third transistors TR1, TR2, and TR3.

The gate electrode 230 may overlap the channel region of the active layer 210 in a thickness direction.

An insulating interlayer 240 may be formed on the active layer 210 to cover the gate electrode 230 and the gate insulation layer 220. Connection electrodes 250 and 260 which may be in contact with or electrically connected to the active layer 210 may each be arranged on the insulating interlayer 240.

The connection electrodes 250 and 260 may extend through the insulating interlayer 240 to be in contact with or electrically connected to the active layer 210.

When the gate insulation layer 220 is provided as a common layer for multiple light-emitting regions, the connection electrodes 250 and 260 may also extend through the gate insulation layer 220.

The connection electrodes 250 and 260 may include a source electrode 250 that may be in contact with or connected to the source region of the active layer 210, and a drain electrode 260 that may be in contact with or connected to the drain region of the active layer 210.

The gate insulation layer 220 and the insulating interlayer 240 may each independently include silicon oxide, silicon nitride, and/or silicon oxynitride, and may each have a stacked structure that includes a silicon oxide layer and a silicon nitride layer.

The gate electrode 230 and the connection electrodes 250 and 260 may each independently include a metal such as Ag, Mg, Al, W, Cu, Ni, Cr, Mo, Ti, Pt, Ta, Nd, Sc, an alloy thereof, or a nitride thereof.

A via insulation layer 270 may be formed on the insulating interlayer 240 to cover the connection electrodes 250 and 260.

The via insulation layer 270 may accommodate a via structure electrically connecting a first electrode 110 and the drain electrode 260. The via insulation layer 270 may serve as a planarization layer of the circuit layer CL. In one or more embodiments, the via insulation layer 270 may include an organic material such as polyimide, an epoxy resin, an acrylic resin, polyester, and/or the like.

The light-emitting devices ED1, ED2, and ED3 may be arranged on the via insulation layer 270. For example, as described with reference to FIGS. 1 to 4, the light-emitting devices ED1, ED2, and ED3 may each include a first electrode 110, a hole transfer region 120, an emission layer 130, an electron transfer region 140, and a second electrode 150 which are sequentially stacked from the via insulation layer 270.

The first electrode 110 may be electrically connected to the respective transistors TR1, TR2, and TR3 or the respective connection electrodes 250 or 260 in the circuit layer CL through the via structure. As illustrated in FIG. 7, in one or more embodiments, the first electrode 110 may be in contact with or connected to the drain electrode 260 to serve as a pixel electrode patterned for each light-emitting region or pixel.

A pixel defining layer 280 may be formed on the via insulation layer 270 to define each light-emitting region or pixel. A blue light-emitting region, a red light-emitting region, and a green light-emitting region may be separated and defined by the pixel defining layer 280, and the light-emitting devices ED1, ED2, and ED3 may respectively correspond to a blue light-emitting device, a red light-emitting device, and a green light-emitting device.

The pixel defining layer 280 may partially cover the first electrode 110 of each light-emitting region.

As illustrated in FIG. 7, the hole transfer region 120 and the electron transfer region 140 may each be provided as a common layer that continuously extends over the pixel defining layer 280 and the first electrodes 110. The emission layer 130 may be formed within each light emitting-region or pixel, and may be separated by the pixel defining layer 280.

In one or more embodiments, the emission layer 130 may also be provided as a common layer that continuously extends over the light emitting-regions or pixels.

In one or more embodiments, the hole transfer region 120, the emission layer 130, and the electron transfer region 140 may each be patterned and separately formed for each light-emitting region or pixel.

The second electrode 150 may be provided as a common electrode that continuously extends over the light-emitting regions or the pixels.

An encapsulation layer 290 may be arranged on the pixel defining layer 280 and the light-emitting devices ED1, ED2, and ED3 to protect the light-emitting devices ED1, ED2, and ED3 from moisture and/or oxygen. The encapsulation layer 290 may be a thin film encapsulation (TFE) having a single-layered structure or multi-layered structure.

The encapsulation layer 290 may include an inorganic layer that includes silicon nitride (SiNₓ), silicon oxide (SiOₓ), indium tin oxide, indium zinc oxide, or any combination thereof; an organic layer that includes polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, and/or the like), an epoxy resin (e.g., an aliphatic glycidyl ether (AGE)), or any combination thereof; or a (e.g., any suitable) combination of the inorganic layer and the organic layer.

The display device may further include a functional layer 300 arranged on the encapsulation layer 290. The functional layer 300 may include a sensor layer such as a touch sensor layer, an optical layer such as a polarizing layer, a color conversion layer, a color filter layer, a window film, or any combination thereof.

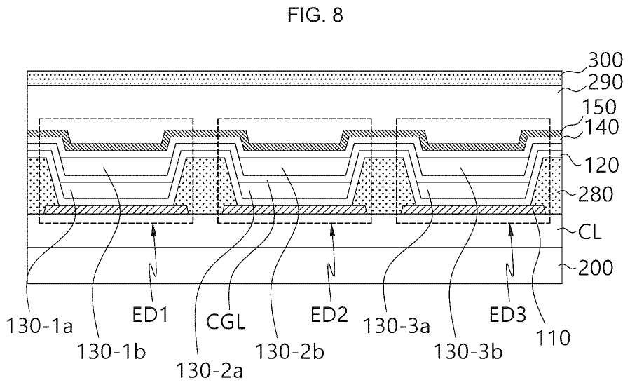

FIG. 8 is a schematic cross-sectional view illustrating a display device in accordance with one or more embodiments of the present disclosure. Detailed descriptions of elements and structures substantially the same as or similar to those described with reference to FIG. 7 are omitted or simplified herein for conciseness.

Referring to FIG. 8, each of the light-emitting devices ED1, ED2, and ED3 may have a tandem structure, e.g., a 2-stack tandem structure.

In one or more embodiments, the hole transfer region 120 and the electron transfer region 140 may be continuously and commonly formed and included in an intermediate layer of each light-emitting structure. Additionally, a charge generation layer CGL may continuously extend across a plurality of pixels and may be commonly included in the intermediate layer of each light-emitting structure.

The first light-emitting device ED1 may include a first lower emission layer 130-1a arranged between the hole transfer region 120 and the charge generation layer CGL, and a first upper emission layer 130-1b arranged between the charge generation layer CGL and the electron transfer region 140.

The second light-emitting device ED2 may include a second lower emission layer 130-2a arranged between the hole transfer region 120 and the charge generation layer CGL, and a second upper emission layer 130-2b arranged between the charge generation layer CGL and the electron transfer region 140.

The third light-emitting device ED3 may include a third lower emission layer 130-3a arranged between the hole transfer region 120 and the charge generation layer CGL, and a third upper emission layer 130-3b arranged between the charge generation layer CGL and the electron transfer region 140.

The lower and upper emission layers included in each light-emitting structure (i.e., in each light-emitting tandem structure) may generate light of a same color. In one or more embodiments, each of the first lower emission layer 130-1a and the first upper emission layer 130-1b included in the first light-emitting device ED1 may correspond to a red emission layer. Each of the second lower emission layer 130-2a and the second upper emission layer 130-2b included in the second light-emitting device ED2 may correspond to a green emission layer. Each of the third lower emission layer 130-3a and the third upper emission layer 130-3b included in the third light-emitting device ED3 may correspond to a blue emission layer.

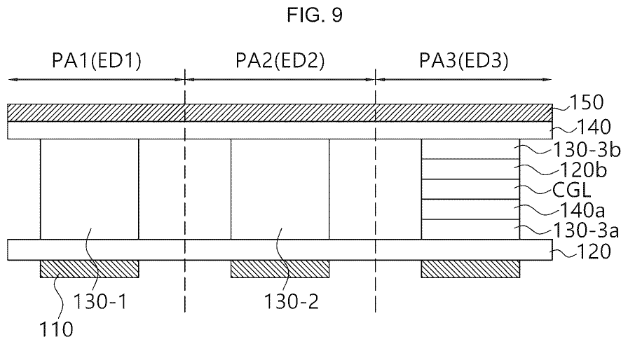

FIG. 9 is a schematic cross-sectional view illustrating a stack construction of light-emitting structure in a display device in accordance with one or more embodiments of the present disclosure. For convenience of illustration and description, illustration of the circuit layer, the base substrate, the pixel defining layer, and/or the like, is omitted from FIG. 9, and a shape of each layer or element in the light-emitting structure is briefly shown as a rectangle.

Referring to FIG. 9, in one or more embodiments, at least one selected from among the light-emitting devices ED1, ED2, and ED3 or selected from among pixel areas PA1, PA2, and PA3 may have a tandem structure including a plurality of emission layers, and at least one selected from among the remainder may have a single emission layer structure.

In one or more embodiments, one selected from among the light-emitting devices ED1, ED2, and ED3 or selected from among the pixel areas PA1, PA2, and PA3 may have a tandem structure, and the remainder may have a single emission layer structure.

As illustrated in FIG. 9, the first light-emitting device ED1, the second light-emitting device ED2, and the third light-emitting device ED3 may be included in the first pixel area PA1, the second pixel area PA2, and the third pixel area PA3, respectively. In one or more embodiments, the first pixel area PA1, the second pixel area PA2, and the third pixel area PA3 may correspond to a red pixel area, a green pixel area, and a blue pixel area, respectively.

The hole transfer region 120, the electron transfer region 140, and the second electrode 150 may each be provided as a common layer continuously extending over the first pixel area PA1, the second pixel area PA2, and the third pixel area PA3.

The first light-emitting device ED1 included in the first pixel area PA1 may include a first emission layer 130-1, and the second light-emitting device ED2 included in the second pixel area PA2 may include a second emission layer 130-2. Each of the first emission layer 130-1 and the second emission layer 130-2 may be a single-layered emission layer.

The third light-emitting device ED3 included in the third pixel area PA3 may have, e.g., a 2-stack tandem structure. The third light-emitting device ED3 may include a third lower emission layer 130-3a and a third upper emission layer 130-3b separated with a charge generation layer CGL interposed therebetween. For example, each of the third lower emission layer 130-3a and the third upper emission layer 130-3b may correspond to a blue emission layer.

A lower electron transfer region 140a may be arranged between the charge generation layer CGL and the third lower emission layer 130-3a. An upper hole transfer region 120b may be arranged between the charge generation layer CGL and the third upper emission layer 130-3b.

Accordingly, a tandem light-emitting structure in which the first electrode 110, the hole transfer region 120, the third lower emission layer 130-3a, the lower electron transfer region 140a, the charge generation layer CGL, the upper hole transfer region 120b, the third upper emission layer 130-3b, the electron transfer region 140, and the second electrode 150 are sequentially stacked may be arranged in the third pixel area PA3.

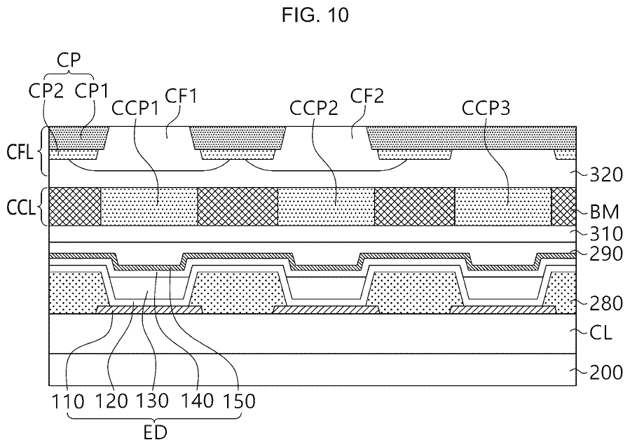

FIG. 10 is a schematic cross-sectional view illustrating a display device in accordance with one or more embodiments of the present disclosure.

FIG. 10 illustrates a display device having a QD-OLED structure according to one or more embodiments. Detailed descriptions regarding elements and structures that are the same as or substantially similar to those described with reference to FIG. 7 will not be repeated here for conciseness.

Referring to FIG. 10, the pixel defining layer 280 and the light-emitting device ED may be arranged on the circuit layer CL, as described above with reference to FIG. 7. In one or more embodiments, each pixel may be to emit light of the same wavelength region. In one or more embodiments, each light-emitting device ED may be to emit a blue light.

In one or more embodiments, each light-emitting region may include the light-emitting device having the tandem structure, as described above with respect to FIG. 5. In these embodiments, the intermediate layer of each light-emitting device ED may be provided as a common layer that continuously extends over a plurality of the light-emitting regions.

A color control layer CCL may be arranged on the encapsulation layer 290, and the color control layer CCL may include color control portions CCP1, CCP2, and CCP3.

The color control portions CCP1, CCP2, and CCP3 may each include a light transformer such as a quantum dot and/or a phosphor. In each of the color control portions CCP1, CCP2, and CCP3, the light transformer may convert a wavelength of a provided light and emit a resulting light.

The color control portions CCP1, CCP2, and CCP3 may be separated or spaced and/or apart (e.g., spaced apart or separated) from one another by a bank BM.

The bank BM may substantially overlap the pixel defining layer 280, and the color control portions CCP1, CCP2, and CCP3 may substantially overlap each of the emission layers 130.

The color control layer CCL may include a first color control portion CCP1 including a first quantum dot that converts a first color light provided from the light-emitting device ED into a second color light, a second color control portion CCP2 including a second quantum dot that converts the first color light into a third color light, and a third color control portion CCP3 that transmits the first color light.

In one or more embodiments, the first color light, the second color light, and the third color light may be a blue light, a red light, and a green light, respectively. The first quantum dot and the second quantum dot may respectively be a red quantum dot and a green quantum dot.

The color control portions CCP1, CCP2, and CCP3 may each further include a scattering material such as inorganic particles. The third color control portion CCP3 may not include (e.g., may exclude) quantum dots and may include the scattering material. The scattering material may include TiO₂, ZnO, Al₂O₃, SiO₂, hollow silica, and/or the like. The scattering material may be one of the aforementioned materials or a (e.g., any suitable) combination thereof.

The color control portions CCP1, CCP2, and CCP3 may each further include a binder resin that disperses the quantum dot and the scattering material. The binder resin may include an acrylic resin, a urethane resin, a silicone resin, an epoxy resin, and/or the like.

A color filter layer CFL that includes color filters CF1 and CF2 and a light-shielding portion CP may be arranged on the color control layer CCL.

The color filter layer CFL may include a first filter CF1 that transmits the second color light, a second filter CF2 that transmits the third color light, and a third filter that transmits the first color light. For example, the first filter CF1 may be a red filter, the second filter CF2 may be a green filter, and the third filter may be a blue filter.

The color filters CF1 and CF2 may each include a photosensitive binder resin and a colorant including a pigment and/or a dye. The first filter CF1 may include a red pigment and/or a red dye, and the second filter CF2 may include a green pigment and/or a green dye.

The light-shielding portion CP may be arranged between the color filters. In one or more embodiments, the light-shielding portion CP may include a first light-shielding portion CP1 and a second light-shielding portion CP2 that include colorants of different colors.

In one or more embodiments, the first light-shielding portion CP1 may include a blue colorant, and the second light-shielding portion CP2 may include a red colorant or a black colorant. In one or more embodiments, in the blue light-emitting region, a portion of the first light-shielding portion CP1 may be provided as a blue color filter and may be exposed between the second light-shielding portions CP2, so that an additional color filter (e.g., the third filter) may not be provided.

A first barrier layer 310 may be arranged between the color control layer CCL and the light-emitting device ED (or the encapsulation layer 290). A second barrier layer 320 may be arranged between the color control layer CCL and the color filter layer CFL.

The barrier layers 310 and 320 may each include at least one inorganic layer. For example, the barrier layers 310 and 320 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or the like.

In one or more embodiments, the barrier layers 310 and 320 may each have a multi-layered structure that further includes an organic layer.

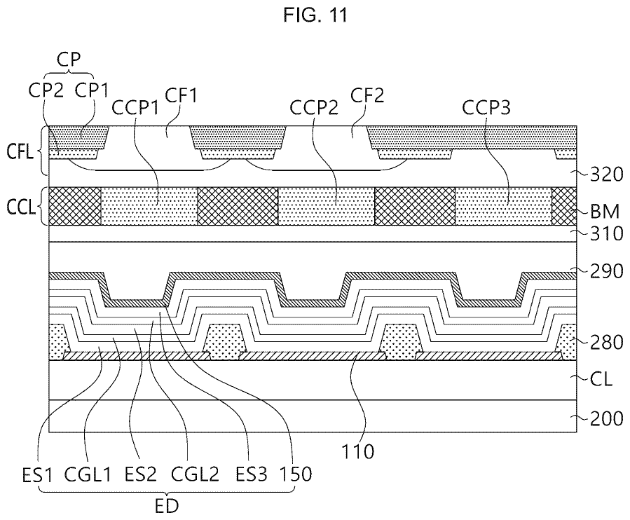

FIG. 11 is a schematic cross-sectional view illustrating a display device in accordance with one or more embodiments of the present disclosure. Detailed descriptions of elements and structures substantially the same as or similar to those described with reference to FIG. 10 are omitted herein.

Referring to FIG. 11, the light-emitting devices ED corresponding to the color control portions CCP1, CCP2, and CCP3 may each be arranged on the first electrode 110 serving as the pixel electrode, and the light-emitting device ED may have a tandem structure.

In one or more embodiments, as described with reference to FIG. 5, the first light-emitting structure ES1, the first charge generation layer CGL1, the second light-emitting structure ES2, the second charge generation layer CGL2, and the third light-emitting structure ES3 may be sequentially stacked between the first electrode 110 and the second electrode 150. In one or more embodiments, the first light-emitting structure ES1, the first charge generation layer CGL1, the second light-emitting structure ES2, the second charge generation layer CGL2, and the third light-emitting structure ES3 may be continuously and commonly formed in a plurality of pixel areas or light-emitting regions.

In one or more embodiments, the first light-emitting structure ES1, the second light-emitting structure ES2, and the third light-emitting structure ES3 may generate different color lights, and the light-emitting device ED may generate a white light (e.g., combined white light). In one or more embodiments, the first light-emitting structure ES1, the second light-emitting structure ES2, and the third light-emitting structure ES3 may all generate blue lights.

In one or more embodiments, as described with reference to FIG. 6, the light-emitting device ED may include a tandem structure of 4-stack, 5-stack, or more of the stacked number.

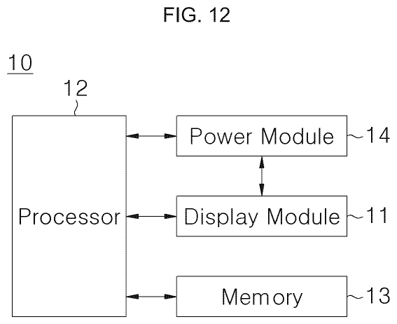

FIG. 12 is a block diagram of an electronic device in accordance with one or more embodiments of the present disclosure.

Referring to FIG. 12, an electronic device 10 according to one or more embodiments may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

Data information for an operation of the processor 12 and/or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter and/or a battery device, and a power conversion module that converts a power supplied by the power supply module to generate a power desired or required for the operation of the electronic device 10.

At least one selected from among components of the electronic device 10 described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

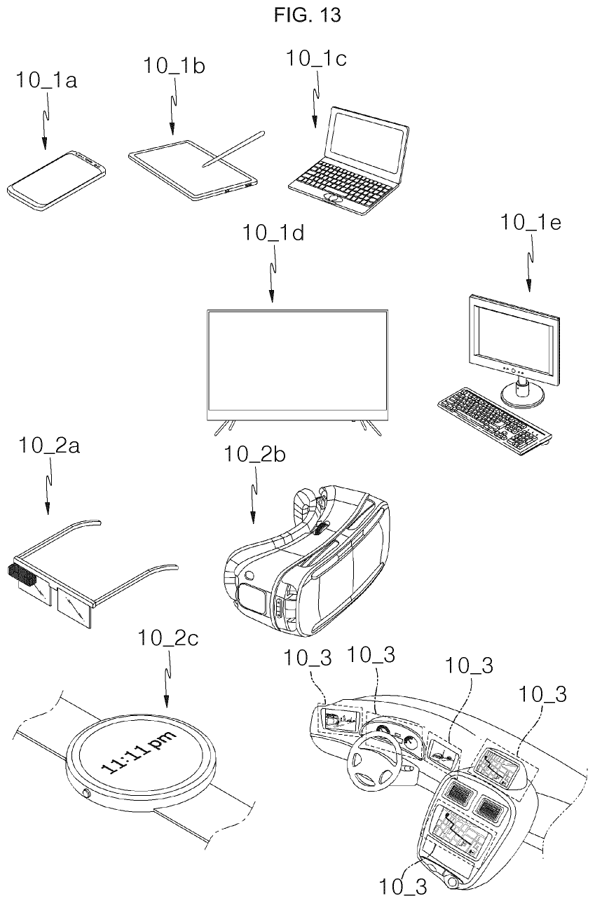

FIG. 13 is a schematic diagram illustrating electronic devices in accordance with one or more suitable embodiments of the present disclosure.

Referring to FIG. 13, non-limiting examples of one or more suitable electronic devices to which the display device according to the above-described embodiments is applied may include an electronic device for displaying an image such as a smartphone 10_1a, a tablet PC 10_b, a laptop 10_1c, a TV 10_1d, a desk monitor 10_1e, and/or the like; a wearable electronic device including a display module such as smart glasses 10_2a, a head mounted display 10_2b, a smart watch 10_2c, and/or the like; a vehicle electronic device 10_3 including a display module such as a center information display (CID) arranged at a vehicle instrument panel, a center fascia, a dashboard, and/or the like, a room mirror display, and/or the like. The electronic device may include a virtual reality glass or an augmented reality glass.

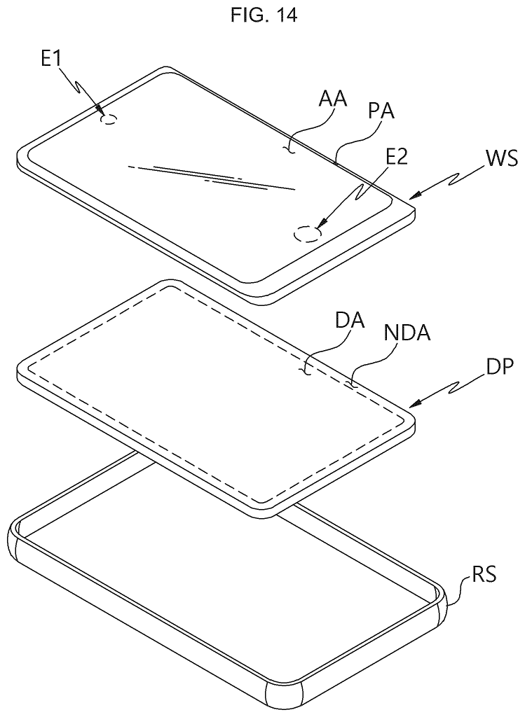

FIG. 14 is a schematic exploded perspective view illustrating an electronic device in accordance with one or more embodiments of the present disclosure.

According to one or more embodiments, the electronic device may be implemented in the form of a mobile phone (smart phone), a tablet, a PC, and/or the like, including the above-described display device.

Referring to FIG. 14, the electronic device may include a window structure WS, a display panel DP, and a rear structure RS.

The window structure WS may provide an external display surface recognized by a user, such as a viewing surface of a mobile phone, and may include a transparent material film. For example, the window structure WS may include glass (e.g., ultra-thin glass (UTG), a hard coating film, a plastic film, and/or the like.

An outer surface of the window structure WS may include an active area AA and a peripheral area PA. The active area AA may provide a surface from which an image of the display device is substantially displayed and to which a user's touch/command is input. The peripheral area PA may substantially correspond to a bezel area of the display device.

The display panel DP may include the above-described display device and may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In one or more embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, in one or more embodiments, a sensor structure for a touch sensing or a fingerprint sensing may be arranged in the display panel DP or between the window structure WS and the display panel DP.

The rear structure RS may serve as a frame structure or a housing of the display device or the electronic device. A cover panel may be arranged between the rear structure RS and the display panel DP.

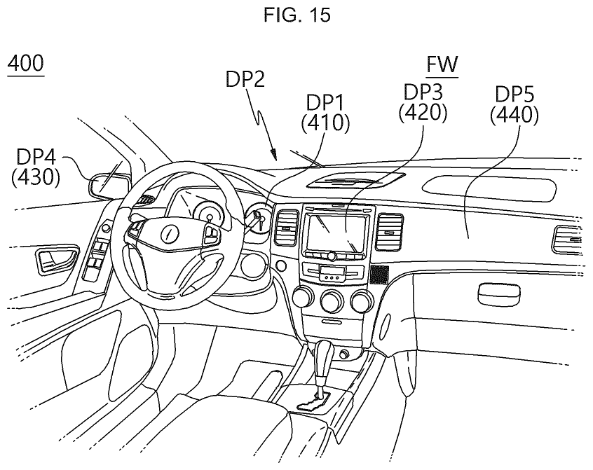

FIG. 15 is a schematic cross-sectional view illustrating an electronic device in accordance with one or more embodiments of the present disclosure.

The electronic device may be installed in, embedded in, attached to, or integrated with a vehicle 400. However, the vehicle 400 is not limited to one or more embodiments illustrated in FIG. 15. Further examples of the vehicle 400 may include a transportation apparatus such as a three-wheeled or four-wheeled vehicle, a construction machine, a two-wheeled vehicle, a motor vehicle, a bicycle, a train, and/or the like. Other examples of the vehicle 400 may also include an electric vehicle, a hybrid vehicle, and/or the like.

Referring to FIG. 15, at least one selected from among first to fifth display devices DP1, DP2, DP3, DP4, and DP5 may be applied to the vehicle 400.

In one or more embodiments, the first display device DP1 may be arranged in a cluster area 410. Driving information such as a driving distance and speed, and one or more suitable warning lights may be displayed in the cluster area 410.

The second display device DP2 may be arranged on a front window FW of the vehicle 400. For example, the second display device DP2 may be installed as a head-up display (HUD).

The third display device DP3 may be arranged on a center fascia 420 of the vehicle 400. In the center fascia 420, a button and/or a switch for controlling an image display or a music player, an air conditioner, a heater, and/or the like, may be displayed, and vehicle information may be displayed thereon.

The fourth display device DP4 may be applied to side mirrors 430 of the vehicle 400. A side mirror 430 may be installed at each of both sides (e.g., two opposite sides) of an exterior of the vehicle 400, and the fourth display device DP4 may be applied to at least one of the side mirrors 430 installed at each of the both sides.

The fifth display device DP5 may be arranged on a passenger seat dashboard 440. Information/image identical to or different from information/image displayed on the cluster area 410 and/or the center fascia 420 may be displayed at the passenger seat dashboard 440.

### Electronic Apparatus

The above-described light-emitting device ED may be applied to an electronic apparatus, and may serve as a light-emitting portion or a light-emitting unit of the electronic apparatus.

The electronic apparatus may include the light-emitting device ED including the polycyclic compound of Chemical Formula 1, thereby achieving improved color properties, light emission efficiency and life-span properties.

In one or more embodiments, the electronic apparatus may include the above-described electronic device.

The electronic apparatus may include, e.g., a video wall, a flat panel display, a curved display, a computer monitor, a medical monitor, a television, a billboard, an indoor light, an outdoor light, a light for signaling, a head-up display, a fully transparent display, a partially transparent display, a flexible display, a rollable display, a foldable display, a laser printer, a phone, a mobile phone, a tablet, a phablet, a personal information terminal (PDA), a wearable device, a laptop computer, a digital camera, a camcorder, a viewfinder, a micro display, a 3D display, a virtual reality display, an augmented reality display, a vehicle, a video wall including multiple displays tiled together, a theater screen, a stadium screen, a phototherapy device, and/or a signage.

Hereinafter, a polycyclic compound according to one or more embodiments will be described in more detail with reference to the Examples and the Comparative Examples. The Examples are provided to assist in understanding the disclosure, but they are provided as non-limiting examples, and the scope of the disclosure is not limited thereto. It will be clear to those skilled in the art that one or more suitable changes and modifications to disclosed examples can be made within the scope of the disclosure.

### Synthesis Example 1: Synthesis of Compound 13

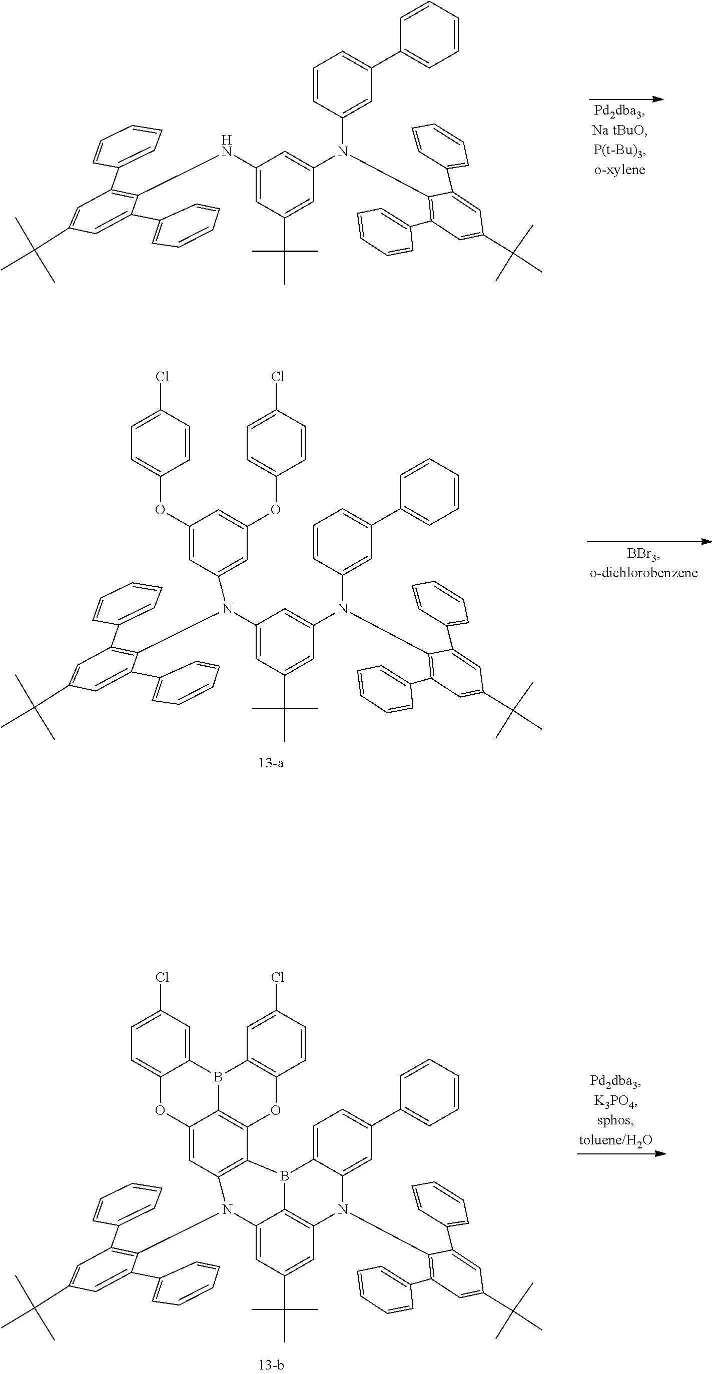

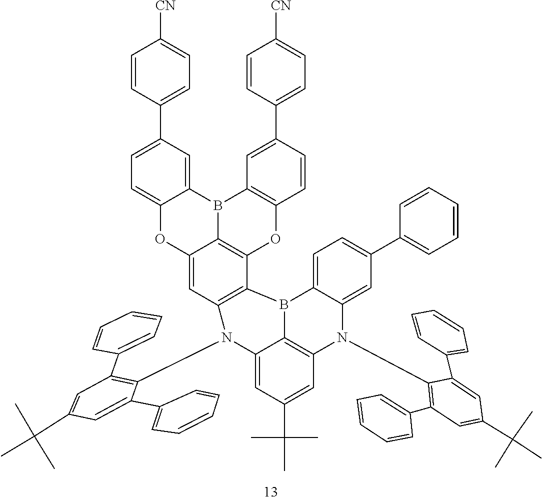 [SMILES: CC(C)(C)c1cc(-c2ccccc2)c(N2c3cc(-c4ccccc4)ccc3B3c4c2cc(C(C)(C)C)cc4N(c2c(-c4ccccc4)cc(C(C)(C)C)cc2-c2ccccc2)c2cc4c5c(c23)Oc2ccc(-c3ccc(C#N)cc3)cc2B5c2cc(-c3ccc(C#N)cc3)ccc2O4)c(-c2ccccc2)c1]

### Synthesis of Intermediate Compound 13-a

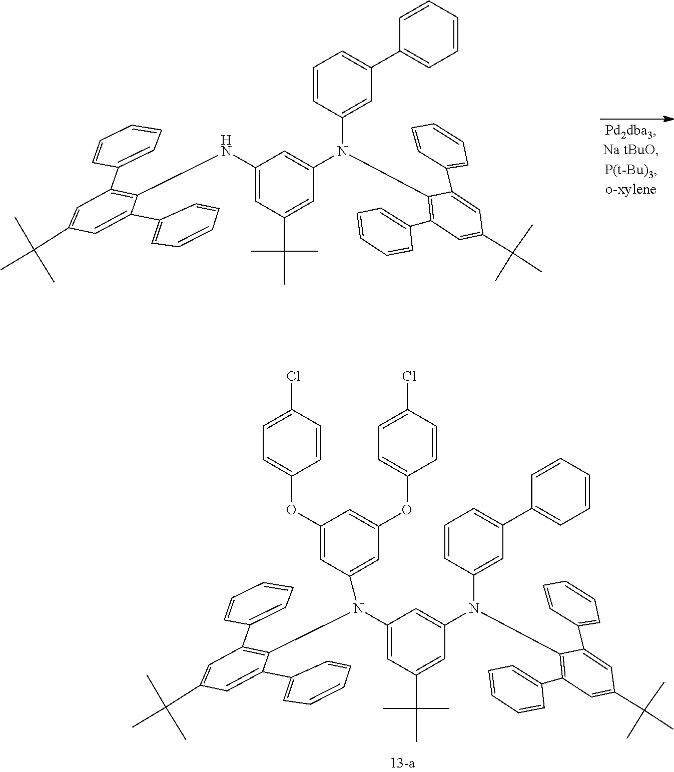

Under an argon atmosphere, a reaction solution was prepared by dissolving N1-([1,1′-biphenyl]-3-yl)-5-(tert-butyl)-N1,N3-bis(5′-(tert-butyl)-[1,1′:3′,1″-terphenyl]-2′-yl)benzene-1,3-diamine (20 g, 22.6 mmol), 4,4′-((5-bromo-1,3-phenylene)bis(oxy))bis(chlorobenzene) (11.1 g, 27.1 mmol), tris(dibenzylideneacetone)dipalladium (Pd₂dba₃) (1.0 g, 1.1 mmol), tris-tert-butyl phosphine (P(t-Bu)₃)) (0.6 mL, 2.3 mmol), and sodium tert-butoxide (Na tBuO) (4.3 g, 45 mmol) in 300 mL of o-xylene in a 1 L flask. The reaction solution was stirred at 120° C. for 2 hours. 4,4′-((5-bromo-1,3-phenylene)bis(oxy))bis(chlorobenzene) is the compound as follows.

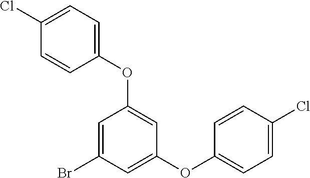 [SMILES: Clc1ccc(Oc2cc(Br)cc(Oc3ccc(Cl)cc3)c2)cc1]

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 13-a (white solid, 14.0 g, yield 51%).

Electrospray Ionization-Liquid Chromatography-Mass Spectroscopy (ESI-LCMS): [M]+: C₈₄H₇₄Cl₂N₂O₂. 1214.43.

### Synthesis of Intermediate Compound 13-b

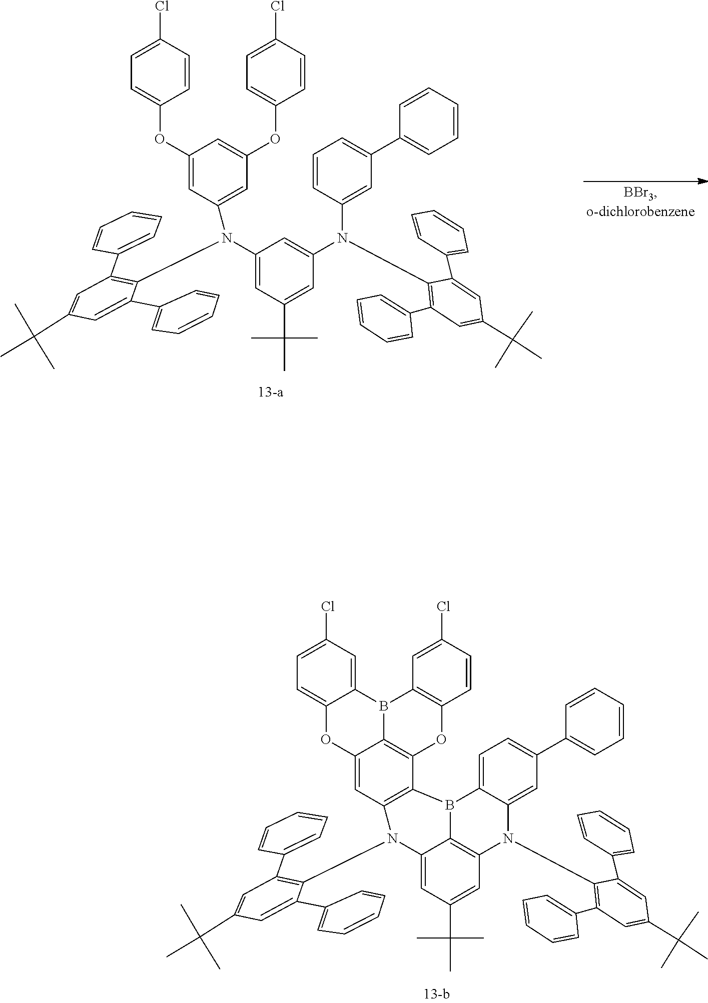

Under an argon atmosphere, the compound 13-a (13.0 g, 10.7 mmol) was dissolved in 200 mL of o-dichlorobenzene in a 1 L flask, and BBr₃ (3.0 equiv.) was added to prepare a reaction solution. The reaction solution was stirred at 140° C. for 12 hours. After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain an intermediate compound 13-b (yellow solid, 2.6 g, yield 20%).

ESI-LCMS: [M]+: C₈₄H₆₈B₂Cl₂N₂O₂. 1230.00

### Synthesis of Compound 13

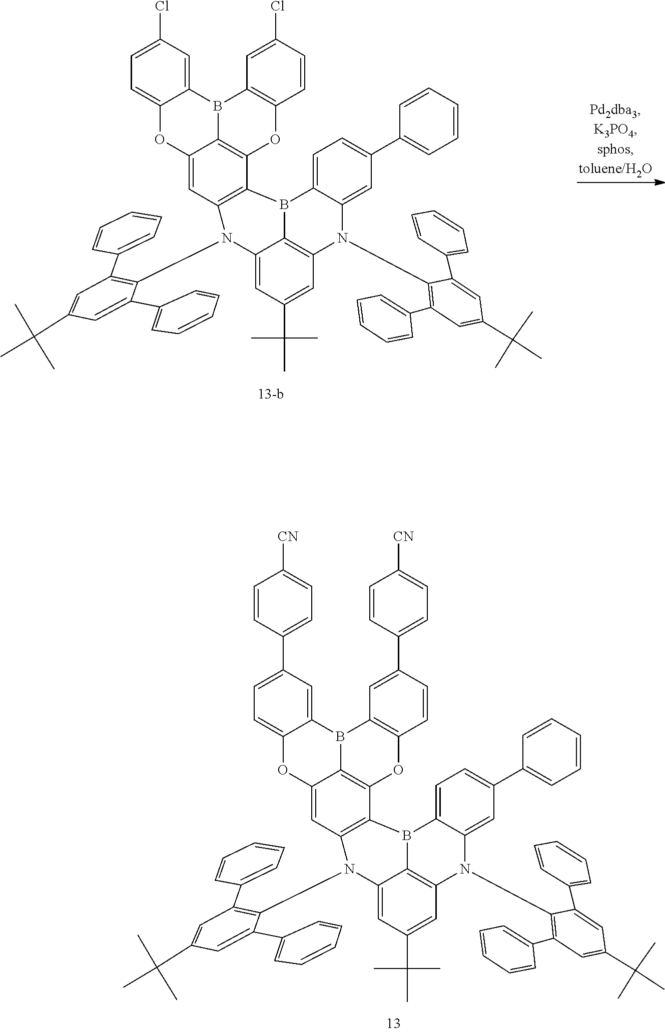

Under an argon atmosphere, the compound 13-b (1.0 g, 0.8 mmol), (4-cyanophenyl)boronic acid (0.4 g, 2.4 mmol), Pd₂dba₃ (0.1 g, 0.1 mmol), 2-dicyclohexylphosphino-2′,6′-dimethoxybiphenyl (sphos) (0.1 g, 0.2 mmol), and potassium phosphate (0.4 g, 1.7 mmol) were dissolved in 20 mL of toluene and 2 mL of H₂O to prepare a reaction solution in a 1 L flask. The reaction solution was stirred at 100° C. for 12 hours. After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The solid obtained therefrom was purified and separated by silica gel column chromatography using CH₂Cl₂ and hexane as developing solvents to obtain the compound 13 (yellow solid, 0.6 g, yield 58%).

ESI-LCMS: [M]+: C₉₈H₇₆B₂N₄O₂. 1363.33

Proton nuclear magnetic resonance spectroscopy (¹H-NMR) (CDCl₃): δ=7.99 (s, 4H), 7.84-7.63 (m, 15H), 7.49-7.41 (m, 18H), 7.27-7.19 (m, 3H), 7.08 (m, 8H), 7.06 (s, 2H), 6.58 (s, 1H), 1.32 (s, 27H).

### Synthesis Example 2: Synthesis of Compound 12

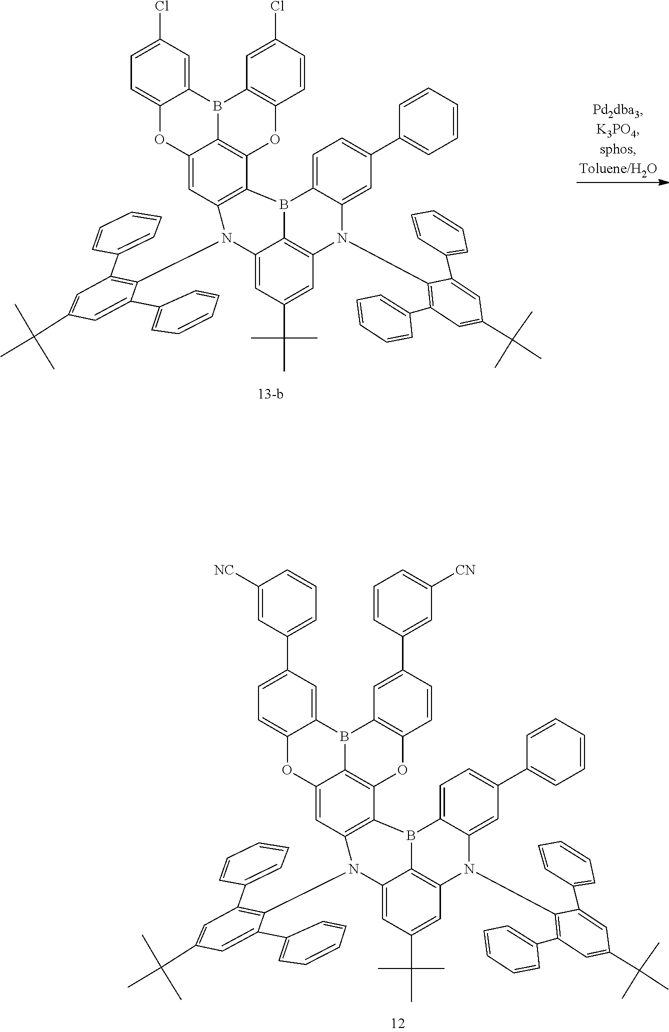

Under an argon atmosphere, the compound 13-b (1.0 g, 0.8 mmol), (3-cyanophenyl)boronic acid (0.4 g, 2.4 mmol), Pd₂dba₃ (0.1 g, 0.1 mmol), 2-dicyclohexylphosphino-2′,6′-dimethoxybiphenyl (0.1 g, 0.2 mmol), and potassium phosphate (0.4 g, 1.7 mmol) were dissolved in 20 mL of toluene and 2 mL of H₂O to prepare a reaction solution in a 1 L flask. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 12 (yellow solid, 0.4 g, yield 40%).

ESI-LCMS: [M]+: C₉₈H₇₆B₂N₄O₂. 1363.33

¹H-NMR (CDCl₃): δ=7.99 (s, 4H), 8.02-7.63 (m, 15H), 7.49-7.41 (m, 18H), 7.27-7.19 (m, 3H), 7.08 (m, 8H), 7.06 (s, 2H), 6.58 (s, 1H), 1.32 (s, 27H).

### Synthesis Example 3: Synthesis of Compound 46

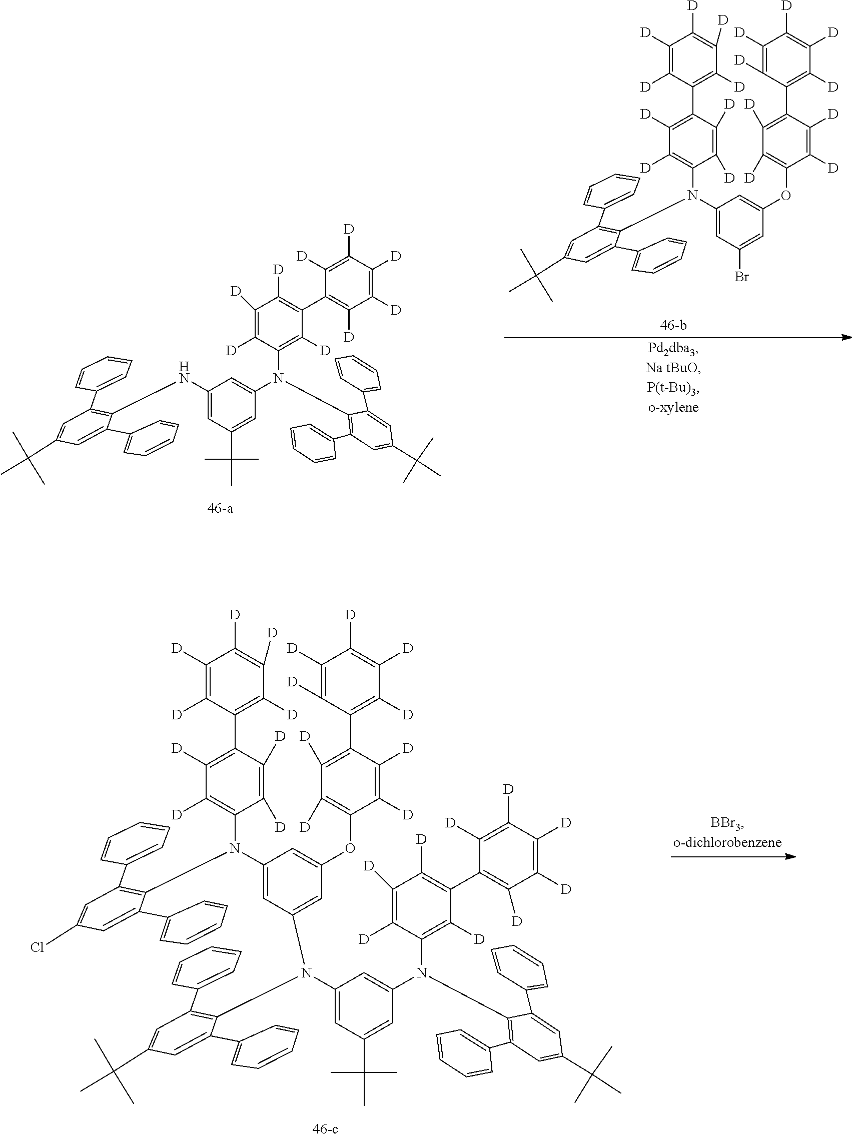

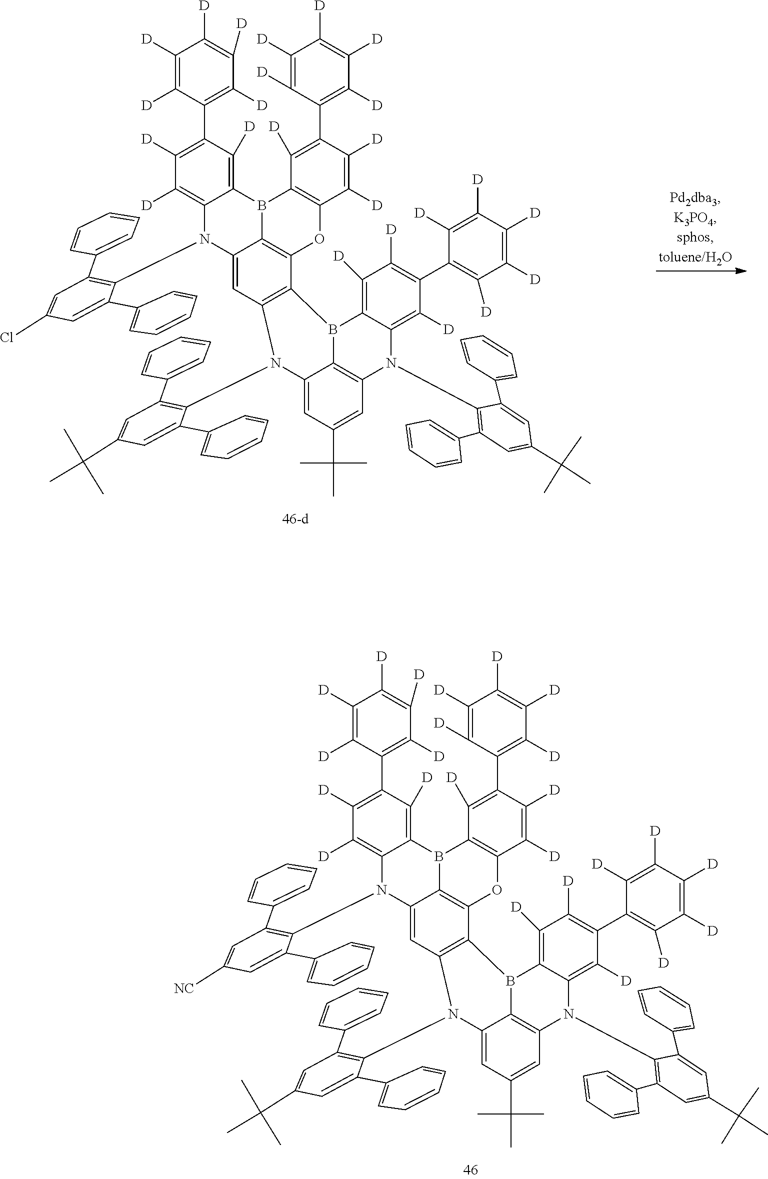

### Synthesis of Intermediate Compound 46-a

Under an argon atmosphere, 5-(tert-butyl)-N1,N3-bis(5′-(tert-butyl)-[1,1′:3′,1″-terphenyl]-2′-yl)benzene-1,3-diamine (30 g, 40.9 mmol), 3-iodo-1,1′-biphenyl-2,2′, 3′,4,4′, 5,5′, 6,6′-d₉ (12.4 g, 42.9 mmol), Pd₂dba₃ (2.0 g, 2.2 mmol), tris-tert-butyl phosphine (1.2 mL, 4.5 mmol), and sodium tert-butoxide (5.9 g, 61.4 mmol) were dissolved in 400 mL of o-xylene in a 1 L flask to prepare a reaction solution. The reaction solution was stirred at 120° C. for 2 hours.

After the stirred solution was cooled to room temperature, an organic layer was extracted and separated using H₂O (1 L) and ethyl acetate (500 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 46-a (white solid, 21.9 g, yield 60%).

ESI-LCMS: [M]+: C₆₆H₅₅D₉N₂. 894.31

### Synthesis of Intermediate Compound 46-b

Under an argon atmosphere, N-(3-(([1,1′-biphenyl]-4-yl-d₉)oxy)-5-bromophenyl)-5′-chloro-[1,1′:3′,1″-terphenyl]-2′-amine (35 g, 57.1 mmol), 4-iodo-1,1′-biphenyl-2,2′,3,3′,4′,5,5′,6,6′-d₉ (24.7 g, 85.6 mmol), Pd₂dba₃ (2.0 g, 2.2 mmol), tris-tert-butyl phosphine (1.2 mL, 4.5 mmol), and sodium tert-butoxide (8.2 g, 85.6 mmol) were dissolved in 500 mL of o-xylene in a 1 L flask to prepare a reaction solution. The reaction solution was stirred at 120° C. for 2 hours.

After the stirred solution was cooled to room temperature, an organic layer was extracted and separated using H₂O (1 L) and ethyl acetate (500 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain intermediate compound 46-b (white solid, 23.4 g, yield 53%).

ESI-LCMS: [M]+: C₄₈H₁₅D₁₈BrClNO. 773.26

### Synthesis of Intermediate Compound 46-c

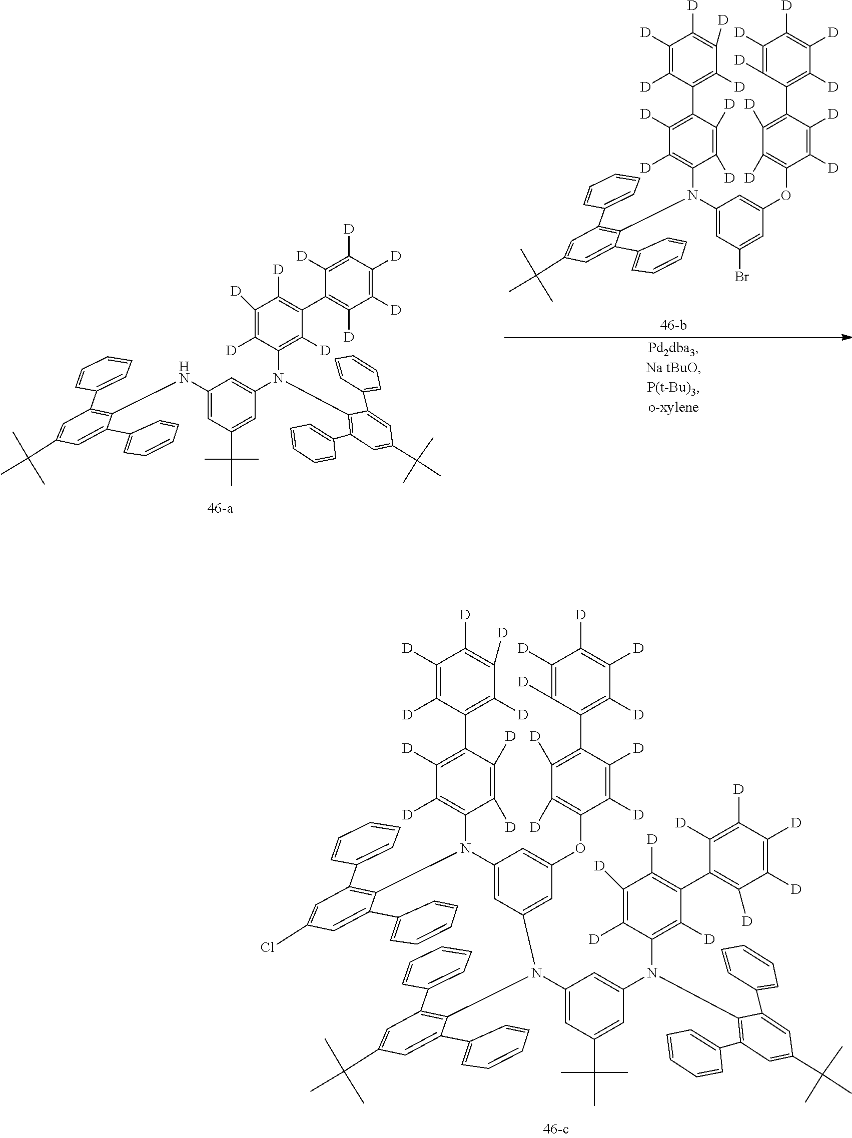

Under an argon atmosphere, the compound 46-a (20.0 g, 22.4 mmol), the compound 46-b (22.2 g, 27.1 mmol), Pd₂dba₃ (1.0 g, 1.1 mmol), tris-tert-butyl phosphine (0.6 mL, 2.3 mmol), and sodium tert-butoxide (4.3 g, 45 mmol) were dissolved in 300 mL of o-xylene to prepare a reaction solution in a 1 L flask. The reaction solution was stirred at 120° C. for 2 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 46-c (white solid, 17.0 g, yield 48%).

ESI-LCMS: [M]+: C₁₁₄H₆₉D₂₇ClN₃O. 1586.66

### Synthesis of Intermediate Compound 46-d

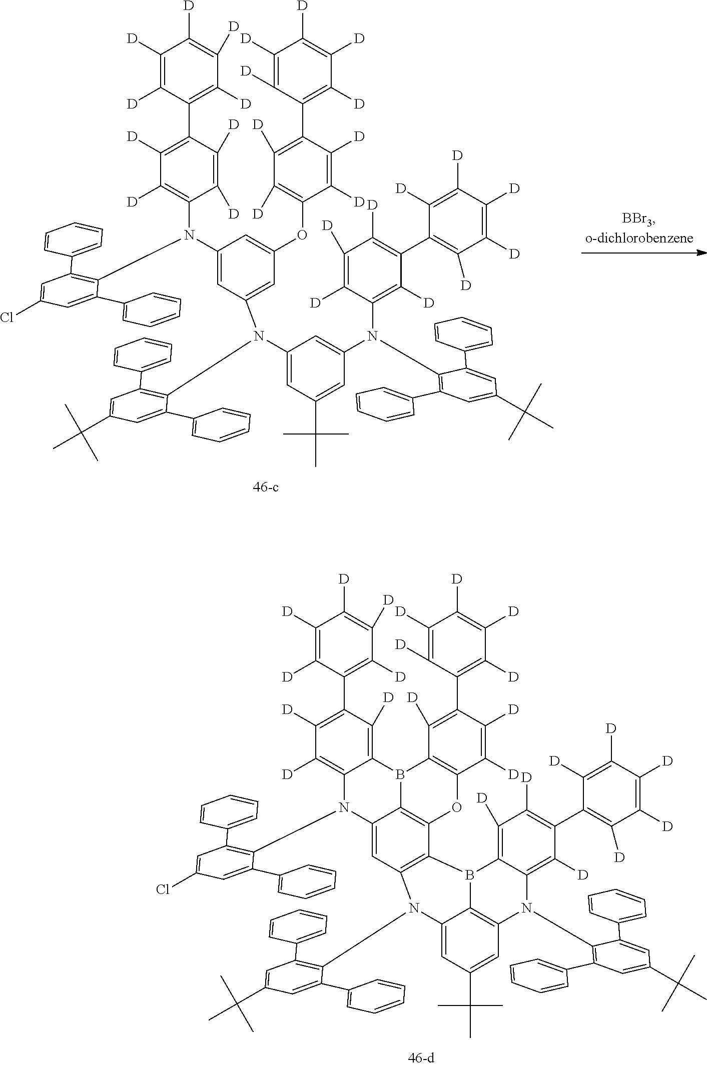

Under an argon atmosphere, the compound 46-c (15.0 g, 9.5 mmol) was dissolved in 200 mL of o-dichlorobenzene in a 1 L flask, and BBr₃ (3.0 equiv.) was added to prepare a reaction solution. The reaction solution was stirred at 140° C. for 12 hours.

The stirred solution was cooled to room temperature. Triethylamine was added to the cooled solution to terminate the reaction, and the solvent was removed under reduced pressure.

The obtained solid was purified and separated by silica gel column chromatography using CH₂Cl₂ and hexane as developing solvents to obtain an intermediate compound 46-d (yellow solid, 2.4 g, yield 16%).

ESI-LCMS: [M]+: C₁₁₄H₆₆D₂₄B₂ClN₃O. 1599.21

### Synthesis of Compound 46

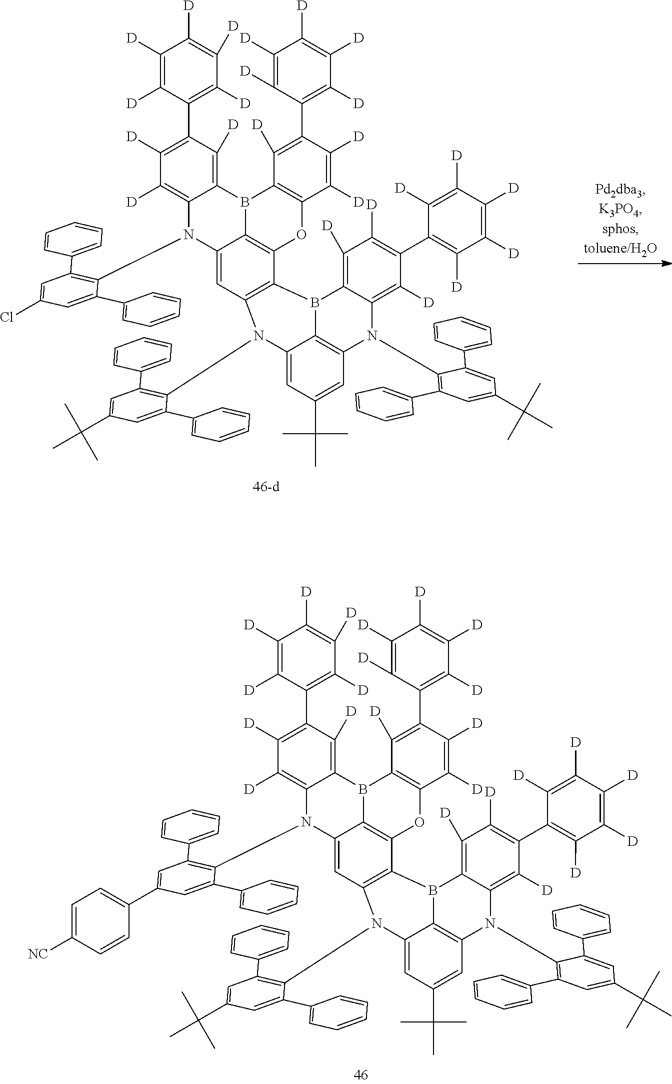

Under an argon atmosphere, the compound 46-d (1.0 g, 0.6 mmol), (4-cyanophenyl)boronic acid (0.2 g, 0.9 mmol), Pd₂dba₃ (0.03 g, 0.03 mmol), 2-dicyclohexylphosphino-2′,6′-dimethoxybiphenyl (0.03 g, 0.06 mmol), and potassium phosphate (0.3 g, 1.3 mmol) were dissolved in 20 mL of toluene and 2 mL of H₂O to prepare a reaction solution. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 46 (yellow solid, 0.5 g, 51%).

ESI-LCMS: [M]+: C₁₂₁H₇₀D₂₄B₂N₄O. 1665.88

¹H-NMR (CDCl₃): δ=7.99 (s, 4H), 8.00-7.84 (m, 6H), 7.43-7.41 (m, 18H), 7.08 (m, 12H), 7.06 (s, 2H), 6.55 (s, 1H), 1.32 (s, 27H).

### Synthesis Example 4: Synthesis of Compound 47

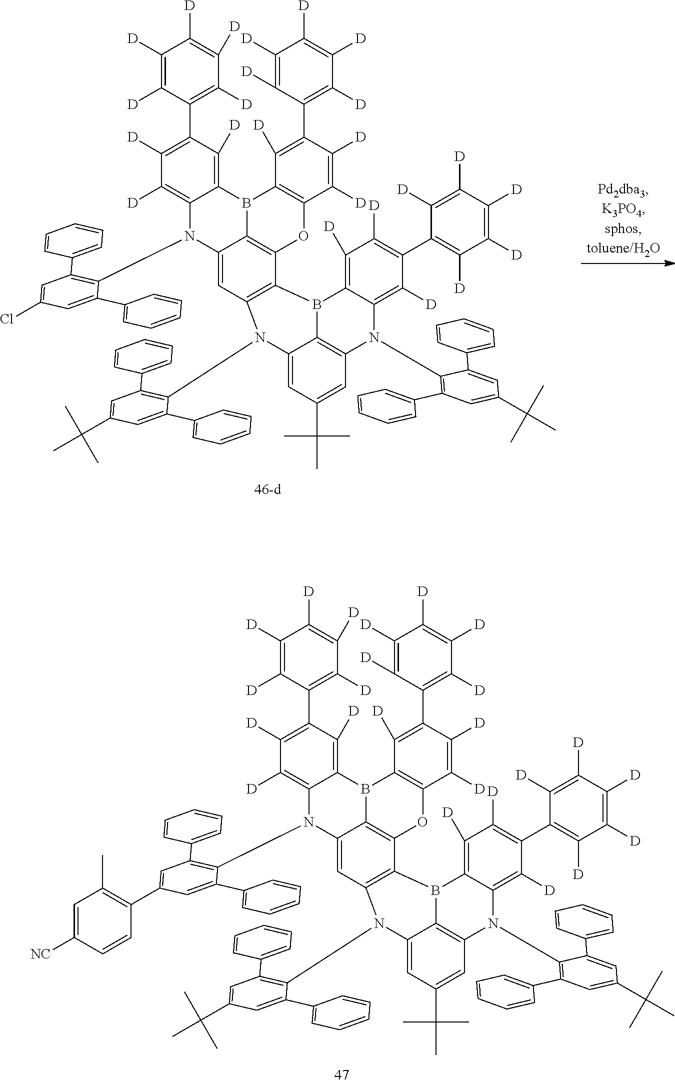

Under an argon atmosphere, the compound 46-d (1.0 g, 0.6 mmol), (4-cyano-2-methylphenyl)boronic acid (0.2 g, 0.9 mmol), Pd₂dba₃ (0.03 g, 0.03 mmol), 2-dicyclohexylphosphino-2′,6′-dimethoxybiphenyl (0.03 g, 0.06 mmol), and potassium phosphate (0.3 g, 1.3 mmol) were dissolved in 20 mL of toluene and 2 mL of H₂O to prepare a reaction solution. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The solid obtained therefrom was purified and separated by silica gel column chromatography using CH₂Cl₂ and hexane as developing solvents to obtain the compound 47 (yellow solid, 0.4 g, yield 36%).

ESI-LCMS: [M]+: C₁₂₂H₇₂D₂₄B₂N₄O. 1679.90

¹H-NMR (CDCl₃): δ=7.99 (s, 4H), 8.00-7.72 (m, 5H), 7.43-7.41 (m, 18H), 7.08 (m, 12H), 7.06 (s, 2H), 6.55 (s, 1H), 2.57 (s, 3H), 1.32 (s, 27H).

### Synthesis Example 5: Synthesis of Compound 34

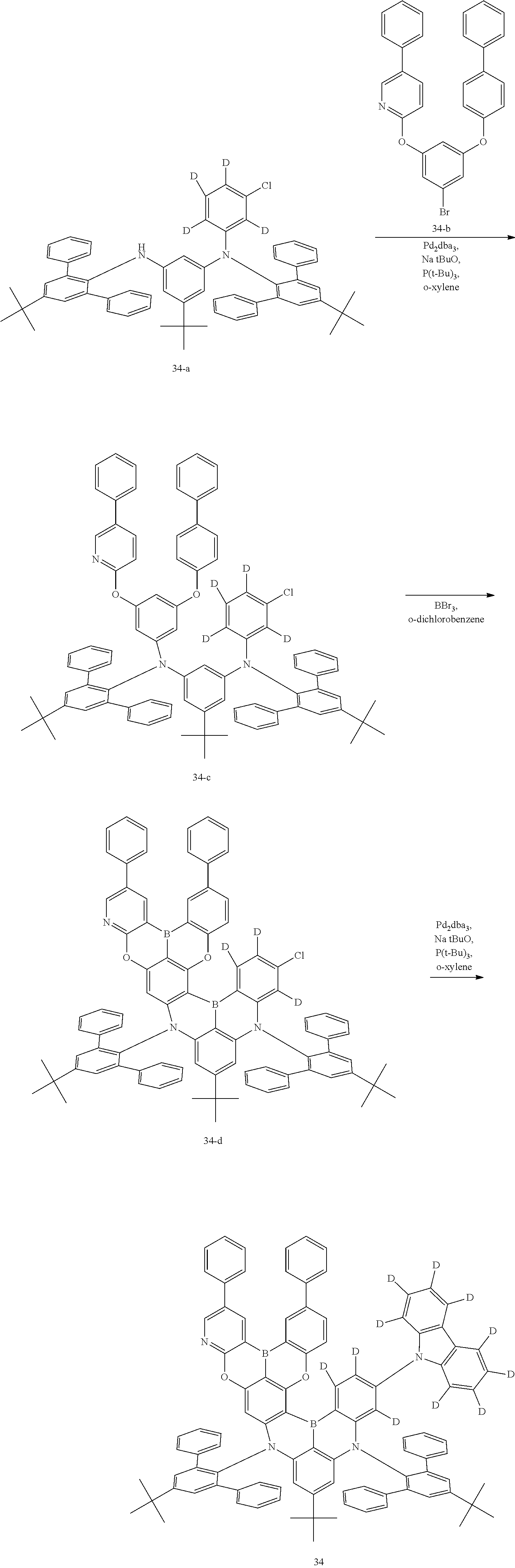

### Synthesis of Intermediate Compound 34-a

Under an argon atmosphere, 5-(tert-butyl)-N1,N3-bis(5′-(tert-butyl)-[1,1′:3′,1″-terphenyl]-2′-yl)benzene-1,3-diamine (30 g, 40.9 mmol), 1-chloro-3-iodobenzene-2,4,5,6-d₄ (11.9 g, 49.1 mmol), Pd₂dba₃ (2.0 g, 2.2 mmol), tris-tert-butyl phosphine (1.2 mL, 4.5 mmol), and sodium tert-butoxide (5.9 g, 61.4 mmol) were dissolved in 400 mL of o-xylene in a 1 L flask to prepare a reaction solution. The reaction solution was stirred at 120° C. for 2 hours.

After the stirred solution was cooled to room temperature, an organic layer was extracted and separated using H₂O (1 L) and ethyl acetate (500 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 24-a (white solid, 22.5 g, yield 65%).

ESI-LCMS: [M]+: C₆₀H₅₅D₄ClN₂. 847.62

### Synthesis of Intermediate Compound 34-b

Under an argon atmosphere, 2-fluoro-5-phenylpyridine (50 g, 289.0 mmol), 3-([1,1′-biphenyl]-4-yloxy)-5-bromophenol (108 g, 317.9 mmol), and cesium carbonate (141.3 g, 433.5 mmol) were dissolved in 600 mL of dimethylformamide (DMF) in a 1 L flask to prepare a reaction solution. The reaction solution was stirred at 150° C. for 5 hours.

After the stirred solution was cooled to room temperature, an organic layer was extracted and separated using H₂O (1 L) and ethyl acetate (2 L). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 34-b (colorless transparent viscous substance, 105.6 g, yield 74%).

ESI-LCMS: [M]+: C₂₉H₂₀BrNO₂. 494.39

### Synthesis of Compound 34-c

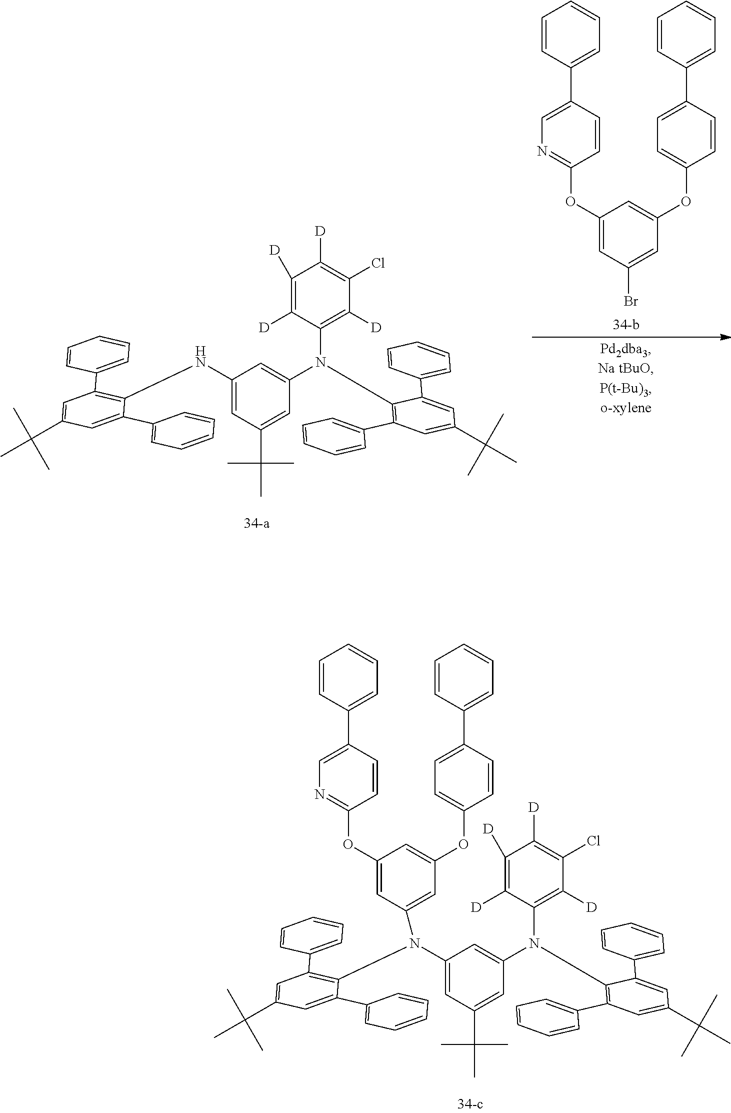

Under an argon atmosphere, the compound 34-a (20.0 g, 23.6 mmol), the compound 34-b (17.5 g, 35.4 mmol), Pd₂dba₃ (1.0 g, 1.1 mmol), tris-tert-butyl phosphine (0.6 mL, 2.3 mmol), and sodium tert-butoxide (3.4 g, 35.4 mmol) were dissolved in 250 mL of o-xylene to prepare a reaction solution. The reaction solution was stirred at 140° C. for 5 hours.

After the stirred solution was cooled to room temperature, an organic layer was extracted and separated using H₂O (1 L) and ethyl acetate (300 mL).

The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 34-c (white solid, 14.3 g, yield 48%).

ESI-LCMS: [M]+: C₈₉H₇₄D₄ClN₃O₂. 1261.10

### Synthesis of Intermediate Compound 34-d

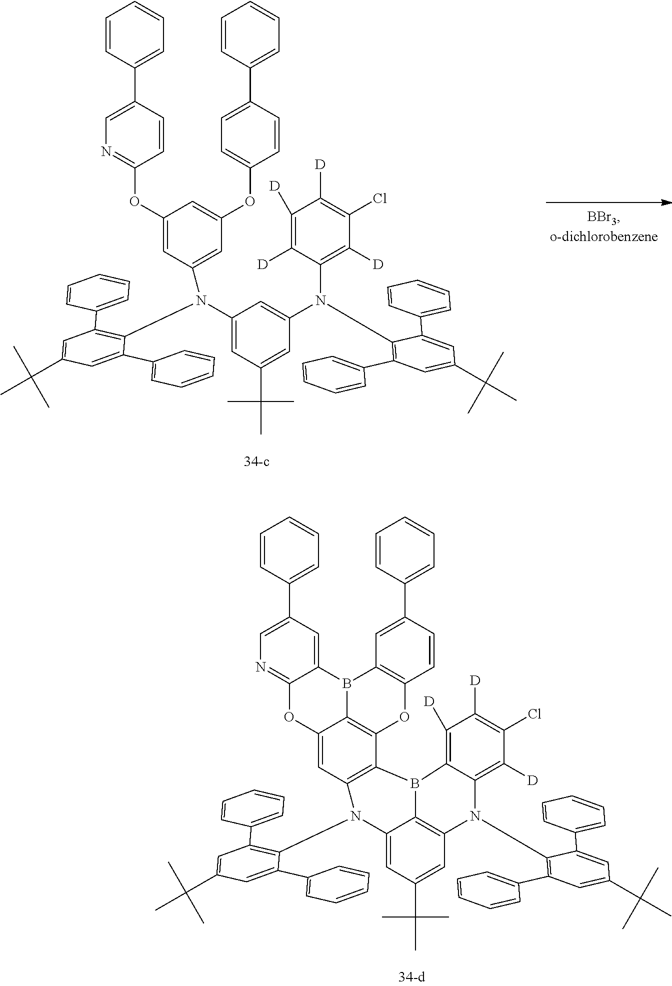

Under an argon atmosphere, the compound 34-c (13.0 g, 10.3 mmol) was dissolved in 200 mL of o-dichlorobenzene in a 1 L flask, and BBr₃ (3.0 equiv.) was added to prepare a reaction solution. The reaction solution was stirred at 140° C. for 12 hours.

After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain an intermediate compound 34-d (yellow solid, 2.7 g, yield 21%).

ESI-LCMS: [M]+: C₈₉H₆₉D₃B₂ClN₃O₂. 1275.66

### Synthesis of Compound 34

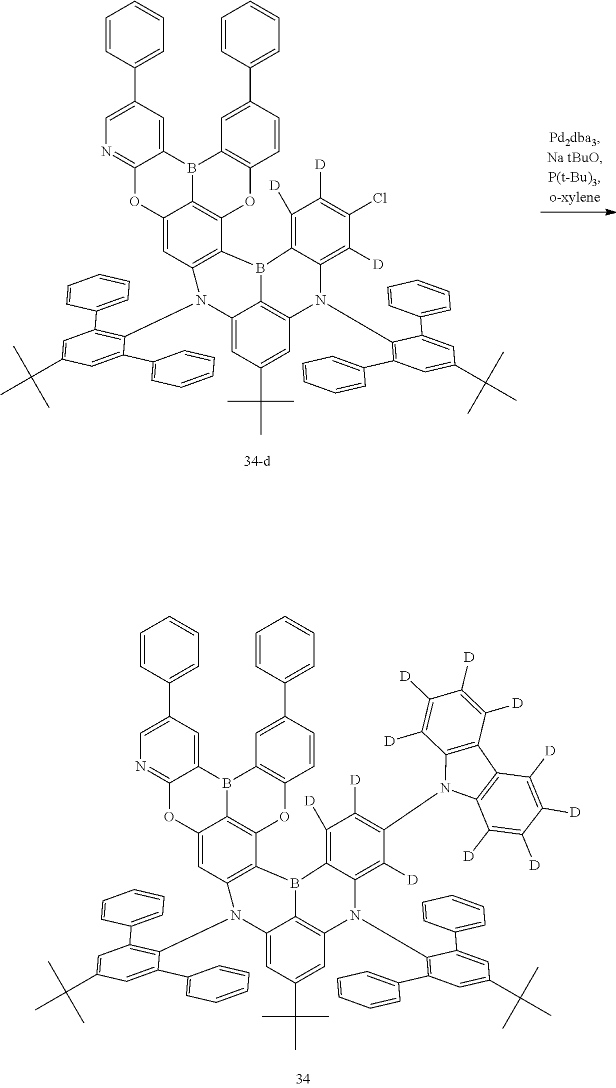

Under an argon atmosphere, the compound 34-d (2.0 g, 1.5 mmol), 9H-carbazole-1,2,3,4,5,6,7,8-d₈ (0.5 g, 3.1 mmol), Pd₂dba₃ (0.06 g, 0.06 mmol), 2-dicyclohexylphosphino-2′,6′-dimethoxybiphenyl (0.06 g, 0.12 mmol), and potassium phosphate (0.6 g, 3.1 mmol) were dissolved in 20 mL of toluene to prepare a reaction solution. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 34 (yellow solid, 1.1 g, 52%).

ESI-LCMS: [M]+: C₁₀₁H₆₉D₁₁B₂N₄O₂. 1414.46

¹H-NMR (CDCl₃): δ=7.99 (s, 4H), 8.00-7.84 (m, 6H), 7.43-7.41 (m, 18H), 7.08 (m, 12H), 7.06 (s, 2H), 6.55 (s, 1H), 1.32 (s, 27H).

### Synthesis Example 6: Synthesis of Compound 18

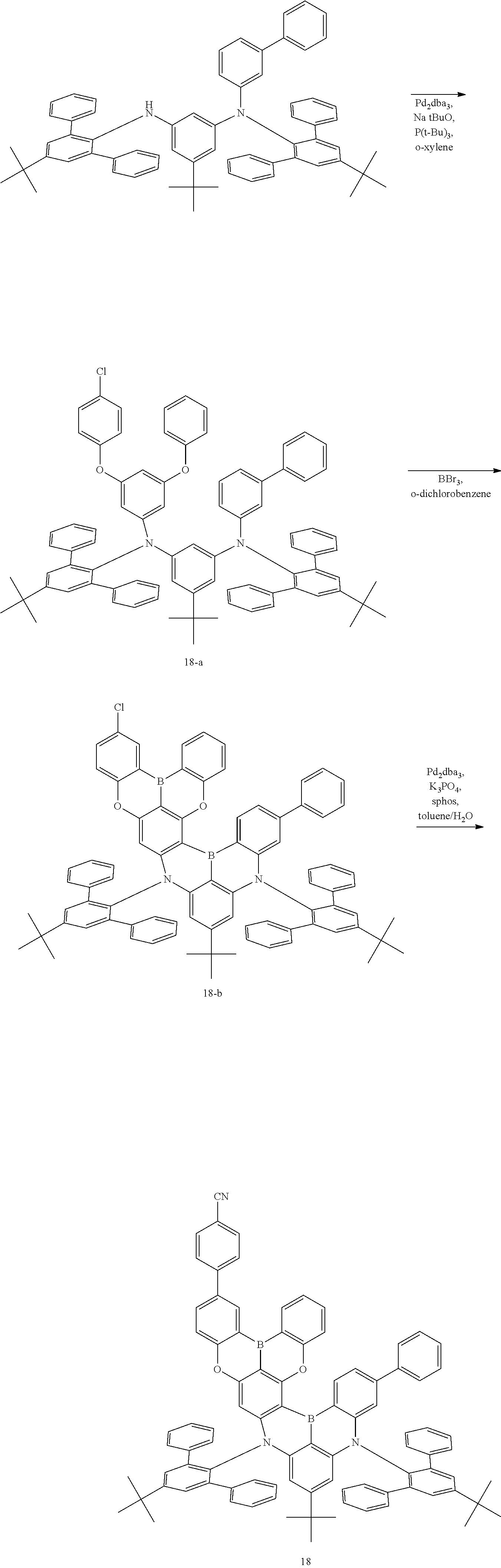

### Synthesis of Intermediate Compound 18-a

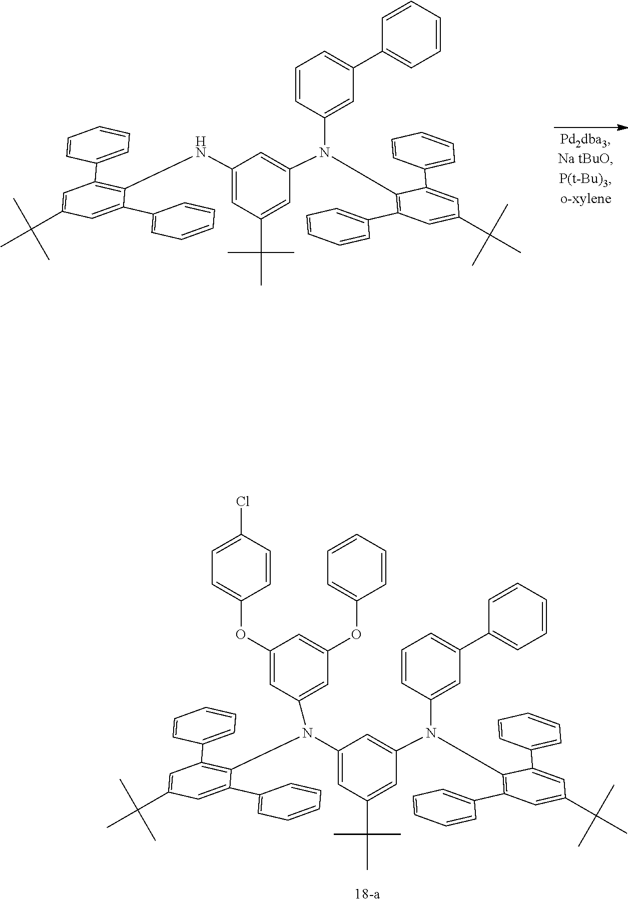

Under an argon atmosphere, a reaction solution was prepared by dissolving N1-([1,1′-biphenyl]-3-yl)-5-(tert-butyl)-N1,N3-bis(5′-(tert-butyl)-[1,1′:3′,1″-terphenyl]-2′-yl)benzene-1,3-diamine (20 g, 22.6 mmol), 1-(4-chlorophenoxy)-3-iodo-5-phenoxybenzene (11.4 g, 27.1 mmol), Pd₂dba₃ (1.0 g, 1.1 mmol), tris-tert-butyl phosphine (0.6 mL, 2.3 mmol), and sodium tert-butoxide (4.3 g, 45 mmol) in 300 mL of o-xylene in a 1 L flask. The reaction solution was stirred at 120° C. for 2 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 18-a (white solid, 14.4 g, yield 54%).

ESI-LCMS: [M]+: C₈₄H₇₅ClN₂O₂. 1179.99.

### Synthesis of Intermediate Compound 18-b

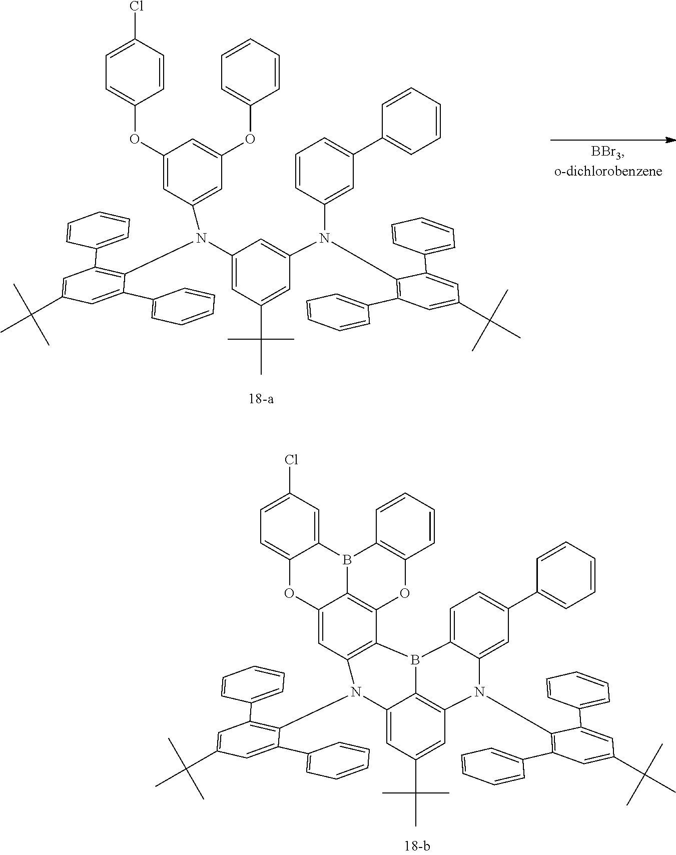

Under an argon atmosphere, the compound 18-a (10.0 g, 8.5 mmol) was dissolved in 150 mL of o-dichlorobenzene in a 1 L flask, and BBr₃ (3.0 equiv.) was added to prepare a reaction solution. The reaction solution was stirred at 140° C. for 12 hours.

After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain an intermediate compound 18-b (yellow solid, 1.8 g, yield 18%).

ESI-LCMS: [M]+: C₈₄H₆₉B₂ClN₂O₂. 1195.56

### Synthesis of Compound 18

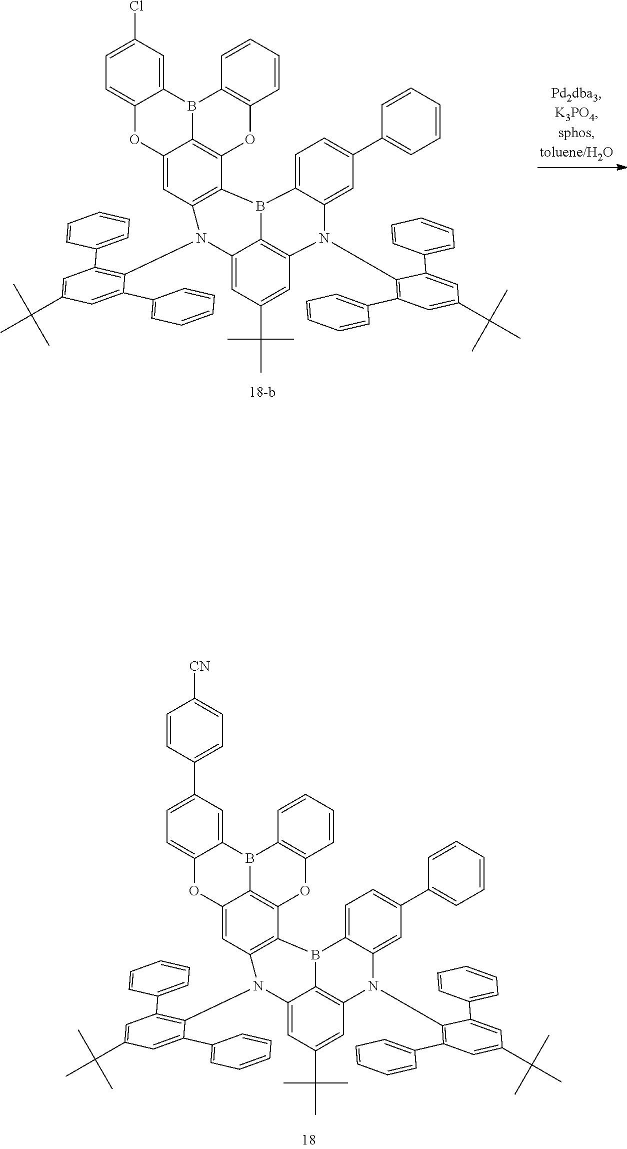

Under an argon atmosphere, the compound 18-b (1.0 g, 0.8 mmol), (4-cyanophenyl)boronic acid (0.2 g, 1.2 mmol), Pd₂dba₃ (0.1 g, 0.1 mmol), 2-dicyclohexylphosphino-2′,6′-dimethoxybiphenyl (0.1 g, 0.2 mmol), and potassium phosphate (0.4 g, 1.7 mmol) were dissolved in 20 mL of toluene and 2 mL of H₂O to prepare a reaction solution in a 1 L flask. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 18 (yellow solid, 0.6 g, yield 64%).

ESI-LCMS: [M]+: C₉₁H₇₃B₂N₃O₂. 1262.22

1H-NMR (CDCl₃): δ=7.99 (s, 4H), 7.90-7.63 (m, 8H), 7.43-7.41 (m, 13H), 7.27-7.19 (m, 3H), 7.08 (m, 8H), 7.06 (s, 2H), 7.00 (d, 1H), 6.58 (s, 1H), 1.32 (s, 27H).

### Synthesis Example 7: Synthesis of Compound 27

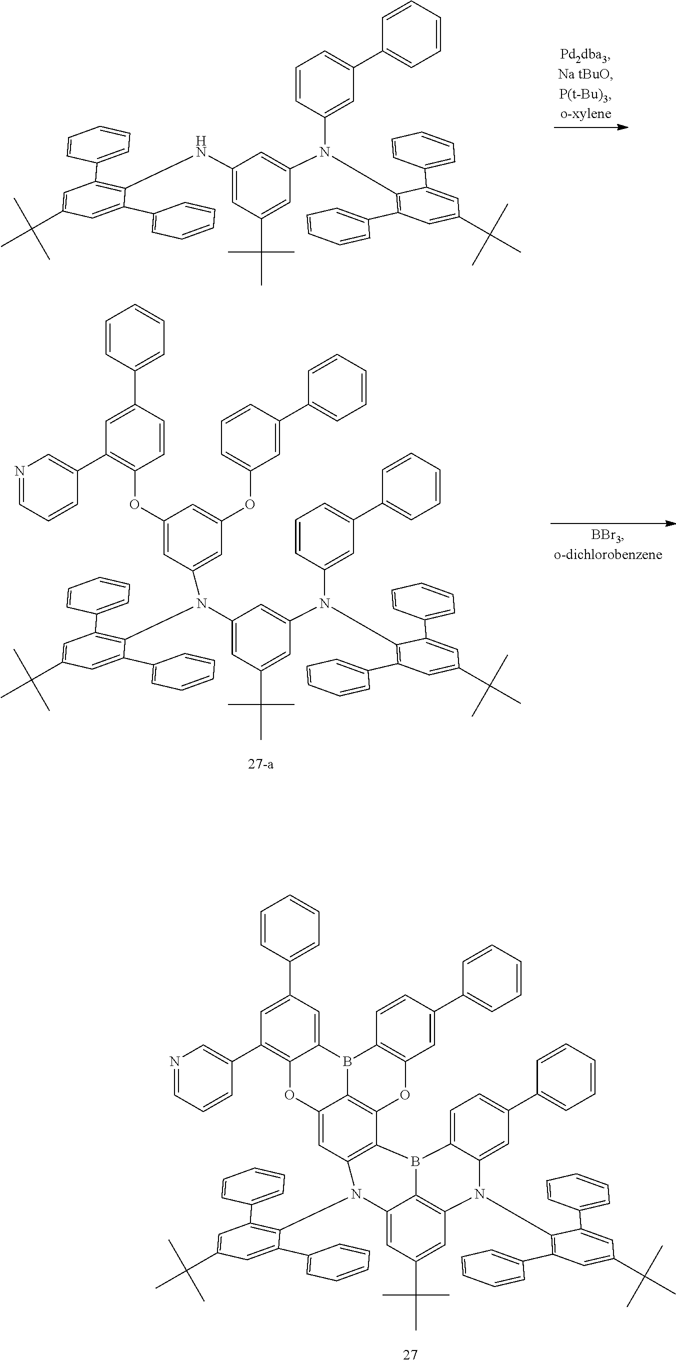

### Synthesis of Intermediate Compound 27-a

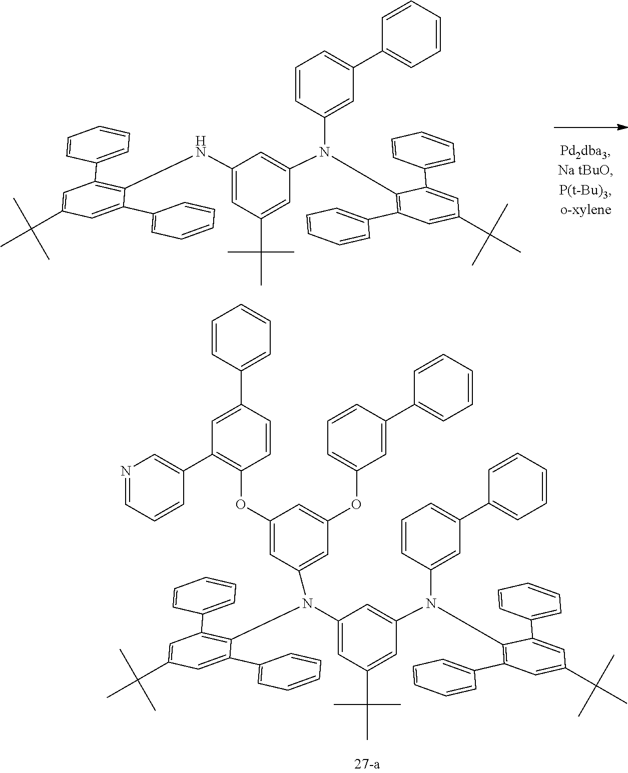

Under argon atmosphere, N1-([1,1′-biphenyl]-3-yl)-5-(tert-butyl)-N1,N3-bis(5′-(tert-butyl)-[1,1′:3′,1″-terphenyl]-2′-yl)benzene-1,3-diamine (20 g, 22.6 mmol), 3-(4-(3-([1,1′-biphenyl]-3-yloxy)-5-bromophenoxy)-[1,1′-biphenyl]-3-yl)pyridine (15.4 g, 27.1 mmol), Pd₂dba₃ (1.0 g, 1.1 mmol), tris-tert-butyl phosphine (0.6 mL, 2.3 mmol), and sodium tert-butoxide (4.3 g, 45 mmol) were dissolved in 300 mL of in o-xylene in a 1 L flask to prepare a reaction solution. The reaction solution was stirred at 120° C. for 2 hours.

After cooling the stirred solution to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as a developing solvent to obtain an intermediate compound 27-a (white solid, 26.1 g, yield 43%).

ESI-LCMS: [M]+: C₁₀₁H₈₇N₃O₂. 1374.83.

### Synthesis of Compound 27

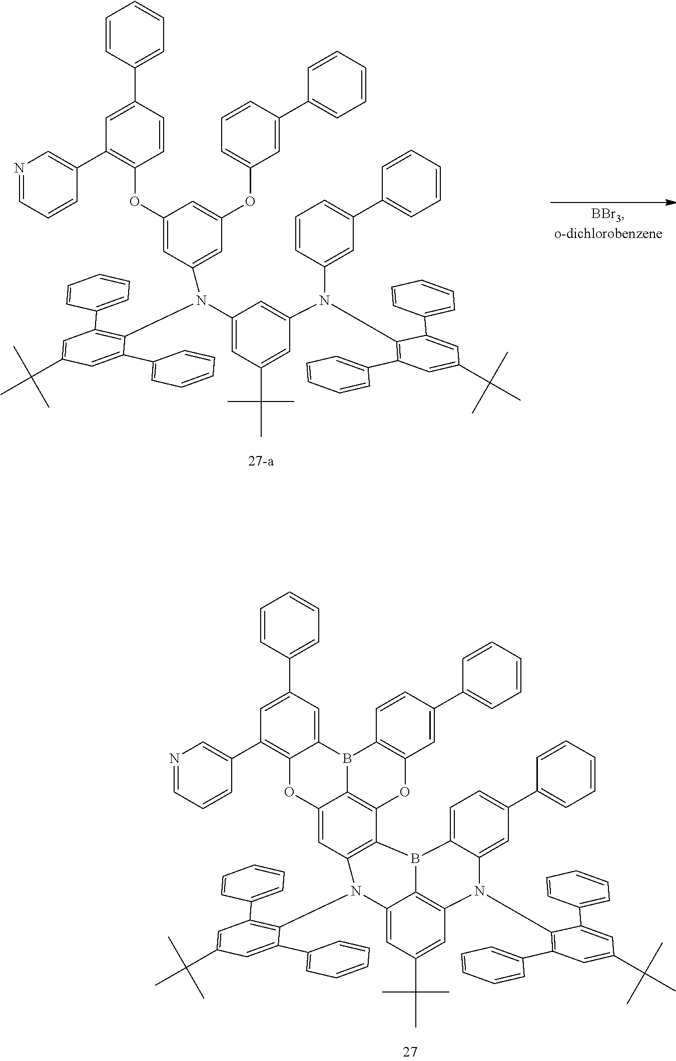

Under an argon atmosphere, the compound 27-a (20.0 g, 14.5 mmol) was dissolved in 300 mL of o-dichlorobenzene in a 1 L flask, and BBr₃ (3.0 equiv.) was added to prepare a reaction solution. The reaction solution was stirred at 140° C. for 12 hours.

After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain the compound 27 (yellow solid, 1.8 g, yield 9%).

ESI-LCMS: [M]+: C₁₀₁H₈₁B₂N₃O₂. 1390.40

¹H-NMR (CDCl₃): δ=9.24 (s, 1H), 8.70 (dd, 1H), 8.42 (dd, H), 7.99-7.97 (m, 5H), 7.90 (d, 2H), 7.75-7.57 (m, 8H), 7.49-7.41 (m, 23H), 7.33 (s, 1H), 7.27 (d, 1H), 7.09-7.06 (m, 10H), 1.32 (s, 27H).

### Synthesis Example 8: Synthesis of Compound 32

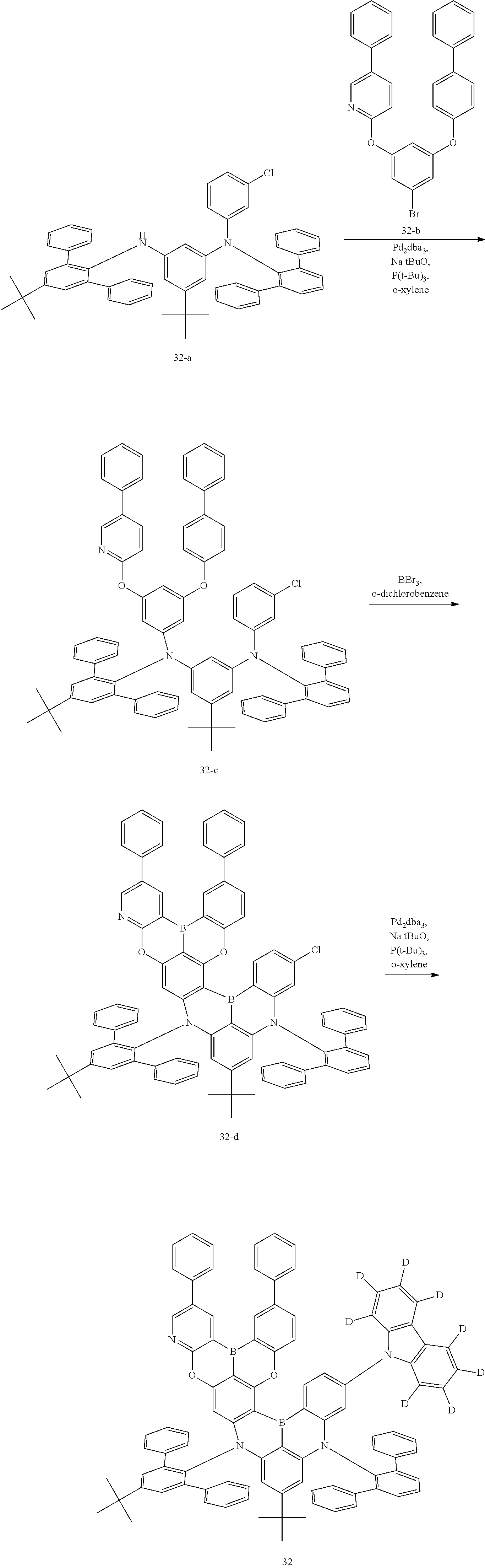

### Synthesis of Intermediate Compound 32-c

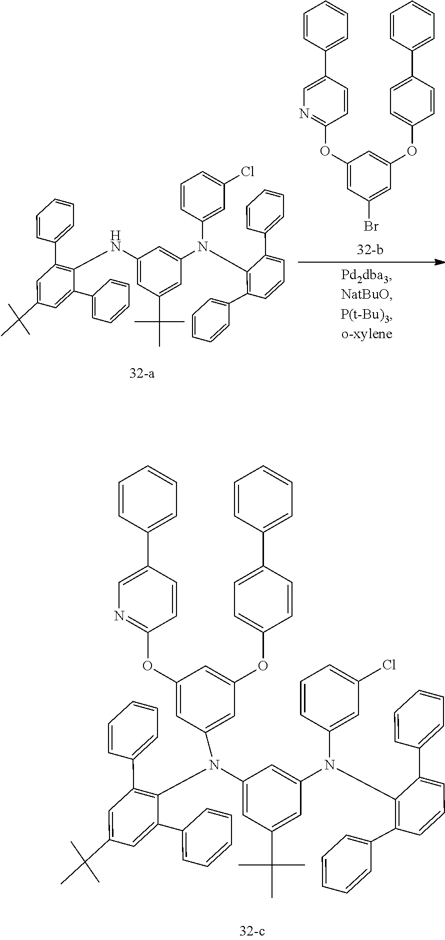 [SMILES: CC(C)(C)c1cc(Nc2c(-c3ccccc3)cc(C(C)(C)C)cc2-c2ccccc2)cc(N(c2cccc(Cl)c2)c2c(-c3ccccc3)cccc2-c2ccccc2)c1 ; Brc1cc(Oc2ccc(-c3ccccc3)cc2)cc(Oc2ccc(-c3ccccc3)cn2)c1 ; CC(C)(C)c1cc(N(c2cccc(Cl)c2)c2c(-c3ccccc3)cccc2-c2ccccc2)cc(N(c2cc(Oc3ccc(-c4ccccc4)cc3)cc(Oc3ccc(-c4ccccc4)cn3)c2)c2c(-c3ccccc3)cc(C(C)(C)C)cc2-c2ccccc2)c1]

Under argon atmosphere, N1-([1,1′:3′,1″-terphenyl]-2′-yl)-5-(tert-butyl)-N3-(5′-(tert-butyl)-[1,1′: 3′, 1″-terphenyl]-2′-yl)-N1-(3-chlorophenyl)benzene-1,3-diamine as the compound 32-a (20.0 g, 25.4 mmol), 2-(3-([1,1′-biphenyl]-4-yloxy)-5-bromophenoxy)-5-phenylpyridine as the compound 32-b (18.8 g, 38.1 mmol), Pd₂dba₃ (1.0 g, 1.1 mmol), tris-tert-butyl phosphine (0.6 mL, 2.3 mmol), and sodium tert-butoxide (3.6 g, 38.1 mmol) was dissolved in 250 mL of o-xylene in a 1 L flask to prepare a reaction solution. The reaction solution was stirred at 140° C. for 5 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 32-c (white solid, 15.8 g, yield 52%).

ESI-LCMS: [M]+: C₈₅H₇₀ClN₃O₂. 1200.96

### Synthesis of Intermediate Compound 32-d

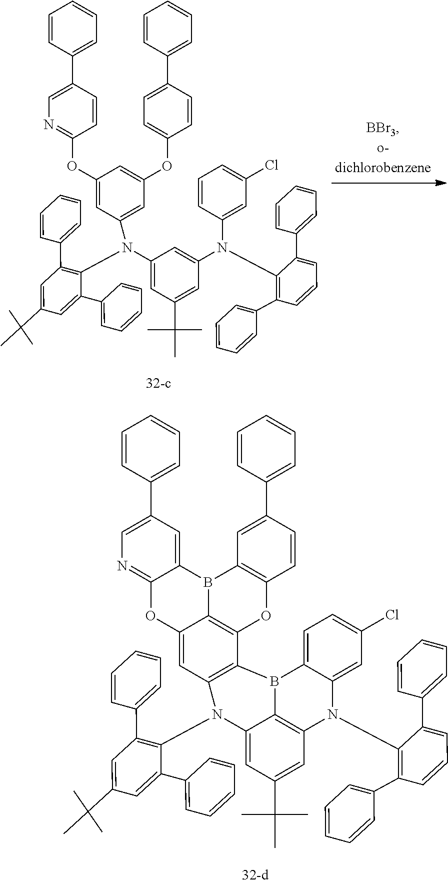 [SMILES: CC(C)(C)c1cc(N(c2cccc(Cl)c2)c2c(-c3ccccc3)cccc2-c2ccccc2)cc(N(c2cc(Oc3ccc(-c4ccccc4)cc3)cc(Oc3ccc(-c4ccccc4)cn3)c2)c2c(-c3ccccc3)cc(C(C)(C)C)cc2-c2ccccc2)c1 ; CC(C)(C)c1cc(-c2ccccc2)c(N2c3cc(C(C)(C)C)cc4c3B(c3ccc(Cl)cc3N4c3c(-c4ccccc4)cccc3-c3ccccc3)c3c2cc2c4c3Oc3ccc(-c5ccccc5)cc3B4c3cc(-c4ccccc4)cnc3O2)c(-c2ccccc2)c1]

Under an argon atmosphere, the compound 32-c (10.0 g, 8.3 mmol) was dissolved in 200 mL of o-dichlorobenzene in a 1 L flask, and BBr₃ (3.0 equiv.) was added to prepare a reaction solution. The reaction solution was stirred at 140° C. for 12 hours.

After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain an intermediate compound 32-d (yellow solid, 2.0 g, yield 20%).

ESI-LCMS: [M]+: C₈₅H₆₄B₂ClN₃O₂. 1216.54

### Synthesis of Compound 32

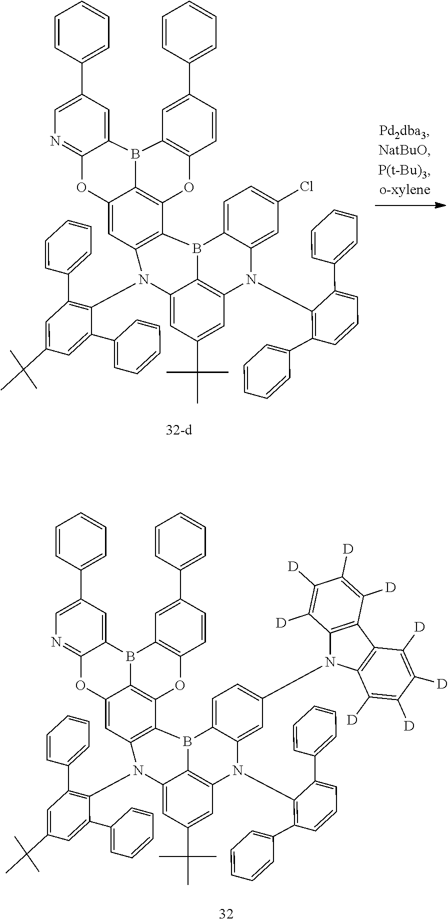 [SMILES: CC(C)(C)c1cc(-c2ccccc2)c(N2c3cc(C(C)(C)C)cc4c3B(c3ccc(Cl)cc3N4c3c(-c4ccccc4)cccc3-c3ccccc3)c3c2cc2c4c3Oc3ccc(-c5ccccc5)cc3B4c3cc(-c4ccccc4)cnc3O2)c(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1c(cc2c4c1Oc1ccc(-c5ccccc5)cc1B4c1cc(-c4ccccc4)cnc1O2)N3c1c(-c2ccccc2)cc(C(C)(C)C)cc1-c1ccccc1]

Under an argon atmosphere, the compound 32-d (1.5 g, 1.2 mmol), 9H-carbazole-1,2,3,4,5,6,7,8-d₉ (0.4 g, 2.4 mmol), Pd₂dba₃ (0.06 g, 0.06 mmol), 2-dicyclohexylphosphino-2′,6′-dimethoxybiphenyl (0.06 g, 0.12 mmol), and potassium phosphate (0.6 g, 3.1 mmol) were dissolved in 20 mL of toluene in a 1 L flask to prepare a reaction solution. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 32 (yellow solid, 0.8 g, 55%).

ESI-LCMS: [M]+: C₇H₆₄D₈B₂N₄O₂. 1355.34

¹H-NMR (CDCl₃): δ=8.20 (d, 2H), 7.99-7.97 (m, 3H), 7.85-7.75 (m, 4H), 7.67-7.63 (m, 2H), 7.51-7.39 (m, 21H), 7.23 (s, 1H), 7.19 (d, 1H), 7.08-7.06 (m, 10H), 1.32 (s, 18H).

### Synthesis Example 9: Synthesis of Compound 63

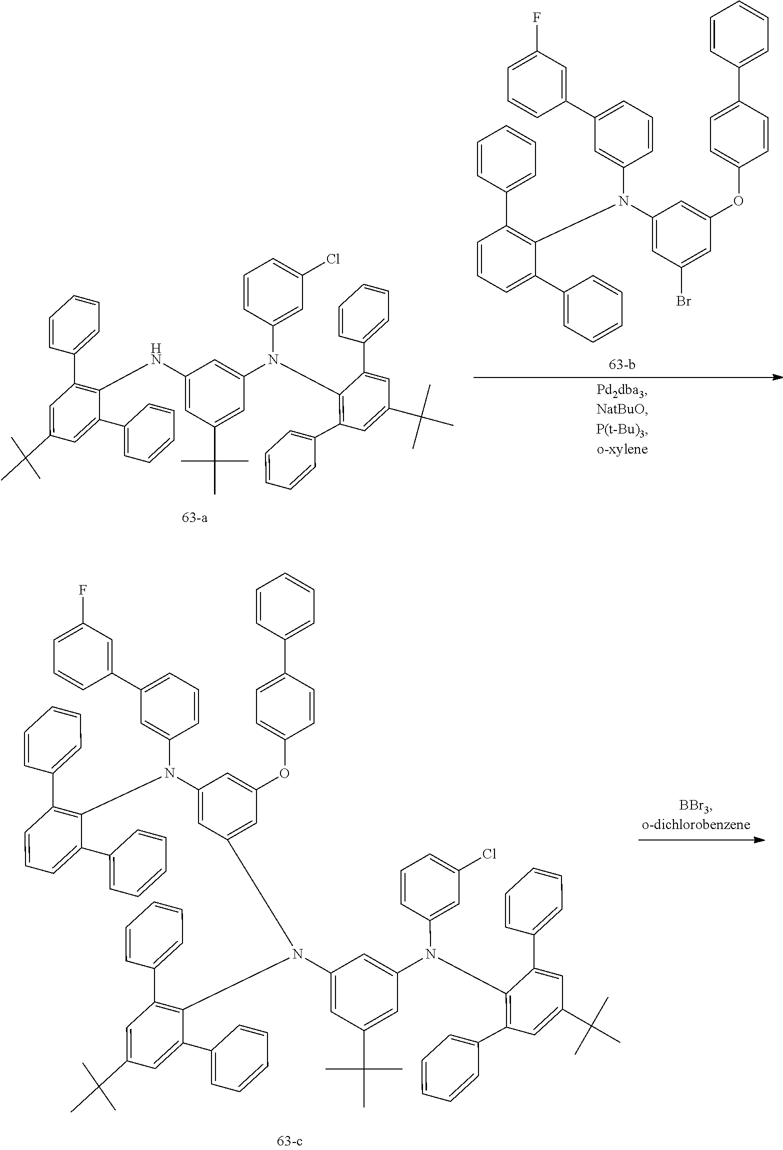 [SMILES: CC(C)(C)c1cc(Nc2c(-c3ccccc3)cc(C(C)(C)C)cc2-c2ccccc2)cc(N(c2cccc(Cl)c2)c2c(-c3ccccc3)cc(C(C)(C)C)cc2-c2ccccc2)c1 ; Fc1cccc(-c2cccc(N(c3cc(Br)cc(Oc4ccc(-c5ccccc5)cc4)c3)c3c(-c4ccccc4)cccc3-c3ccccc3)c2)c1 ; CC(C)(C)c1cc(N(c2cccc(Cl)c2)c2c(-c3ccccc3)cc(C(C)(C)C)cc2-c2ccccc2)cc(N(c2cc(Oc3ccc(-c4ccccc4)cc3)cc(N(c3cccc(-c4cccc(F)c4)c3)c3c(-c4ccccc4)cccc3-c3ccccc3)c2)c2c(-c3ccccc3)cc(C(C)(C)C)cc2-c2ccccc2)c1]

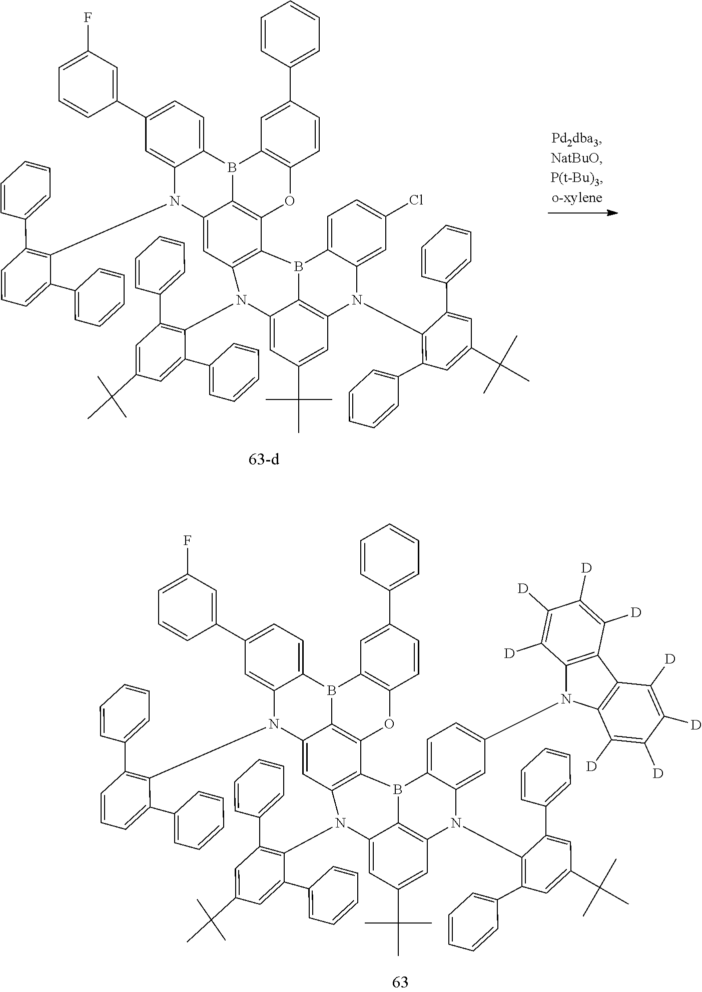 [SMILES: CC(C)(C)c1cc(-c2ccccc2)c(N2c3cc(Cl)ccc3B3c4c2cc(C(C)(C)C)cc4N(c2c(-c4ccccc4)cc(C(C)(C)C)cc2-c2ccccc2)c2cc4c5c(c23)Oc2ccc(-c3ccccc3)cc2B5c2ccc(-c3cccc(F)c3)cc2N4c2c(-c3ccccc3)cccc2-c2ccccc2)c(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1c(cc2c4c1Oc1ccc(-c5ccccc5)cc1B4c1ccc(-c4cccc(F)c4)cc1N2c1c(-c2ccccc2)cccc1-c1ccccc1)N3c1c(-c2ccccc2)cc(C(C)(C)C)cc1-c1ccccc1]

### Synthesis of Intermediate Compound 63-c

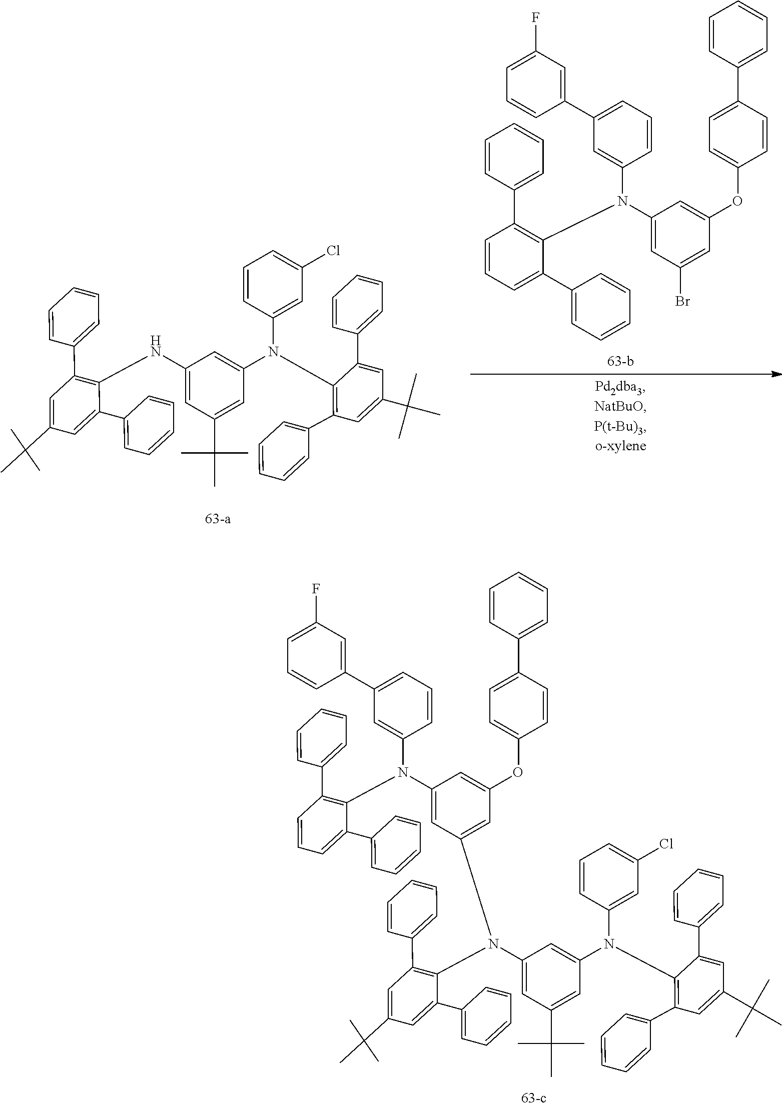 [SMILES: CC(C)(C)c1cc(Nc2c(-c3ccccc3)cc(C(C)(C)C)cc2-c2ccccc2)cc(N(c2cccc(Cl)c2)c2c(-c3ccccc3)cc(C(C)(C)C)cc2-c2ccccc2)c1 ; Fc1cccc(-c2cccc(N(c3cc(Br)cc(Oc4ccc(-c5ccccc5)cc4)c3)c3c(-c4ccccc4)cccc3-c3ccccc3)c2)c1 ; CC(C)(C)c1cc(N(c2cccc(Cl)c2)c2c(-c3ccccc3)cc(C(C)(C)C)cc2-c2ccccc2)cc(N(c2cc(Oc3ccc(-c4ccccc4)cc3)cc(N(c3cccc(-c4cccc(F)c4)c3)c3c(-c4ccccc4)cccc3-c3ccccc3)c2)c2c(-c3ccccc3)cc(C(C)(C)C)cc2-c2ccccc2)c1]

Under argon atmosphere, 5-(tert-butyl)-N1,N3-bis(5′-(tert-butyl)-[1,1′:3′,1″-terphenyl]-2′-yl)-N1-(3-chlorophenyl)benzene-1,3-diamine as the compound 63-a (20.0 g, 23.7 mmol), N-(3-([1,1′-biphenyl]-4-yloxy)-5-bromophenyl)-N-(3′-fluoro-[1,1′-biphenyl]-3-yl)-[1,1′:3′,1″-terphenyl]-2′-amine as the compound 63-b (26.3 g, 35.6 mmol), Pd₂dba₃ (1.0 g, 1.1 mmol), tris-tert-butyl phosphine (0.6 mL, 2.3 mmol), and sodium tert-butoxide (3.4 g, 35.6 mmol) were dissolved in 300 mL of o-xylene in a 1 L flask to prepare a reaction solution. The reaction solution was stirred at 140° C. for 5 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 63-c (white solid, 14.5 g, yield 41%).

ESI-LCMS: [M]+: C₁₀₈H₉₁ClFN₃O. 1501.38

### Synthesis of Intermediate Compound 63-d

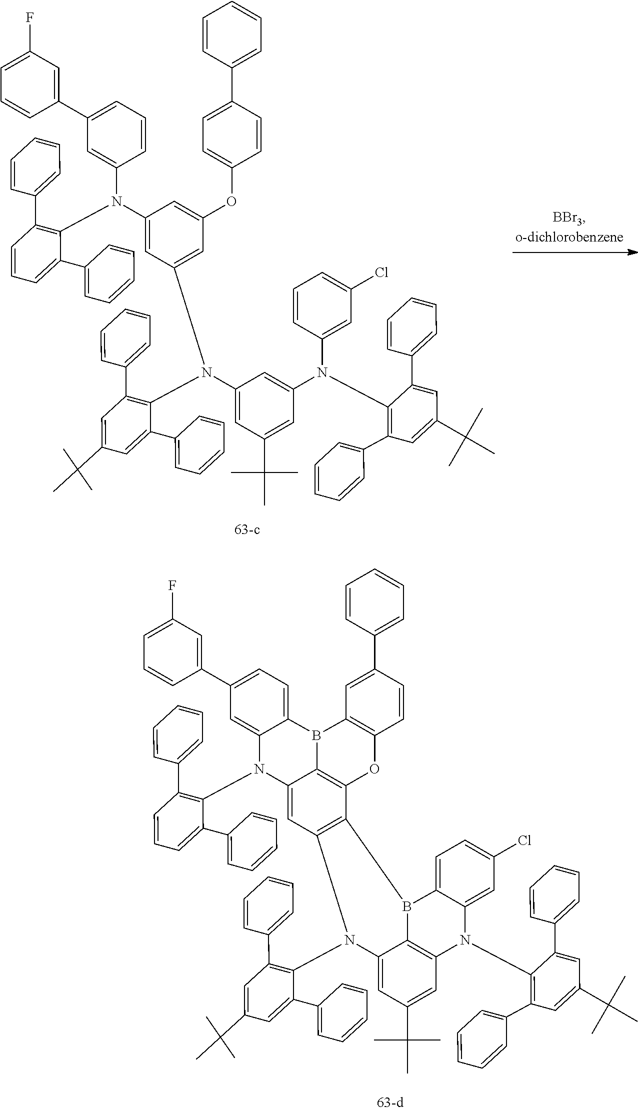 [SMILES: CC(C)(C)c1cc(N(c2cccc(Cl)c2)c2c(-c3ccccc3)cc(C(C)(C)C)cc2-c2ccccc2)cc(N(c2cc(Oc3ccc(-c4ccccc4)cc3)cc(N(c3cccc(-c4cccc(F)c4)c3)c3c(-c4ccccc4)cccc3-c3ccccc3)c2)c2c(-c3ccccc3)cc(C(C)(C)C)cc2-c2ccccc2)c1 ; CC(C)(C)c1cc(-c2ccccc2)c(N2c3cc(Cl)ccc3B3c4c2cc(C(C)(C)C)cc4N(c2c(-c4ccccc4)cc(C(C)(C)C)cc2-c2ccccc2)c2cc4c5c(c23)Oc2ccc(-c3ccccc3)cc2B5c2ccc(-c3cccc(F)c3)cc2N4c2c(-c3ccccc3)cccc2-c2ccccc2)c(-c2ccccc2)c1]

Under an argon atmosphere, the compound 63-c (10.0 g, 6.7 mmol) was dissolved in 150 mL of o-dichlorobenzene in a 1 L flask, and BBr₃ (3.0 equiv.) was added to prepare a reaction solution. The reaction solution was stirred at 140° C. for 12 hours.

After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain an intermediate compound 63-d (yellow solid, 1.9 g, yield 19%).

ESI-LCMS: [M]+: C₁₀₈H₈₅B₂ClFN₃O. 1516.96

### Synthesis of Compound 63

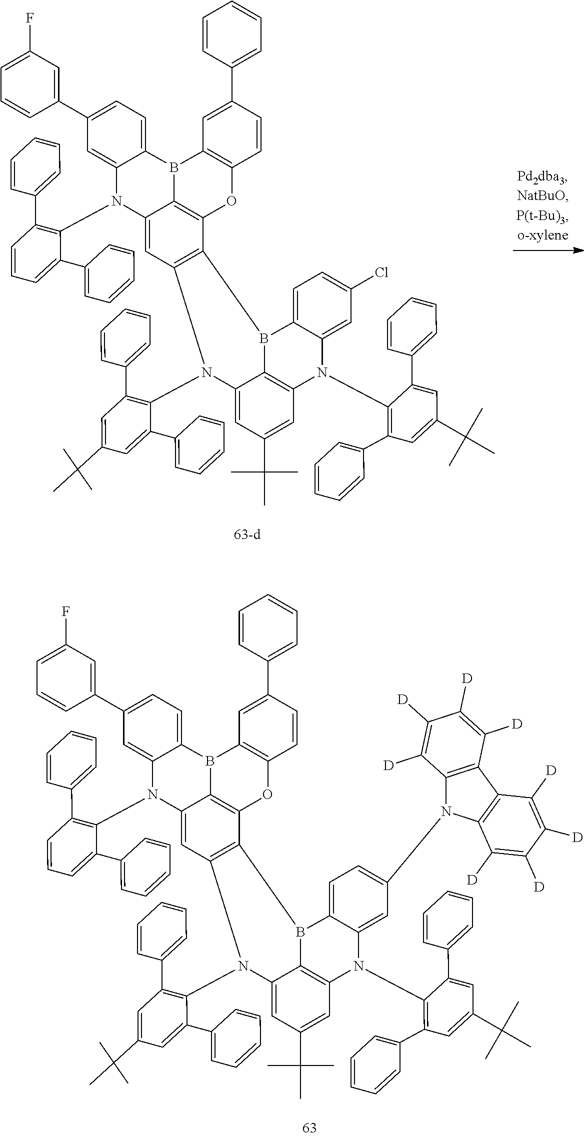 [SMILES: CC(C)(C)c1cc(-c2ccccc2)c(N2c3cc(Cl)ccc3B3c4c2cc(C(C)(C)C)cc4N(c2c(-c4ccccc4)cc(C(C)(C)C)cc2-c2ccccc2)c2cc4c5c(c23)Oc2ccc(-c3ccccc3)cc2B5c2ccc(-c3cccc(F)c3)cc2N4c2c(-c3ccccc3)cccc2-c2ccccc2)c(-c2ccccc2)c1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1c(cc2c4c1Oc1ccc(-c5ccccc5)cc1B4c1ccc(-c4cccc(F)c4)cc1N2c1c(-c2ccccc2)cccc1-c1ccccc1)N3c1c(-c2ccccc2)cc(C(C)(C)C)cc1-c1ccccc1]

Under an argon atmosphere, the compound 63-d (1.5 g, 1.0 mmol), 9H-carbazole-1,2,3,4,5,6,7,8-d₈ (0.4 g, 2.0 mmol), Pd₂dba₃ (0.06 g, 0.06 mmol), 2-dicyclohexylphosphino-2′,6′-dimethoxybiphenyl (0.06 g, 0.12 mmol), and potassium phosphate (0.6 g, 3.1 mmol) were dissolved in 20 mL of toluene in a 1 L flask to prepare a reaction solution. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 63 (yellow solid, 1.0 g, 62%).

ESI-LCMS: [M]+: C₁₂₀H₈₅D₈B₂FN₄O. 1655.76

¹H-NMR (CDCl₃): δ=8.20 (d, 2H), 7.99 (s, 4H), 7.90 (d, 1H), 7.85 (d, 1H), 7.75-7.63 (m, 6H), 7.52-7.39 (m, 26H), 7.28 (d, 1H), 7.27 (d, 1H), 7.23 (d, 1H), 7.22 (dd, 1H), 7.08-7.06 (m, 14H), 6.55 (s, 1H), 1.32 (s, 27H).

### Synthesis Example 10: Synthesis of Compound 84

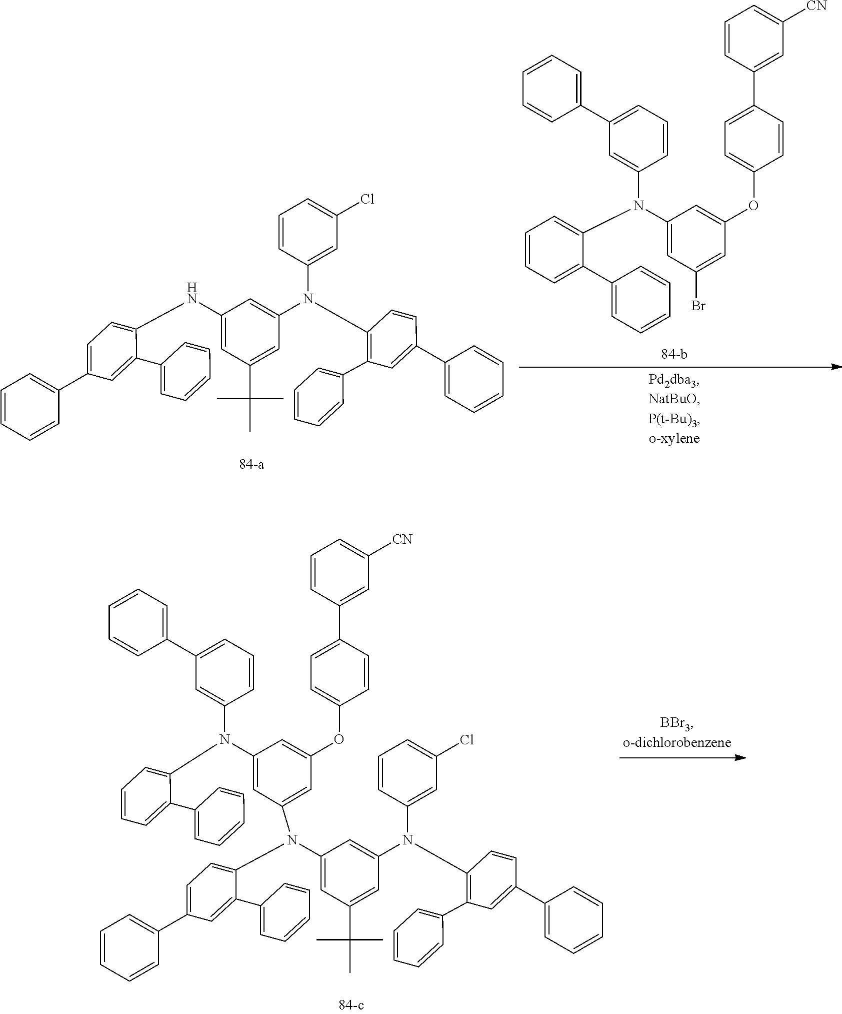 [SMILES: CC(C)(C)c1cc(Nc2ccc(-c3ccccc3)cc2-c2ccccc2)cc(N(c2cccc(Cl)c2)c2ccc(-c3ccccc3)cc2-c2ccccc2)c1 ; N#Cc1cccc(-c2ccc(Oc3cc(Br)cc(N(c4cccc(-c5ccccc5)c4)c4ccccc4-c4ccccc4)c3)cc2)c1 ; CC(C)(C)c1cc(N(c2cccc(Cl)c2)c2ccc(-c3ccccc3)cc2-c2ccccc2)cc(N(c2cc(Oc3ccc(-c4cccc(C#N)c4)cc3)cc(N(c3cccc(-c4ccccc4)c3)c3ccccc3-c3ccccc3)c2)c2ccc(-c3ccccc3)cc2-c2ccccc2)c1]

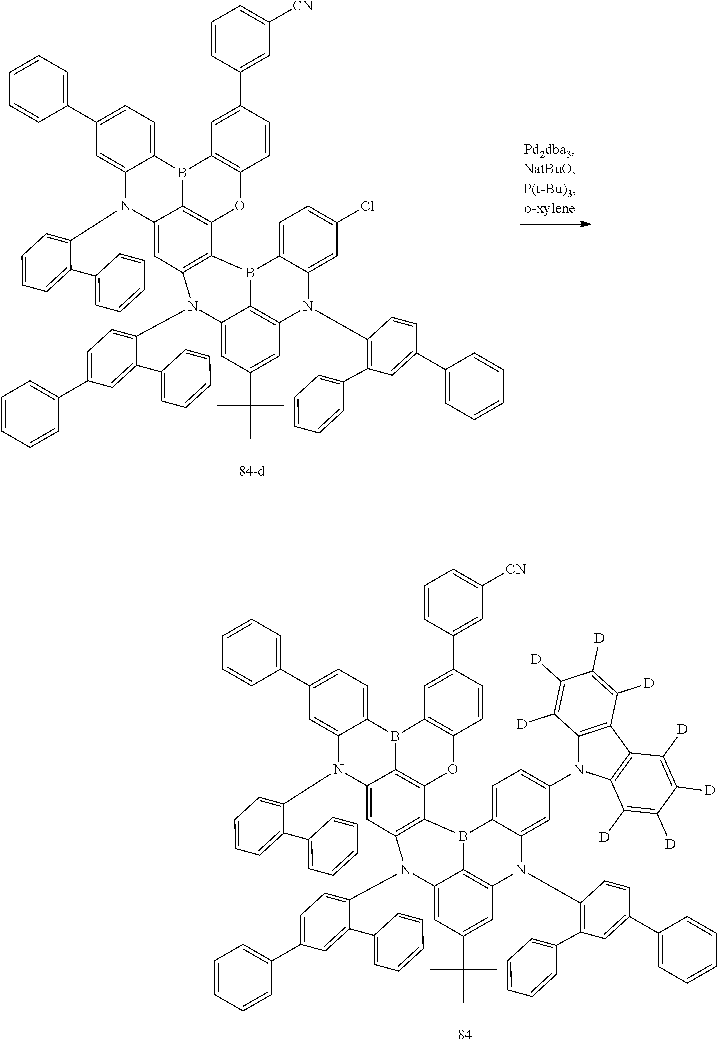 [SMILES: CC(C)(C)c1cc2c3c(c1)N(c1ccc(-c4ccccc4)cc1-c1ccccc1)c1cc4c5c(c1B3c1ccc(Cl)cc1N2c1ccc(-c2ccccc2)cc1-c1ccccc1)Oc1ccc(-c2cccc(C#N)c2)cc1B5c1ccc(-c2ccccc2)cc1N4c1ccccc1-c1ccccc1 ; [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(C(C)(C)C)cc3c1B2c1c(cc2c4c1Oc1ccc(-c5cccc(C#N)c5)cc1B4c1ccc(-c4ccccc4)cc1N2c1ccccc1-c1ccccc1)N3c1ccc(-c2ccccc2)cc1-c1ccccc1]

### Synthesis of Intermediate Compound 84-c

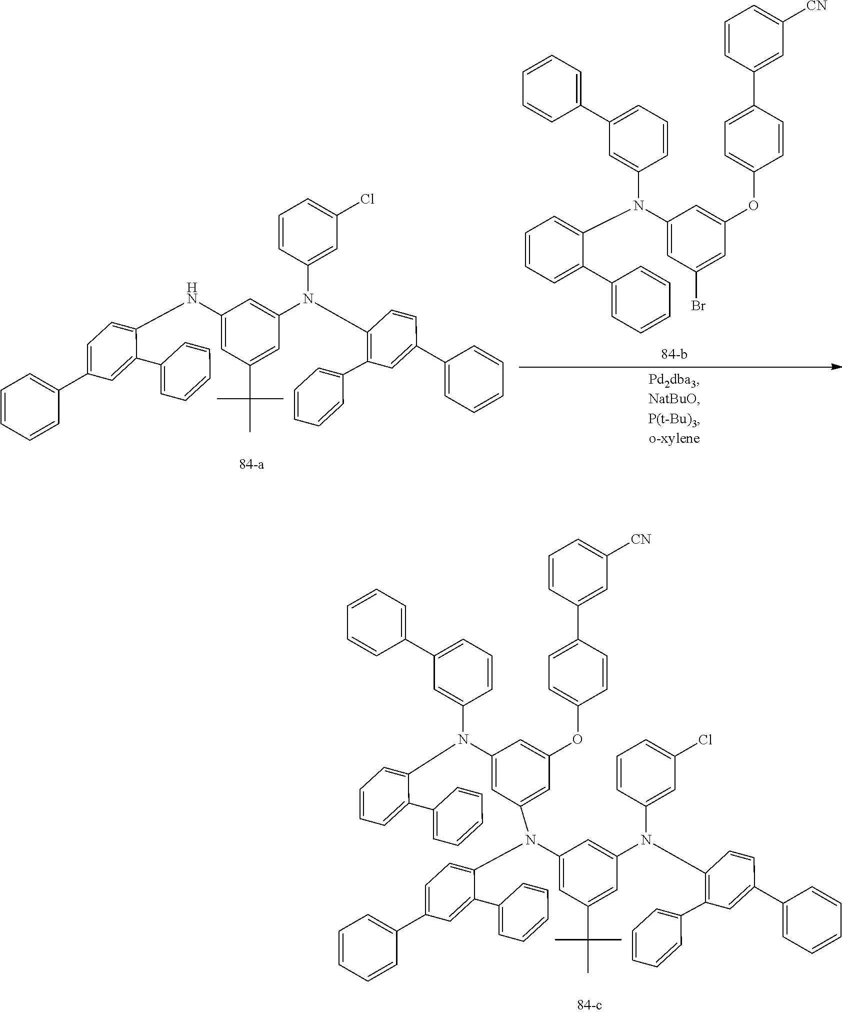 [SMILES: CC(C)(C)c1cc(Nc2ccc(-c3ccccc3)cc2-c2ccccc2)cc(N(c2cccc(Cl)c2)c2ccc(-c3ccccc3)cc2-c2ccccc2)c1 ; N#Cc1cccc(-c2ccc(Oc3cc(Br)cc(N(c4cccc(-c5ccccc5)c4)c4ccccc4-c4ccccc4)c3)cc2)c1 ; CC(C)(C)c1cc(N(c2cccc(Cl)c2)c2ccc(-c3ccccc3)cc2-c2ccccc2)cc(N(c2cc(Oc3ccc(-c4cccc(C#N)c4)cc3)cc(N(c3cccc(-c4ccccc4)c3)c3ccccc3-c3ccccc3)c2)c2ccc(-c3ccccc3)cc2-c2ccccc2)c1]

Under an argon atmosphere, N1,N3-di([1,1′:3′,1″-terphenyl]-4′-yl)-5-(tert-butyl)-N1-(3-chlorophenyl)benzene-1,3-diamine as the compound 84-a (20.0 g, 27.3 mmol), 4′-(3-([1,1′-biphenyl]-2-yl([1,1′-biphenyl]-3-yl)amino)-5-bromophenoxy)-[1,1′-biphenyl]-3-carbonitrile as the compound 84-b (27.4 g, 41.0 mmol), Pd₂dba₃ (1.0 g, 1.1 mmol), tris-tert-butyl phosphine (0.6 mL, 2.3 mmol), and sodium tert-butoxide (3.4 g, 35.6 mmol) was dissolved in 300 mL of o-xylene in a 1 L flask to prepare a reaction solution. The reaction solution was stirred at 140° C. for 5 hours.

An organic layer was extracted and separated from the stirred solution using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 84-c (white solid, 13.7 g, yield 38%).

ESI-LCMS: [M]+: C₉₅H₇₁ClN₄O. 1320.09

### Synthesis of Intermediate Compound 84-d

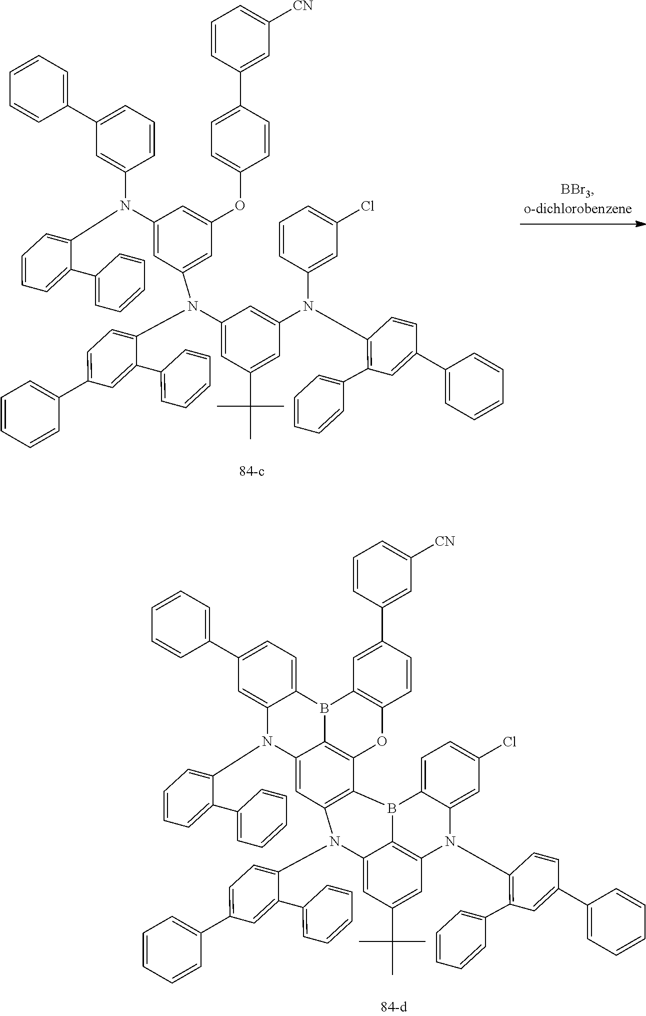 [SMILES: CC(C)(C)c1cc(N(c2cccc(Cl)c2)c2ccc(-c3ccccc3)cc2-c2ccccc2)cc(N(c2cc(Oc3ccc(-c4cccc(C#N)c4)cc3)cc(N(c3cccc(-c4ccccc4)c3)c3ccccc3-c3ccccc3)c2)c2ccc(-c3ccccc3)cc2-c2ccccc2)c1 ; CC(C)(C)c1cc2c3c(c1)N(c1ccc(-c4ccccc4)cc1-c1ccccc1)c1cc4c5c(c1B3c1ccc(Cl)cc1N2c1ccc(-c2ccccc2)cc1-c1ccccc1)Oc1ccc(-c2cccc(C#N)c2)cc1B5c1ccc(-c2ccccc2)cc1N4c1ccccc1-c1ccccc1]

Under an argon atmosphere, the compound 84-c (10.0 g, 7.6 mmol) was dissolved in 150 mL of o-dichlorobenzene in a 1 L flask, and BBr₃ (3.0 equiv.) was added to prepare a reaction solution. The reaction solution was stirred at 140° C. for 12 hours.

After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain an intermediate compound 84-d (yellow solid, 1.1 g, yield 11%).

ESI-LCMS: [M]+: C₉₅H₆₅B₂ClN₄O. 1335.66

### Synthesis of Compound 84

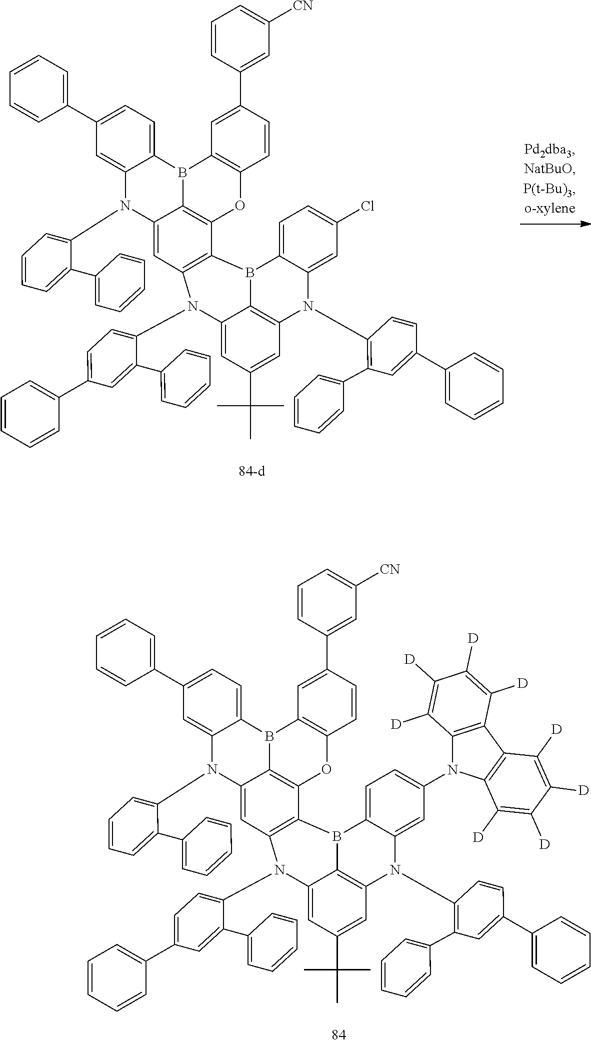 [SMILES: CC(C)(C)c1cc2c3c(c1)N(c1ccc(-c4ccccc4)cc1-c1ccccc1)c1cc4c5c(c1B3c1ccc(Cl)cc1N2c1ccc(-c2ccccc2)cc1-c1ccccc1)Oc1ccc(-c2cccc(C#N)c2)cc1B5c1ccc(-c2ccccc2)cc1N4c1ccccc1-c1ccccc1 ; [2H]c1c([2H])c([2H])c2c(c1[2H])c1c([2H])c([2H])c([2H])c([2H])c1n2-c1ccc2c(c1)N(c1ccc(-c3ccccc3)cc1-c1ccccc1)c1cc(C(C)(C)C)cc3c1B2c1c(cc2c4c1Oc1ccc(-c5cccc(C#N)c5)cc1B4c1ccc(-c4ccccc4)cc1N2c1ccccc1-c1ccccc1)N3c1ccc(-c2ccccc2)cc1-c1ccccc1]

Under an argon atmosphere, the compound 84-d (1.0 g, 0.6 mmol), 9H-carbazole-1,2,3,4,5,6,7,8-d₈ (0.2 g, 1.4 mmol), Pd₂dba₃ (0.06 g, 0.06 mmol), 2-dicyclohexylphosphino-2′,6′-dimethoxybiphenyl (0.06 g, 0.12 mmol), and potassium phosphate (0.6 g, 3.1 mmol) were dissolved in 20 mL of toluene in a 1 L flask to prepare a reaction solution. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 84 (yellow solid, 0.3 g, 39%).

ESI-LCMS: [M]+: C₁₀₇H₆₅D₈B₂N₅O. 1474.46

¹H-NMR (CDCl₃): δ=8.10 (dd, 1H), 8.02 (dd, 1H), 7.90-7.65 (m, 18H), 7.49-7.41 (m, 21H), 7.27-7.08 (m, 12H), 6.55 (s, 1H), 1.32 (s, 9H).

### Synthesis Example 11: Synthesis of Compound 96

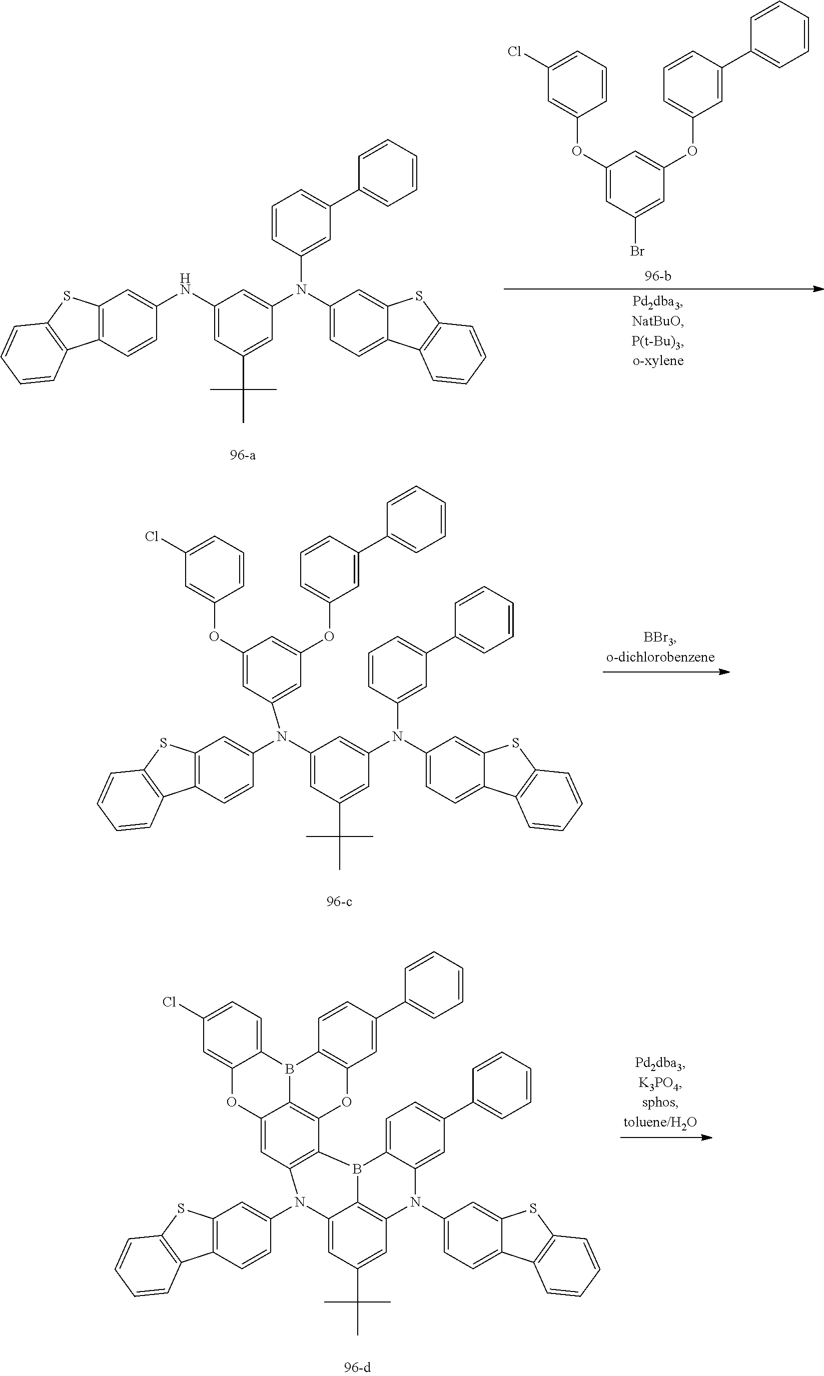 [SMILES: CC(C)(C)c1cc(Nc2ccc3c(c2)sc2ccccc23)cc(N(c2cccc(-c3ccccc3)c2)c2ccc3c(c2)sc2ccccc23)c1 ; Clc1cccc(Oc2cc(Br)cc(Oc3cccc(-c4ccccc4)c3)c2)c1 ; CC(C)(C)c1cc(N(c2cc(Oc3cccc(Cl)c3)cc(Oc3cccc(-c4ccccc4)c3)c2)c2ccc3c(c2)sc2ccccc23)cc(N(c2cccc(-c3ccccc3)c2)c2ccc3c(c2)sc2ccccc23)c1 ; CC(C)(C)c1cc2c3c(c1)N(c1ccc4c(c1)sc1ccccc14)c1cc4c5c(c1B3c1ccc(-c3ccccc3)cc1N2c1ccc2c(c1)sc1ccccc12)Oc1cc(-c2ccccc2)ccc1B5c1ccc(Cl)cc1O4]

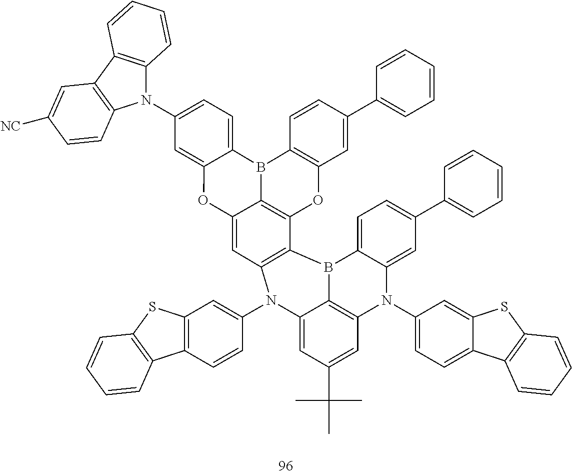 [SMILES: CC(C)(C)c1cc2c3c(c1)N(c1ccc4c(c1)sc1ccccc14)c1cc4c5c(c1B3c1ccc(-c3ccccc3)cc1N2c1ccc2c(c1)sc1ccccc12)Oc1cc(-c2ccccc2)ccc1B5c1ccc(-n2c3ccccc3c3cc(C#N)ccc32)cc1O4]

### Synthesis of Intermediate Compound 96-c

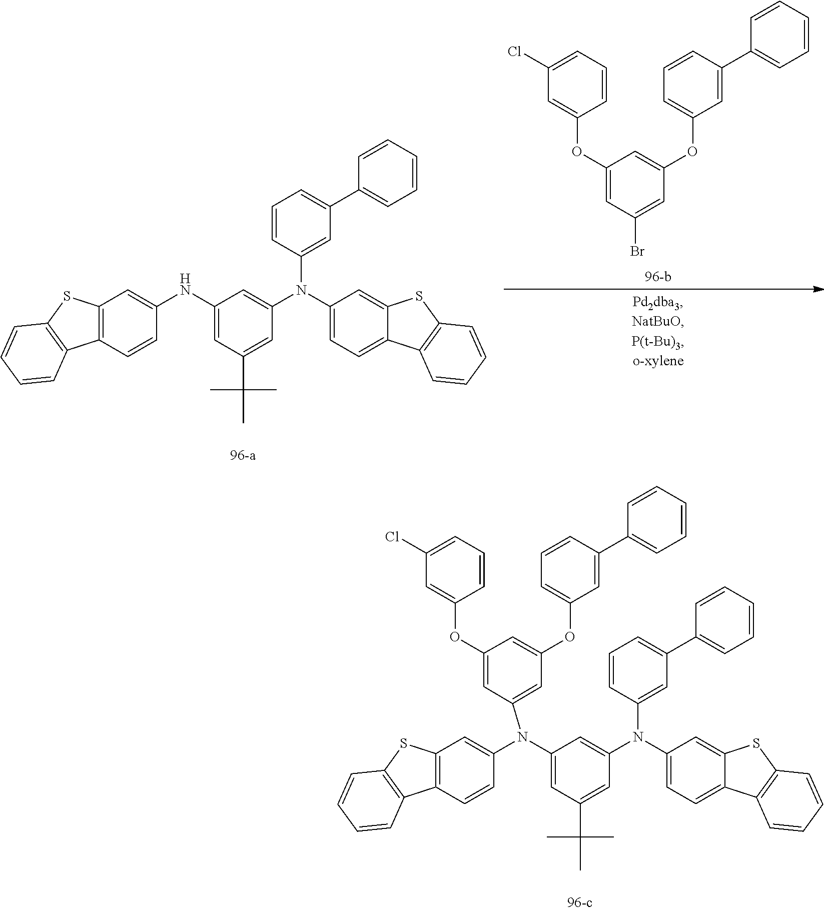 [SMILES: CC(C)(C)c1cc(Nc2ccc3c(c2)sc2ccccc23)cc(N(c2cccc(-c3ccccc3)c2)c2ccc3c(c2)sc2ccccc23)c1 ; Clc1cccc(Oc2cc(Br)cc(Oc3cccc(-c4ccccc4)c3)c2)c1 ; CC(C)(C)c1cc(N(c2cc(Oc3cccc(Cl)c3)cc(Oc3cccc(-c4ccccc4)c3)c2)c2ccc3c(c2)sc2ccccc23)cc(N(c2cccc(-c3ccccc3)c2)c2ccc3c(c2)sc2ccccc23)c1]

Under an argon atmosphere, a reaction solution was prepared by dissolving N1-([1,1′-biphenyl]-3-yl)-5-(tert-butyl)-N1,N3-bis(dibenzo[b,d]thiophen-3-yl)benzene-1,3-diamine as the compound 96-a (15.0 g, 22.1 mmol), 3-(3-bromo-5-(3-chlorophenoxy)phenoxy)-1,1′-biphenyl (14.9 g, 33.1 mmol) as the compound 96-b, Pd₂dba₃ (1.0 g, 1.1 mmol), tris-tert-butyl phosphine (0.6 mL, 2.3 mmol), and sodium tert-butoxide (3.2 g, 33.1 mmol) in 250 mL of o-xylene in a 1 L flask. The reaction solution was stirred at 140° C. for 5 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain an intermediate compound 96-c (white solid, 13.2 g, yield 57%).

ESI-LCMS: [M]+: C₇₀H₅₁ClN₂O₂S₂. 1051.76

### Synthesis of Intermediate Compound 96-d

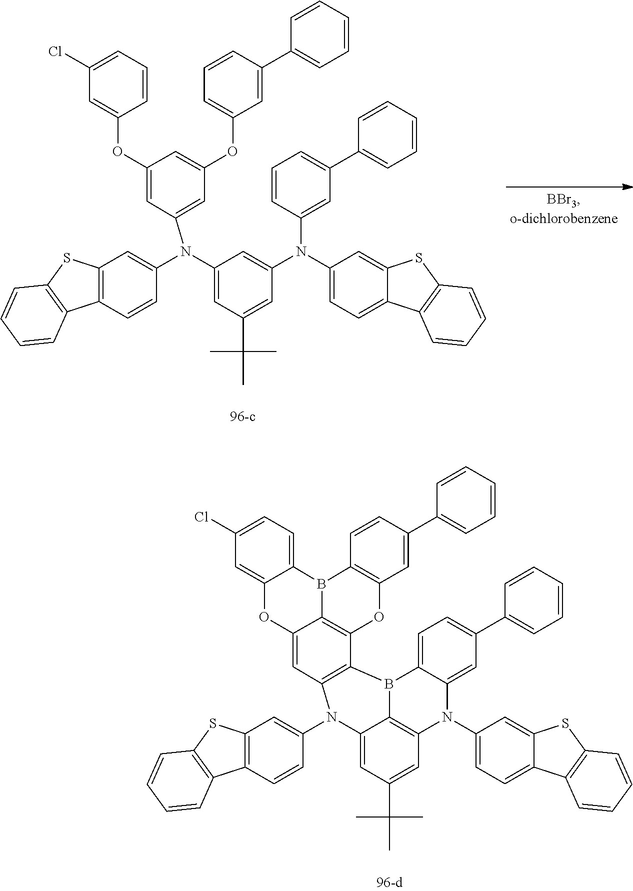 [SMILES: CC(C)(C)c1cc(N(c2cc(Oc3cccc(Cl)c3)cc(Oc3cccc(-c4ccccc4)c3)c2)c2ccc3c(c2)sc2ccccc23)cc(N(c2cccc(-c3ccccc3)c2)c2ccc3c(c2)sc2ccccc23)c1 ; CC(C)(C)c1cc2c3c(c1)N(c1ccc4c(c1)sc1ccccc14)c1cc4c5c(c1B3c1ccc(-c3ccccc3)cc1N2c1ccc2c(c1)sc1ccccc12)Oc1cc(-c2ccccc2)ccc1B5c1ccc(Cl)cc1O4]

Under an argon atmosphere, the compound 96-c (10.0 g, 9.5 mmol) was dissolved in 150 mL of o-dichlorobenzene in a 1 L flask, and BBr₃ (3.0 equiv.) was added to prepare a reaction solution. The reaction solution was stirred at 140° C. for 12 hours.

After the stirred solution was cooled to room temperature, triethylamine was added to terminate the reaction, and the solvent was removed under reduced pressure.

The obtained solid was purified and separated by silica gel column chromatography using CH₂Cl₂ and hexane as developing solvents to obtain intermediate compound 96-d (yellow solid, 1.8 g, yield 18%).

ESI-LCMS: [M]+: C₇₀H₄₅B₂ClN₂O₂S₂. 1067.33

### Synthesis of Compound 96

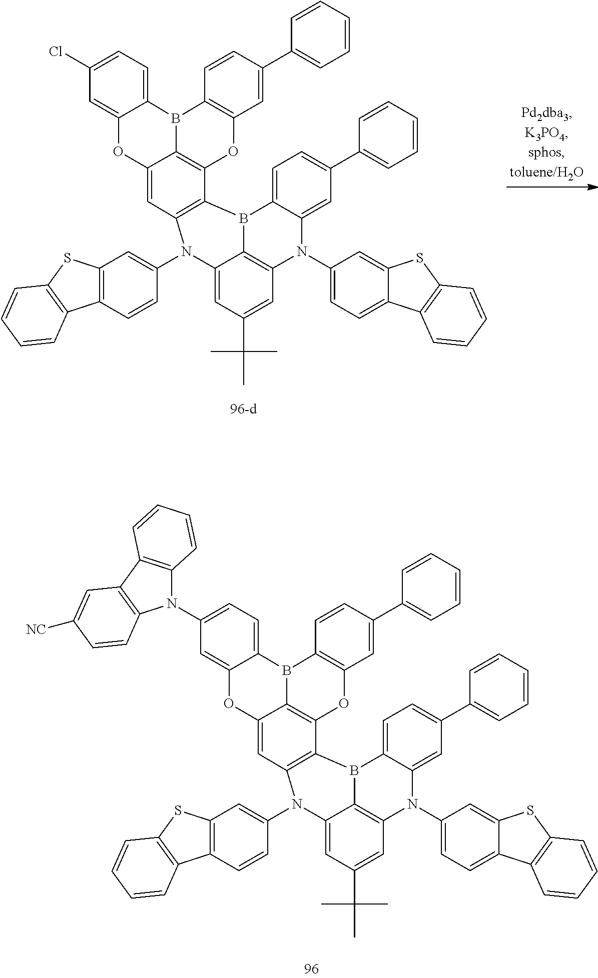 [SMILES: CC(C)(C)c1cc2c3c(c1)N(c1ccc4c(c1)sc1ccccc14)c1cc4c5c(c1B3c1ccc(-c3ccccc3)cc1N2c1ccc2c(c1)sc1ccccc12)Oc1cc(-c2ccccc2)ccc1B5c1ccc(Cl)cc1O4 ; CC(C)(C)c1cc2c3c(c1)N(c1ccc4c(c1)sc1ccccc14)c1cc4c5c(c1B3c1ccc(-c3ccccc3)cc1N2c1ccc2c(c1)sc1ccccc12)Oc1cc(-c2ccccc2)ccc1B5c1ccc(-n2c3ccccc3c3cc(C#N)ccc32)cc1O4]

Under an argon atmosphere, the compound 96-d (1.0 g, 0.9 mmol), 9H-carbazole-3-carbonitrile (0.3 g, 1.4 mmol), Pd₂dba₃ (0.06 g, 0.06 mmol), 2-dicyclohexylphosphino-2′,6′-dimethoxybiphenyl (0.06 g, 0.12 mmol), and potassium phosphate (0.6 g, 3.1 mmol) were dissolved in 20 mL of toluene in a flask to prepare a reaction solution. The reaction solution was stirred at 100° C. for 12 hours.

After the stirred solution was cooled to room temperature, an organic layer was extracted and separated using H₂O (1 L) and ethyl acetate (300 mL). The separated organic layer was dried over anhydrous MgSO₄ and filtered. The solvent was removed from the filtered solution under reduced pressure.

The obtained solid was purified and separated by silica gel column chromatography using CH₂Cl₂ and hexane as developing solvents to obtain the compound 96 (yellow solid, 0.5 g, 51%).

ESI-LCMS: [M]+: C₈₃H₅₂B₂N₄O₂S₂. 1223.10

¹H-NMR (CDCl₃): δ=8.55 (dd, 1H), 8.45 (dd, 2H), 8.01-7.75 (m, 14H), 7.64 (d, 2H), 7.49-7.33 (m, 18H), 7.27 (d, 1H), 7.16 (ddd, 1H), 7.11 (d, 1H), 7.06 (s, 1H), 6.58 (s, 1H), 1.32 (s, 9H).

### Fabrication of Light-Emitting Device

As a first electrode, a glass substrate (Corning product) on which a 15 Ω/cm² (1200 Å) ITO electrode was formed was cut into a size of 50 mm×50 mm×0.7 mm, and the cut substrate was ultrasonically cleaned for 5 minutes with isopropyl alcohol and then with pure water. The ultrasonically cleaned substrate was irradiated with an ultraviolet ray for 30 minutes and exposed to ozone, and then mounted on a vacuum deposition device.

Thereafter, NPB (N,N′-di(naphthalen-1-yl)-N,N′-diphenyl-benzidine) was deposited on the first electrode to form a hole injection layer having a thickness of 300 Å. HT-13 was deposited on the hole injection layer to form a hole transport layer having a thickness of 200 Å. CzSi (9-(4-tert-Butylphenyl)-3,6-bis(triphenylsilyl)-9H-carbazole) was deposited on the hole transport layer to form an electron blocking layer having a thickness of 100 Å.

A host mixture of PH-13 and ET-16 in a weight ratio of 1:1; PD1-13; and one compound of Examples or Comparative Examples were co-deposited in a weight ratio of 85:14:1 on the electron blocking layer to form an emission layer having a thickness of 200 Å.

TSPO1 (diphenyl(4-(triphenylsilyl)phenyl)phosphine oxide) was deposited on the emission layer to form an electron transfer layer having a thickness of 200 Å. Thereafter, TPBi (1,3,5-Tri(1-phenyl-1H-benzo[d]imidazol-2-yl)benzene) was deposited on the electron transfer layer to form a buffer layer having a thickness of 300 Å, and then LiF was deposited on the buffer layer to form an electron injection layer having a thickness of 10 Å. Subsequently, Al was deposited on the electron injection layer to form a second electrode having a thickness of 3000 Å, and then HT-7 was deposited on the second electrode to form a capping layer having a thickness of 700 Å, thereby fabricating a light-emitting device. Each layer was formed by a vacuum deposition method.

Commercially available products purified by sublimation were used for the fabrication of the device as shown below.

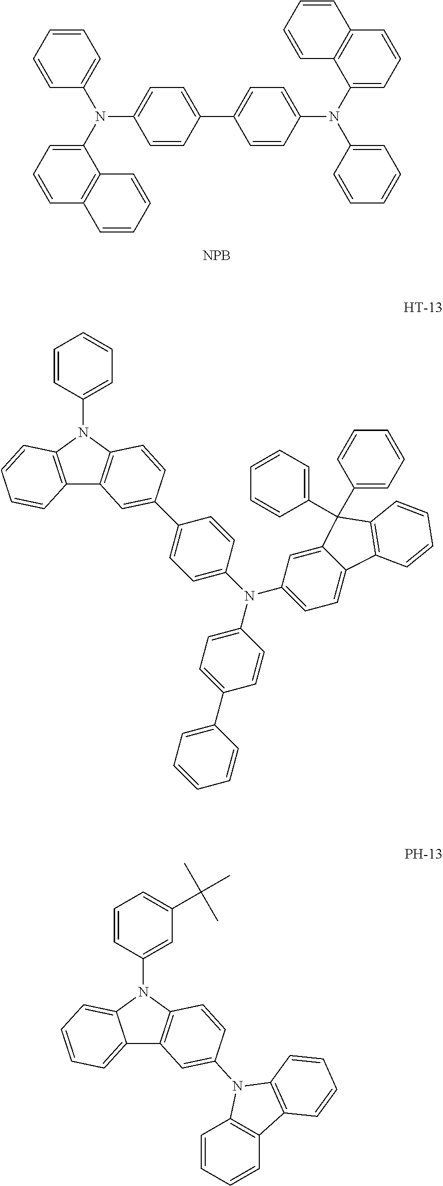 [SMILES: c1ccc(N(c2ccc(-c3ccc(N(c4ccccc4)c4cccc5ccccc45)cc3)cc2)c2cccc3ccccc23)cc1 ; "NPB" ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC(C)(C)c1cccc(-n2c3ccccc3c3cc(-n4c5ccccc5c5ccccc54)ccc32)c1]

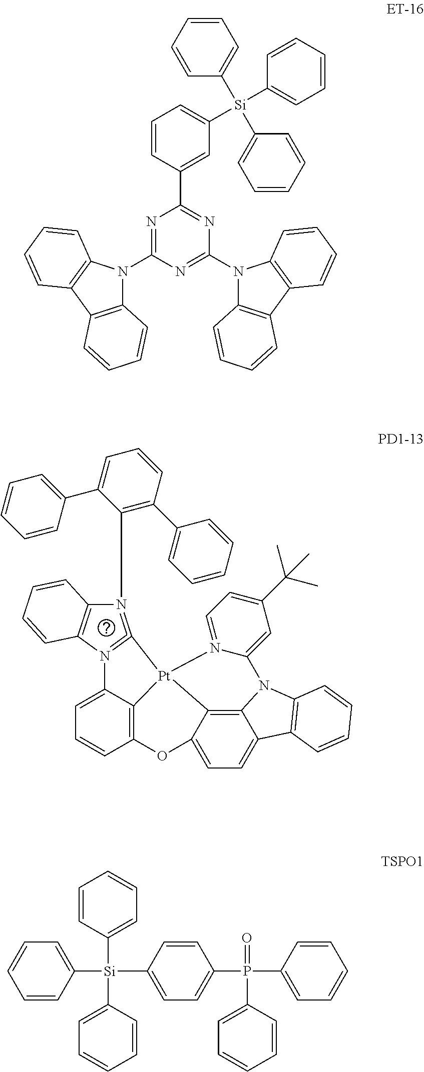

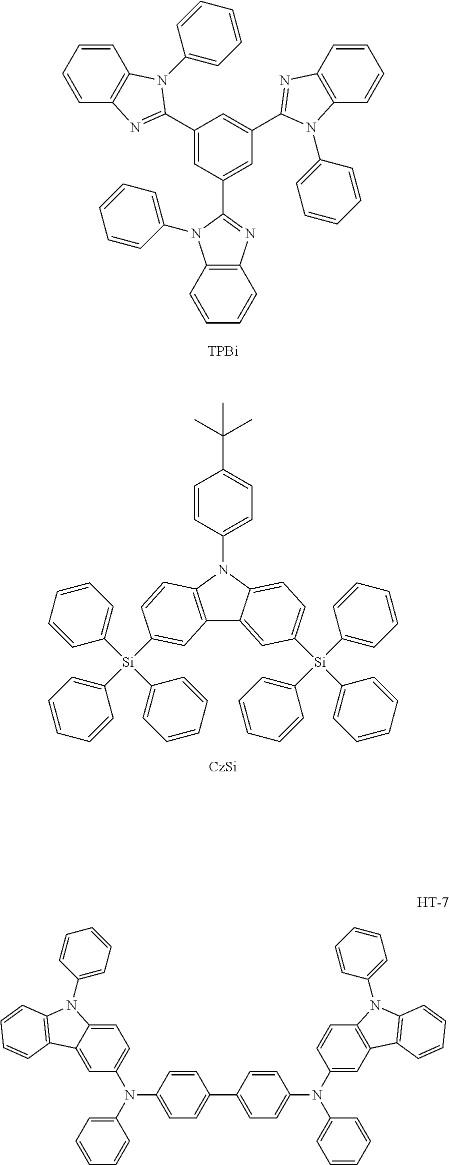

### Evaluation Example

### Evaluation Example 1. Evaluation on Properties of Polycyclic Compounds

Properties of compounds of Examples and Comparative Examples as shown below were evaluated.

### Compounds of Examples

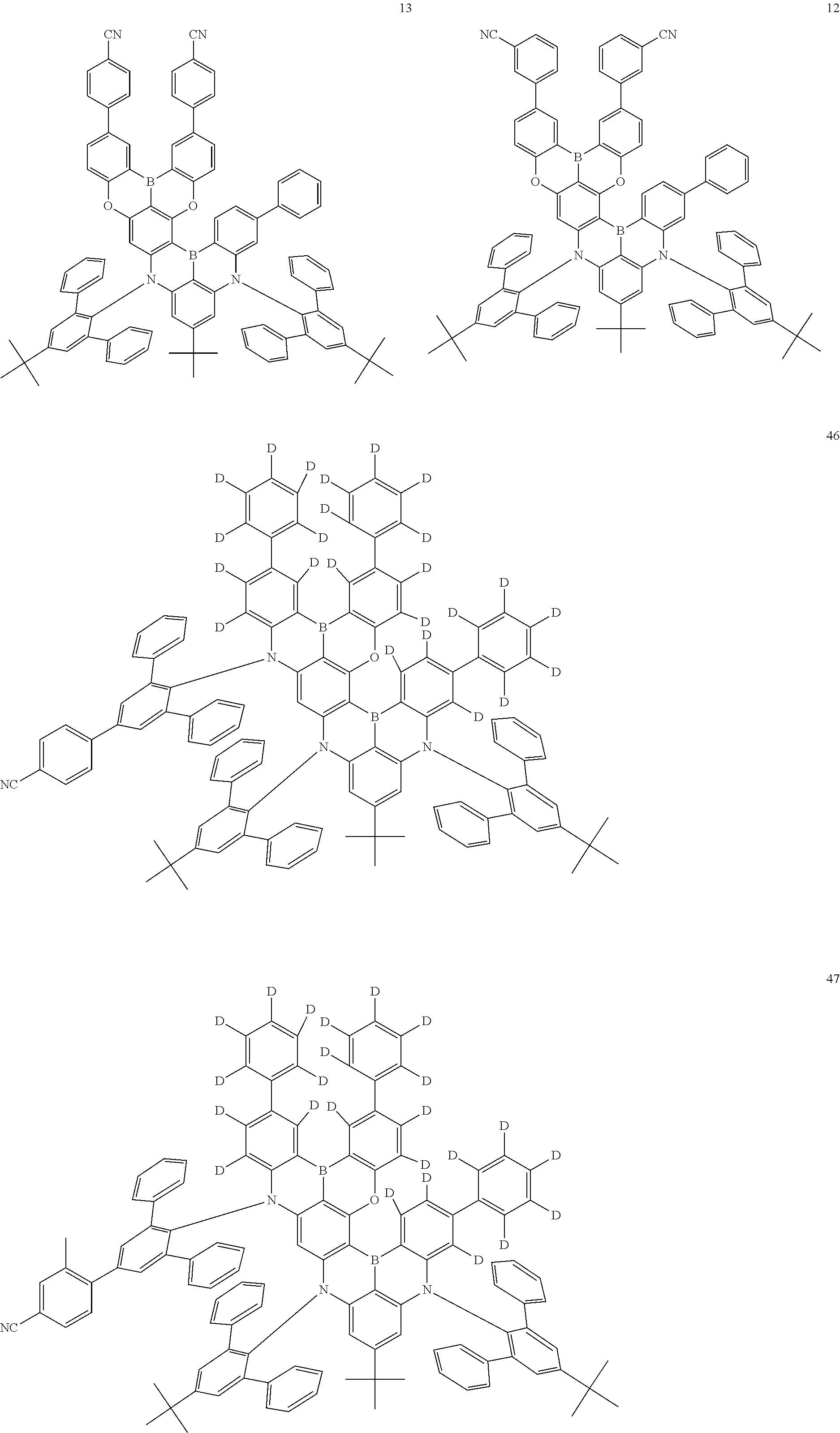

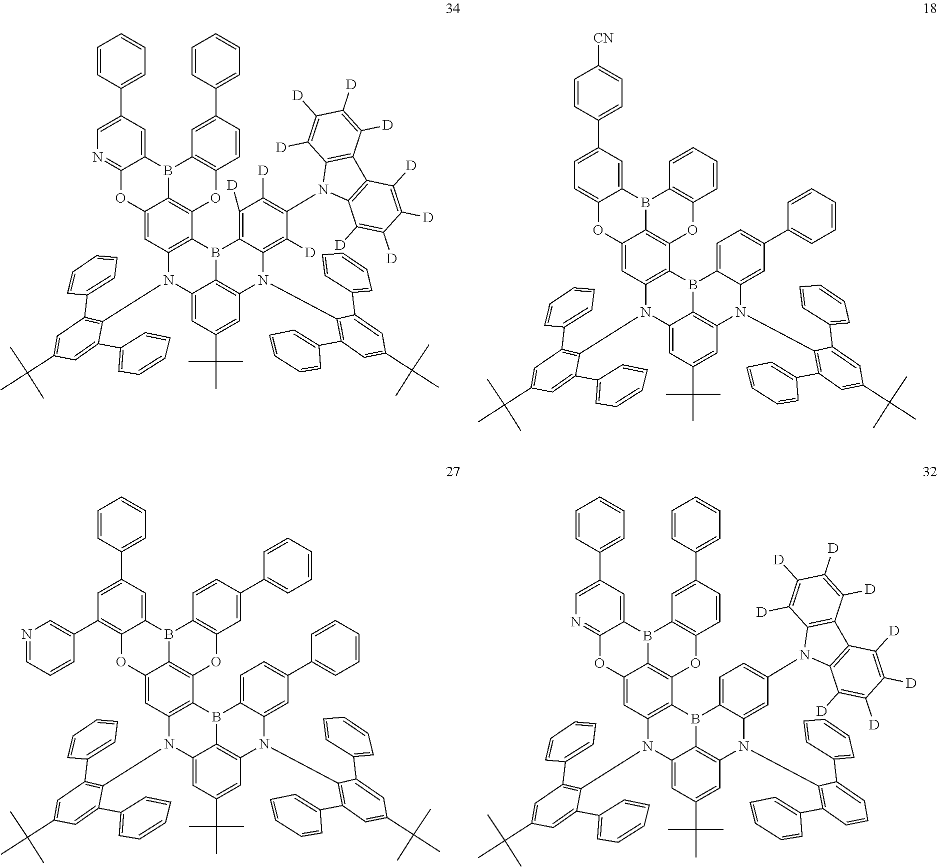

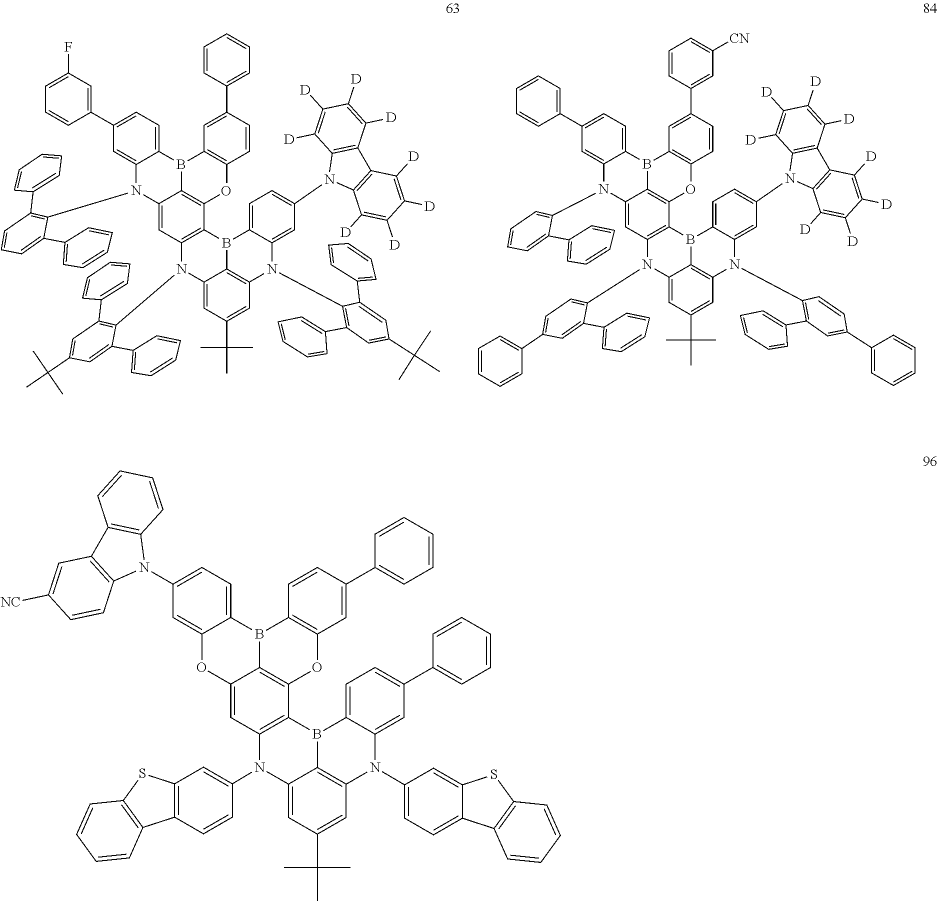

### Compounds of Comparative Examples

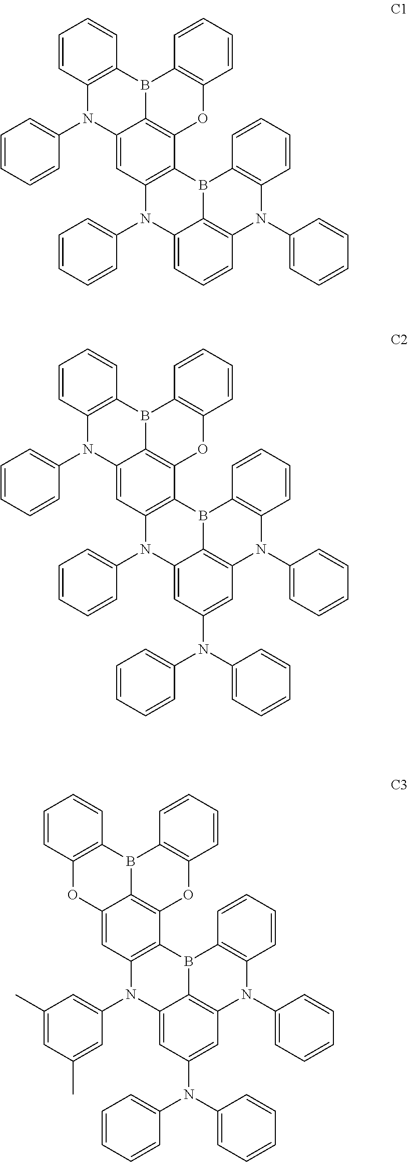 [SMILES: c1ccc(N2c3ccccc3B3c4c2cccc4N(c2ccccc2)c2cc4c5c(c23)Oc2ccccc2B5c2ccccc2N4c2ccccc2)cc1 ; c1ccc(N(c2ccccc2)c2cc3c4c(c2)N(c2ccccc2)c2cc5c6c(c2B4c2ccccc2N3c2ccccc2)Oc2ccccc2B6c2ccccc2N5c2ccccc2)cc1 ; Cc1cc(C)cc(N2c3cc(N(c4ccccc4)c4ccccc4)cc4c3B(c3ccccc3N4c3ccccc3)c3c2cc2c4c3Oc3ccccc3B4c3ccccc3O2)c1]

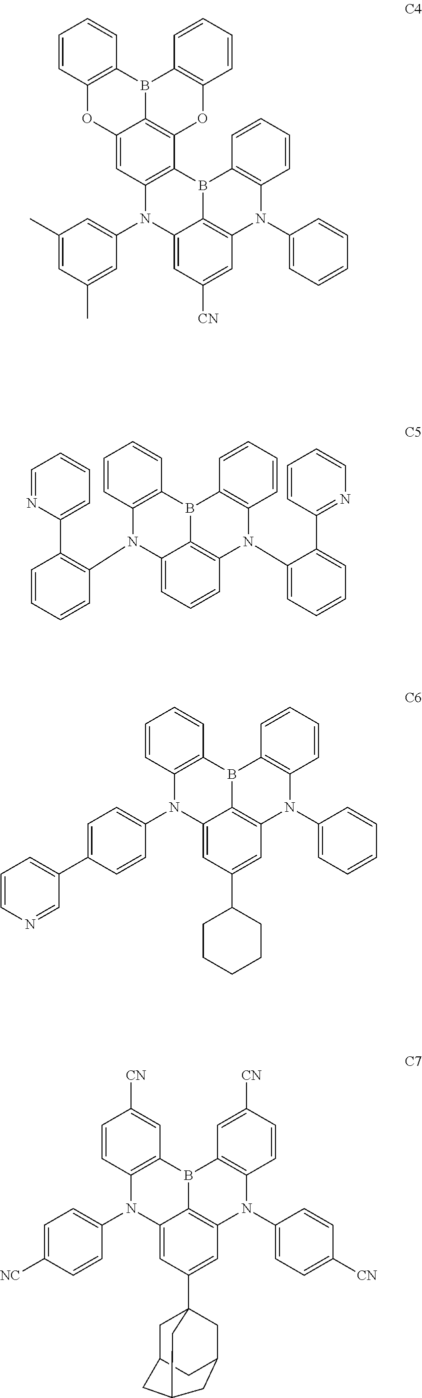 [SMILES: Cc1cc(C)cc(N2c3cc(C#N)cc4c3B(c3ccccc3N4c3ccccc3)c3c2cc2c4c3Oc3ccccc3B4c3ccccc3O2)c1 ; c1ccc(-c2ccccc2N2c3ccccc3B3c4ccccc4N(c4ccccc4-c4ccccn4)c4cccc2c43)nc1 ; c1ccc(N2c3ccccc3B3c4ccccc4N(c4ccc(-c5cccnc5)cc4)c4cc(C5CCCCC5)cc2c43)cc1 ; N#Cc1ccc(N2c3ccc(C#N)cc3B3c4cc(C#N)ccc4N(c4ccc(C#N)cc4)c4cc(C56CC7CC(CC(C7)C5)C6)cc2c43)cc1]

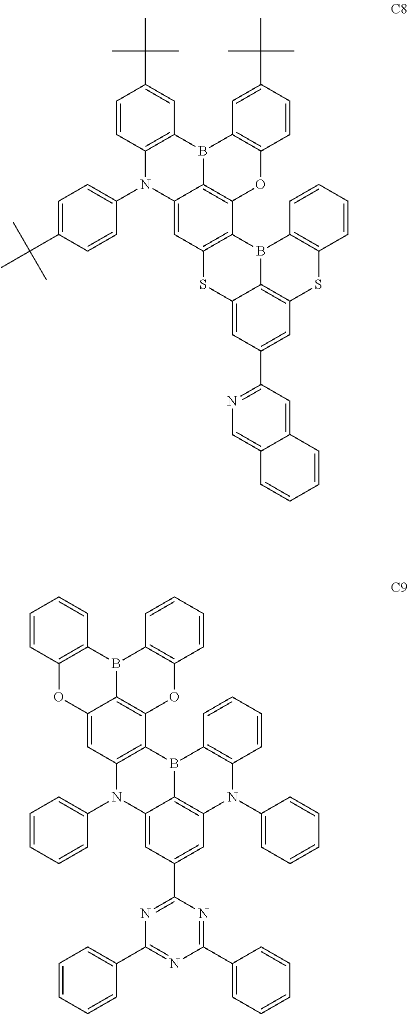 [SMILES: CC(C)(C)c1ccc(N2c3ccc(C(C)(C)C)cc3B3c4cc(C(C)(C)C)ccc4Oc4c5c(cc2c43)Sc2cc(-c3cc4ccccc4cn3)cc3c2B5c2ccccc2S3)cc1 ; c1ccc(-c2nc(-c3ccccc3)nc(-c3cc4c5c(c3)N(c3ccccc3)c3cc6c7c(c3B5c3ccccc3N4c3ccccc3)Oc3ccccc3B7c3ccccc3O6)n2)cc1]

A HOMO energy level (eV) was measured using Smart Manager software of SP2 electrochemical workstation manufactured by ZIVE LAB.

### An Absolute Value (ΔEst) of a Difference Between an Energy Level of the Lowest Singlet Excited State (Si Level) and an Energy Level of the Lowest Triplet Excited State (T1 Level), and a Maximum Emission Wavelength

The lowest triplet excited energy level (T1 level), the lowest singlet excited energy level (S1 level), and the maximum emission wavelength (nm) were measured using HORIBA fluoromax+ spectrometer equipped with a xenon light source and a monochromator, and FluorEssence software.

The absolute value of the difference between the energy level of lowest singlet excited state (Si level) and the energy level of lowest triplet excited state (Ti level) was calculated.

The evaluation results are shown in Table 1.

TABLE 1

| | | | maximum emission | |
|---|---|---|---|---|
| | dopant | HOMO(eV) | wavelength (nm) | ΔEₛₜ |
| Example 1 | compound 18 | −5.5 | 457 | 0.09 |
| Example 2 | compound 27 | −5.45 | 456 | 0.09 |
| Example 3 | compound 32 | −5.48 | 458 | 0.08 |
| Example 4 | compound 47 | −5.5 | 457 | 0.09 |
| Example 5 | compound 63 | −5.4 | 458 | 0.11 |
| Example 6 | compound 84 | −5.42 | 458 | 0.1 |
| Example 7 | compound 96 | −5.39 | 458 | 0.11 |
| Example 8 | compound 13 | −5.55 | 460 | 0.06 |
| Example 9 | compound 12 | −5.54 | 461 | 0.07 |
| Example 10 | compound 46 | −5.45 | 458 | 0.09 |
| Example 11 | compound 34 | −5.43 | 457 | 0.08 |
| Comparative | compound C1 | −5.23 | 448 | 0.13 |
| Example 1 | | | | |
| Comparative | compound C2 | −5.2 | 450 | 0.09 |
| Example 2 | | | | |
| Comparative | compound C3 | −5.18 | 451 | 0.08 |
| Example 3 | | | | |
| Comparative | compound C4 | −5.29 | 489 | 0.21 |
| Example 4 | | | | |
| Comparative | compound C5 | −5.13 | 450 | 0.2 |
| Example 5 | | | | |
| Comparative | compound C6 | −5.1 | 453 | 0.16 |
| Example 6 | | | | |
| Comparative | compound C7 | −5.43 | 459 | 0.18 |
| Example 7 | | | | |
| Comparative | compound C8 | −5.28 | 490 | 0.18 |
| Example 8 | | | | |
| Comparative | compound C9 | −5.21 | 500 | 0.15 |
| Example 9 | | | | |

Referring to Table 1, the polycyclic compounds according to one or more embodiments of the present disclosure were each evaluated to have a deep HOMO energy level, a small ΔEst, and the maximum emission wavelength in a range of 445 nm to 465 nm. The polycyclic compounds according to one or more embodiments of the present disclosure were evaluated to have a deeper HOMO energy level while inducing a short-wavelength effect.

The polycyclic compounds according to Comparative Examples 1, 2 and 3 were each evaluated to have a shallow HOMO energy level.

The polycyclic compounds according to Comparative Examples 5 and 6 were each evaluated to have a shallow HOMO energy level and a large ΔEst.

The polycyclic compound according to Comparative Example 7 was evaluated to have a large ΔEst.

The polycyclic compounds according to Comparative Examples 4, 8 and 9 were each evaluated to have a shallow HOMO energy level and a large ΔEst, and the maximum emission wavelength greater than 480 nm (a green emission region).

### Evaluation Example 2. Performance Evaluation of Light-Emitting Device

Properties of each of the light-emitting devices fabricated as described above were measured at a current density of 10 mA/cm² using V7000 OLED IVL Test System, (Polaronix). For example, the light-emitting device was continuously driven at a current density of 10 mA/cm², and a time until a luminance dropped from 95% of an initial value was measured. A relative value with respect to the time measured in the light-emitting device using the compound of Comparative Example 1 was expressed as a life-span (T95) of each light-emitting device.

TABLE 2

| | | | | driving | front | emission | life- |
|---|---|---|---|---|---|---|---|
| | host | | | voltage | efficiency | wavelength | span |
| | (HT/ET) | sensitizer | dopant | (V) | (cd/A/y) | (nm) | (T95) |
| Example 1 | PH-13/ET-16 | PD1-13 | Compound 18 | 4.1 | 550 | 458 | 5.8 |
| Example 2 | PH-13/ET-16 | PD1-13 | Compound 27 | 4.1 | 565 | 457 | 5.5 |
| Example 3 | PH-13/ET-16 | PD1-13 | Compound 32 | 4.1 | 545 | 459 | 5.4 |
| Example 4 | PH-13/ET-16 | PD1-13 | Compound 47 | 4.0 | 575 | 459 | 5.2 |
| Example 5 | PH-13/ET-16 | PD1-13 | Compound 63 | 4.0 | 563 | 459 | 5.1 |
| Example 6 | PH-13/ET-16 | PD1-13 | Compound 84 | 4.1 | 520 | 459 | 3.4 |
| Example 7 | PH-13/ET-16 | PD1-13 | Compound 96 | 4.1 | 530 | 459 | 3.2 |
| Example 8 | PH-13/ET-16 | PD1-13 | Compound 13 | 3.9 | 580 | 461 | 5.4 |
| Example 9 | PH-13/ET-16 | PD1-13 | Compound 12 | 3.8 | 570 | 462 | 5.3 |
| Example 10 | PH-13/ET-16 | PD1-13 | Compound 46 | 4.0 | 550 | 459 | 6.6 |
| Example 11 | PH-13/ET-16 | PD1-13 | Compound 34 | 4.0 | 565 | 458 | 7.5 |
| Comparative | PH-13/ET-16 | PD1-13 | Compound C1 | 4.2 | 430 | 457 | 1 |
| Example 1 | | | | | | | |
| Comparative | PH-13/ET-16 | PD1-13 | Compound C2 | 4.1 | 440 | 458 | 0.8 |
| Example 2 | | | | | | | |
| Comparative | PH-13/ET-16 | PD1-13 | Compound C3 | 4.1 | 455 | 458 | 0.7 |
| Example 3 | | | | | | | |
| Comparative | PH-13/ET-16 | PD1-13 | Compound C4 | 4.2 | 150 | 490 | 0.01 |
| Example 4 | | | | | | | |
| Comparative | PH-13/ET-16 | PD1-13 | Compound C5 | 4.3 | 400 | 455 | 0.1 |
| Example 5 | | | | | | | |
| Comparative | PH-13/ET-16 | PD1-13 | Compound C6 | 4.2 | 380 | 458 | 0.1 |
| Example 6 | | | | | | | |
| Comparative | PH-13/ET-16 | PD1-13 | Compound C7 | 4.7 | 350 | 464 | 0.2 |
| Example 7 | | | | | | | |
| Comparative | PH-13/ET-16 | PD1-13 | Compound C8 | 4.5 | 120 | 495 | 0.01 |
| Example 8 | | | | | | | |
| Comparative | PH-13/ET-16 | PD1-13 | Compound C9 | 4.8 | 100 | 515 | 0.01 |
| Example 9 | | | | | | | |

Referring to Table 2, in the light-emitting devices according to one or more embodiments of the present disclosure, an intramolecular electron mobility (charge transfer, CT) of the polycyclic compound was improved, thereby improving the front efficiency, and oxidation of the polycyclic compound was suppressed or reduced, thereby improving the life-span properties.

In the light-emitting devices according to Comparative Examples, the front efficiency was decreased to be 455 (cd/A/y) or less, and the life-span (T95) was evaluated to be 1 or less.

In this disclosure, it will be understood that if (e.g., when) an element (or a region, a layer, a portion, and/or the like) is referred to as being “on” or “connected to” another element, it may be directly arranged on or connected to the other element, or intervening elements may be arranged therebetween. In contrast, “directly on” may refer to that there are no additional layers, films, regions, plates, and/or the like, between a layer, a film, a region, a plate, and/or the like and the other part. For example, “directly on” may refer to two layers or two members are arranged without utilizing an additional member such as an adhesive member therebetween.

As used herein, the term “and/or” or “or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

It will be understood that, although the terms “first,” “second,” and/or the like may be used herein to describe one or more suitable elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed herein could be termed a second element, component, region, layer, or section, respectively, without departing from the scope of the disclosure. Similarly, a second element, component, region, layer, or section may be termed a first element, component, region, layer, or section, respectively. As used herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

It will be further understood that the terms “comprise(s)/comprising,” “include(s)/including,” and/or “have(has)/having,” if (e.g., when) used in this disclosure, specify the presence of stated features, integers, steps, operations, elements, components, and/or groups thereof, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting device, the display apparatus/device, the electronic apparatus/device, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the disclosure have been described, it is understood that the disclosure should not be limited to these embodiments, but one or more suitable changes and modifications can be made by one ordinary skilled in the art within the spirit and scope of disclosure as hereinafter claimed.

Accordingly, the technical scope of the disclosure is not intended to be limited to the contents set forth in the detailed description of the disclosure, but is intended to be defined by the appended claims and equivalents thereof.

What is claimed is:

1. A polycyclic compound represented by Chemical Formula 1: 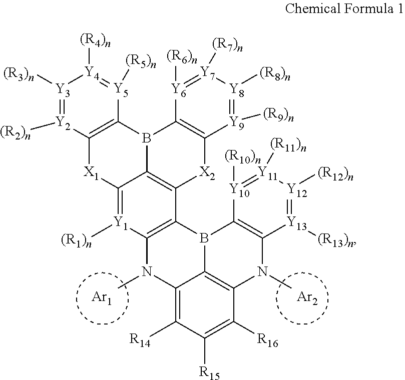
wherein, in Chemical Formula 1, X₁ and X₂ are each independently be N(R₁₇), S, O, or Se,
Y₁ to Y₁₃ are each independently C or N, R₁ to R₁₃ and R₁₇ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₆-C₆₀ condensed polycyclic group, a substituted or unsubstituted silyl group, or an electron withdrawing group, and two adjacent groups selected from among R₂ to R₁₃ are optionally bonded to each other to form a saturated ring,
the electron withdrawing group is a group having a para Hammett substituent constant (σp) according to Hammett's rule of greater than 0,
n at each occurrence is independently 0 or 1,
R₁₄ to R₁₆ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
Ar₁ and Ar₂ are each independently a substituted or unsubstituted C₆-C₆₀ aryl group or a substituted or unsubstituted C₂-C₆₀ heteroaryl group,
at least one selected from among Y₁ to Y₁₃ is N; at least one selected from among R₁ to R₁₃ and R₁₇ is an electron withdrawing group; at least one selected from among R₁ to R₁₃ and R₁₇ is a group substituted with an electron withdrawing group; at least one selected from among Y₁ to Y₁₃ is N, and at least one selected from among R₁ to R₁₃ and R₁₇ is an electron withdrawing group; at least one selected from among Y₁ to Y₁₃ is N, and at least one selected from among R₁ to R₁₃ and R₁₇ is a group substituted with an electron withdrawing group; at least one selected from among R₁ to R₁₃ and R₁₇ is an electron withdrawing group, and at least one selected from among the remainder of R₁ to R₁₃ and R₁₇ is a group substituted with an electron withdrawing group; or at least one selected from among Y₁ to Y₁₃ is N, at least one selected from among R₁ to R₁₃ and R₁₇ is an electron withdrawing group, and at least one selected from among the remainder of R₁ to R₁₃ and R₁₇ is a group substituted with an electron withdrawing group, and
when the number of the electron withdrawing group and/or the number of the group substituted with the electron withdrawing group are each two or more, then the electron withdrawing groups are the same as or different from each other, and/or the groups substituted with the electron withdrawing group are the same as or different from each other.

2. The polycyclic compound of claim 1, wherein the electron withdrawing group is selected from among —F, —Cl, —Br, —I, —CF₃, —COR₁₈, —CO₂R₁₉, —SOR₂₀, —SO₂R₂₁, —CN, —SCN, —NO₂, and a π electron-depleted nitrogen-containing C₂-C₃₀ cyclic group, and
R₁₈ to R₂₁ are each independently a substituted or unsubstituted C₁-C₃₀ alkyl group, a substituted or unsubstituted C₃-C₃₀ cycloalkyl group, or a substituted or unsubstituted C₆-C₆₀ aryl group.

3. The polycyclic compound of claim 1, wherein R₁₄ to R₁₆ are not an electron withdrawing group, and are not a group substituted with an electron withdrawing group.

4. The polycyclic compound of claim 1, wherein R₁₄ to R₁₆ are not an electron donating group, and are not a group substituted with an electron donating group, and
the electron donating group is a group having a substituent constant (σp) of Hammett's rule of less than −0.23.

5. The polycyclic compound of claim 4, wherein the electron donating group is —NH₂, —NH(R₂₂), —N(R₂₃)(R₂₄), —OR₂₅, or a π electron-rich C₃-C₃₀ cyclic group, and
R₂₂ to R₂₅ are each independently a substituted or unsubstituted C₁-C₃₀ alkyl group, a substituted or unsubstituted C₃-C₃₀ cycloalkyl group, or a substituted or unsubstituted C₆-C₆₀ aryl group.

6. The polycyclic compound of claim 1, wherein:
at least one selected from among Y₂ to Y₉ is N;
at least one selected from among R₂ to R₉ is an electron withdrawing group;
at least one selected from among R₂ to R₉ is a group substituted with an electron withdrawing group;
at least one selected from among Y₂ to Y₉ is N, and at least one selected from among R₂ to R₉ is an electron withdrawing group;
at least one selected from among Y₂ to Y₉ is N, and at least one selected from among R₂ to R₉ is a group substituted with an electron withdrawing group;
at least one selected from among R₂ to R₉ is an electron withdrawing group, and at least one selected from among the remainder of R₂ to R₉ is a group substituted with an electron withdrawing group; or
at least one selected from among Y₂ to Y₉ is N, and at least one selected from among R₂ to R₉ is an electron withdrawing group, and at least one selected from among the remainder of R₂ to R₉ is a group substituted with an electron withdrawing group.

7. The polycyclic compound of claim 1, wherein the polycyclic compound is represented by any one of Chemical Formulae 1-1 to 1-4: 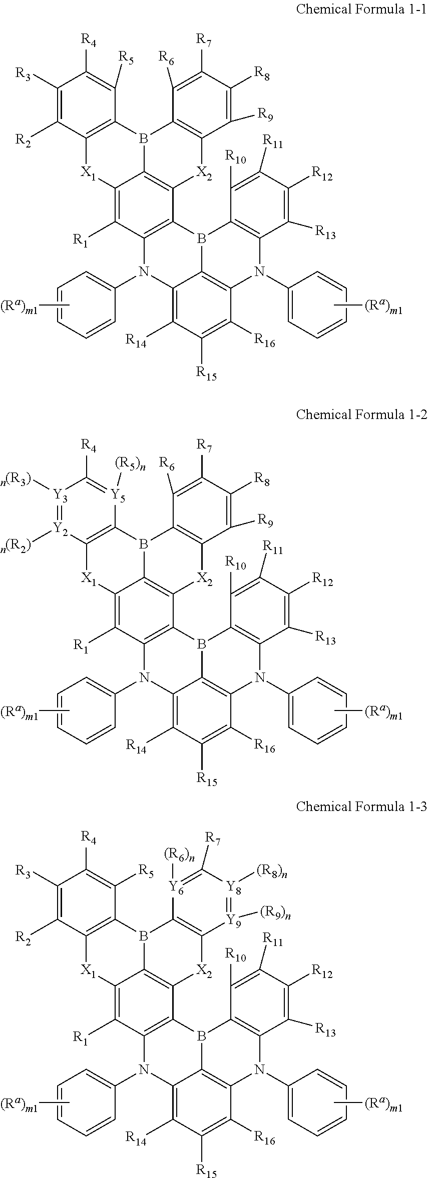 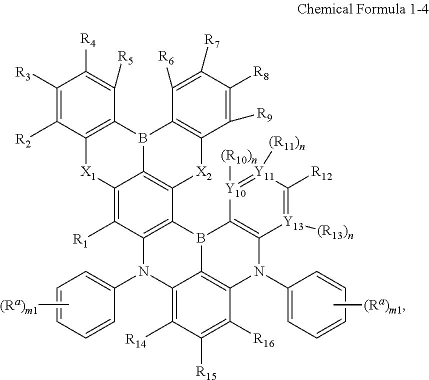
and
wherein, in Chemical Formulae 1-1 to 1-4, X₁ and X₂ are each independently N(R₁₇) or O,
Y₂, Y₃, Y₅, Y₆, Y₈, Y₉, Y₁₀, Y₁₁, and Y₁₃ are each independently C or N,
R₁ to R₁₃ and R₁₇ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted condensed polycyclic group of C₈-C₆₀, a substituted or unsubstituted silyl group, or an electron withdrawing group, and two adjacent groups selected from among R₂ to R₁₃ are not be bonded to each other,
n at each occurrence is independently 0 or 1,
R₁₄ to R₁₆ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
m1 at each occurrence is independently an integer from 0 to 5,
a single or multiple R^{a}(s) are each independently hydrogen, deuterium, a substituted or unsubstituted C₁-C₂₀ alkyl group, a substituted or unsubstituted C₂-C₂₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₆₀ aryl group, a substituted or unsubstituted C₂-C₃₀ heteroaryl group, or a substituted or unsubstituted C₈-C₃₀ condensed polycyclic group, and
when the number of R^{a}(s) is 2 or more, then two adjacent groups selected from among multiple R^{a}(s) are optionally combined with each other to form a saturated ring or an unsaturated ring.

8. The polycyclic compound of claim 1, wherein at least one selected from among R₁ to R₁₃ and R₁₇ is selected from among a group represented by any one selected from among Chemical Formulae 2-1 to 2-25: 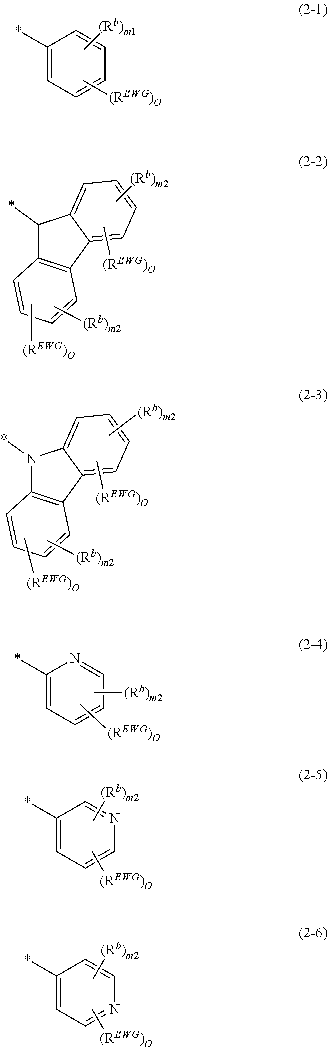 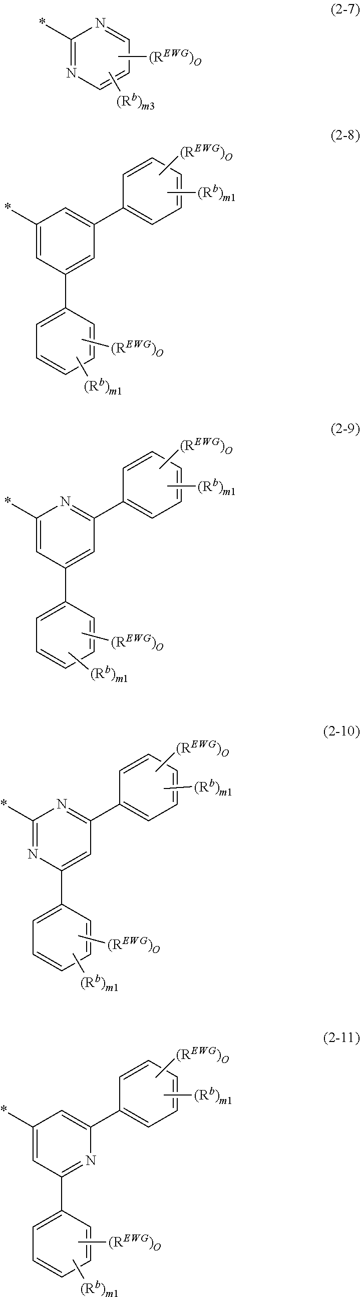 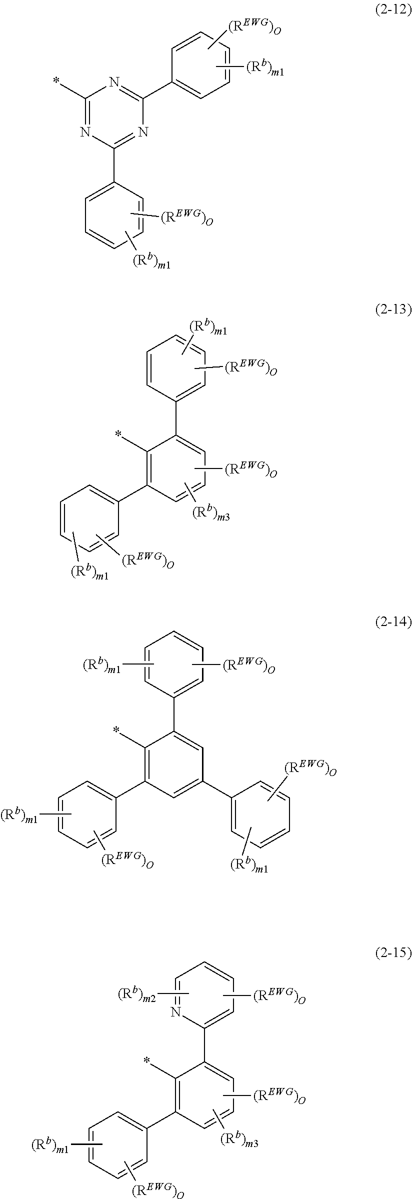 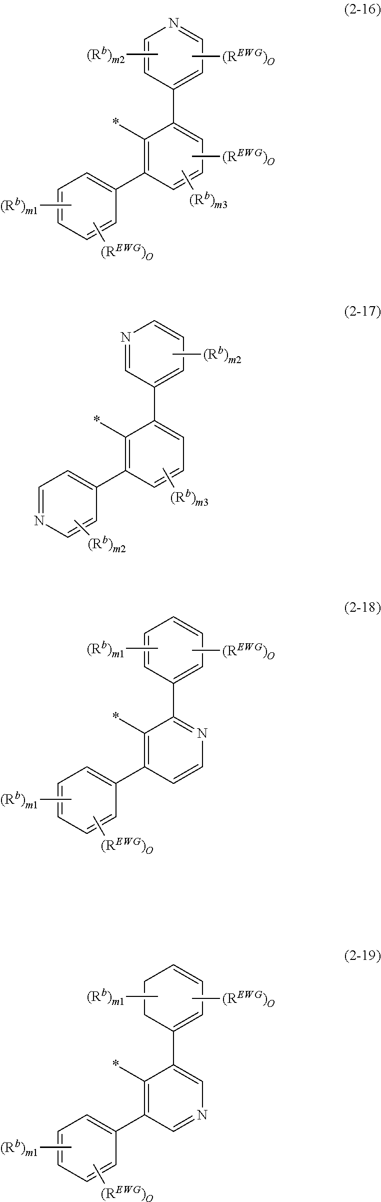 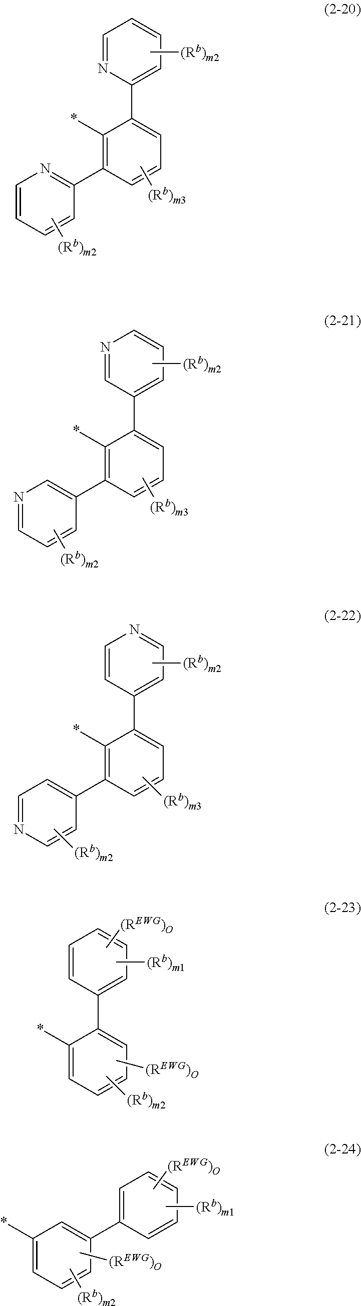 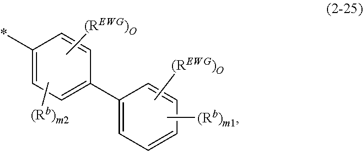
and
wherein, in Chemical Formulae 2-1 to 2-25, o at each occurrence is independently an integer from 0 to 2,
a single or plural R^{EWG}(s) are each independently selected from among —F, —Cl, —Br, —I, —CF₃, —COR₁₈, —CO₂R₁₉, —SOR₂₀, —SO₂R₂₁, —CN, —SCN, —NO₂, and a π electron-depleted nitrogen-containing C₃-C₃₀ cyclic group,
R₁₈ to R₂₁ are each independently a substituted or unsubstituted C₁-C₃₀ alkyl group, a substituted or unsubstituted C₃-C₃₀ cycloalkyl group, or a substituted or unsubstituted C₆-C₆₀ aryl group,
m1 at each occurrence is independently an integer from 0 to 5, m2 at each occurrence is independently an integer from 0 to 4, and m3 at each occurrence independently an integer from 0 to 3,
a single or multiple R^{b}(s) are each independently hydrogen, deuterium, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group, and
when the number of R^{b}(s) is 2 or more, then multiple R^{b}(s) are the same as or different from each other, and two adjacent groups selected from among the multiple R^{b}(s) are optionally combined with each other to form a saturated ring or an unsaturated ring.

9. The polycyclic compound of claim 1, wherein Ar₁ and Ar₂ are each independently a group represented by any one selected from among Chemical Formulae 3-1 to 3-12: 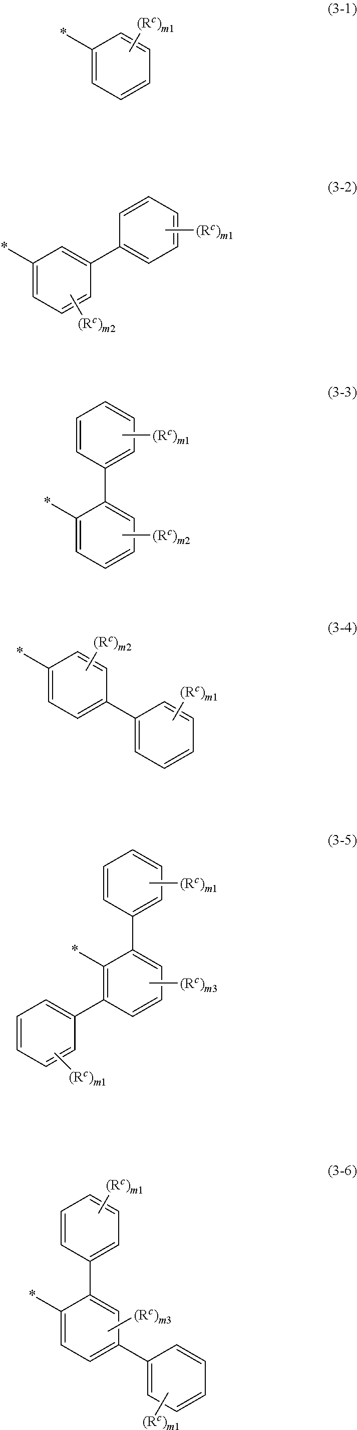 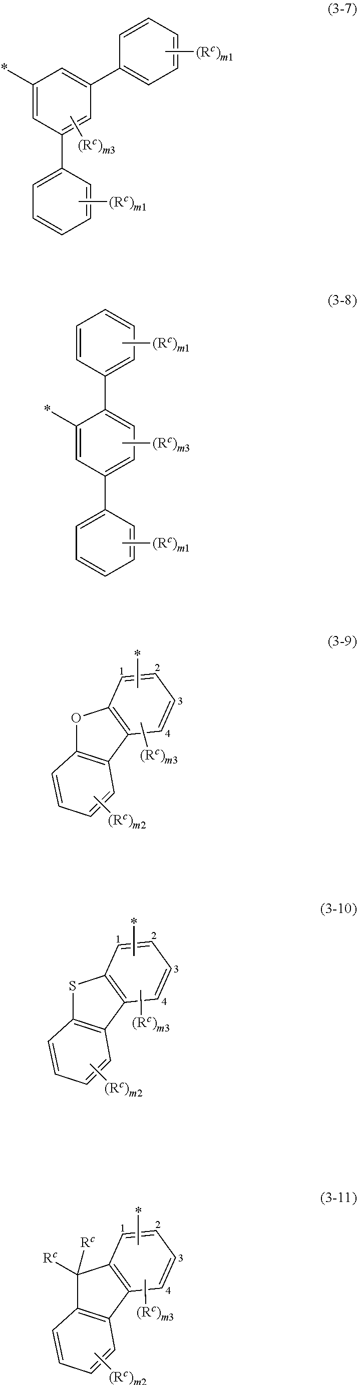 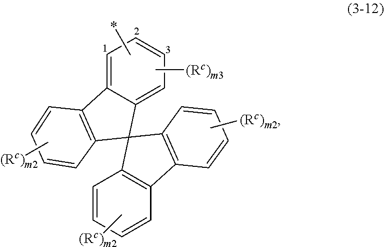
wherein, in Chemical Formulae 3-1 to 3-12, m1 at each occurrence is independently an integer from 0 to 5, m2 at each occurrence is independently an integer from 0 to 4, and m3 at each occurrence is independently an integer from 0 to 3,
a single or multiple R^{c}(s) are each independently hydrogen, deuterium, a substituted or unsubstituted C₁-C₁₀ alkyl group, a substituted or unsubstituted C₂-C₁₀ alkenyl group, a substituted or unsubstituted C₃-C₁₀ cycloalkyl group, or a substituted or unsubstituted C₆-C₁₀ aryl group,
when multiple R^{c}(s) are included, then the multiple R^{c}(s) are the same as or different from each other, and two adjacent groups selected from among the multiple R^{c}(s) are optionally combined with each other to form a saturated ring or an unsaturated ring, and
wherein, in Chemical Formulae 3-9 to 3-11, *- binding site is one of carbons designated as the numbers of 1 to 4, and *- binding site in Chemical Formula 3-12 is one of carbons designated as the numbers of 1 to 3.

10. The polycyclic compound of claim 8, wherein:
R₁₇ is a group represented by any one selected from among Chemical Formulae 2-14 to 2-25;
R₁₂ is a group represented by any one selected from among Chemical Formulae 2-2, 2-3, and 2-8 to 2-12; or
R₁₇ is a group represented by any one selected from among Chemical Formulae 2-14 to 2-25, and R₁₂ is a group represented by any one selected from among Chemical Formulae 2-2, 2-3, and 2-8 to 2-12.

11. The polycyclic compound of claim 9, wherein Ar₁ and Ar₂ are each independently a group represented by any one selected from among Chemical Formulae 3-5 to 3-12.

12. The polycyclic compound of claim 11, wherein Ar₁ and Ar₂ are each independently a group represented by Chemical Formula 3-5.

13. The polycyclic compound of claim 1, wherein the electron withdrawing group is selected from among —F, —Cl, —Br, —I, —CF₃, —COR₁₈, —CO₂R₁₉, —SOR₂₀, —SO₂R₂₁, —CN, —SCN, a substituted or unsubstituted triazine group, a substituted or unsubstituted thiazole group, a substituted or unsubstituted benzothiazole group, a substituted or unsubstituted pyrazine group, a substituted or unsubstituted pyridine group, a substituted or unsubstituted pyridazine group, a substituted or unsubstituted pyrimidine group, a substituted or unsubstituted naphthyridine group, a substituted or unsubstituted phthalazine group, a substituted or unsubstituted quinoline group, a substituted or unsubstituted quinazoline group, a substituted or unsubstituted benzocinnoline group, a substituted or unsubstituted phenanthroline group, and a substituted or unsubstituted acridine group, and
R₁₈ to R₂₁ are each independently a substituted or unsubstituted C₁-C₁₀ alkyl group, a substituted or unsubstituted C₃-C₁₀ cycloalkyl group, or a substituted or unsubstituted C₆-C₁₀ aryl group.

14. A light-emitting device, comprising:
a first electrode;
a second electrode; and
an emission layer between the first electrode and the second electrode, the emission layer comprising a polycyclic compound represented by Chemical Formula 1: 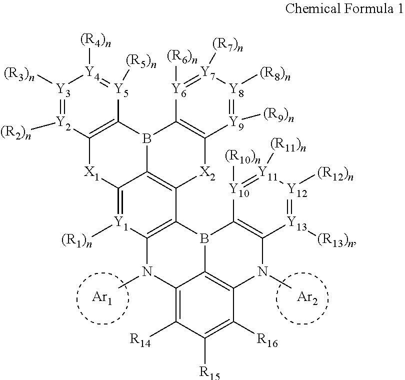
wherein, in Chemical Formula 1, X₁ and X₂ are each independently be N(R₁₇), S, O, or Se,
Y₁ to Y₁₃ are each independently be C or N,
R₁ to R₁₃ and R₁₇ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₆-C₆₀ condensed polycyclic group, a substituted or unsubstituted silyl group, or an electron withdrawing group, and two adjacent groups selected from among R₂ to R₁₃ are optionally bonded to each other to form a saturated ring,
the electron withdrawing group is a group having a para Hammett substituent constant (σp) according to Hammett's rule of greater than 0.05,
n at each occurrence is independently 0 or 1,
R₁₄ to R₁₆ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
Ar₁ and Ar₂ are each independently a substituted or unsubstituted C₆-C₆₀ aryl group or a substituted or unsubstituted C₂-C₆₀ heteroaryl group,
at least one selected from among Y₁ to Y₁₃ is N; at least one selected from among R₁ to R₁₃ and R₁₇ is an electron withdrawing group; at least one selected from among R₁ to R₁₃ and R₁₇ is a group substituted with an electron withdrawing group; at least one selected from among Y₁ to Y₁₃ is N, and at least one selected from among R₁ to R₁₃ and R₁₇ is an electron withdrawing group; at least one selected from among Y₁ to Y₁₃ is N, and at least one selected from among R₁ to R₁₃ and R₁₇ is a group substituted with an electron withdrawing group; at least one selected from among R₁ to R₁₃ and R₁₇ is an electron withdrawing group, and at least one selected from among the remainder of R₁ to R₁₃ and R₁₇ is a group substituted with an electron withdrawing group; or at least one selected from among Y₁ to Y₁₃ is N, at least one selected from among R₁ to R₁₃ and R₁₇ is an electron withdrawing group, and at least one selected from among the remainder of R₁ to R₁₃ and R₁₇ is a group substituted with an electron withdrawing group, and
when the number of the electron withdrawing group and/or the number of the group substituted with the electron withdrawing group are each two or more, then the electron withdrawing groups are the same as or different from each other, and/or the groups substituted with the electron withdrawing group are the same as or different from each other.

15. The light-emitting device of claim 14, further comprising a charge generation layer between the first electrode and the second electrode,
wherein the emission layer comprises a plurality of emission layers, and the charge generation layer is between adjacent emission layers, and
wherein at least one selected from among the plurality of emission layers comprises the polycyclic compound of Chemical Formula 1.

16. The light-emitting device of claim 14, wherein the polycyclic compound is included as a thermally activated delayed fluorescence (TADF) dopant, or a host for a phosphorescent dopant.

17. The light-emitting device of claim 14, wherein the emission layer is to emit a blue light having a maximum emission wavelength from about 440 nm to about 480 nm.

18. The light-emitting device of claim 14, wherein the polycyclic compound is represented by any one selected from among Chemical Formulae 1-1 to 1-4: 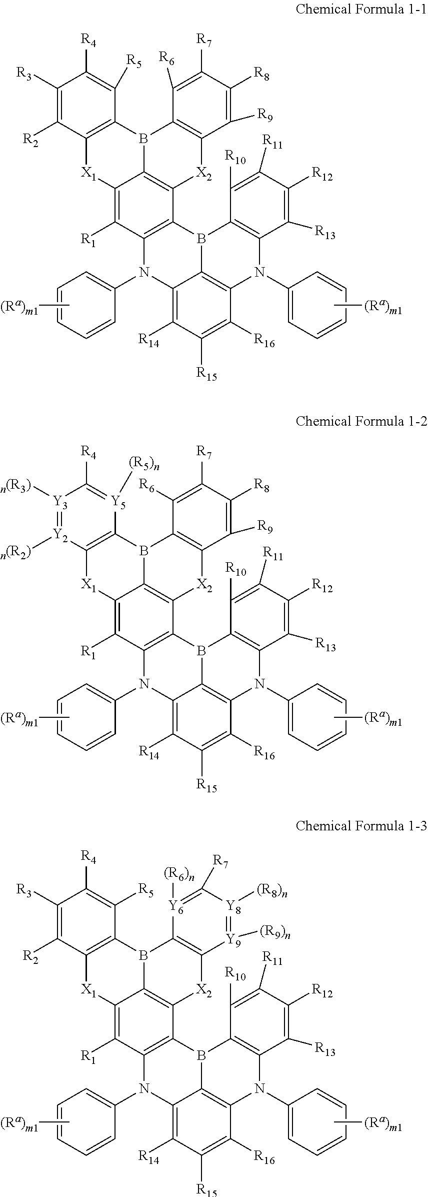 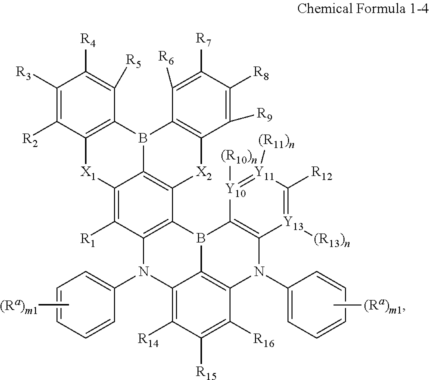
wherein, in Chemical Formulae 1-1 to 1-4, X₁ and X₂ are each independently N(R₁₇) or O,
Y₂, Y₃, Y₅, Y₆, Y₃, Y₉, Y₁o, Y₁₁, and Y₁₃ are each independently be C or N,
R₁ to R₁₃ and R₁₇ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted condensed polycyclic group of C₈-C₆₀, a substituted or unsubstituted silyl group, or an electron withdrawing group, and two adjacent groups selected from among R₂ to R₁₃ are not be bonded to each other,
n at each occurrence is independently 0 or 1,
R₁₄ to R₁₆ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
m1 at each occurrence is independently an integer from 0 to 5,
a single or multiple R^{a}(s) are each independently hydrogen, deuterium, a substituted or unsubstituted C₁-C₂₀ alkyl group, a substituted or unsubstituted C₂-C₂₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₆₀ aryl group, a substituted or unsubstituted C₂-C₃₀ heteroaryl group, or a substituted or unsubstituted C₈-C₃₀ condensed polycyclic group, and
when the number of R^{a}(s) is 2 or more, then two adjacent groups selected from among multiple R^{a}(s) are optionally combined with each other to form a saturated ring or an unsaturated ring.

19. An electronic apparatus comprising a light-emitting device, wherein:
the light-emitting device comprises:
a first electrode;
a second electrode; and
an emission layer between the first electrode and the second electrode, the emission layer comprising a polycyclic compound represented by Chemical Formula 1: 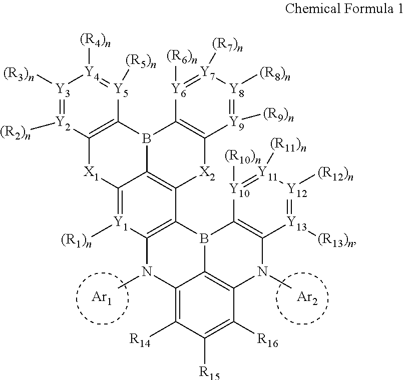
wherein, in Chemical Formula 1, X₁ and X₂ are each independently be N(R₁₇), S, O, or Se,
Y₁ to Y₁₃ are each independently be C or N,
R₁ to R₁₃ and R₁₇ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, or an electron withdrawing group, and two adjacent groups selected from among R₂ to R₁₃ are optionally bonded to each other to form a saturated ring,
the electron withdrawing group is a group having a para Hammett substituent constant (σp) according to Hammett's rule of greater than 0.05,
n at each occurrence is independently 0 or 1,
R₁₄ to R₁₆ are each independently hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group,
Ar₁ and Ar₂ are each independently a substituted or unsubstituted C₆-C₆₀ aryl group or a substituted or unsubstituted C₂-C₆₀ heteroaryl group, and
at least one selected from among Y₁ to Y₁₃ is N; at least one selected from among R₁ to R₁₃ and R₁₇ is an electron withdrawing group; at least one selected from among R₁ to R₁₃ and R₁₇ is a group substituted with an electron withdrawing group; at least one selected from among Y₁ to Y₁₃ is N, and at least one selected from among R₁ to R₁₃ and R₁₇ is an electron withdrawing group; at least one selected from among Y₁ to Y₁₃ is N, and at least one selected from among R₁ to R₁₃ and R₁₇ is a group substituted with an electron withdrawing group; at least one selected from among R₁ to R₁₃ and R₁₇ is an electron withdrawing group, and at least one selected from among the remainder of R₁ to R₁₃ and R₁₇ is a group substituted with an electron withdrawing group; or at least one selected from among Y₁ to Y₁₃ is N, at least one selected from among R₁ to R₁₃ and R₁₇ is an electron withdrawing group, and at least one selected from among the remainder of R₁ to R₁₃ and R₁₇ is a group substituted with an electron withdrawing group.

20. The electronic apparatus of claim 19, wherein the electronic apparatus is at least one of a flat panel display, a curved display, a computer monitor, a medical monitor, a television, a billboard, an indoor light, an outdoor light, a light for signaling, a head-up display, a fully transparent display, a partially transparent display, a flexible display, a rollable display, a foldable display, a stretchable display, a laser printer, a phone, a mobile phone, a tablet, a phablet, a personal information terminal, a wearable device, a laptop computer, a digital camera, a camcorder, a viewfinder, a micro display, a 3D display, a virtual reality display, an augmented reality display, a vehicle, a video wall comprising multiple displays tiled together, a theater screen, a stadium screen, a phototherapy device, or a signage.
